(19) United States
(12) Patent Application Publication
(10) Pub. No.: US 2025/0037654 A1
(43) Pub. Date: Jan. 30, 2025

(54) ELECTRONIC DEVICE

(71) Applicant: Semiconductor Energy Laboratory Co., Ltd., Atsugi-shi, Kanagawa-ken (JP)

(72) Inventors: Munehiro KOZUMA, Atsugi (JP); Tatsuya ONUKI, Atsugi (JP); Hidetomo KOBAYASHI, Isehara (JP); Yuki OKAMOTO, Ebina (JP); Shunpei YAMAZAKI, Setagaya (JP)

(21) Appl. No.: 18/697,595

(22) PCT Filed: Sep. 27, 2022
(86) PCT No.: PCT/IB2022/059151

§ 371 Date: Apr. 1, 2024

(30) Foreign Application Priority Data
Oct. 8, 2021 (JP) 2021-165925
Oct. 27, 2021 (JP) 2021-175406
Nov. 10, 2021 (JP) 2021-183622
Nov. 30, 2021 (JP) 2021-194250
Dec. 10, 2021 (JP) 2021-200812
Jun. 16, 2022 (JP) 2022-097575

(51) Int. Cl. G09G 3/3233; G06F 3/01; G06F 3/041; G09G 3/32

(52) U.S. Cl. CPC G09G 3/3233; G06F 3/013; G06F 3/041; G09G 3/32; G09G 2300/0852; G09G 2310/04; G09G 2310/08; G09G 2320/0257; G09G 2320/0261; G09G 2320/0686; G09G 2330/021; G09G 2340/0435; G09G 2354/00

(57) ABSTRACT

A novel electronic device is provided. The electronic device includes a display apparatus, an arithmetic portion, and a gaze detection portion, and the display apparatus includes a functional circuit and a display portion divided into a plurality of sub-display portions. The gaze detection portion has a function of detecting a gaze of a user. The arithmetic portion has a function of distributing each of the plurality of sub-display portions into a first section or a second section on the basis of a detection result by the gaze detection portion. The first section includes a region overlapping with a gaze point. The functional circuit has a function of making the driving frequency of the second section lower than the driving frequency of the first section. The functional circuit also has a function of making a resolution of an image displayed on the sub-display portions included in the second section lower than a resolution of an image displayed on the sub-display portions included in the first section.

### TECHNICAL FIELD

One embodiment of the present invention relates to an electronic device. One embodiment of the present invention relates to a wearable electronic device including a display apparatus.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof.

### BACKGROUND ART

In recent years, HMD (Head Mounted Display)-type electronic devices suitable for applications such as virtual reality (VR) and augmented reality (AR) have been widely used. HMDs are capable of displaying an image showing 360-degree view of the user's surroundings in accordance with the motion of the user's head or the user's gaze or operation; thus, the user can have a high sense of immersion and a high realistic sensation.

An HMD has a structure in which an optical member or the like magnifies an image displayed on a display apparatus and the user sees the magnified image. In this case, the size of a housing is liable to increase because of the presence of the optical member or the user is liable to easily see pixels and strongly sense graininess; hence, the display apparatus is required to have high definition and a smaller size. For example, Patent Document 1 discloses an HMD that includes minute pixels using transistors capable of high-speed driving.

### REFERENCE

### Patent Document

[Patent Document 1] Japanese Published Patent Application No. 2000-2856

### SUMMARY OF THE INVENTION

### Problems to be Solved by the Invention

An HMD-type electronic device needs to have a high drawing processing capability (a capability of performing high-speed arithmetic processing of image data) in accordance with the motion of a user's head and a user's gaze or operation. The power consumption tends to increase in the case where an arithmetic circuit with high drawing processing capacity arithmetically processes image data used in a display apparatus having increased definition and a reduced size. In addition, the arithmetic circuit with high drawing processing capacity necessitates a heat dissipation mechanism for cooling the arithmetic circuit, which will result in an increase in size of the electronic device.

Alternatively, drawing processing capacity of the arithmetic circuit is liable to run short in the case where a functional circuit such as an application processor for driving the display apparatus is provided in a region overlapping with a display portion and the display apparatus has increased definition and a reduced size.

An object of one embodiment of the present invention is to provide an electronic device having reduced power consumption. Another object of one embodiment of the present invention is to provide an electronic device having a reduced size and a reduced weight. Another object of one embodiment of the present invention is to provide an electronic device having superior drawing processing capacity. Another object of one embodiment of the present invention is to provide a novel electronic device.

Note that the description of these objects does not preclude the presence of other objects. In one embodiment of the present invention, there is no need to achieve all these objects. Note that objects other than these can be derived from the description of the specification, the drawings, the claims, and the like.

### Means for Solving the Problems

(1) One embodiment of the present invention is an electronic device including a display apparatus, an arithmetic portion, and a gaze detection portion; the display apparatus includes a functional circuit and a display portion divided into a plurality of sub-display portions; the gaze detection portion has a function of detecting a gaze of a user; the arithmetic portion has a function of distributing each of the plurality of sub-display portions into a first section or a second section on the basis of a detection result by the gaze detection portion; and the functional circuit has a function of making a second driving frequency which is a driving frequency of the sub-display portions included in the second section lower than a first driving frequency which is a driving frequency of the sub-display portions included in the first section.

The first section includes a region overlapping with a user's gaze point. The second section is set outside the first section. The second driving frequency is preferably lower than or equal to a half of the first driving frequency, further preferably lower than or equal to one fifth of the first driving frequency.

The sub-display portion may include a plurality of pixel circuits and a plurality of light-emitting elements. The display apparatus may include a plurality of gate driver circuits and a plurality of source driver circuits. For example, one of the plurality of gate driver circuits and one of the plurality of source driver circuits are electrically connected to one of the plurality of sub-display portions. The display apparatus may include a first layer, a second layer over the first layer, and a third layer over the second layer. For example, each of the plurality of gate driver circuits, the plurality of source driver circuits, and the functional circuit may be provided in the first layer, the plurality of pixel circuits may be provided in the second layer, and the plurality of light-emitting elements may be provided in the third layer.

(2) Another embodiment of the present invention is an electronic device including a display apparatus, an arithmetic portion, and a gaze detection portion; the display apparatus includes a functional circuit and a display portion divided into a plurality of sub-display portions; the gaze detection portion has a function of detecting a gaze of a user, the arithmetic portion has a function of distributing each of the plurality of sub-display portions into a first section or a second section on the basis of a detection result by the gaze detection portion; the functional circuit has a function of making a second driving frequency which is a driving frequency of the sub-display portions included in the second section lower than a first driving frequency which is a driving frequency of the sub-display portions included in the first section; the functional circuit includes a transistor including a first semiconductor; the plurality of sub-display portions each include a plurality of pixel circuits and a plurality of light-emitting elements, and the plurality of pixel circuits include a transistor including a second semiconductor.

In (2), the functional circuit may be provided in a first layer, the plurality of pixel circuits may be provided in a second layer over the first layer, and the plurality of light-emitting elements may be provided in a third layer over the second layer.

(3) Another embodiment of the present invention is an electronic device including a display apparatus, an arithmetic portion, and a gaze detection portion; the display apparatus includes a functional circuit and a display portion divided into a plurality of sub-display portions; the gaze detection portion has a function of detecting a gaze of a user; the arithmetic portion has a function of distributing each of the plurality of sub-display portions into a first section or a second section on the basis of a detection result by the gaze detection portion; the functional circuit has a function of making a second driving frequency which is a driving frequency of the sub-display portions included in the second section lower than a first driving frequency which is a driving frequency of the sub-display portions included in the first section; the display apparatus includes a plurality of gate driver circuits and a plurality of source driver circuits; one of the plurality of gate driver circuits and one of the plurality of source driver circuits are electrically connected to one of the plurality of sub-display portions; the plurality of gate driver circuits and the plurality of source driver circuits each include a transistor including a first semiconductor; the plurality of sub-display portions each include a plurality of pixel circuits and a plurality of light-emitting elements; and the plurality of pixel circuits each include a transistor including a second semiconductor.

In (3), the plurality of gate driver circuits and the plurality of source driver circuits may be provided in a first layer, the plurality of pixel circuits may be provided in a second layer over the first layer, and the plurality of light-emitting elements may be provided in a third layer over the second layer.

The first semiconductor may contain silicon. The second semiconductor may contain an oxide semiconductor.

Note that in the case where a transistor including the first semiconductor is provided in the first layer, the transistor including the first semiconductor is referred to as a “first layer transistor” in some cases. The first layer includes a plurality of first layer transistors. Thus, each of the plurality of gate driver circuits, the plurality of source driver circuits, the functional circuit, and the like provided in the first layer includes the first layer transistor.

In the case where a transistor including the second semiconductor is provided in the second layer, the transistor including the second semiconductor is referred to as a “second layer transistor” in some cases. The second layer includes a plurality of second layer transistors. Thus, each of the plurality of pixel circuits provided in the second layer includes the second layer transistor.

The pixel circuit may include a first transistor, a second transistor in which one of a source and a drain is electrically connected to a gate of the first transistor, and a capacitor electrically connected to the gate of the first transistor, and a channel formation region of the second transistor may include an oxide semiconductor. As the light-emitting element, an organic EL element can be used, for example.

The electronic device may include a memory device having a function of retaining image data of each of the plurality of sub-display portions.

(4) Another embodiment of the present invention is an electronic device including a display apparatus, an arithmetic portion, and a touch sensor; the display apparatus includes a functional circuit and a display portion divided into a plurality of sub-display portions; the touch sensor has a function of detecting a selected position on the display portion; the arithmetic portion has a function of distributing each of the plurality of sub-display portions into a first section or a second section on the basis of a detection result by the touch sensor; and the functional circuit has a function of making a second driving frequency which is a driving frequency of the sub-display portions included in the second section lower than a first driving frequency which is a driving frequency of the sub-display portions included in the first section.

In addition, in (1) to (4), a function of making a resolution of an image displayed on the sub-display portions included in the second section lower than a resolution of an image displayed on the sub-display portions included in the first section may be included. The emission luminance of the sub-display portions included in the second section may be lower than an emission luminance of the sub-display portions included in the first section. Moreover, a distance detection portion may be provided. The arithmetic portion may distribute the plurality of sub-display portions into the first section and the second section on the basis of a detection result by the distance detection portion.

### Effect of the Invention

According to one embodiment of the present invention, an electronic device having reduced power consumption can be provided. According to another embodiment of the present invention, an electronic device having a reduced size and a reduced weight can be provided. According to another embodiment of the present invention, an electronic device having superior drawing processing capacity can be provided. According to another embodiment of the present invention, a novel electronic device can be provided.

Note that the description of these effects does not preclude the presence of other effects. One embodiment of the present invention does not necessarily have all these effects. Note that effects other than these can be derived from the description of the specification, the drawings, the claims, and the like.

### BRIEF DESCRIPTION OF THE DRAWINGS

FIG. 1A and FIG. 1B are diagrams illustrating a structure example of an electronic device.

FIG. 2A and FIG. 2B are diagrams illustrating structure examples of an electronic device.

FIG. 3A and FIG. 3B are diagrams illustrating a structure example of a display apparatus.

FIG. 4 is a diagram illustrating a structure example of a display apparatus.

FIG. 5A to FIG. 5C are each a perspective view of a display module.

FIG. 6 is a diagram illustrating an operation example of an electronic device.

FIG. 7A and FIG. 7B are schematic diagrams illustrating a structure example of an electronic device.

FIG. 8A and FIG. 8B are schematic diagrams illustrating a structure example of an electronic device.

FIG. 9A and FIG. 9B are schematic diagrams illustrating a structure example of an electronic device.

FIG. 10A and FIG. 10B are diagrams illustrating a structure example of a display apparatus.

FIG. 11A to FIG. 11D are diagrams each illustrating an example of a pixel circuit configuration.

FIG. 12A to FIG. 12D are diagrams each illustrating an example of a pixel circuit configuration.

FIG. 13 is a timing chart illustrating a driving method of a display apparatus.

FIG. 14A is a block diagram illustrating an example of a pixel circuit configuration. FIG. 14B is a diagram illustrating an example of a pixel circuit configuration.

FIG. 15A and FIG. 15B are diagrams illustrating an operation example of a display apparatus.

FIG. 16A and FIG. 16B are diagrams illustrating a structure example of a display apparatus.

FIG. 17A to FIG. 17D are diagrams illustrating structure examples of a display apparatus.

FIG. 18A to FIG. 18C are diagrams illustrating structure examples of a display apparatus.

FIG. 19 is a block diagram illustrating a structure example of a display apparatus.

FIG. 20 is a block diagram illustrating a structure example of a display apparatus.

FIG. 21A and FIG. 21B are diagrams illustrating an application example of a display apparatus to a thin client FIG. 22A and FIG. 22B are diagrams illustrating a structure example of a display apparatus.

FIG. 23 is a diagram illustrating a structure example of a display apparatus.

FIG. 24 is a diagram illustrating a structure example of a display apparatus.

FIG. 25A is a diagram illustrating a state in which a user is using a portable information terminal.

FIG. 25B is a front view of the portable information terminal. FIG. 25C is a diagram illustrating an operation state of a display portion.

FIG. 26A is a diagram showing a state in which a user is using a portable information terminal.

FIG. 26B is a front view of the portable information terminal. FIG. 26C is a diagram illustrating an operation state of a display portion.

FIG. 27A and FIG. 27C are diagrams illustrating states in which a user is contacting a display portion. FIG. 27B and FIG. 27D are diagrams illustrating operation states of the display portion.

FIG. 28A is a diagram illustrating a sub-display portion. FIG. 28B1 to FIG. 28B7 are diagrams each illustrating a structure example of a pixel.

FIG. 29A to FIG. 29G are diagrams each illustrating a structure example of a pixel.

FIG. 30 is a diagram illustrating a display portion.

FIG. 31A and FIG. 31B are diagrams illustrating a structure example of a display apparatus.

FIG. 32A to FIG. 32D are diagrams illustrating structure examples of a light-emitting element.

FIG. 33A to FIG. 33D are diagrams illustrating structure examples of a light-emitting element.

FIG. 34A to FIG. 34D are diagrams illustrating structure examples of a light-emitting element.

FIG. 35A to FIG. 35C are diagrams illustrating structure examples of a light-emitting element.

FIG. 36 is a diagram illustrating a structure example of a display apparatus.

FIG. 37 is a diagram illustrating a structure example of a display apparatus.

FIG. 38A and FIG. 38B are diagrams each illustrating a structure example of a display apparatus.

FIG. 39A and FIG. 39B are diagrams each illustrating a structure example of the display apparatus.

FIG. 40A and FIG. 40B are diagrams each illustrating a structure example of a display apparatus.

FIG. 41 is a diagram illustrating a structure example of a display apparatus.

FIG. 42 is a diagram illustrating a structure example of a display apparatus.

FIG. 43 is a diagram illustrating a structure example of a display apparatus.

FIG. 44 is a diagram illustrating a structure example of a display apparatus.

FIG. 45A to FIG. 45C are diagrams illustrating a structure example of a transistor.

FIG. 46A to FIG. 46C are diagrams illustrating a structure example of a transistor.

FIG. 47A is a diagram showing the classification of crystal structures. FIG. 47B is a graph showing an XRD spectrum of a CAAC-IGZO film. FIG. 47C is an image showing a nanobeam electron diffraction pattern of a CAAC-IGZO film.

FIG. 48A to FIG. 48F are diagrams illustrating an example of a size of a display region of a display apparatus.

FIG. 49A to FIG. 49C are diagrams illustrating examples of the number of display apparatuses taken out of one substrate.

FIG. 50A to FIG. 50C are diagrams illustrating examples of the number of display apparatuses taken out of one substrate.

FIG. 51A to FIG. 51D are diagrams for describing Example.

FIG. 52 is a diagram for describing Example.

FIG. 53A to FIG. 53F are diagrams for describing Example.

FIG. 54A and FIG. 54B are diagrams for describing Example.

FIG. 55A to FIG. 55C are diagrams for describing Example.

FIG. 56A and FIG. 56B are schematic perspective views of a display apparatus. FIG. 56C is a diagram illustrating a pixel circuit in the display apparatus. FIG. 56D is a diagram showing Id-Vg characteristics of an OSFET.

FIG. 57 is a schematic perspective view, an optical micrograph, and a layout diagram of a display apparatus.

FIG. 58A is a photograph of an appearance of a display apparatus. FIG. 58B is a cross-sectional TEM image showing a stacked-layer structure of the display apparatus.

FIG. 59 is a schematic perspective view of a display apparatus.

FIG. 60 is a block diagram of a source driver circuit, a gate driver circuit, and the like.

FIG. 61A and FIG. 61B show images displayed on a display apparatus.

FIG. 62A and FIG. 62B show images displayed on a display apparatus.

FIG. 63A1 and FIG. 63B1 show images displayed on a display apparatus. FIG. 63A2 and FIG. 63B2 are diagrams illustrating distributions of set frame rates.

FIG. 64 is a graph showing measurement results of power consumption of AMPs.

FIG. 65 is a diagram illustrating a pixel circuit of a display apparatus.

FIG. 66 is a diagram illustrating a method for driving a pixel.

FIG. 67A to FIG. 67C are conceptual diagrams showing changes in power consumption of a normally-off processor.

FIG. 68 is a diagram showing a relation between time needed for restoration and standby power of a normally-off processor.

FIG. 69A is a layout diagram of a normally-off processor. FIG. 69B is a graph showing power consumption of the normally-off processor.

### MODE FOR CARRYING OUT THE INVENTION

Embodiments are described below with reference to the drawings. However, the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

Furthermore, unless otherwise specified, an off-state current in this specification and the like refers to a drain current of a transistor in an off state (also referred to as a non-conduction state or a cutoff state). Unless otherwise specified, an off state refers to, in an n-channel transistor, a state where a voltage V_{gs} between its gate and source is lower than a threshold voltage Vₜₕ (in a p-channel transistor, higher than Vₜₕ).

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in this specification and the like, an “OS transistor” can also be referred to as a transistor including an oxide or an oxide semiconductor. Moreover, in this specification and the like, the term “OSFET” can also be referred to as an FET (Field Effect Transistor) including an oxide or an oxide semiconductor. In some cases, an “OS transistor” can be a synonym of an “OSFET”.

### Embodiment 1

In this embodiment, an electronic device, a display apparatus, and the like according to one embodiment of the present invention will be described. The electronic device of one embodiment of the present invention can be suitably used also as a wearable electronic device for VR or AR applications, for example.

### <Structure Example of Electronic Device>

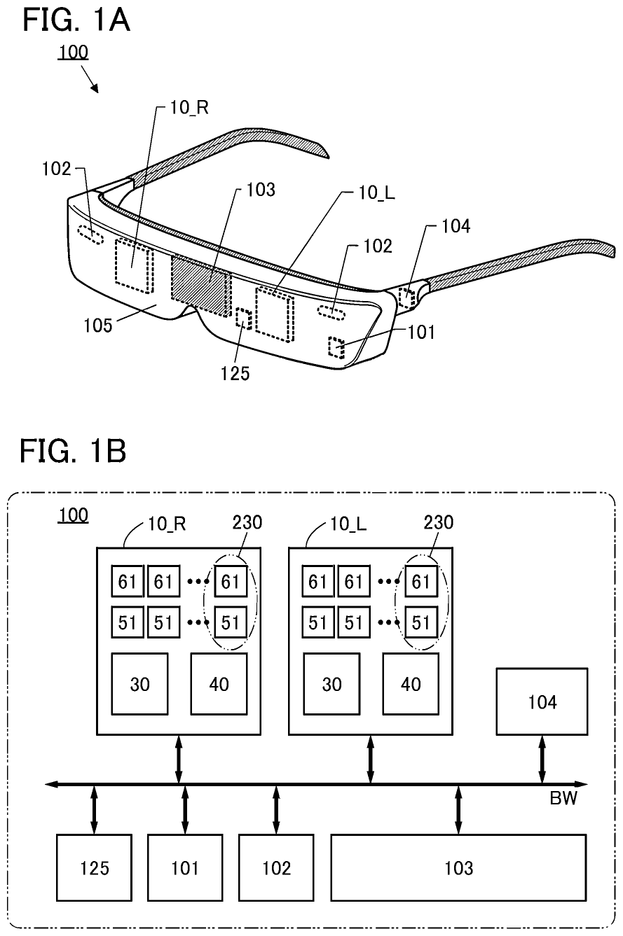

FIG. 1A is a perspective view of a glasses-type (goggle-type) electronic device 100 as an example of a wearable electronic device. FIG. 1A illustrates the electronic device 100 that includes, in a housing 105, a pair of display apparatuses 10 (a display apparatus 10_L and a display apparatus 10_R), a motion detection portion 101, gaze detection portions 102, an arithmetic portion 103, and a communication portion 104.

FIG. 1B is a block diagram of the electronic device 100 in FIG. 1A. As in FIG. 1A, the electronic device 100 includes the display apparatus 10_L, the display apparatus 10_R, the motion detection portion 101, the gaze detection portions 102, the arithmetic portion 103, and the communication portion 104, and a variety of signals are transmitted and received between these components through a bus wiring BW. Each of the display apparatus 10_L and the display apparatus 10_R includes a plurality of pixels 230, a driver circuit 30, and a functional circuit 40. One pixel 230 includes one light-emitting element 61 and one pixel circuit 51. Thus, each of the display apparatus 10_L and the display apparatus 10_R includes a plurality of light-emitting elements 61 and a plurality of pixel circuits 51.

The motion detection portion 101 has a function of detecting the motion of the housing 105, i.e., the motion of the head of the user who wears the electronic device 100. The motion detection portion 101 can include a motion sensor using a MEMS (Micro Electro Mechanical Systems) technology, for example. As the motion sensor, a three-axis motion sensor, a six-axis motion sensor, or the like can be used. Information on the motion of the housing 105 detected by the motion detection portion 101 may be referred to as first information, motion data, or the like.

The gaze detection portion 102 has a function of obtaining information regarding the user's gaze. Specifically, the gaze detection portion 102 has a function of detecting the user's gaze. The user's gaze, for example, may be obtained by a gaze measurement (eye tracking) method such as a pupil center corneal reflection method or a bright/dark pupil effect method. Alternatively, the user's gaze may be obtained by a gaze measurement method using a laser, an ultrasonic wave, or the like. Note that plurality of gaze detection portions may be provided.

The arithmetic portion 103 has a function of calculating the user's gaze point by using a gaze detection result in the gaze detection portion 102. That is, an object the user is gazing in the image being displayed on the display apparatus 10_L and the display apparatus 10_R can be found. In addition, whether or not the user is gazing at a part other than the screen can be found. Note that information regarding the user's gaze obtained by the gaze detection portion 102 (the gaze detection result) may be referred to as second information, gaze information, or the like in some cases.

The arithmetic portion 103 has a function of performing drawing processing (arithmetic process of image data) in accordance with the motion of the housing 105. The arithmetic portion 103 performs the drawing processing in accordance with the motion of the housing 105 with the use of the first information and image data that is input from the outside through the communication portion 104. As the image data, for example, a 360-degree omnidirectional image data can be used. The 360-degree omnidirectional image data is image data captured by a celestial sphere camera (an omnidirectional camera or a 360° camera), image data generated by computer graphics, or the like, for example. Specifically, the arithmetic portion 103 has a function of converting the 360-degree omnidirectional image data on the basis of the first information into image data that can be displayed on the display apparatus 10_L and the display apparatus 10_R.

The arithmetic portion 103 has a function of determining the size and shape of a plurality of regions that are set for each of the display portions of the display apparatus 10_L and the display apparatus 10_R with use of the second information. Specifically, the arithmetic portion 103 calculates a gaze point on the display portion on the basis of the second information and sets a first region S1 to a third region S3 and the like described later on the display portion with use of the gaze point as a reference.

A microprocessor such as a DSP (Digital Signal Processor), or a GPU (Graphics Processing Unit) as well as a central processing unit (CPU) can be used alone or in combination as the arithmetic portion 103. A structure may be employed in which such a microprocessor is obtained with a PLD (Programmable Logic Device) such as an FPGA (Field Programmable Gate Array) or an FPAA (Field Programmable Analog Array).

The arithmetic portion 103 interprets and executes instructions from various programs with the use of a processor to perform various kinds of data processing and program control. The programs that can be executed by the processor may be stored in a memory region included in the processor or a memory portion which is additionally provided. As the memory portion, a memory device using a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device using a volatile memory element, such as a DRAM (Dynamic RAM) and an SRAM (Static RAM); or the like may be used, for example.

The communication portion 104 has a function of communicating with an external device by wire or wirelessly to obtain a variety of data, including image data. The communication portion 104 is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), or WCDMA (Wideband Code Division Multiple Access: registered trademark), or a communication standard developed by IEEE such as Wi-Fi (registered trademark), Bluetooth (registered trademark), or ZigBee (registered trademark). The third-generation mobile communication system (3G), the fourth-generation mobile communication system (4G), or the fifth-generation mobile communication system (5G) defined by the International Telecommunication Union (ITU) or the like can be used.

The communication portion 104 may include an external port such as a LAN (Local Area Network) connection terminal, a digital broadcast-receiving terminal, or an AC adaptor connection terminal.

Each of the display apparatus 10_L and the display apparatus 10_R includes the plurality of light-emitting elements 61, the plurality of pixel circuits 51, the driver circuit 30, and the functional circuit 40. The pixel circuit 51 has a function of controlling light emission of the light-emitting element 61. The driver circuit 30 has a function of controlling the pixel circuit 51.

Information on the plurality of regions in the display portion of the display apparatus 10 determined by the arithmetic portion 103 can be used for driving such that the resolution differs from region to region. The functional circuit 40 has a function of controlling the driver circuit 30 such that the display resolution is high in a region close to a gaze point and controlling the driver circuit 30 such that the display resolution is low in a region distant from the gaze point.

For example, when rewriting of image data is performed for every other pixel or every other plurality of pixels, low display resolution can be achieved. By reducing the number of pixels that perform rewriting of image data, power consumption of the display apparatus can be reduced.

As in one embodiment of the present invention, the arithmetic portion 103 may be provided in addition to the functional circuit 40. Providing the arithmetic portion 103 makes it possible for the arithmetic portion 103 to perform heavy-load arithmetic processing such as drawing processing in accordance with the motion of the housing 105 and determining a plurality of regions described later (the first region S1 to the third region S3) in accordance with a gaze point. Meanwhile, the functional circuit 40 performs the processing of controlling the driver circuit 30, so that reductions in circuit size and power consumption can be achieved. A wearable electronic device in particular is required to detect the motion of the user's head, gaze, or the like in a short period, and thus high speed arithmetic processing is required, leading to high power consumption for an arithmetic operation. By contrast, in one embodiment of the present invention, the function of outputting a control signal for the driver circuit 30 is separated from the arithmetic portion 103 and can be performed by the functional circuit 40. This prevents concentration of load on one arithmetic portion and can reduce the load on the arithmetic portion. Thus, low power consumption as a whole can be achieved.

The electronic device 100 may be provided with a sensor 125. The sensor 125 has a function of obtaining information on one or more of the senses of sight, hearing, touch, taste, and smell of the user. Specifically, the sensor 125 has a function of sensing or measuring one or more of the following information: force, displacement, position, speed, acceleration, angular velocity, rotational frequency, distance, light, magnetism, temperature, sound, time, electric field, current, voltage, electric power, radiation, humidity, gradient, oscillation, smell, and infrared rays. The electronic device 100 may be provided with one or more sensors 125.

With use of the sensor 125, ambient temperature, humidity, illumination, odor, and the like may be measured. Furthermore, with use of the sensor 125, information for personal authentication using a fingerprint, a palm print, an iris, a retina, a shape of a blood vessel (including the shape of a vein and a shape of an artery), a face, or the like may be obtained, for example. Moreover, with use of the sensor 125, the number of blinks, eyelid behavior, pupil size, body temperature, pulse, oxygen saturation in blood, or the like of the user may be measured, so that the user's fatigue level, health condition, and the like can be detected. The electronic device 100 may sense the user's fatigue level, health condition, and the like and display an alert or the like on the display apparatus 10.

The operation of the electronic device 100 may be controlled by detecting the user's gaze and eyelid movement. Since the user does not need to touch and operate the electronic device 100, an input operation or the like can be achieved with holding nothing in both hands (in a state where both hands are free).

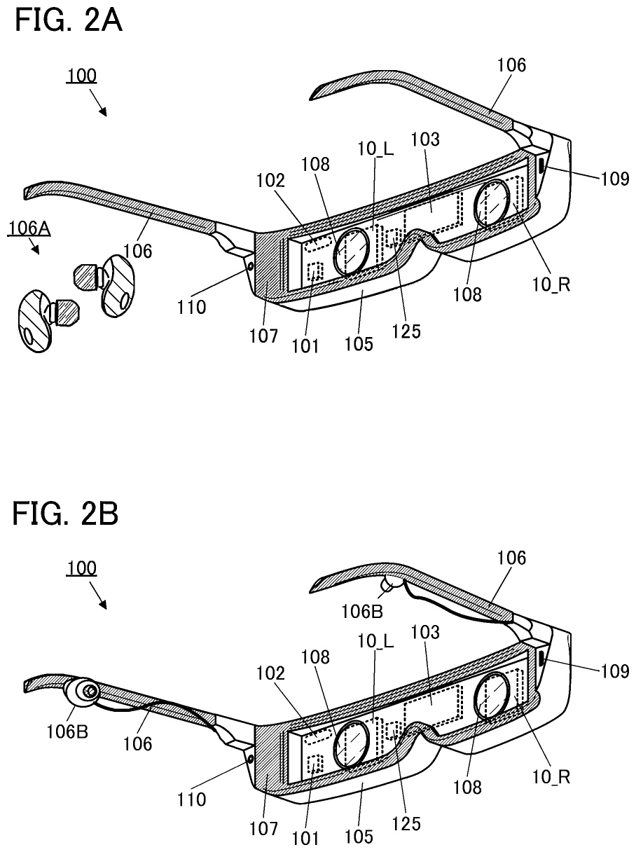

FIG. 2A is a perspective view illustrating the electronic device 100. In FIG. 2A, the housing 105 of the electronic device 100 includes therein, for example, a wearing portion 106, a cushion 107, a pair of lenses 108, and the like, in addition to the pair of the display apparatus 10_L and the display apparatus 10_R and the arithmetic portion 103. The pair of the display apparatus 10_L and the display apparatus 10_R are positioned inside the housing 105 so as to be seen through the lenses 108.

In addition, an input terminal 109 and an output terminal 110 are provided in the housing 105 illustrated in FIG. 2A. To the input terminal 109, a cable for supplying an image signal (image data) from a video output device or the like, power for charging a battery (not illustrated) provided in the housing 105, or the like can be connected. The output terminal 110 can function as, for example, an audio output terminal to which earphones, headphones, or the like can be connected.

In addition, the housing 105 preferably includes a mechanism by which the left and right positions of the lenses 108 and the display apparatus 10_L and the display apparatus 10_R can be adjusted to the optimal positions in accordance with the positions of the user's eyes. Moreover, the housing 105 preferably includes a mechanism for adjusting focus by changing the distance between the lenses 108 and the display apparatus 10_L and the display apparatus 10_R.

The cushion 107 is a portion to be in contact with the user's face (forehead, cheek, or the like). When the cushion 107 is in close contact with the user's face, external light incidence (light leakage) can be prevented, which increases the sense of immersion. A soft material is preferably used for the cushion 107 so that the cushion 107 can be in close contact with the user's face when the user wears the electronic device 100. Using such a material is preferable because it provides a soft texture and the user does not feel cold when wearing the electronic device in a cold season, for example. The member to be in contact with the user's skin, such as the cushion 107 or the wearing portion 106, is preferably detachable, in which case cleaning or replacement can be easily performed.

The electronic device of one embodiment of the present invention may further include earphones 106A. The earphones 106A include a communication portion (not illustrated) and have a wireless communication function. The earphones 106A can output audio data with the wireless communication function. The earphones 106A may include a vibration mechanism to function as bone-conduction earphones.

The earphones 106A can be connected to the wearing portion 106 directly or by wire like earphones 106B illustrated in FIG. 2B. The earphones 106B and the wearing portion 106 may each have a magnet. This is preferable because the earphones 106B can be fixed to the wearing portion 106 with magnetic force and thus can be easily housed.

### <Structure Example of Display Apparatus>

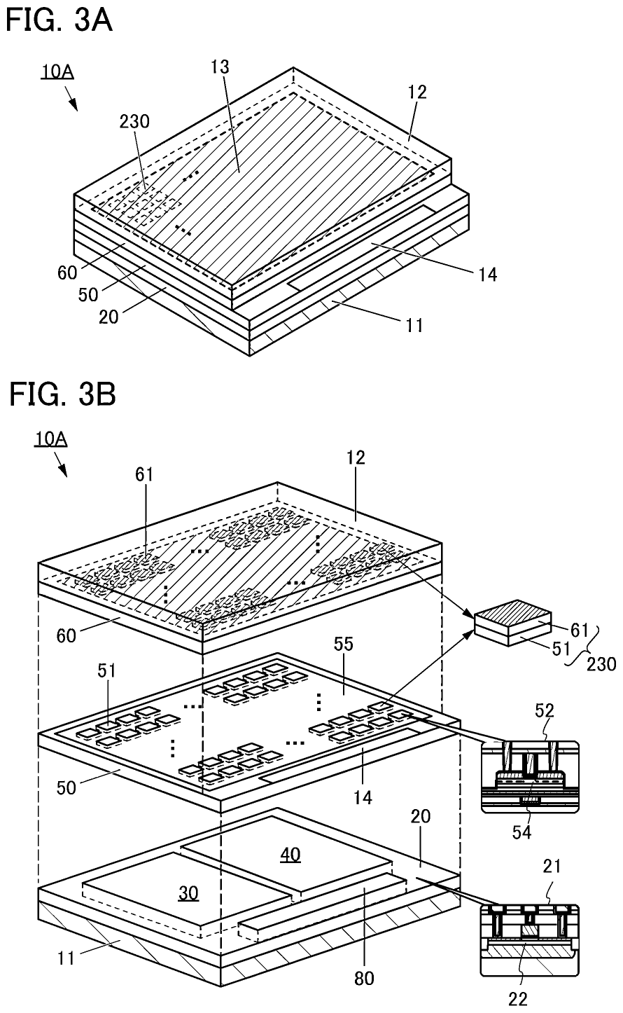

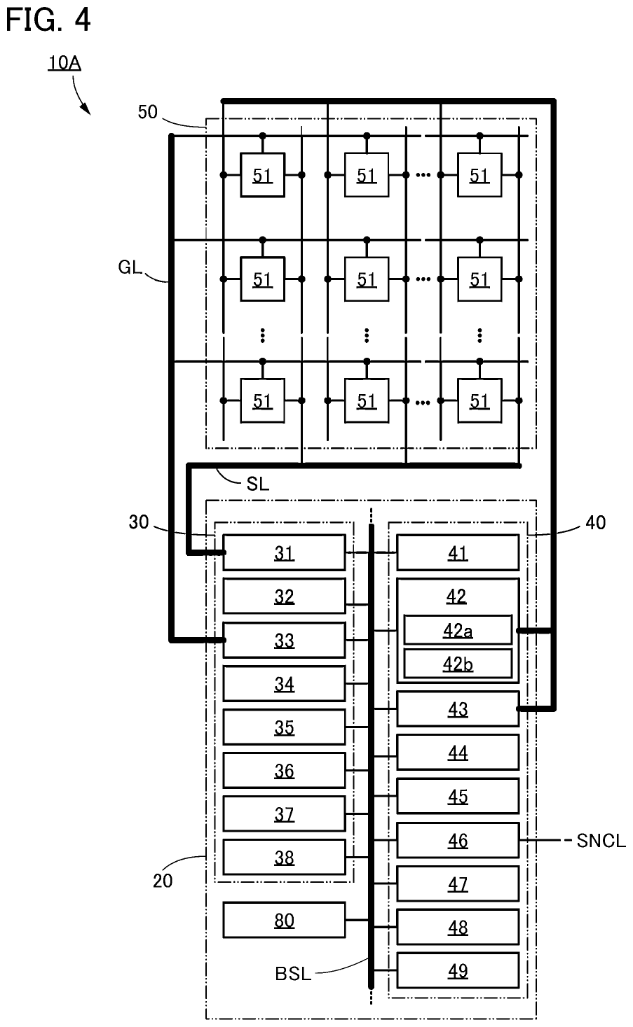

A structure of a display apparatus 10A that can be used for the display apparatus 10_L and the display apparatus 10_R illustrated in FIG. 1A and FIG. 1B will be described with reference to FIG. 3A, FIG. 3B, and FIG. 4.

FIG. 3A is a perspective view of the display apparatus 10A that can be used for the display apparatus 10_L and the display apparatus 10_R illustrated in FIG. 1A and FIG. 1B.

The display apparatus 10A includes a substrate 11 and a substrate 12. The display apparatus 10A includes a display portion 13 provided between the substrate 11 and the substrate 12. The display portion 13 includes the plurality of pixels 230. The pixels 230 each include the pixel circuit 51 and the light-emitting element 61. The display portion 13 is a region where an image is displayed in the display apparatus 10A.

By using the pixels 230 arranged in a matrix of 1920×1080 pixels, the display portion 13 can achieve display with a resolution of a so-called full hi-vision (also referred to as “2K resolution”, “2K1K”, “2K”, or the like). For example, by using the pixels 230 arranged in a matrix of 3840×2160 pixels, the display portion 13 can achieve display with a resolution of a so-called ultra hi-vision (also referred to as “4K resolution”, “4K2K”, “4K”, or the like). For example, by using the pixels 230 arranged in a matrix of 7680×4320 pixels, the display portion 13 can achieve display with a resolution of a so-called super hi-vision (also referred to as “8K resolution”, “8K4K”, “8K”, or the like). By increasing the number of pixels 230, the display portion 13 that can perform display with 16K or 32K resolution can also be obtained.

Furthermore, the pixel density (definition) of the display portion 13 is preferably higher than or equal to 1000 ppi and lower than or equal to 10000 ppi. For example, the definition may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 13. For example, the display portion 13 is compatible with a variety of screen ratios such as 1:1 (a square), 4:3, 16:9, and 16:10.

In this specification and the like, the term “element” can be replaced with the term “device” in some cases. For example, a display element, a light-emitting element, and a liquid crystal element can be rephrased as a display device, a light-emitting device, and a liquid crystal device, respectively.

Various kinds of signals and power supply potentials are input to the display apparatus 10A from the outside via a terminal portion 14, so that image display can be performed using a display element provided in the display portion 13. Any of a variety of elements can be used as the display element. Typically, a light-emitting element having a function of emitting light, such as an organic EL element or an LED element, a liquid crystal element, a MEMS (Micro Electro Mechanical Systems) element, or the like can be used.

A plurality of layers are provided between the substrate 11 and the substrate 12, and each of the layers is provided with a transistor for a circuit operation, or a display element which emits light. A pixel circuit having a function of controlling an operation of the display element, a driver circuit having a function of controlling the pixel circuit, a functional circuit having a function of controlling the driver circuit, and the like are provided in the plurality of layers.

FIG. 3B is a perspective view schematically illustrating the structures of the layers provided between the substrate 11 and the substrate 12.

A layer 20 is provided over the substrate 11. The layer 20 includes the driver circuit 30, the functional circuit 40, and an input/output circuit 80. The layer 20 includes a transistor 21 containing silicon in a channel formation region 22 (such a transistor is also referred to as a Si transistor or SiFET). The substrate 11 is, for example, a silicon substrate (a single crystal silicon substrate or a polycrystal silicon substrate). A silicon substrate is preferable because it has higher thermal conductivity than a glass substrate. By providing the driver circuit 30, the functional circuit 40, and the input/output circuit 80 in the same layer, wirings electrically connecting the driver circuit 30, the functional circuit 40, and the input/output circuit 80 can be short. As a result, charge and discharge time of a control signal used when the functional circuit 40 controls the driver circuit 30 becomes short, leading to a reduction in power consumption. In addition, charge and discharge time during which a signal is supplied from the input/output circuit 80 to the functional circuit 40 and the driver circuit 30 becomes short, leading to a reduction in power consumption.

The transistor 21 can be a transistor containing single crystal silicon in its channel formation region (also referred to as a “c-Si transistor”), for example. In particular, the use of a transistor containing single crystal silicon in a channel formation region as the transistor provided in the layer 20 can increase the on-state current of the transistor. This enables high-speed driving of circuits included in the layer 20 and is thus preferable. The Si transistor can be formed by microfabrication to have a channel length greater than or equal to 3 nm and less than or equal to 10 nm, for example; thus, a CPU, an accelerator such as a GPU, an application processor, or the like can be integrated with the display portion in the display apparatus 10A.

A transistor containing polycrystalline silicon in its channel formation region (also referred to as a “Poly-Si transistor”) may be provided in the layer 20. As the polycrystalline silicon, low-temperature polysilicon (LTPS) may be used. Note that a transistor containing LTPS in its channel formation region is also referred to as an “LTPS transistor”. An OS transistor may be provided in the layer 20 as necessary.

Any of a variety of circuits such as a shift register, a level shifter, an inverter, a latch, an analog switch, and a logic circuit can be used as the driver circuit 30. The driver circuit 30 includes a gate driver circuit, a source driver circuit, or the like, for example. In addition, an arithmetic circuit, a memory circuit, a power supply circuit, and the like may be included. Since the gate driver circuit, the source driver circuit, and other circuits can be placed to overlap with the display portion 13, the width of a non-display region (also referred to as a bezel) provided along the outer periphery of the display portion 13 of the display apparatus 10A can be extremely narrow compared with the case where these circuits and the display portion 13 are arranged side by side, whereby the display apparatus 10A can be downsized.

The functional circuit 40 has a function of an application processor for controlling the circuits in the display apparatus 10A and generating signals used for controlling the circuits, for example. The functional circuit 40 may include a CPU and a circuit used for correcting image data such as a GPU. The functional circuit 40 may include an LVDS (Low Voltage Differential Signaling) circuit, an MIPI (Mobile Industry Processor Interface) circuit, and a D/A (Digital to Analog) converter circuit, for example, having a function of an interface for receiving image data or the like from the outside of the display apparatus 10A. The functional circuit 40 may include a circuit for compressing and decompressing image data and a power supply circuit, for example.

A layer 50 is provided over the layer 20. The layer 50 includes a pixel circuit group 55 including the plurality of pixel circuits 51. An OS transistor may be provided in the layer 50. Each of the pixel circuits 51 may include an OS transistor. Note that the layer 50 can be stacked over the layer 20.

A Si transistor may be provided in the layer 50. For example, the pixel circuits 51 may each include a transistor containing single crystal silicon or polycrystalline silicon in its channel formation region. As the polycrystalline silicon, LTPS may be used. For example, the layer 50 can be formed over another substrate and bonded to the layer 20.

As another example, the pixel circuits 51 may each include a plurality of kinds of transistors using different semiconductor materials. In the case where the pixel circuits 51 each include a plurality of kinds of transistors using different semiconductor materials, the transistors may be provided in different layers for each kind of transistor. For example, in the case where the pixel circuits 51 each include a Si transistor and an OS transistor, the Si transistor and the OS transistor may be provided to overlap with each other. Providing the transistors to overlap with each other reduces the area occupied by the pixel circuits 51. Thus, the definition of the display apparatus 10A can be improved. Note that a structure in which an LTPS transistor and an OS transistor are combined is referred to as LTPO in some cases.

It is preferable to use, as the transistor 52 that is an OS transistor, a transistor including an oxide containing at least one of indium, an element M (the element M is aluminum, gallium, yttrium, or tin), and zinc in a channel formation region 54. Such an OS transistor has a characteristic of an extremely low off-state current. Thus, it is particularly preferable to use the OS transistor as a transistor provided in the pixel circuit, in which case analog data written to the pixel circuit can be retained for a long period.

A layer 60 is provided over the layer 50. Over the layer 60, the substrate 12 is provided. The substrate 12 is preferably a light-transmitting substrate or a layer formed of a light-transmitting material. The layer 60 includes the plurality of light-emitting elements 61. The layer 60 can be stacked over the layer 50. As the light-emitting element 61, an organic electroluminescent element (also referred to as an organic EL element) or the like can be used, for example. However, the light-emitting element 61 is not limited thereto, and an inorganic EL element formed of an inorganic material may be used, for example. Note that an “organic EL element” and an “inorganic EL element” are collectively referred to as “EL element” in some cases. The light-emitting element 61 may contain an inorganic compound such as quantum dots. For example, when used for a light-emitting layer, the quantum dots can function as a light-emitting material.

As shown in FIG. 3B, the display apparatus 10A of one embodiment of the present invention can have a structure in which the light-emitting elements 61, the pixel circuits 51, the driver circuit 30, and the functional circuit 40 are stacked; thus, the aperture ratio (effective display area ratio) of the pixels can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits 51 can be arranged extremely densely, and thus the definition of the pixels can be extremely high. For example, the pixels can be arranged in the display portion 13 of the display apparatus 10A (a region where the pixel circuits 51 and the light-emitting elements 61 are stacked) with a definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

The display apparatus 10A described above has an extremely high definition, and thus can be suitably used for a device for VR such as a head-mounted display or a glasses-type device for AR. For example, even in the case of a structure in which the display portion of the display apparatus 10A is seen through an optical member such as a lens, pixels of the extremely-high-definition display portion included in the display apparatus 10A are not seen when the display portion is magnified by the lens, so that display providing a high sense of immersion can be performed.

Note that in the case where the display apparatus 10A is used as a wearable display apparatus for VR or AR, the display portion 13 can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 13 may have a diagonal size of 1.5 inches or approximately 1.5 inches. When the display portion 13 has a diagonal size less than or equal to 2.0 inches, the number of times of light-exposure treatment using a light-exposure apparatus (typically, a scanner apparatus) can be one; thus, the productivity of a manufacturing process can be improved.

The display apparatus 10A according to one embodiment of the present invention can be used for an electronic device other than a wearable electronic device. In that case, the display portion 13 can have a diagonal size greater than 2.0 inches. The structure of transistors used in the pixel circuits 51 may be selected as appropriate depending on the diagonal size of the display portion 13. In the case where c-Si transistors are used in the pixel circuits 51, for example, the diagonal size of the display portion 13 is preferably greater than or equal to 0.1 inches and less than or equal to 3 inches. In the case where LTPS transistors are used in the pixel circuits 51, the diagonal size of the display portion 13 is preferably greater than or equal to 0.1 inches and less than or equal to 30 inches, further preferably greater than or equal to 1 inch and less than or equal to 30 inches. In the case where LTPO transistors are used in the pixel circuits 51, the diagonal size of the display portion 13 is preferably greater than or equal to 0.1 inches and less than or equal to 50 inches, further preferably greater than or equal to 1 inch and less than or equal to 50 inches. In the case where OS transistors are used in the pixel circuits 51, the diagonal size of the display portion 13 is preferably greater than or equal to 0.1 inches and less than or equal to 200 inches, further preferably greater than or equal to 50 inches and less than or equal to 100 inches.

A size increase of a display apparatus using c-Si transistors is extremely difficult because a size increase of a single crystal silicon substrate is difficult. Furthermore, in the case where LTPS transistors are used in a display apparatus, LTPS transistors are unlikely to respond to a size increase (typically to a screen diagonal size greater than 30 inches) since a laser crystallization apparatus is used in the manufacturing process. By contrast, since the manufacturing process does not necessarily require a laser crystallization apparatus or the like or can be performed at a relatively low process temperature (typically, lower than or equal to 450° C.), OS transistors can be used for a display apparatus with a relatively large area (typically, a diagonal size greater than or equal to 50 inches and less than or equal to 100 inches). In addition, LTPO can be applied to a diagonal size of a display portion between the case of using LTPS transistors and the case of using OS transistors (typically, greater than or equal to 1 inch and less than or equal to 50 inches).

Specific structure examples of the driver circuit 30 and the functional circuit 40 will be described with reference to FIG. 4. FIG. 4 is a block diagram illustrating a plurality of wirings connecting the pixel circuits 51, the driver circuit 30, and the functional circuit 40 in the display apparatus 10A, a bus wiring in the display apparatus 10A, and the like.

In the display apparatus 10A shown in FIG. 4, the plurality of pixel circuits 51 are arranged in a matrix in the layer 50.

Furthermore, the driver circuit 30, the functional circuit 40, and the input/output circuit 80 are provided in the layer 20 in the display apparatus 10A illustrated in FIG. 4. The driver circuit 30 includes, for example, a source driver circuit 31, a digital-analog converter (DAC) circuit 32, a gate driver circuit 33, and a level shifter 34, an amplifier circuit 35, an inspection circuit 36, a video generation circuit 37, and a video distribution circuit 38. The functional circuit 40 includes, for example, a memory device 41, a GPU 42, an EL correction circuit 43, a timing generation circuit 44, a CPU 45, a sensor controller 46, a power supply circuit 47, a temperature sensor 48, and a luminance correction circuit 49. The functional circuit 40 has a function of an application processor. The GPU 42 also functions as an AI accelerator.

The input/output circuit 80 is compatible with a transmission method such as LVDS), and the input/output circuit 80 has a function of distributing control signals, image data, and the like input via the terminal portion 14 to the driver circuit 30 and the functional circuit 40. Furthermore, the input/output circuit 80 has a function of outputting information of the display apparatus 10A to the outside via the terminal portion 14.

In the display apparatus 10A in FIG. 4, an example of a structure in which the circuits included in the driver circuit 30, the circuits included in the functional circuit 40, and the input/output circuit 80 are each electrically connected to a bus wiring BSL is illustrated.

The source driver circuit 31 has a function of transmitting image data to the pixel circuits 51 included in the pixels 230, for example. Thus, the source driver circuit 31 is electrically connected to the pixel circuits 51 through a wiring SL. Note that a plurality of source driver circuits 31 may be provided.

The digital-analog converter circuit 32 has a function of converting image data that has been digitally processed by a GPU, a correction circuit, or the like described later, into analog data, for example. The image data converted into analog data is amplified by the amplifier circuit 35 such as an operational amplifier and is transmitted to the pixel circuits 51 via the source driver circuit 31. Note that the image data may be transmitted to the source driver circuit 31, the digital-analog converter circuit 32, and the pixel circuits 51 in this order. The digital-analog converter circuit 32 and the amplifier circuit 35 may be included in the source driver circuit 31.

The gate driver circuit 33 has a function of selecting the pixel circuit to which image data is to be transmitted among the pixel circuits 51, for example. Thus, the gate driver circuit 33 is electrically connected to the pixel circuits 51 through a wiring GL. Note that a plurality of gate driver circuits 33 may be provided such that the number of the gate driver circuits 33 corresponds to the number of the source driver circuits 31.

The level shifter 34 has a function of converting signals to be input to the source driver circuit 31, the digital-analog converter circuit 32, the gate driver circuit 33, and the like into appropriate levels, for example.

The memory device 41 has a function of storing image data to be displayed by the pixel circuits 51, for example. Note that the memory device 41 can be configured to store the image data as digital data or analog data.

In the case where the memory device 41 stores image data, the memory device 41 is preferably a nonvolatile memory. In that case, a NAND memory or the like can be used as the memory device 41, for example.

In the case where the memory device 41 stores temporary data generated in the GPU 42, the EL correction circuit 43, the CPU 45, or the like, the memory device 41 is preferably a volatile memory. In that case, an SRAM, a DRAM, or the like can be used as the memory device 41, for example.

The GPU 42 has a function of performing processing for outputting, to the pixel circuits 51, image data read from the memory device 41, for example. Specifically, the GPU 42 is configured to perform pipeline processing in parallel and thus can perform high-speed processing of image data to be output to the pixel circuits 51. The GPU 42 can also have a function of a decoder for decoding an encoded image.

The functional circuit 40 may include a plurality of circuits that can improve the display quality of the display apparatus 10A. As such circuits, for example, correction (toning and dimming) circuits that detect color irregularity of a displayed image and correct the color irregularity to obtain an optimal image may be provided. In the case where a light-emitting device utilizing organic EL is used as the display element, for example, an EL correction circuit that corrects image data in accordance with the properties of the light-emitting device may be provided in the functional circuit 40. The functional circuit 40 includes, for example, the EL correction circuit 43.

The above-described image correction may be performed using artificial intelligence. For example, a current flowing in a pixel circuit (or a voltage applied to the pixel circuit) may be monitored and obtained, a displayed image may be obtained with an image sensor or the like, the current (or voltage) and the image may be used as input data in an arithmetic operation of the artificial intelligence (e.g., an artificial neural network), and the output result may be used to judge whether the image should be corrected.

Such an arithmetic operation of artificial intelligence can be applied to not only image correction but also upconversion for increasing the resolution of image data. As an example, FIG. 4 illustrates the GPU 42 that includes blocks for performing arithmetic operations for various kinds of correction (e.g., color irregularity correction 42a and upconversion 42b).

The upconversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+ method, an SRCNN (Super-Resolution Convolutional Neural Network) method, and the like.

The algorithm used for the upconversion processing may be different for each region determined in accordance with a gaze point. For example, upconversion processing for a region including the gaze point and the vicinity of the gaze point is performed using an algorithm with a low processing speed but high accuracy, and upconversion processing for a region other than the above region is performed using an algorithm with low accuracy but a high processing speed. In that case, the time required for upconversion processing can be shortened. In addition, power consumption required for upconversion processing can be reduced.

Without limitation to upconversion processing, downconversion processing for decreasing the resolution of image data may be performed. In the case where the resolution of image data is higher than the resolution of the display portion 13, part of the image data is not displayed on the display portion 13, in some cases. In that case, downconversion processing enables the entire image data to be displayed on the display portion 13.

The timing generation circuit 44 has a function of controlling driving frequency (e.g., frame frequency, frame rate, or refresh rate) for displaying an image, for example. In the case where a still image is displayed on the display apparatus 10A, for example, the driving frequency is lowered by the timing generation circuit 44, so that power consumption of the display apparatus 10A can be reduced. The driving with a lowered driving frequency for reducing power consumption of a display apparatus may be referred to as idling stop (IDS) driving.

The CPU 45 has a function of performing general-purpose processing such as execution of an operating system, control of data, and execution of various kinds of arithmetic operations and programs, for example. The CPU 45 has a role in, for example, giving an instruction for a writing operation or a reading operation of image data in the memory device 41, an operation for correcting image data, an operation for a later-described sensor, or the like. Furthermore, the CPU 45 may have a function of transmitting a control signal to at least one of the circuits included in the functional circuit 40, for example.

The sensor controller 46 has a function of controlling a sensor, for example. FIG. 4 illustrates a wiring SNCL as a wiring for electrical connection to the sensor.

The sensor can be, for example, a touch sensor that can be provided in the display portion 13. Alternatively, the sensor can be an illuminance sensor, for example.

The power supply circuit 47 has a function of generating voltages to be supplied to the pixel circuits 51, the driver circuit 30, and the functional circuit 40, for example. Note that the power supply circuit 47 may have a function of selecting a circuit to which a voltage is to be supplied. The power supply circuit 47 can stop supply of a voltage to the CPU 45, the GPU 42, and the like during a period in which a still image is displayed so that the power consumption of the whole display apparatus 10A is reduced, for example.

As described above, the display apparatus of one embodiment of the present invention can have a structure in which display elements, pixel circuits, a driver circuit, and the functional circuit 40 are stacked. The driver circuit and the functional circuit, which are peripheral circuits, can be provided so as to overlap with the pixel circuits and thus the width of the bezel can be made extremely small, so that the display apparatus can be downsized. A structure of the display apparatus of one embodiment of the present invention in which circuits are stacked enables its wirings connecting the circuits to be shortened, resulting in a reduction in weight of the display apparatus. The display apparatus of one embodiment of the present invention can include a display portion with an increased definition of pixels; thus, the display apparatus can have high display quality.

### <Structure Example of Display Module>

Next, a structure example of a display module including the display apparatus 10A will be described.

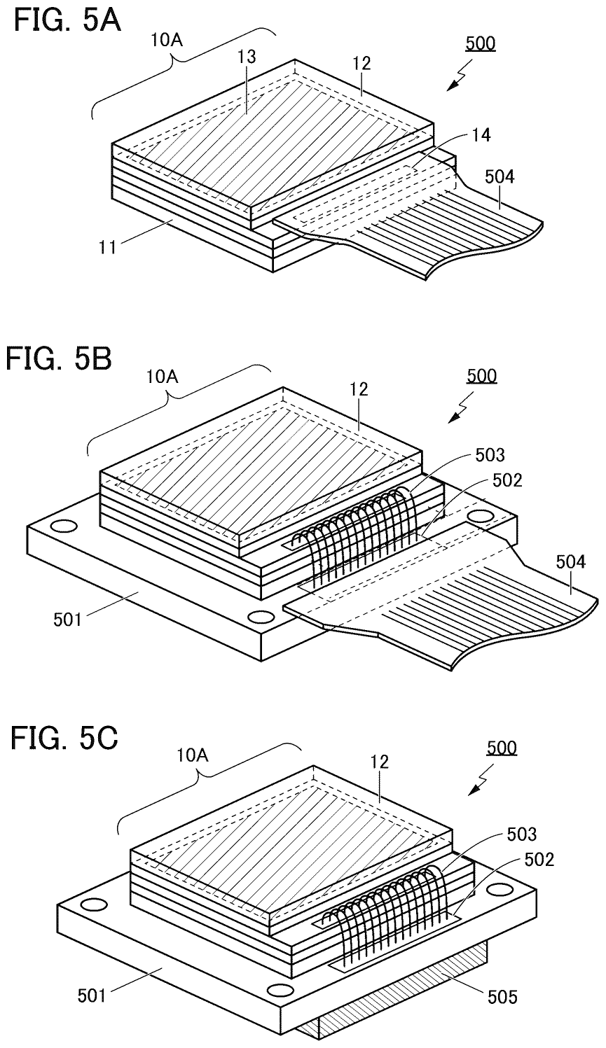

FIG. 5A to FIG. 5C are each a perspective view of a display module 500. The display module 500 has a structure in which an FPC (Flexible printed circuit) 504 is provided on the terminal portion 14 of the display apparatus 10A. The FPC 504 has a structure in which a film formed of an insulator is provided with a wiring. The FPC 504 is flexible. The FPC 504 functions as a wiring for supplying a video signal, a control signal, a power supply potential, and the like to the display apparatus 10A from the outside. An IC may be mounted on the FPC 504.

The display module 500 illustrated in FIG. 5B includes the display apparatus 10A over a printed wiring board 501. The printed wiring board 501 includes wirings inside a substrate formed of an insulator and/or on the surface of the substrate.

In the display module 500 illustrated in FIG. 5B, the terminal portion 14 of the display apparatus 10A is electrically connected to a terminal portion 502 of the printed wiring board 501 through a wire 503. The wire 503 can be formed in wire bonding. Ball bonding or wedge bonding can be used as the wire bonding.

After the wire 503 is formed, the wire 503 may be covered with a resin material or the like. Note that the display apparatus 10A and the printed wiring board 501 may be electrically connected to each other by a method other than the wire bonding. For example, the display apparatus 10A and the printed wiring board 501 may be electrically connected to each other using an anisotropic conductive adhesive, a bump, or the like.

In the display module 500 illustrated in FIG. 5B, the terminal portion 502 of the printed wiring board 501 is electrically connected to the FPC 504. In the case where the electrode pitch in the terminal portion 14 of the display apparatus 10A is different from the electrode pitch in the FPC 504, for example, the terminal portion 14 may be electrically connected to the FPC 504 via the printed wiring board 501. Specifically, the interval (pitch) between a plurality of electrodes in the terminal portion 14 can be converted into the interval between a plurality of electrodes in the terminal portion 502 using wirings formed on the printed wiring board 501. Accordingly, even when the electrode pitch in the terminal portion 14 is different from the electrode pitch in the FPC 504, electrical connection between the electrodes can be made.

The printed wiring board 501 can be provided with a variety of elements such as a resistor, a capacitor element, and a semiconductor element.

As in the display module 500 illustrated in FIG. 5C, the terminal portion 502 may be electrically connected to a connection portion 505 provided on a bottom surface (a surface where the display apparatus 10A is not provided) of the printed wiring board 501. With the use of a socket-type connection portion as the connection portion 505, for example, the display module 500 can be easily attached to and detached from another device.

### <Operation Example of Electronic Device>

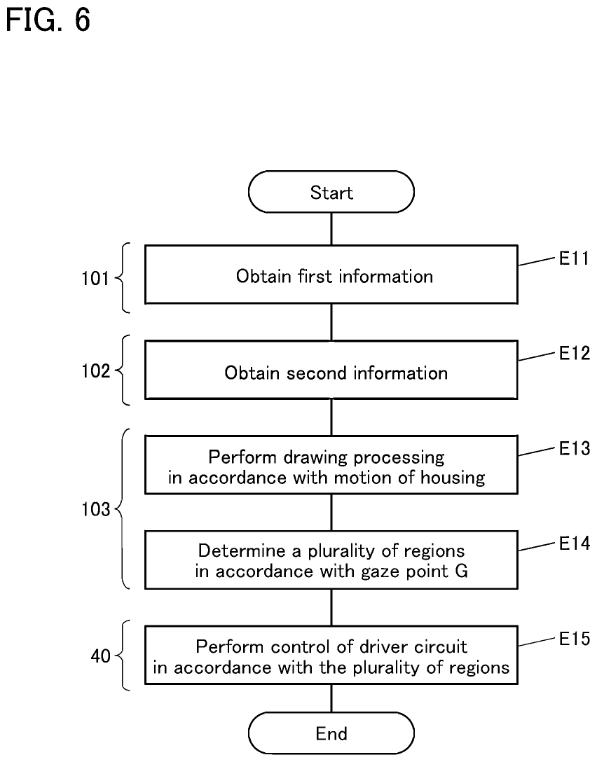

An operation example of the electronic device 100 will be described with reference to drawings. FIG. 6 is a flow chart for illustrating the operation example of the electronic device 100.

The motion detection portion 101 obtains the first information (the information on the motion of the housing 105) (Step E11).

The gaze detection portion 102 obtains the second information (the information on the user's gaze) (Step E12).

The arithmetic portion 103 performs drawing processing of 360-degree omnidirectional image data on the basis of the first information (Step E13).

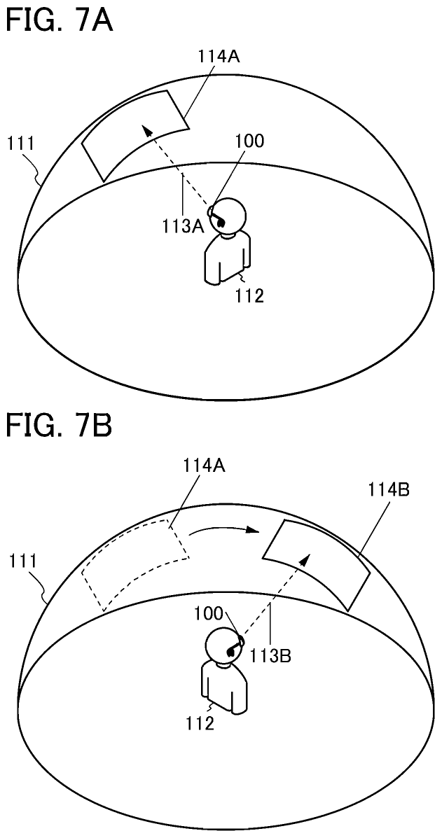

Step E13 is described by giving a specific example. The schematic view in FIG. 7A illustrates a user 112 positioned at the center of 360-degree omnidirectional image data 111. The user 112 can see an image 114A that is displayed on the display apparatus 10A of the electronic device 100 and that is in a direction 113A.

The schematic view in FIG. 7B illustrates the state where the user 112 that has been in the state of the schematic view in FIG. 7A moves his/her head to see an image 114B that is in a direction 113B. The image 114A changes into the image 114B in accordance with the motion of the housing of the electronic device 100, so that the user 112 can perceive the space expressed by the 360-degree omnidirectional image data 111.

As illustrated in FIG. 7A and FIG. 7B, the user 112 moves the housing of the electronic device 100 in accordance with the motion of his/her head. When an image obtained from the 360-degree omnidirectional image data 111 in accordance with the motion of the electronic device 100 is processed with higher drawing processing capacity, the user 112 can perceive a virtual space closer to the real world.

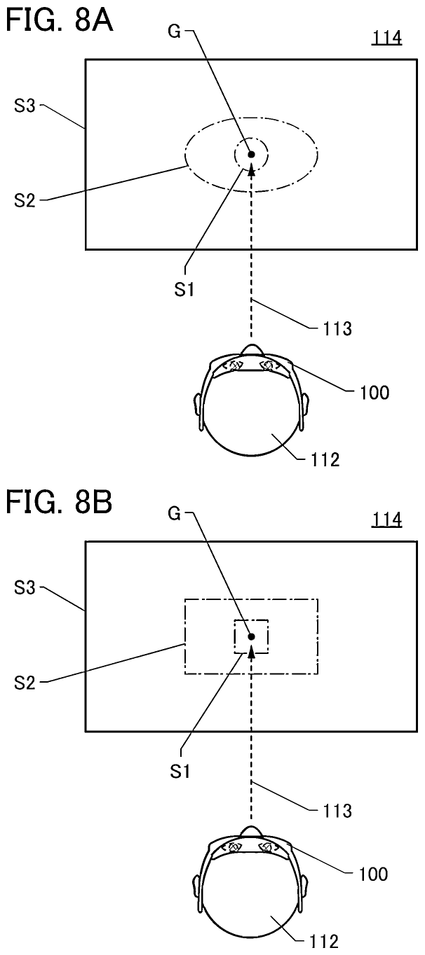

The arithmetic portion 103 determines a plurality of regions of the display portion in the display apparatus in accordance with a gaze point G based on the second information (Step E14). As illustrated in FIG. 8A, the first region S1 including the gaze point G is determined, the second region S2 adjacent to the first region S1 is determined, for example. Furthermore, the outside of the second region is the third region S3.

Step E14 is described by giving a specific example.

In general, the human visual field is roughly classified into the following five fields, although varying between individuals. The discriminating visual field refers to the region (a region including a gaze point) within approximately 5° from the center of vision, where visual performance such as eyesight and color identification is the most excellent. The effective visual field refers to the region that is horizontally within approximately 300 and vertically within approximately 200 from the center of vision (a gaze point) and adjacent to the outside of the discriminating visual field, where instant identification of particular information is possible only with an eye movement. The stable visual field refers to the region that is horizontally within approximately 90° and vertically within approximately 70° from the center of vision and adjacent to the outside of the effective visual field, where identification of particular information is possible without any difficulty with a head movement. The inducting visual field refers to the region that is horizontally within approximately 100° and vertically within approximately 85° from the center of vision and adjacent to the outside of the stable visual field, where the presence of a particular target can be sensed but the identification ability is low. The supplementary visual field refers to the region that is horizontally within approximately 100° to 200° and vertically within approximately 85° to 130° from the center of vision and adjacent to the outside of the inducting visual field, where the identification ability for a particular target is significantly low to an extent that the presence of a stimulus can be sensed.

From the above, it is found that the image quality in the discriminating visual field and the effective visual field is important in the image 114. The image quality in the discriminating visual field is particularly important.

FIG. 8A is a schematic view illustrating the state where the user 112 sees the image 114 displayed on the display portion of the display apparatus 10A of the electronic device 100 from the front (image display surface). The image 114 illustrated in FIG. 8A also corresponds to the display portion. The gaze point G in the direction of a gaze 113 of the user 112 is illustrated on the image 114. In this specification and the like, a region including the discriminating visual field and a region including the effective visual field on the image 114 are referred to as the “first region S1” and the “second region S2”, respectively. Furthermore, a region including the stable visual field, the inducting visual field, or the supplementary visual field is referred to as the “third region S3”.

Although the boundary (outline) between the first region S1 and the second region S2 is illustrated by a curved line in FIG. 8A, one embodiment of the present invention is not limited thereto. As illustrated in FIG. 8B, the boundary (outline) between the first region S1 and the second region S2 may be rectangular or polygonal. Alternatively, the boundary may have a shape in which a straight line and a curved line are combined. The display portion of the display apparatus 10A may be divided into two regions; one of the regions including the discriminating visual field and the effective visual field may be referred to as the first region S1, and the other region may be referred to as the second region S2. In this case, the third region S3 is not formed.

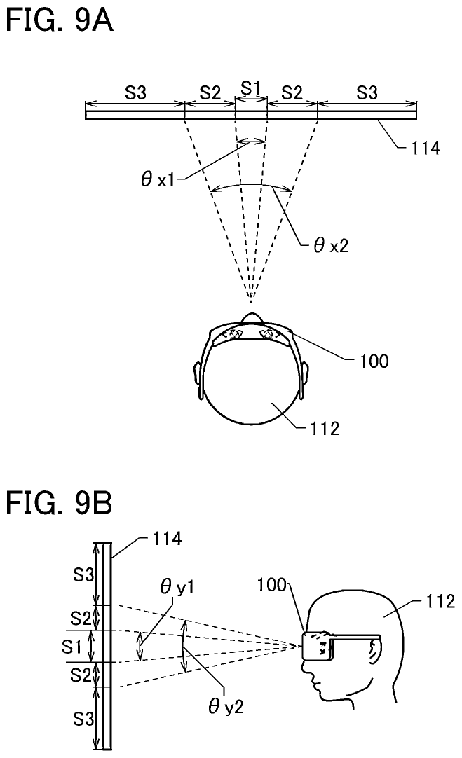

FIG. 9A is a top view of the image 114 displayed on the display portion of the display apparatus 10A of the electronic device 100, and FIG. 9B is a side view of the image 114 displayed on the display portion of the display apparatus 10A of the electronic device 100. In this specification and the like, the angle of the first region S1 in the horizontal direction is denoted by “angle θx1”, and the angle of the second region S2 in the horizontal direction is denoted by “angle θx2” (see FIG. 9A). In this specification and the like, the angle of the first region S1 in the vertical direction is denoted by “angle θy1”, and the angle of the second region S2 in the vertical direction is denoted by “angle θy2” (see FIG. 9B).

For example, by setting the angle θx1 to 10° and the angle θy1 to 10°, the area of the first region S1 can be widened. In that case, part of the effective visual field is included in the first region S1. Furthermore, by setting the angle θx2 to 45° and the angle θy2 to 350, the area of the second region S2 can be increased. In that case, part of the stable visual field is included in the second region S2.

The position of the gaze point G varies to some extent by a swing of the gaze 113. Thus, the angle θx1 and the angle θy1 are each preferably greater than or equal to 5° and smaller than 20°. When the area of the first region S1 is set larger than the discriminating visual field, the operation of the display apparatus 10A is stabilized and the image visibility is improved.

When the gaze 113 of the user 112 moves, the gaze point G also moves. Accordingly, the first region S1 and the second region S2 also move. For example, in the case where the fluctuation amount of the gaze 113 exceeds a certain value, it is judged that the gaze 113 has moved. That is, in the case where the fluctuation amount of the gaze point G exceeds a certain value, it is judged that the gaze point G has moved. Furthermore, in the case where the fluctuation amount of the gaze 113 becomes lower than or equal to the certain value, it is judged that the gaze 113 has stopped moving, and the first region S1 to the third region S3 are determined. That is, in the case where the fluctuation amount of the gaze point G becomes lower than or equal to the certain value, it is judged that the gaze point G has stopped moving, and the first region S1 to the third region S3 are determined.

The functional circuit 40 performs control of the driver circuit 30 corresponding to the plurality of regions (the first region S1 to the third region S3) (Step E15). For example, the driving frequency is adjusted so as to be suited for the plurality of regions.

### <Structure Example of Pixel Circuit>

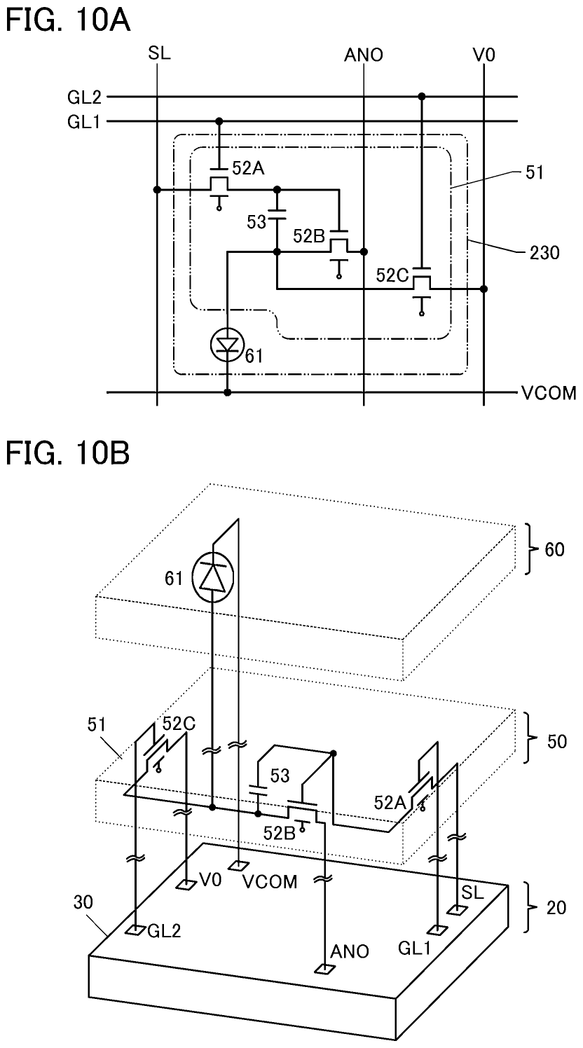

FIG. 10A and FIG. 10B illustrate a structure example of the pixel circuit 51 and the light-emitting element 61 connected to the pixel circuit 51. FIG. 10A schematically illustrates connection of the elements, and FIG. 10B schematically illustrates the vertical position relation of the layer 20 including the driver circuit, the layer 50 including a plurality of transistors of the pixel circuit, and the layer 60 including a light-emitting element.

The pixel circuit 51 illustrated as an example in FIG. 10A and FIG. 10B includes a transistor 52A, a transistor 52B, a transistor 52C, and a capacitor 53. The transistor 52A, the transistor 52B, and the transistor 52C can be OS transistors. Each of the OS transistors of the transistor 52A, the transistor 52B, and the transistor 52C preferably includes a back gate electrode, in which case the structure in which the back gate electrode is supplied with the same signals as those supplied to the gate electrode or the structure in which the back gate electrode is supplied with signals different from those supplied to the gate electrode can be used.

The transistor 52B includes the gate electrode electrically connected to the transistor 52A, a first electrode electrically connected to the light-emitting element 61, and a second electrode electrically connected to a wiring ANO. The wiring ANO is a wiring for supplying a potential for supplying a current to the light-emitting element 61.

The transistor 52A includes a first terminal electrically connected to the gate electrode of the transistor 52B, a second terminal electrically connected to the wiring SL which functions as a source line, and the gate electrode having a function of controlling the conduction state or non-conduction state on the basis of the potential of a wiring GL1 which functions as a gate line.

The transistor 52C includes a first terminal electrically connected to a wiring V0, a second terminal electrically connected to the light-emitting element 61, and the gate electrode having a function of controlling the conduction state or non-conduction state on the basis of the potential of a wiring GL2 which functions as a gate line. The wiring V0 is a wiring for supplying a reference potential and a wiring for outputting a current flowing through the pixel circuit 51 to the driver circuit 30 or the functional circuit 40.

The capacitor 53 includes a conductive film electrically connected to the gate electrode of the transistor 52B and a conductive film electrically connected to the second electrode of the transistor 52C.

The light-emitting element 61 includes a first electrode electrically connected to the first electrode of the transistor 52B and a second electrode electrically connected to a wiring VCOM. The wiring VCOM is a wiring for supplying a potential for supplying a current to the light-emitting element 61.

Accordingly, the intensity of light emitted from the light-emitting element 61 can be controlled in accordance with an image signal supplied to the gate electrode of the transistor 52B. Furthermore, variations in voltage between the gate and the source of the transistor 52B can be reduced by the reference potential of the wiring V0 supplied through the transistor 52C.

A current value that can be used for correction of a video signal can be output from the wiring V0. Specifically, the wiring V0 can function as a monitor line for outputting a current flowing through the transistor 52B or a current flowing through the light-emitting element 61 to the outside. A current output to the wiring V0 is converted into a voltage by a source follower circuit or the like and output to the outside. Alternatively, the current output to the wiring V0 can be converted into a digital signal by an A-D converter or the like and output to the functional circuit 40 or the like.

Note that the light-emitting element described in one embodiment of the present invention refers to a self-luminous display element such as an organic EL element (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

Note that in the structure illustrated as an example in FIG. 10B, the wirings electrically connecting the pixel circuit 51 and the driver circuit 30 can be shortened, so that wiring resistance of the wirings can be reduced. Thus, data can be written at high speed, which enables high-speed driving of the display apparatus 10A. Therefore, even when the number of the pixel circuits 51 included in the display apparatus 10A is increased, a sufficient frame period can be ensured, and thus, the pixel density of the display apparatus 10A can be increased. In addition, the increased pixel density of the display apparatus 10A can increase the definition of an image displayed by the display apparatus 10A. For example, the pixel density of the display apparatus 10A can be higher than or equal to 1000 ppi, higher than or equal to 5000 ppi, or higher than or equal to 7000 ppi. Thus, the display apparatus 10A can be, for example, a display apparatus for AR or VR and can be suitably used in an electronic device with a short distance between a display portion and the user, such as an HMD.

Although FIG. 10A and FIG. 10 illustrate, as an example, the pixel circuit 51 including three transistors in total, one embodiment of the present invention is not limited thereto. Structure examples and a driving method example of a pixel circuit which can be used for the pixel circuit 51 will be described below.

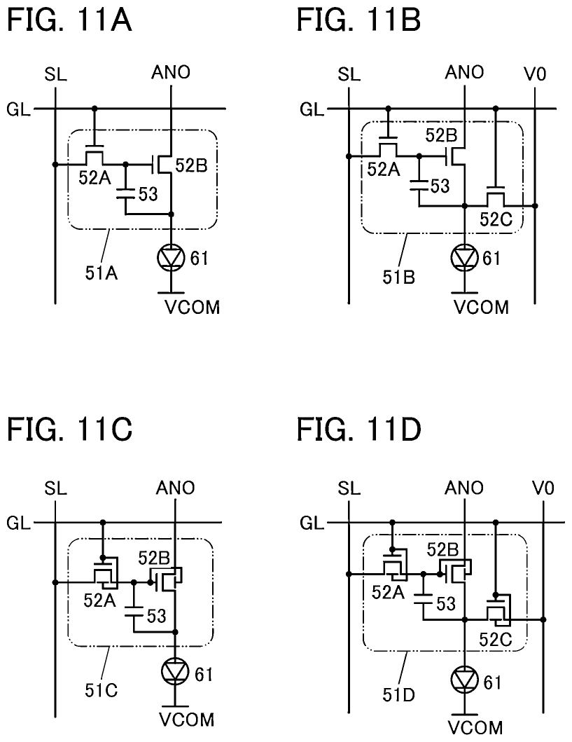

A pixel circuit 51A illustrated in FIG. 11A includes the transistor 52A, the transistor 52B, and the capacitor 53. FIG. 11A illustrates the light-emitting element 61 connected to the pixel circuit 51A. The wiring SL, the wiring GL, the wiring ANO, and the wiring VCOM are electrically connected to the pixel circuit 51A. The pixel circuit 51A has a structure in which the transistor 52C is removed from the pixel circuit 51 illustrated in FIG. 10A and the wiring GL1 and the wiring GL2 are replaced with the wiring GL.

A gate of the transistor 52A is electrically connected to the wiring GL, one of a source and a drain of the transistor 52A is electrically connected to the wiring SL, and the other of the source and the drain of the transistor 52A is electrically connected to a gate of the transistor 52B and one electrode of a capacitor C1. One of a source and a drain of the transistor 52B is electrically connected to the wiring ANO and the other of the source and the drain of the transistor 52B is electrically connected to an anode of the light-emitting element 61. The other electrode of the capacitor C1 is electrically connected to the anode of the light-emitting element 61. A cathode of the light-emitting element 61 is electrically connected to the wiring VCOM.

A pixel circuit 51B illustrated in FIG. 11B has a structure in which a transistor 52C is added to the pixel circuit 51A. In addition, the wiring V0 is electrically connected to the pixel circuit 51B.

A pixel circuit 51C illustrated in FIG. 11C is an example of the case where a transistor in which a pair of gates are electrically connected to each other is used as each of the transistor 52A and the transistor 52B of the pixel circuit 51A. A pixel circuit 51D illustrated in FIG. 11D is an example of the case where such transistors are used in the pixel circuit 51B. Thus, the current that can flow through the transistor can be increased. Note that although a transistor in which a pair of gates are electrically connected to each other is used for each of the transistors here, one embodiment of the present invention is not limited thereto. A transistor that includes a pair of gates electrically connected to different wirings may be used. When, for example, a transistor in which one of gates is electrically connected to a source is used, the reliability can be increased.

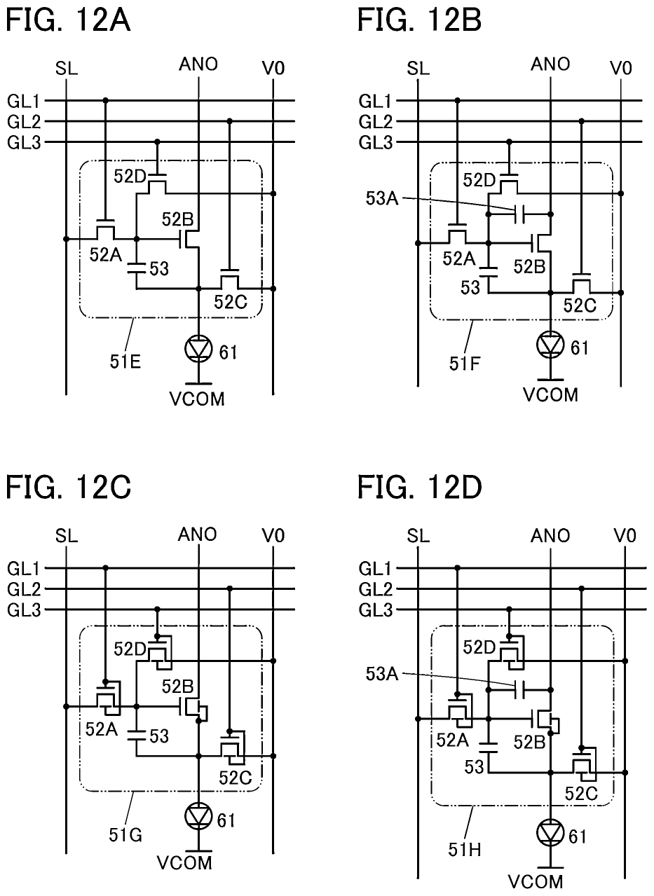

A pixel circuit 51E illustrated in FIG. 12A has a structure in which a transistor 52D is added to the pixel circuit 51B. The wiring GL1, the wiring GL2, and a wiring GL3 functioning as gate lines are electrically connected to the pixel circuit 51E. Note that in this embodiment and the like, the wiring GL1, the wiring GL2, and the wiring GL3 are collectively referred to as the wiring GL in some cases. Thus, the wiring GL is not limited to one wiring and consists of a plurality of wirings in some cases.

A gate of the transistor 52D is electrically connected to the wiring GL3, one of a source and a drain of the transistor 52D is electrically connected to the gate of the transistor 52B, and the other of the source and the drain of the transistor 52D is electrically connected to the wiring V0. The gate of the transistor 52A is electrically connected to the wiring GL1, and the gate of the transistor 52C is electrically connected to the wiring GL2.

When the transistor 52C and the transistor 52D are turned on at the same time, the source and the gate of the transistor 52B have the same potential, so that the transistor 52B can be turned off. Thus, a current flowing to the light-emitting element 61 can be blocked forcibly. Such a pixel circuit is suitable for the case of using a display method in which a display period and a non-lighting period are alternately provided.

A pixel circuit 51F illustrated in FIG. 12B is an example of the case where a capacitor 53A is added to the pixel circuit 51E. The capacitor 53A functions as a storage capacitor.

A pixel circuit 51G illustrated in FIG. 12C and a pixel circuit 51H illustrated in FIG. 12D are respectively examples of the cases where transistors each including a pair of gates are used in the pixel circuit 51E and the pixel circuit 51F. A transistor in which a pair of gates are electrically connected to each other is used as each of the transistor 52A, the transistor 52C, and the transistor 52D, and a transistor in which one of gates is electrically connected to a source is used as the transistor 52B.

Next, an example of a method for driving a display apparatus in which the pixel circuit 51E is used will be described. Note that a similar driving method can be applied to display apparatuses in which the pixel circuits 51F, 51G, and 51H are used.

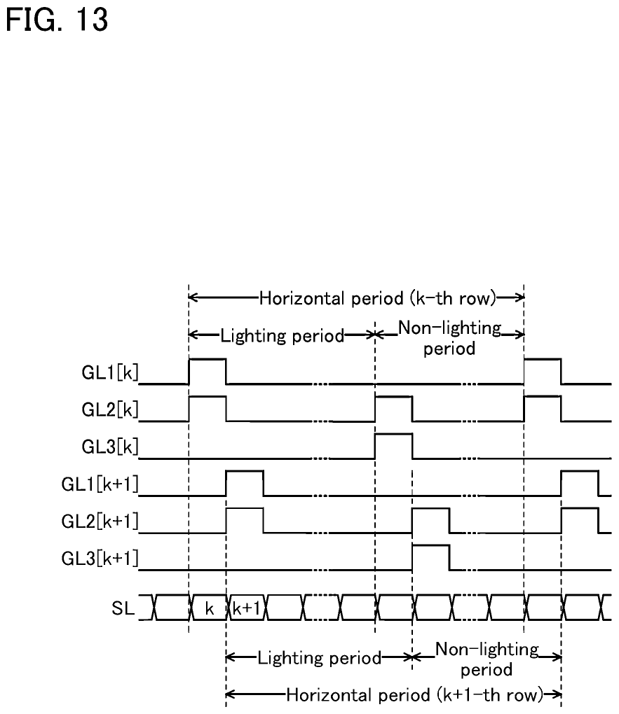

FIG. 13 is a timing chart of a method for driving the display apparatus in which the pixel circuit 51E is used. Changes in the potentials of a wiring GL1[k], a wiring GL2[k], and a wiring GL3[k] that are gate lines of the k-th row and changes in the potentials of a wiring GL1[k+1], a wiring GL2[k+1], and a wiring GL3[k+1] that are gate lines of the k+1-th row are shown here. FIG. 13 also shows the timing of supplying a signal to the wiring SL functioning as a source line.

Here, an example of the driving method in which one horizontal period is divided into a lighting period and a non-lighting period is shown. A horizontal period of the k-th row is shifted from a horizontal period of the k+1-th row by a selection period of the gate line.

In the lighting period of the k-th row, first, the wiring GL1[k] and the wiring GL2[k] are supplied with a high-level potential and the wiring SL is supplied with a source signal. Thus, the transistor 52A and the transistor 52C are brought into on states, so that a potential corresponding to the source signal is written from the wiring SL to the gate of the transistor 52B. After that, the wiring GL1[k] and the wiring GL2[k] are supplied with a low-level potential, so that the transistor 52A and the transistor 52C are brought into off states and the gate potential of the transistor 52B is retained.

Subsequently, in a lighting period of the k+1-th row, data is written by an operation similar to that described above.

Next, the non-lighting period is described. In the non-lighting period of the k-th row, the wiring GL2[k] and the wiring GL3[k] are supplied with a high-level potential. Accordingly, the transistor 52C and the transistor 52D are brought into on states, and the source and the gate of the transistor 52B are supplied with the same potential, so that almost no current flows through the transistor 52B. Thus, the light-emitting element 61 is turned off. All the subpixels that are positioned in the k-th row are turned off. The subpixels of the k-th row remain in the non-lighting state until the next lighting period.

Subsequently, in a non-lighting period of the k+1-th row, all the subpixels of the k+1-th row are in the non-lighting state in a manner similar to that described above.

Such a driving method described above, in which the subpixels are not constantly on through one horizontal period and a non-lighting period is provided in one horizontal period, can be called duty driving. With duty driving, an afterimage phenomenon can be suppressed at the time of displaying moving images; therefore, a display apparatus with high performance in displaying moving images can be provided. Particularly in a VR device and the like, a reduction in an afterimage can alleviate what is called VR sickness.

In the duty driving, the proportion of the lighting period in one horizontal period can be called a duty cycle. For example, a duty cycle of 50% means that the lighting period and the non-lighting period have the same length. Note that the duty cycle can be set freely and can be adjusted appropriately within a range higher than 0% and lower than or equal to 100%, for example.

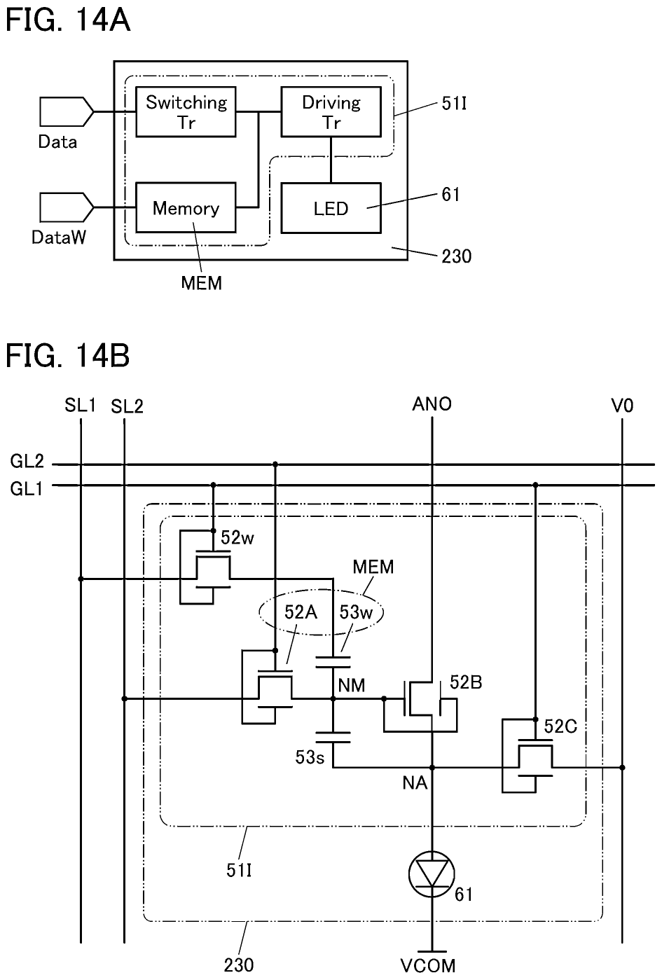

A structure different from the structures of the above-described pixel circuits will be described with reference to FIG. 14A and FIG. 14B.

FIG. 14A is a block diagram of the pixel 230. The pixel 230 includes the pixel circuit 51 and the light-emitting element (LED) 61. The pixel circuit 51I illustrated in FIG. 14A includes a switching transistor (Switching Tr), a driving transistor (Driving Tr) and a memory circuit MEM (Memory).

FIG. 14B is a specific circuit diagram of a pixel circuit 51I.

The pixel circuit 51I illustrated in FIG. 14B includes a transistor 52w, the transistor 52A, the transistor 52B, the transistor 52C, a capacitor 53s, and a capacitor 53w. FIG. 14B illustrates the light-emitting element 61 connected to the pixel circuit 51I.

Data DataW is supplied to the memory circuit MEM through a wiring SL2 and the transistor 52A. When the data DataW is supplied to the pixel in addition to image data Data, a current flowing through the light-emitting element becomes large, so that the display apparatus can exhibit high luminance.

The transistor 52w functions as a switching transistor. The transistor 52B functions as a driving transistor. One of a source and a drain of the transistor 52w is electrically connected to one electrode of the capacitor 53w. The other electrode of the capacitor 53w is electrically connected to one of the source and the drain of the transistor 52A. The one of the source and the drain of the transistor 52A is electrically connected to the gate of the transistor 52B. The gate of the transistor 52B is electrically connected to one electrode of the capacitor 53s. The other electrode of the capacitor 53s is electrically connected to one of the source and the drain of the transistor 52B. The one of the source and the drain of the transistor 52B is electrically connected to one of a source and a drain of the transistor 52C. The one of the source and the drain of the transistor 52C is electrically connected to one electrode of the light-emitting element 61. The transistors illustrated in FIG. 14B each include a back gate electrically connected to its gate; however, the connection of the back gate is not limited thereto. The transistors do not necessarily include the back gates.

Here, a node to which the other electrode of the capacitor 53w, the one of the source and the drain of the transistor 52A, the gate of the transistor 52B, and the one electrode of the capacitor 53s are connected is referred to as anode NM. Anode to which the other electrode of the capacitor 53s, the one of the source and the drain of the transistor 52B, the one of the source and the drain of the transistor 52C, and the one electrode of the light-emitting element 61 are connected is referred to as a node NA.

A gate of the transistor 52w is electrically connected to the wiring GL1. The gate of the transistor 52C is electrically connected to the wiring GL1. The gate of the transistor 52A is electrically connected to the wiring GL2. The other of the source and the drain of the transistor 52w is electrically connected to a wiring SL1. The other of the source and the drain of the transistor 52C is electrically connected to the wiring V0. The other of the source and the drain of the transistor 52A is electrically connected to a wiring SL2. Note that in this embodiment and the like, the wiring SL1 and the wiring SL2 are collectively referred to as the wiring SL in some cases. Thus, the wiring SL is not limited to one wiring and consists of a plurality of wirings in some cases.

The other of the source and the drain of the transistor 52B is electrically connected to the wiring ANO. The other electrode of the light-emitting element 61 is electrically connected to the wiring VCOM.

The wiring GL1 and the wiring GL2 can have a function of signal lines for controlling the operation of the transistors. The wiring SL1 can have a function of a signal line for supplying the image data Data to the pixel. The wiring SL2 can have a function of a signal line for writing the data DataW to the memory circuit MEM. For example, the wiring SL2 can have a function of a signal line for supplying a correction signal to the pixel. The wiring V0 has a function of a monitor line for obtaining the electrical characteristics of the transistor 52B. A specific potential is supplied from the wiring V0 to the other electrode of the capacitor 53s through the transistor 52C, whereby writing of an image signal can be stabilized.

The transistor 52A and the capacitor 53w constitute the memory circuit MEM. The node NM is a memory node; when the transistor 52A is brought into an on state, the data DataW supplied from the wiring SL2 can be written to the node NM. The use of an OS transistor with an extremely low off-state current as the transistor 52A allows the potential of the node NM to be retained for a long time.

In the pixel circuit 51I, the image data Data supplied from the wiring SL1 is supplied to the capacitor 53w through the transistor 52w. One of the source and the drain of the transistor 52w and the node NM are capacitively coupled. Thus, the potential of the node NM to which the data DataW is written changes depending on the image data Data. Furthermore, the node NA and the node NM are capacitively coupled through the capacitor 53s. Thus, the potential of the node NA changes depending on the data DataW and the image data Data.

Note that the transistor 52w functions as a selection transistor for determining whether or not the image data Data is to be supplied. The transistor 52C functions as a reset transistor for determining whether or not to set the potential of the node NA to be equal to that of the wiring V0.

The display apparatus of one embodiment of the present invention can detect an abnormal pixel using the functional circuit 40 provided to overlap with the pixel circuit group 55. Information on the abnormal pixel can be used to correct a display defect due to the abnormal pixel, leading to normal display.

Some or all of steps of a correction method described below as an example may be performed by a circuit provided outside the display apparatus. Alternatively, some of the steps of the correction method may be performed by the functional circuit 40 and the other steps may be performed by a circuit provided outside the display apparatus.

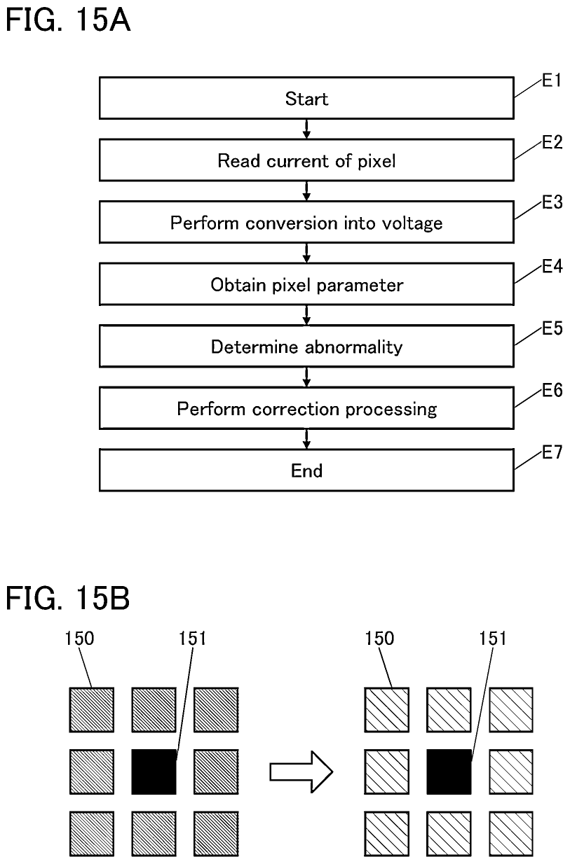

A more specific example of the correction method will be described below. FIG. 15A is a flow chart of the correction method described below.

First, a correction operation starts in Step E1.

Next, currents of the pixels are read in Step E2. For example, each of the pixels can be driven so as to output a current to a monitor line electrically connected to the pixel.

In the case where the pixel circuit group 55 is divided into a plurality of sections 59 as in a later-described display apparatus 10B or the like, current reading operations can be performed concurrently for each of the sections 59. With the pixel circuit group 55 divided into the plurality of sections 59, the time required to read currents of all pixels can be extremely short.

Then, the read currents are converted into voltages in Step E3. In the case of using a digital signal in later processing, conversion to digital data can be performed in Step E3. For example, analog data can be converted into digital data using an analog-digital converter circuit (A-D converter).

Next, pixel parameters of the pixels are obtained on the basis of the obtained data in Step E4. Examples of the pixel parameter include the threshold voltage and field-effect mobility of the driving transistor, the threshold voltage of the light-emitting element, and a current value at a certain voltage.

Subsequently, each of the pixels is determined to be abnormal or not on the basis of the pixel parameter in Step E5. For example, a pixel is determined to be abnormal when its pixel parameter has a value exceeding (or lower than) a predetermined threshold value.

Examples of the abnormal pixel include a dark spot defect with luminance significantly lower than that corresponding to an input data potential, and a bright spot defect with luminance significantly higher than that corresponding to an input data potential.

The address of the abnormal pixel and the kind of the defect can be specified and obtained in Step E5.

Then, correction processing is performed in Step E6.

An example of the correction processing is described with reference to FIG. 15B. FIG. 15B schematically illustrates 3×3 pixels each of which includes a pair of the pixel circuit 51 and the light-emitting element 61. Here, the pixel at the center is regarded as a pixel 151 having a dark spot defect. FIG. 15B schematically illustrates a state where the pixel 151 is in a non-lighting state and pixels 150 around the pixel 151 are in lighting states with predetermined luminance.

A dark spot defect is due to a pixel unlikely to have normal luminance even when correction for increasing a data potential input to the pixel is performed. Hence, correction for increasing luminance is performed on the pixels 150 around the pixel 151 that is a pixel having a dark spot defect, as illustrated in FIG. 15B. As a result, a normal image can be displayed even when a dark spot defect is caused.

In the case of a bright spot defect, the luminance of pixels around the defect is decreased, so that the bright spot defect can be less noticeable.

Such a correction method for compensating for an abnormal pixel by pixels around the abnormal pixel is effective particularly in the case of a display apparatus with a high definition (e.g., 1000 ppi or higher), in which it is difficult to see a plurality of adjacent pixels separately from each other.

It is preferable that correction be performed such that a data potential is not input to a pixel in which abnormality such as a dark spot defect or a bright spot defect has been caused.

As described above, a correction parameter can be set for each pixel. When the correction parameter is applied to image data to be input, correction image data which enables the display apparatus 10A to display an optimal image can be generated.

As well as in an abnormal pixel and pixels around the abnormal pixel, pixel parameters vary in pixels not determined to be abnormal; thus, display unevenness due to the variation might be recognized when an image is displayed, in some cases. Hence, correction parameters for the pixels not determined to be abnormal can be set so as to cancel (level off) the variation of the pixel parameters. For example, a reference value based on the mean value, average value, or the like of pixel parameters of some or all of the pixels can be set, and a correction value used for canceling a difference of a pixel parameter of a certain pixel from the reference value can be set as a correction parameter of the pixel.

For each of pixels around an abnormal pixel, it is preferable to set correction data in which both a correction amount for compensating for the abnormal pixel and a correction amount for canceling pixel parameter variation are taken into account.

Next, the correction operation ends in Step E7.

After that, an image can be displayed on the basis of the correction parameters obtained in the correction operation and image data to be input.

Note that a neural network may be used in a step of the correction operation. In the neural network, correction parameters can be determined on the basis of inference results obtained by machine learning, for example. In the case where correction parameters are determined by a neural network, for example, high-accuracy correction can be performed to make an abnormal pixel less noticeable without using a detailed algorithm for correction.

The above is the description of the correction method.

### Modification Example 1

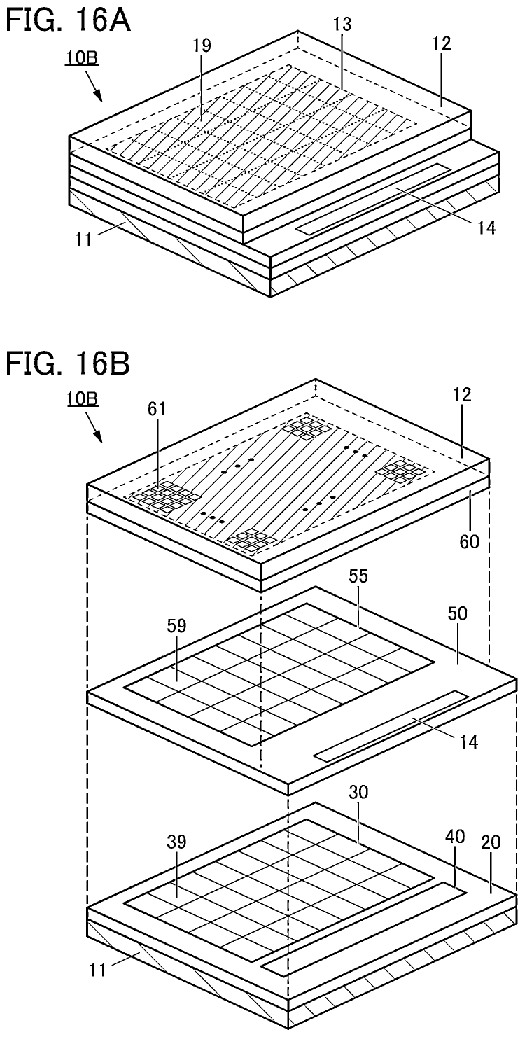

FIG. 16A and FIG. 16B are perspective views of the display apparatus 10B, which is a modification example of the display apparatus 10A. FIG. 16B is a perspective view for illustrating structures of layers included in the display apparatus 10B. Note that description is made mainly on portions different from those of the display apparatus 10A to reduce repeated description.

In the display apparatus 10B, the driver circuit 30 and the pixel circuit group 55 including the plurality of pixel circuits 51 overlap with each other. In the display apparatus 10B, the pixel circuit group 55 is divided into the plurality of sections 59 and the driver circuit 30 is divided into a plurality of sections 39. The plurality of sections 39 each include the source driver circuit 31 and the gate driver circuit 33.

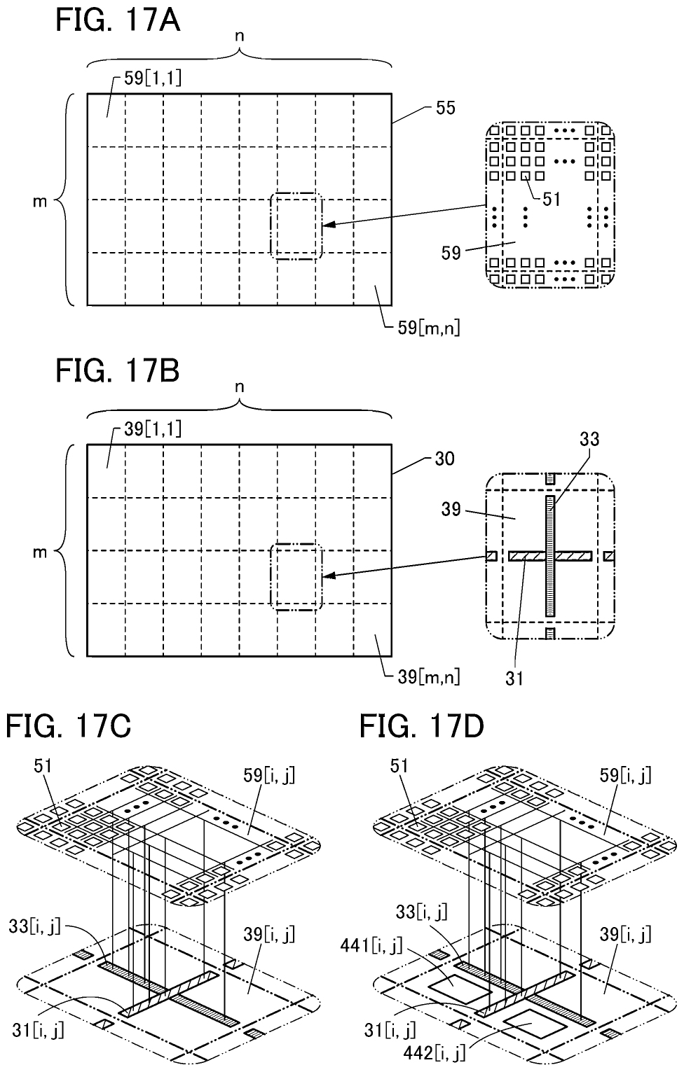

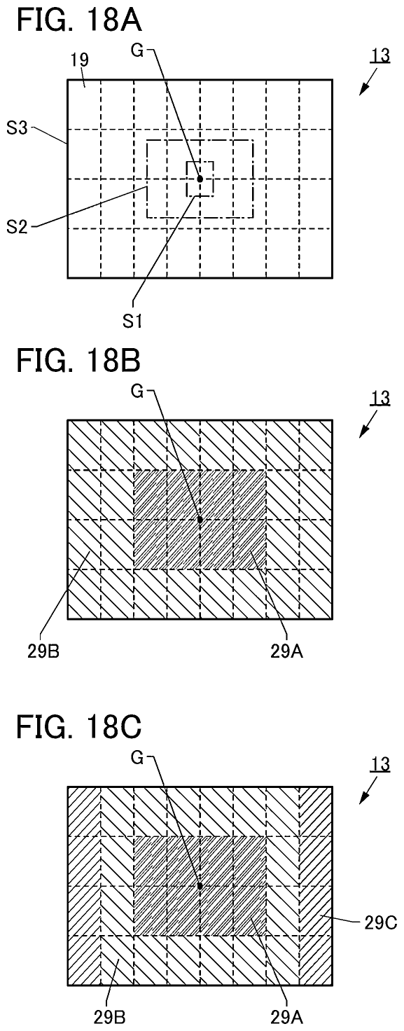

FIG. 17A illustrates a structure example of the pixel circuit group 55 included in the display apparatus 10B. FIG. 17B illustrates a structure example of the driver circuit 30 included in the display apparatus 10B. The sections 59 and the sections 39 are each arranged in a matrix of m rows and n columns (m and n are each an integer greater than or equal to 1). In this specification and the like, the section 59 in the first row and the first column is denoted by a section 59[1,1], and the section 59 in the m-th row and the n-th column is denoted by a section 59[m,n]. Similarly, the section 39 in the first row and the first column is denoted by a section 39[1,1], and the section 39 in the m-th row and the n-th column is denoted by a section 39[m,n]. FIG. 17A and FIG. 17B illustrate a case where m is 4 and n is 8. That is, the pixel circuit group 55 and the driver circuit 30 are each divided into 32 sections.

The plurality of sections 59 each include the plurality of pixel circuits 51, a plurality of wirings SL, and a plurality of wirings GL. In each of the plurality of sections 59, one of the plurality of pixel circuits 51 is electrically connected to at least one of the plurality of wirings SL and at least one of the plurality of wirings GL.

One of the sections 59 and one of the sections 39 are provided to overlap with each other (see FIG. 17C). For example, a section 59[i,j] (i is an integer greater than or equal to 1 and less than or equal to m, and j is an integer greater than or equal to 1 and less than or equal to n) and a section 39[i,j] are provided to overlap with each other. A source driver circuit 31[i,j] included in the section 39[i,j] is electrically connected to the wiring SL included in the section 59[i,j]. A gate driver circuit 33[i,j] included in the section 39[i,j] is electrically connected to the wiring GL included in the section 59[i,j]. The source driver circuit 31[i,j] and the gate driver circuit 33[i,j] have a function of controlling the plurality of pixel circuits 51 included in the section 59[i,j].

When the section 59[i,j] and the section 39[i,j] are provided to overlap with each other, a connection distance (wiring length) between the pixel circuit 51 included in the section 59[i,j] and each of the source driver circuit 31 and the gate driver circuit 33 included in the section 39[i,j] can be made extremely short. As a result, the wiring resistance and the parasitic capacitance are reduced, and thus time taken for charging and discharging can be reduced and high-speed driving can be achieved. Moreover, power consumption can be reduced. Furthermore, the size and weight of the display apparatus can be reduced.

In addition, the display apparatus 10B includes the source driver circuit 31 and the gate driver circuit 33 in each of the sections 39. Thus, the display portion 13 can be divided into the sections 59 corresponding to the sections 39, and image data rewriting can be performed. For example, in the display portion 13, image rewriting can be performed only in a section where an image has been changed and image data can be retained in a section with no change, so that power consumption can be reduced.

In this embodiment and the like, one of the sections of the display portion 13 that are divided so as to correspond to the sections 59 is referred to as a sub-display portion 19. Thus, the sub-display portion 19 is also one of the display portion 13 divided into the sections 39. The display portion 13 includes a plurality of sub-display portions 19. The display portion 13 can also be regarded as being formed of a plurality of sub-display portions 19. In the display apparatus 10B described with reference to FIG. 16 and FIG. 17, the display portion 13 is divided into 32 sub-display portions 19 (see FIG. 16A). Each of the sub-display portions 19 includes the plurality of pixels 230 illustrated in FIG. 10 and the like. Specifically, one of the sub-display portions 19 includes one of the sections 59 including the plurality of pixel circuits 51, and the plurality of light-emitting elements 61. Each of the sections 39 has a function of controlling the plurality of pixels 230 included in one sub-display portion 19.

In the display apparatus 10B, driving frequency at the time of displaying an image can be set freely for each of the sub-display portions 19 by the timing generation circuit 44 included in the functional circuit 40. The functional circuit 40 has a function of controlling operations in the plurality of sections 39 and the plurality of sections 59. In other words, the functional circuit 40 has a function of controlling driving frequency and operation timing of each of the plurality of sub-display portions 19 arranged in a matrix. In addition, the functional circuit 40 has a function of adjusting synchronization between the sub-display portions.

A timing controller 441 and an input/output circuit (an input/output circuit 442) may be provided for each of the sections 39 (see FIG. 17D). For the input/output circuit 442, an I2C (Inter-Integrated Circuit) interface can be used, for example. The timing generation circuit 441 included in the section 39[i,j] is denoted as a timing controller 441[i,j] in FIG. 17C and FIG. 17D. Furthermore, the input/output circuit 442 included the section 39[i,j] is denoted as an input/output circuit 442[i,j].

The functional circuit 40 supplies setting signals for the scan direction and driving frequency of the gate driver circuit 33[i,j] and operation parameters, such as the number of pixels in image data reduced for decreasing a resolution (the number of pixels where image data rewriting is not performed at the time of image data rewriting), to the input/output circuit 442[i,j], for example. The source driver circuit 31[i,j] and the gate driver circuit 33[i,j] operate in accordance with the operation parameters.

In the case where the sub-display portions 19 each include a light-receiving element described later, the input/output circuit 442 outputs information obtained by photoelectric conversion by the light-receiving element to the functional circuit 40.

In the display apparatus 10B in the electronic device of one embodiment of the present invention, the pixel circuit 51 and the driver circuit 30 are stacked and the driving frequency is different in each of the sub-display portions 19 in accordance with the motion of the user's gaze, whereby low power consumption can be achieved.

FIG. 18A illustrates the display portion 13 including the sub-display portions 19 in four rows and eight columns. FIG. 18A also illustrates the first region S1 to the third region S3 with the gaze point G as a center. The arithmetic portion 103 distributing each of the plurality of sub-display portions 19 to either a first section 29A overlapping with the first region S1 or the second region S2 and a second section 29B overlapping with the third region S3. In other words, the arithmetic portion 103 distributes each of the plurality of sections 39 to either the first section 29A or the second section 29B. In this case, the first section 29A overlapping with the first region S1 or the second region S2 includes a region overlapping with the gaze point G. Furthermore, the second section 29B includes the sub-display portions 19 positioned outside the first section 29A (see FIG. 18B).

The operations of the driver circuits (the source driver circuit 31 and the gate driver circuit 33) included in each of the plurality of sections 39 are controlled by the functional circuit 40. For example, the second section 29B is a section overlapping with the third region S3 including the above-described stable visual field, inducting visual field, and supplementary visual field, and is hard for the user to discriminate. Thus, the user perceives a small reduction in practical display quality (hereinafter also referred to as “practical display quality”) even when the number of times of image data rewriting per unit time (hereinafter also referred to as “image rewriting frequency”) at the time of displaying an image is smaller in the second section 29B than in the first section 29A. In other words, a reduction in practical display quality is small even when driving frequency of the sub-display portion 19 included in the second section 29B (also referred to as “second driving frequency”) is lower than driving frequency of the sub-display portions 19 included in the first section 29A (also referred to as “first driving frequency”).

A decrease in the driving frequency can result in a reduction in power consumption of the display apparatus. On the other hand, a decrease in the driving frequency reduces the display quality. In particular, the display quality in displaying a moving image is reduced. According to one embodiment of the present invention, the second driving frequency is made lower than the first driving frequency; thus, power consumption can be reduced in a section where the visibility by the user is low and the reduction of the practical display quality can be suppressed. According to one embodiment of the present invention, both display quality maintenance and a reduction in power consumption can be achieved.

The first driving frequency can be higher than or equal to 30 Hz and lower than or equal to 500 Hz, preferably higher than or equal to 60 Hz and lower than or equal to 500 Hz. The second driving frequency is preferably lower than or equal to the first driving frequency, further preferably lower than or equal to a half of the first driving frequency, still further preferably lower than or equal to one fifth of the first driving frequency.

A section of the sub-display portions 19 overlapping with the third region S3 that is farther from the first section 29A may be set as a third section 29C (see FIG. 18C), and driving frequency of the sub-display portions 19 included in the third section 29C (also referred to as “third driving frequency”) may be made lower than the driving frequency in the second section 29B. The third driving frequency is preferably lower than or equal to the second driving frequency, further preferably lower than or equal to a half of the second driving frequency, still further preferably lower than or equal to one fifth of the second driving frequency. By significantly lowering the image rewriting frequency, power consumption can be further reduced. Note that rewriting of image data may be stopped if necessary. By stopping rewriting of image data, power consumption can be further reduced.

In the case where such a driving method is employed, a transistor with an extremely low off-state current is suitably used as a transistor included in the pixel circuit 51. For example, an OS transistor is suitably used as the transistor included in the pixel circuit 51. An OS transistor has an extremely low off-state current and thus can achieve long-term retention of image data supplied to the pixel circuit 51. It is particularly suitable to use an OS transistor as the transistor 52A.

In some cases, an image whose brightness, contrast, color tone, or the like is greatly different from that of the previous image is displayed as in the case where a video scene displayed on the display portion 13 is changed, for example. Such a case causes a mismatch of the timing at which an image is changed between the first section 29A and a section whose driving frequency is lower than that of the first section 29A. This might cause a great difference in the brightness, contrast, color tone, or the like between the sections, leading to the loss of the practical display quality. In such a case where a video scene is changed, image data rewriting can be performed in the sections other than the first section 29A at a driving frequency which is the same as that of the first section 29A once, and then the driving frequency of the sections other than the first section 29A can be decreased.

Furthermore, in the case where the fluctuation amount of the gaze point G is judged to be exceeding a certain value, image data rewriting may be performed in the sections other than the first section 29A at a driving frequency which is the same as that of the first section 29A, and in the case where the fluctuation amount is judged to be within the certain value, the driving frequency of the sections other than the first section 29A may be decreased. In the case where the fluctuation amount of the gaze point G is judged to be small, the driving frequency of the sections other than the first section 29A may be further decreased.

In the case where the display apparatus 10B does not include a frame memory, which is a memory device for temporarily retaining image data, or includes one frame memory for the entire display portion 13, each of the second driving frequency and the third driving frequency needs to be an integral submultiple of the first driving frequency.

When the plurality of sub-display portions 19 are provided with respective frame memories, each of the second driving frequency and the third driving frequency can be set to a given value without limitation to an integral submultiple of the first driving frequency. When the second driving frequency and the third driving frequency are set to given values, the degree of freedom in setting the driving frequencies can be increased. As a result, a reduction in the practical display quality can be small.

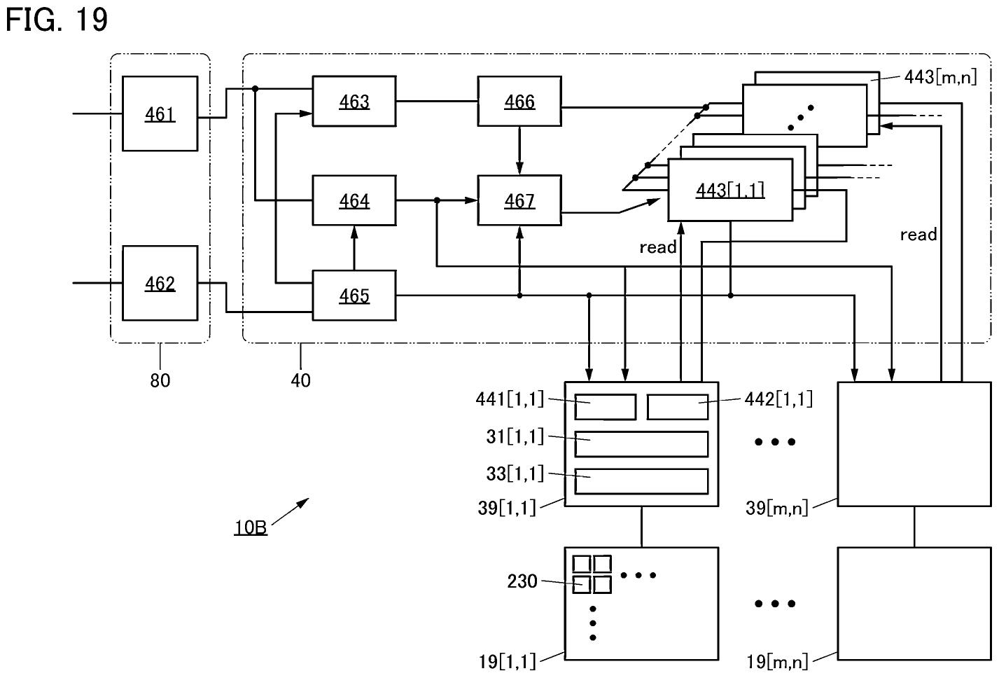

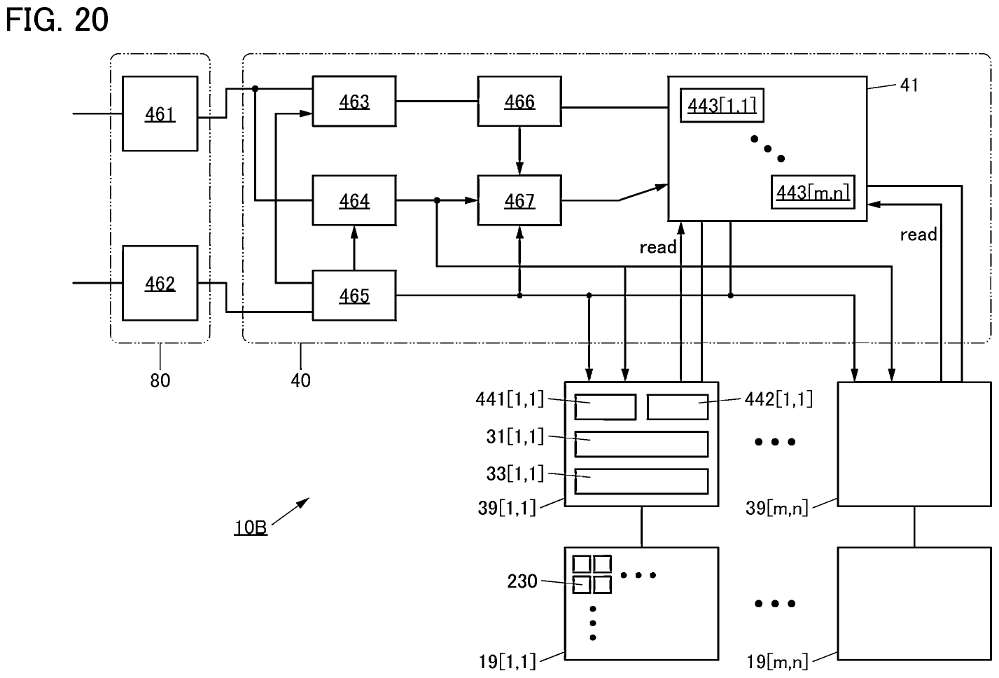

FIG. 19 is a block diagram illustrating a structure example of the display apparatus 10B including a frame memory 443 for each of the sub-display portions 19. In FIG. 19, the input/output circuit 80 includes an image information input portion 461 and a clock signal input portion 462. The functional circuit 40 includes an image data temporary retention portion 463, an operation parameter setting portion 464, an internal clock signal generating portion 465, an image processing portion 466, a memory controller 467, and a plurality of frame memories 443.

Alternatively, a flash memory, a MRAM, a PRAM, a ReRAM, an FeRAM, a DRAM, an SRAM, or the like may be used as the image data temporary memory portion 463 and the frame memory 443. As the image data temporary storage portion 463 and the frame memory 443, a DOSRAM (registered trademark), a NOSRAM (registered trademark), or the like may be used.

One of the plurality of frame memories 443 has a function of retaining image data to be displayed on one of the plurality of sub-display portions 19. For example, a frame memory 443[1,1] has a function of retaining image data to be displayed on a sub-display portion 19[1,1]. Similarly, a frame memory 443[m,n] has a function of retaining image data to be displayed on a sub-display portion 19[m,n].

One of the plurality of sub-display portions 19 is electrically connected to one of the plurality of sections 39. In FIG. 19, each of the plurality of sections 39 includes the source driver circuit 31, the gate driver circuit 33, the timing generation circuit 441, and the input/output circuit 442. In FIG. 19 and the like, the timing generation circuit 441 included in the section 39[1,1] is denoted as a timing generation circuit 441[1,1]. Furthermore, the input/output circuit 442 included the section 39[1,1] is denoted as an input/output circuit 442[1,1].

Image data to be displayed on the display portion 13 and operation parameters of the display apparatus 10B are supplied to the image information input portion 461 from the outside. A clock signal is supplied to the clock signal input portion 462 from the outside. The clock signal is supplied to the internal clock signal generating portion 465 via the clock signal input portion 462.

The internal clock signal generating portion 465 has a function of generating a clock signal used in the display apparatus 10B (also referred to as “internal clock signal”) with the use of the clock signal supplied from the outside. The internal clock signal is supplied to the image data temporary retention portion 463, the operation parameter setting portion 464, the memory controller 467, the section 39, and the like and used for matching operation timing between the circuits included in the display apparatus 10B, for example.

The image data input via the image information input portion 461 is supplied to the image data temporary retention portion 463. The operation parameters input via the image information input portion 461 are supplied to the operation parameter setting portion 464.

The image data temporary retention portion 463 retains the supplied image data, and supplies the image data to the image processing portion 466 in synchronization with the internal clock signal. Thus, the image data temporary memory portion 463 is one kind of frame memory. Providing the image data temporary retention portion 463 can eliminate a mismatch between the timing at which image data is supplied from the outside and the timing at which the image data is processed in the display apparatus 10B.

The operation parameter setting portion 464 has a function of retaining the supplied operation parameters. The operation parameters include information for determining the driving frequency, scan direction, resolution, or the like for each of the plurality of sub-display portions 19.

The image processing portion 466 has a function of performing arithmetic processing of the image data retained in the image data temporary retention portion 463. For example, the image processing portion 466 has a function of performing contrast adjustment, brightness adjustment, and gamma correction of the image data. Furthermore, the image processing portion 466 has a function of dividing the image data retained in the image data temporary retention portion 463 for the sub-display portions 19.

The image processing portion 466 has a function of reading image data stored in each of the plurality of frame memories 443, performing arithmetic processing on the image data, and writing back the arithmetically processed image data to the frame memories 443. For example, when a still image is displayed on the display portion 13, arithmetic processing is performed on image data stored in some or all of the plurality of frame memories 443, whereby luminance, contrast, or the like can be adjusted.

The memory controller 467 has a function of controlling the operations of the plurality of frame memories 443. The image data is retained in the plurality of frame memories 443 after being divided by the image processing portion 466 for the sub-display portions 19. Each of the plurality of frame memories 443 has a function of supplying image data to the corresponding section 39 in response to a read request signal (read) from the section 39.

Note that the memory device 41 may be used as the frame memories 443 as illustrated in FIG. 20. In other words, image data divided for the sub-display portions 19 may be retained in the memory device 41.

The frame memories 443 may be provided in a component other than the functional circuit 40. Alternatively, the frame memory 443 may be provided in a semiconductor device (e.g., another memory device) other than the display apparatus 10B.

Note that sections set for the display portion 13 are not limited to the three sections of the first section 29A, the second section 29B, and the third section 29C. The display portion 13 may include four or more sections. When a plurality of sections are set for the display portion 13 and the driving frequencies of the sections are gradually lowered, a reduction in the practical display quality can be smaller.

The above-described upconversion processing may be performed on an image to be displayed on the first section 29A. When an image obtained by the upconversion processing is displayed on the first section 29A, the display quality can be increased. The above-described upconversion processing may be performed on an image to be displayed on the sections other than the first section 29A. When an image obtained by the upconversion processing is displayed on the sections other than the first section 29A, a reduction in the practical display quality that occurs in the case where the driving frequencies of the sections other than the first section 29A are lowered can be smaller.

Note that the upconversion processing of an image to be displayed on the first section 29A may be performed using an algorithm with high accuracy, and the upconversion processing of an image to be displayed on the sections other than the first section 29A may be performed using an algorithm with low accuracy. A reduction in the practical display quality that occurs in the case where the driving frequencies of the sections other than the first section 29A are lowered can be smaller also in such a case.

In the case where the resolution of image data is desired to be lower than the resolution of the display portion 13, or in the case where high-speed rewriting and low power consumption have a priority, for example, downconversion processing may be performed on an image displayed on the sections other than the first section 29A in accordance with the purpose or the like. For example, high-speed rewriting and low power consumption can be achieved by rewriting an image displayed on the sections other than the first section 29A every several rows, every several columns, or every several pixels.

The resolutions of images displayed on the sections other than the first section 29A including a gaze point are lower than the resolution of an image displayed on the first section 29A, enabling a reduction in the load at the time of generation of a video signal (rendering). The processing is also referred to as foveated rendering. With a combination of the reduction of a driving frequency of the sections other than the first section 29A and the foveated rendering, much lower power consumption can be achieved while a decrease in display quality is suppressed.

When image data rewriting performed in each of the sub-display portions 19 is performed concurrently in all of the sub-display portions 19, high-speed rewriting can be achieved. In other words, when image data rewriting performed in each of the sections 39 is performed concurrently in all of the sections 39, high-speed rewriting can be achieved.

In general, while pixels in one row are selected by a gate driver circuit, a source driver circuit writes image data to all of the pixels in one row concurrently in the case of line sequential driving. In the case where the display portion 13 is not divided into the sub-display portions 19 and has a resolution of 4000×2000 pixels, for example, image data needs to be written to 4000 pixels by the source driver circuit while the pixels in one row are selected by the gate driver circuit. In the case where the frame frequency is 120 Hz, one frame period is approximately 8.3 msec. Accordingly, the gate driver circuit needs to select pixels in 2000 rows in approximately 8.3 msec, and the time for selecting pixels in one row, that is, the time for writing image data to each pixel is approximately 4.17 μsec. In other words, it becomes more difficult to ensure sufficient time for rewriting image data as the resolution of the display portion increases or as the frame frequency increases.

The display portion 13 of the display apparatus 10B described as an example in this embodiment is divided into four parts in the row direction. Thus, the time for writing image data to each pixel in one sub-display portion 19 can be four times as long as that of the case where the display portion 13 is not divided. According to one embodiment of the present invention, the time for rewriting image data can be easily ensured even in the case where the frame frequency is 240 Hz or 360 Hz; thus, a display apparatus with high display quality can be achieved.

Since the display portion 13 of the display apparatus 10B described as an example in this embodiment is divided into four parts in the row direction, the length of the wiring SL electrically connecting the source driver circuit and the pixel circuit becomes one fourth. Accordingly, each of the resistance value and parasitic capacitance of the wiring SL becomes one fourth, whereby the time required for writing (rewriting) image data can be shortened.

In addition, the display portion 13 of the display apparatus 10B described as an example in this embodiment is divided into eight parts in the column direction; thus, the length of the wiring GL electrically connecting the gate driver circuit and the pixel circuit becomes one eighth. Accordingly, each of the resistance value and parasitic capacitance of the wiring GL becomes one eighth, whereby degradation and delay of a signal can be suppressed and the time for rewriting image data can be easily ensured.

According to the display apparatus 10B of one embodiment of the present invention, sufficient time for writing image data can be easily ensured, and thus high-speed rewriting of a display image can be achieved. Thus, a display apparatus with high display quality can be achieved. In particular, a display apparatus that excels in displaying a moving image can be achieved.

Here, a mode is described in which the display apparatus 10 of one embodiment of the present invention is employed for a thin client. In recent years, the thin client in which main arithmetic processing is performed on a server and limited processing is performed on a client side has been attracting attention. As a thin client execution method, a network boot method, a server base method, a blade PC method, a virtual desktop (VDI) method, and the like are proposed.

In any of the methods, a large amount of data is transmitted from a server to a client in a thin client, so that power consumption at the time of transmitting data is increased. With the use of an electronic device including the display apparatus 10 of one embodiment of the present invention as a client, power saving during data transmission can be achieved.

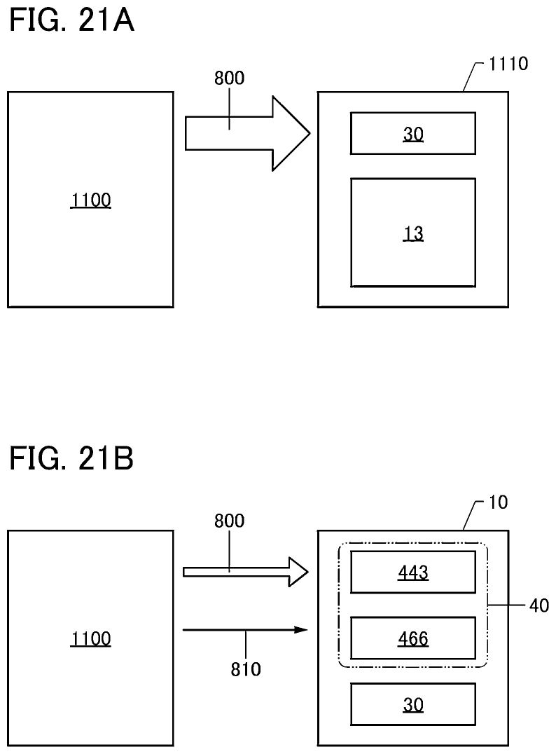

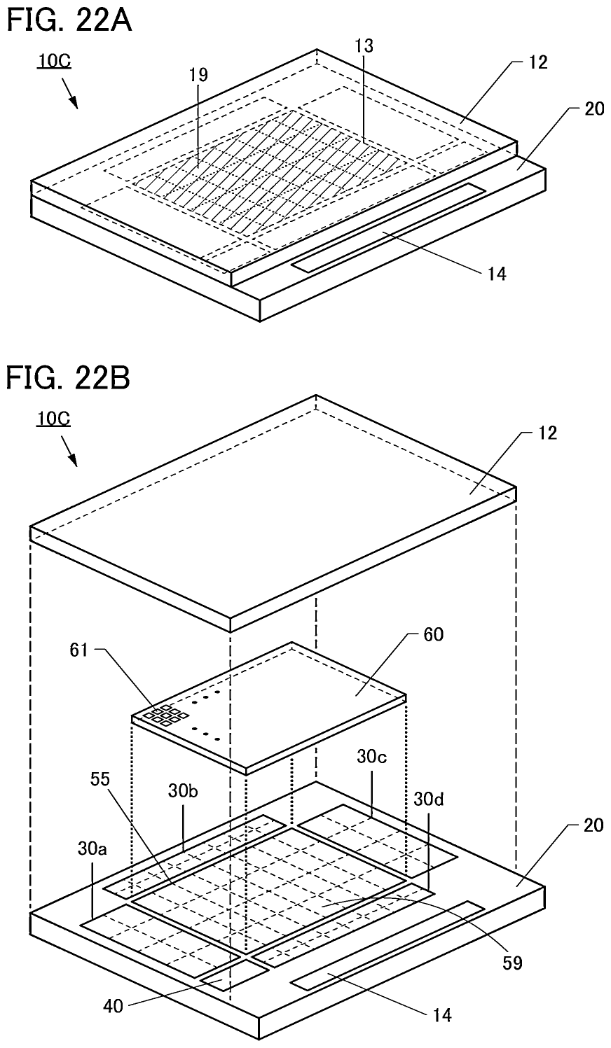

For example, a case where a conventional display apparatus 1110 (a display apparatus including the driver circuit 30 and the display portion 13, but not including the functional circuit 40) is used as a client or a case where an electronic device including the conventional display apparatus 1110 is used is considered (see FIG. 21A). In such cases, the server 1100 needs to continue to transmit image data 800 to the display apparatus 1110 in a period during which the image is displayed on the display apparatus 1110, regardless of a moving image or a still image.

Next, a case where the display apparatus 10 of one embodiment of the present invention is used as a client or a case where an electronic device including the display apparatus 10 is used is considered (see FIG. 21B). The display apparatus 10 of one embodiment of the present invention can store the image data 800 supplied from the server 1100 in the frame memory 443 that is part of the functional circuit 40. Thus, in the case of displaying a still image, even when transmission of the image data 800 is stopped, display of the still image can be continued using the image data 800 stored in the frame memory 443.

When the display apparatus 10 including the plurality of frame memories 443 is used, image data can be rewritten every frame memory 443. For example, in the case where a change is generated in part of the image data, only the image data 800 corresponding to a region with the change is transmitted to a client from the server 1100. That is, since all pieces of the image data 800 does not need to be transmitted, the transmission quantity of the image data 800 can be reduced. Accordingly, power saving during data transmission can be achieved.

The display apparatus 10 of one embodiment of the present invention includes the image processing portion 466. For example, the image processing portion 466 can perform contrast adjustment, brightness adjustment, gamma correction, and the like of image data stored in the frame memory 443 in response to a processing instruction 810 from the server 1100. The arithmetic operation of the image data 800 is performed on the server 1100 side and the image data 800 does not need to be transmitted to the client side, resulting in power saving of data transmission. It is effective for power saving in the case where the image data has no change or a little change.

As described above, the resolution of a region that does not include the gaze point can be lowered by foveated rendering. By performing the foveated rendering in the thin client, the transmission quantity of the image data 800 can be reduced. Therefore, performing the foveated rendering with the thin client is effective for power saving in data transmission.

### Modification Example 2

FIG. 22A and FIG. 22B are perspective views of a display apparatus 10C, which is a modification example of the display apparatus 10A. Note that the display apparatus 10C is also a modification example of the display apparatus 10B. FIG. 22B is a perspective view illustrating structures of layers included in the display apparatus 10C. Note that description is made mainly on portions different from those of the display apparatus 10A and the display apparatus 10B to reduce repeated description.

The pixel circuit group 55 including the plurality of pixel circuits 51, the driver circuit 30, the functional circuit 40, and the terminal portion 14 may be provided in the same layer. In the display apparatus 10C, the pixel circuit group 55, the driver circuit 30, the functional circuit 40, and the terminal portion 14 are provided in the layer 20. Since the pixel circuit group 55, the driver circuit 30, and the functional circuit 40 are provided in the same layer, wirings electrically connecting the circuits can be short. Thus, wiring resistance and parasitic capacitance are reduced, leading to lower power consumption.

In the case where a c-Si transistor is used as a transistor included in the display apparatus 10C, for example, a single crystal silicon substrate can be used as the layer 20 and the pixel circuit group 55, the driver circuit 30, the functional circuit 40, and the terminal portion 14 can be provided in the layer 20. When a single crystal silicon substrate is used as the layer 20, the substrate 11 can be omitted. As a result, a reduction in the weight of the display apparatus 10C can be achieved. In addition, the cost of manufacturing the display apparatus 10C can be reduced. Thus, the productivity of the display apparatus 10C can be improved.

Note that the transistor used in the display apparatus 10C is not limited to a c-Si transistor. Any of a variety of transistors such as a Poly-Si transistor or an OS transistor can be employed as the transistor used in the display apparatus 10C.

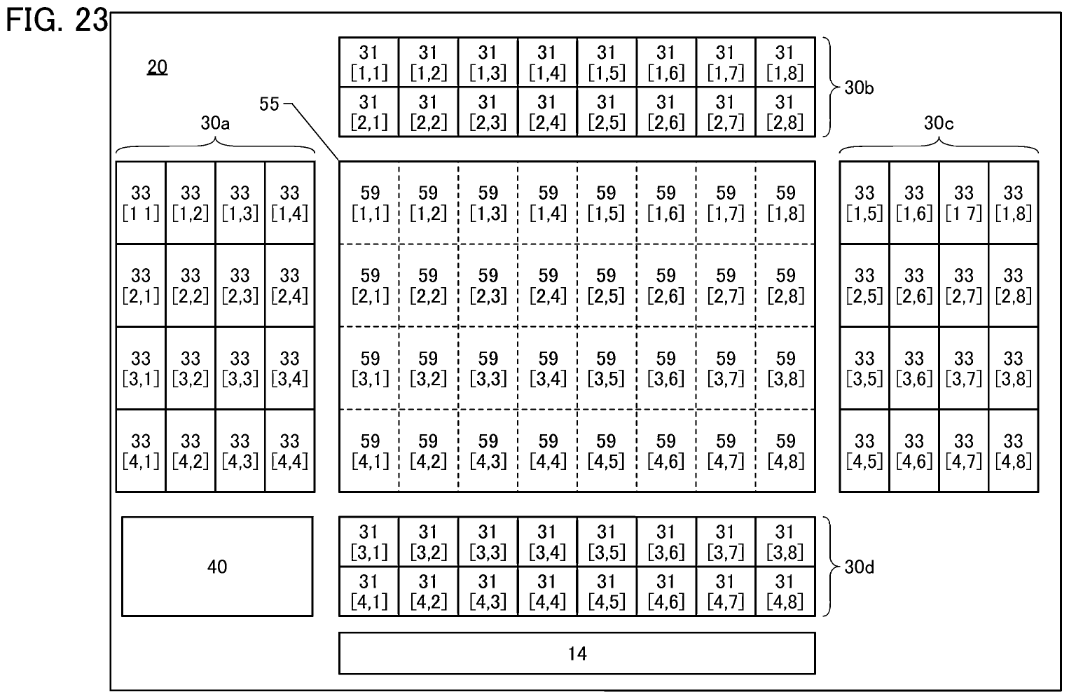

In the display apparatus 10C illustrated in FIG. 22A and FIG. 22B, the display portion 13 is composed of the sub-display portions 19 arranged in a matrix of m rows and n columns. Accordingly, the pixel circuit group 55 is divided into the sections 59 arranged in a matrix of m rows and n columns. FIG. 23 illustrates a planar layout of the layer 20. FIG. 23 illustrates the sections 59 of the case where m is 4 and n is 8.

The driver circuit 30 is provided in the display apparatus 10C as four divided regions: a driver circuit 30a, a driver circuit 30b, a driver circuit 30c, and a driver circuit 30d. The driver circuit 30a, the driver circuit 30b, the driver circuit 30c, and the driver circuit 30d are provided outside the pixel circuit group 55. Specifically, the driver circuit 30a is provided on a first side of the four sides of the pixel circuit group 55, the driver circuit 30c is provided on a third side that faces the first side with the pixel circuit group 55 positioned therebetween, the driver circuit 30b is provided on a second side, and the driver circuit 30d is provided on a fourth side that faces the second side with the pixel circuit group 55 positioned therebetween.

The driver circuit 30a and the driver circuit 30c each include 16 the gate driver circuits 33. The driver circuit 30b and the driver circuit 30d each include 16 the source driver circuits 31. One of the gate driver circuits 33 is electrically connected to the plurality of pixel circuits 51 included in one of the sections 59. One of the source driver circuits 31 is electrically connected to the plurality of pixel circuits 51 included in one of the sections 59.

The gate driver circuit 33 electrically connected to the section 59[1,1] is denoted as a gate driver circuit 33[1,1], and the source driver circuit 31 electrically connected to the section 59[1,1] is denoted as a source driver circuit 31[1,1] in FIG. 23. Similarly, the gate driver circuit 33 electrically connected to a section 59[4,8] is denoted as a gate driver circuit 33[4,8], and the source driver circuit 31 electrically connected to the section 59[4,8] is denoted as a source driver circuit 31[4,8].

The driver circuit 30a includes the gate driver circuit 33[1,1] to a gate driver circuit 33[1,4], a gate driver circuit 33[2,1] to a gate driver circuit 33[2,4], a gate driver circuit 33[3,1] to a gate driver circuit 33[3,4], and a gate driver circuit 33[4,1] to a gate driver circuit 33[4,4]. The driver circuit 30b includes the source driver circuit 31[1,1] to a source driver circuit 31[1,8] and a source driver circuit 31[2,1] to a source driver circuit 31[2,8]. The driver circuit 30c includes a gate driver circuit 33[1,5] to a gate driver circuit 33[1,8], a gate driver circuit 33[2,5] to a gate driver circuit 33[2,8], a gate driver circuit 33[3,5] to a gate driver circuit 33[3,8], and a gate driver circuit 33[4,5] to the gate driver circuit 33[4,8]. The driver circuit 30d includes a source driver circuit 31[3,1] to a source driver circuit 31[3,8] and a source driver circuit 31[4,1] to the source driver circuit 31[4,8].

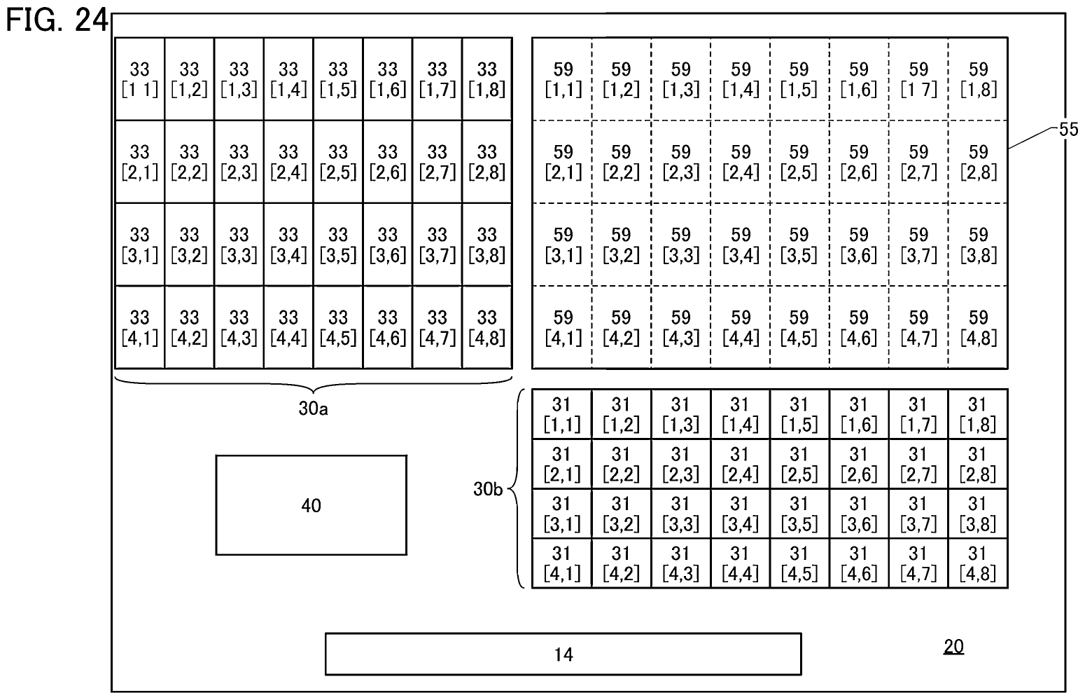

The positions of the pixel circuit group 55, the driver circuit 30, and the functional circuit 40 provided in the layer 20 are not limited to those illustrated in FIG. 23. For example, a structure illustrated in FIG. 24 may be employed. In FIG. 24, the driver circuit 30 is provided as two divided regions: the driver circuit 30a and the driver circuit 30b. For example, the driver circuit 30a includes 32 the gate driver circuits 33 (the gate driver circuit 33[1,1] to the gate driver circuit 33[4,8]) and the driver circuit 30b includes 32 the source driver circuits 31 (the source driver circuit 31[1,1] to the source driver circuit 31[4,8]).

Note that the display apparatus 10B and the display apparatus 10C according to one embodiment of the present invention are each an example in which the display portion 13 is divided into the 32 sub-display portions 19. However, the division number of the display portion 13 in each of the display apparatus 10B and the display apparatus 10C of one embodiment of the present invention may be 16, 64, 128, or the like, without limitation to 32. As the division number of the display portion 13 increases, a reduction in practical display quality perceived by the user can be smaller.

At least part of the structure examples, the drawings corresponding thereto, and the like described as an example in this embodiment can be combined with any of the other structure examples, the other drawings, and the like as appropriate.

### Embodiment 2

One embodiment of the present invention can be suitably used for a portable information terminal such as a smartphone, for example. In this embodiment, a portable information terminal of one embodiment of the present invention will be described with reference to drawings. Note that any of the other embodiments or the like is referred to for matters that are not described in this embodiment to avoid repeated description.

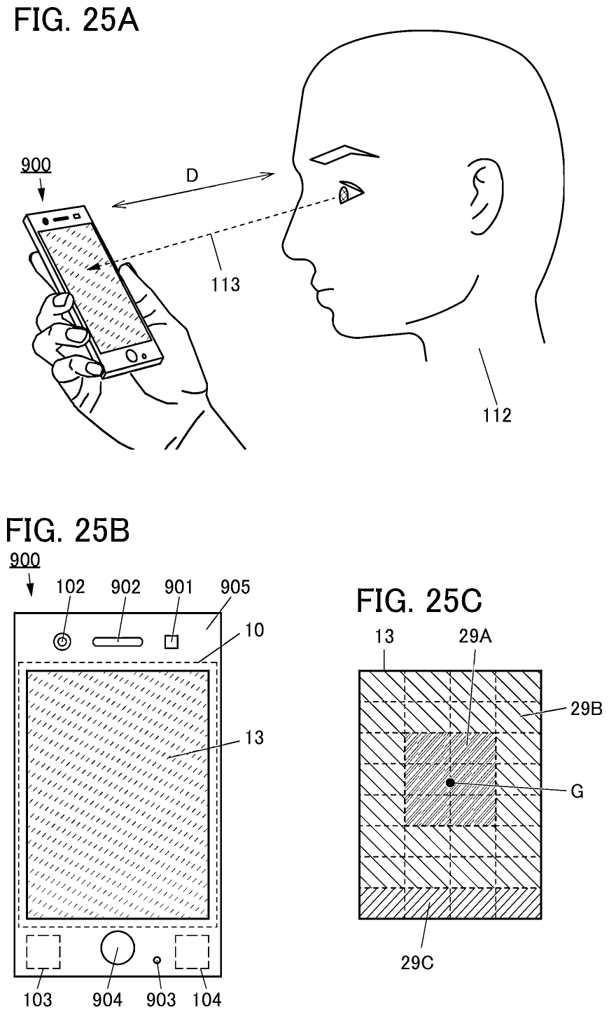

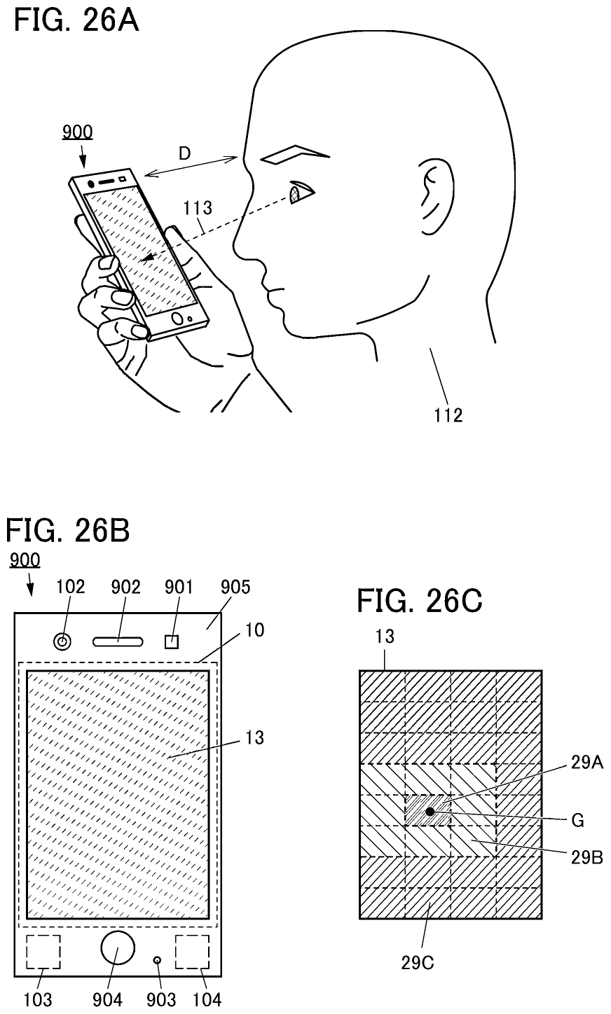

FIG. 25A and FIG. 26A are diagrams illustrating a state where the user 112 is using the portable information terminal 900. FIG. 25B and FIG. 26B are front views of the portable information terminal 900. FIG. 25C and FIG. 26C are diagrams illustrating an operation state of the display portion 13.

The portable information terminal 900 includes the gaze detection portion 102, a distance detection portion 901, a speaker 902, a microphone 903, an operation button 904, a housing 905, and the display apparatus 10. The housing 905 also includes the arithmetic portion 103, the communication portion 104, an antenna (not illustrated), a battery (not illustrated), and the like therein. The portable information terminal 900 may include the sensor 125 described in the above embodiment.

As the display apparatus 10, the display apparatus 10A, the display apparatus 10B, the display apparatus 10C, or the like described in the above embodiment can be used.

In the portable information terminal 900 described in this embodiment, the display portion 13 of the display apparatus 10 includes the sub-display portions 19 (see FIG. 16A, FIG. 18A, and the like) of eight rows and four columns. That is, the display portion 13 of the display apparatus 10 included in the portable information terminal 900 is divided into 32 sub-display portions 19. Note that there is no limitation on the number of sub-display portions 19 included in the display portion 13.

The portable information terminal 900 has a function of detecting the gaze 113 with the use of the gaze detection portion 102 and a function of detecting the distance D (also referred to as “distance data”) from the portable information terminal 900 to the user 112 with the use of the distance detection portion 901. The gaze detection portion 102 may be an imaging element, for example. The distance detection portion 901 may include an optical sensor (e.g., TOF (Time Of Flight) sensor), an ultrasonic sensor, or the like, for example.

The arithmetic portion 103 has a function of calculating the user's gaze point G by using gaze data obtained in the gaze detection portion 102. The arithmetic portion 103 has a function of distributing each of the plurality of sub-display portions 19 to the first section 29A, the second section 29B, or the third section 29C with the use of the distance data obtained by the distance detection portion 901 and the gaze data.

When the distance D from the portable information terminal 900 to the user 112 is relatively long, for example, six sub-display portions 19 are distributed to the first section 29A, 22 sub-display portions 19 are distributed to the second section 29B, and four sub-display portions 19 are distributed to the third section 29C as illustrated in FIG. 25C.

When the distance D from the portable information terminal 900 to the user 112 is relatively short, for example, one sub-display portion 19 is distributed to the first section 29A, eight sub-display portions 19 are distributed to the second section 29B, and 23 sub-display portions 19 are distributed to the third section 29C as illustrated in FIG. 26C.

As the portable information terminal 900 approaches the user 112, the discriminating visual field on the display portion 13 is narrowed. Thus, as the portable information terminal 900 approaches the user 112, the first region S1 including the discriminating visual field becomes smaller. Thus, the number of the sub-display portions 19 that are distributed to the first section 29A can be reduced. In addition, the number of the sub-display portions 19 that are distributed to the second section 29B can be reduced. In addition, the number of the sub-display portions 19 that are distributed to the third section 29C can be increased.

As described in the above embodiment, it is possible that the first section 29A, the second section 29B, and the third section 29C are in order of from highest to lowest driving frequency in the sub-display portion 19. A lower driving frequency enables a reduction in power consumption of the display apparatus 10. Thus, the increase in the number of the sub-display portions 19 that are distributed to the third section 29C reduces the power consumption of the display apparatus 10. Furthermore, as described in the above embodiment, with a combination of adjustment of the driving frequencies of the sub-display portions 19 and the foveated rendering, power saving of the entire electronic device as well as the display apparatus 10 can be achieved.

In addition, the first section 29A, the second section 29B, and the third section 29C may be in order of from highest to lowest emission luminance. When the emission luminance of the sub-display portions 19 distributed to each of the second section 29B and the third section 29C is lower than the emission luminance of the sub-display portions 19 distributed to the first section 29A, the power consumption of the display apparatus 10 can be reduced while the decrease in display quality is suppressed. Thus, power saving of the electronic device can be achieved.

The portable information terminal 900 may include a touch panel including a touch sensor overlapping with the display portion 13 of the display apparatus 10. The display apparatus 10 included in the portable information terminal 900 may include a touch sensor.

The touch sensor or the touch panel can detect the position of the display portion 13 that is contacted by the finger 119 or the like of the user. That is, the contact position of the user's finger 119 or the like on the display portion 13 can be detected. In other words, the position on the display portion 13 selected by the user can be detected. That is, the position on the display portion 13 selected by the user can be detected.

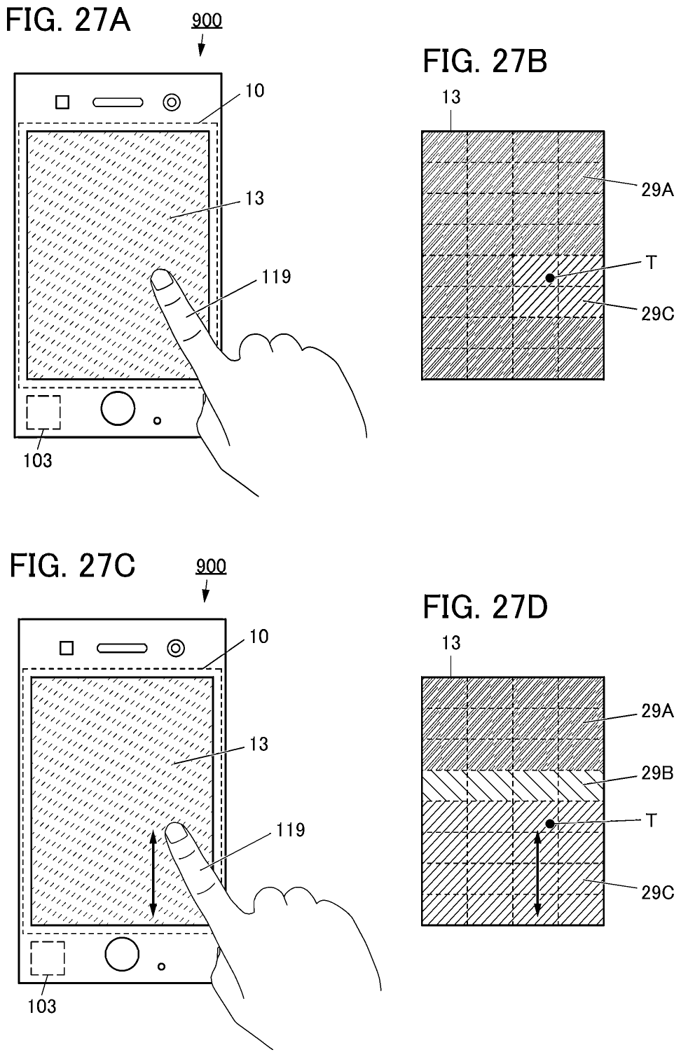

FIG. 27A illustrates a state where the user 112 is contacting part of the display portion 13 with his/her finger 119. FIG. 27B is a diagram illustrating an operation state of the display portion 13. In this embodiment and the like, a portion being in contact with the user on the display portion 13 is denoted by “contact point T”.

Note that with the touch sensor or the touch panel, the selection position on the display portion 13 can be detected in some cases even when the user's finger 119 or the like is not completely in contact with it. Therefore, in this specification and the like, a “contact” sometimes includes a state of being not in complete contact (a state of proximity). Therefore, in this specification and the like, “contact” and “selection” can be replaced with each other in some cases. For example, in this specification and the like, the term “contact point” may be replaced with the term “selection point”.

The arithmetic portion 103 has a function of distributing each of the plurality of sub-display portions 19 to the first section 29A, the second section 29B, or the third section 29C on the basis of the contact point T. FIG. 27B illustrates an example in which the sub-display portion 19 overlapping with the contact point T and some of the plurality of sub-display portions 19 in contact with the sub-display portion 19 are distributed to the third section 29C, and the other sub-display portions 19 are distributed to the first section 29A. Since the user's view is blocked at the contact point T and in the vicinity thereof, the driving frequency can be significantly reduced.

In the case where the sub-display portion 19 includes a light-receiving element described later, a region where the user's view is blocked by the contact point T, a shadow of the finger 119, or the like may be detected, for example. For example, the emission luminance of the sub-display portion 19 corresponding to the region may be reduced. Alternatively, light emission of the sub-display portion 19 of the region may be stopped (quenched). The power saving of the display apparatus 10 can be achieved by reducing the emission luminance of the sub-display portion 19 or stopping the emission of the sub-display portion 19. Thus, power saving of the electronic device can be achieved.

FIG. 27C illustrates an example in which the user 112 performs a flick operation or a swipe operation on the display portion 13 with his/her finger 119. The flick operation is a quick and snappy motion to move the contact point T with his/her finger in contact with the display portion 13. In addition, the swipe operation is a sliding motion across a given portion of the display portion 13 in a particular direction.

FIG. 27D is a diagram illustrating an operation state of the display portion 13. FIG. 27C and FIG. 27D show an operation example in the case where a flick operation or a swipe operation is performed in a lower half of the display portion 13 to perform scrolling of a screen in the vertical direction.

A region where a flick operation or a swipe operation is performed on the display portion 13 (the lower half of the display portion 13 in this embodiment) is not perceived by the user in many cases. Thus, FIG. 27D illustrates an example in which 16 sub-display portions 19 positioned in the lower-half of the display portion 13 are distributed to the third section 29C. In the illustrated example, four sub-display portions 19 adjacent to the third section 29C are distributed to the second section 29B and the other 12 sub-display portions 19 are distributed to the first section 29A.

Alternatively, the distribution of the sub-display portions 19 may be changed depending on the speed of the scroll. In the case where the speed of scrolling is fast, the sub-display portions 19 in the upper half of the display portion 13 may be distributed to the second section 29B. In the case where the speed of scrolling is extremely high, all the sub-display portions 19 included in the display portion 13 may be distributed to the third section 29C. In the case where the speed of scrolling is extremely low, the sub-display portions 19 may be distributed in a manner similar to that in FIG. 27B.

The distribution of the sub-display portions 19 to the first section 29A, the second section 29B, and the third section 29C is changed as appropriate in accordance with the usage mode of an electronic device such as a portable information terminal, whereby power consumption can be reduced while a decrease in display quality is reduced.

At least part of the structure examples, the drawings corresponding thereto, and the like described in this embodiment can be combined with any of the other structure examples, the other drawings, and the like as appropriate.

### Embodiment 3

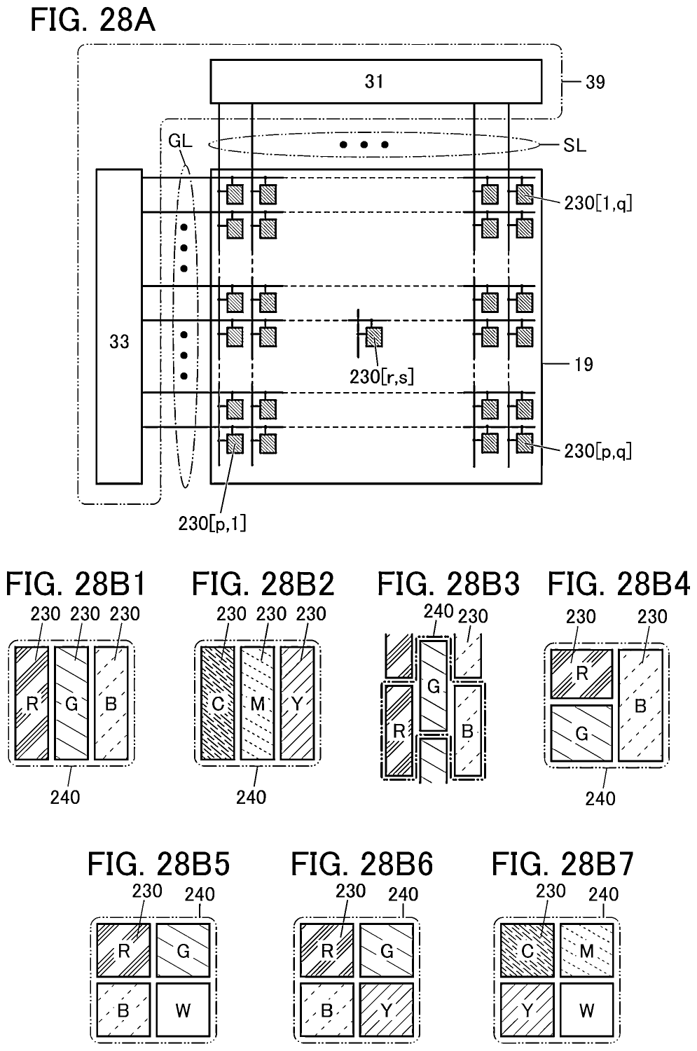

In this embodiment, a structure example of the sub-display portion 19 including the plurality of pixels 230 arranged in a matrix of p rows and q columns (p and q are each an integer greater than or equal to 2) will be described. FIG. 28A is a block diagram illustrating the sub-display portion 19. The sub-display portion 19 is electrically connected to the source driver circuit 31 and the gate driver circuit 33 which are provided in the section 39.

In FIG. 28A, the pixel 230 in the p-th row and the first column is denoted as a pixel 230[p,1], the pixel 230 in the first row and the q-th column is denoted as a pixel 230[1,q], and the pixel 230 in the p-th row and the q-th column is denoted as a pixel 230[p,q].

A circuit included in the gate driver circuit 33 functions as, for example, a scan line driver circuit. A circuit included in the source driver circuit 31 functions as, for example, a signal line driver circuit.

For example, OS transistors may be used as the transistors included in the pixels 230 and Si transistors may be used as the transistors included in a driver circuit. The off-state current of an OS transistor is low, so that power consumption can be reduced. Since a Si transistor has a higher operation speed than an OS transistor, a Si transistor is suitably used in a driver circuit. The display apparatus may include OS transistors as both the transistors included in the pixels 230 and the transistors included in a driver circuit. The display apparatus may include Si transistors as both the transistors included in the pixels 230 and the transistors included in a driver circuit. Alternatively, the display apparatus may include Si transistors as the transistors included in the pixels 230 and OS transistors as the transistors included in a driver circuit.

Both a Si transistor and an OS transistor may be used as the transistors included in the pixels 230. Both a Si transistor and an OS transistor may be used as the transistors included in a driver circuit.

In FIG. 28A, p wirings GL are arranged substantially parallel to each other and the potentials thereof are controlled by the gate driver circuit 33, and q wirings SL are arranged substantially parallel to each other and the potentials thereof are controlled by the source driver circuit 31. For example, the pixels 230 arranged in the r-th row (r represents a given number and is an integer greater than or equal to 1 and less than or equal top in this embodiment and the like) are electrically connected to the gate driver circuit 33 through the wiring GL of the r-th row. The pixels 230 arranged in the s-th column (s represents a given number and is an integer greater than or equal to 1 and less than or equal to q in this embodiment and the like) are electrically connected to the source driver circuit 31 through the wiring SL of the s-th column. In FIG. 28A, the pixel 230 in the r-th row and the s-th column is denoted as a pixel 230[r, s].

Note that the number of the wirings GL electrically connected to the pixels 230 included in one row is not limited to one. Furthermore, the number of the wirings SL electrically connected to the pixels 230 included in one column is not limited to one. The wiring GL and the wiring SL are examples, and wirings connected to the pixels 230 are not limited to the wiring GL and the wiring SL.

Full-color display can be achieved by making the pixel 230 that controls red light, the pixel 230 that controls green light, and the pixel 230 that controls blue light, collectively function as a pixel 240 and by controlling the amount of light emission (emission luminance) from each of the pixels 230. In other words, each of the three pixels 230 functions as a subpixel. That is, three subpixels control the emission amount or the like of red light, green light, and blue light (see FIG. 28B1). Note that the colors of light controlled by the three subpixels are not limited to a combination of red (R), green (G), and blue (B) and may be cyan (C), magenta (M), and yellow (Y) (see FIG. 28B2)

By using the pixels 240 arranged in a matrix of 1920×1080, the display portion 13 can achieve full-color display with a so-called 2K resolution. For example, by using the pixels 240 arranged in a matrix of 3840×2160, the display portion 13 can achieve full-color display with a so-called 4K resolution. For example, by using the pixels 240 arranged in a matrix of 7680×4320, the display portion 13 can achieve full-color display with a so-called 8K resolution. By increasing the number of pixels 240, the display portion 13 that can perform full-color display with 16K or 32K resolution can also be obtained.

Alternatively, three pixels 230 constituting one pixel 240 may be arranged in a delta arrangement (see FIG. 28B3). Specifically, three pixels 230 constituting one pixel 240 may be arranged such that the lines connecting the center points of the three pixels 230 form a triangle. Alternatively, three pixels 230 constituting one pixel 240 may be arranged in an S-stripe arrangement (see FIG. 28B4). Note that the arrangement of the pixels 230 is not limited to a stripe arrangement, a delta arrangement, or an S-stripe arrangement. The pixels 230 may be arranged in a zigzag arrangement, a Bayer arrangement, or a PenTile arrangement.

The three subpixels (pixels 230) do not necessarily have the same area. In the case where the emission efficiency, reliability, and the like vary depending on emission colors, the subpixel area may be changed depending on the emission color (see FIG. 28B4).

Four subpixels may collectively function as one pixel. For example, a subpixel that controls white light may be added to the three subpixels that control red light, green light, and blue light (see FIG. 28B5). The addition of the subpixel that controls white light can increase the luminance of a display region. Alternatively, a subpixel that controls yellow light may be added to the three subpixels that control red light, green light, and blue light (see FIG. 28B6). Further alternatively, a subpixel that controls white light may be added to the three subpixels that control cyan light, magenta light, and yellow light (see FIG. 28B7).

When the number of subpixels functioning as one pixel is increased and subpixels that control light of red, green, blue, cyan, magenta, yellow, and the like are used in an appropriate combination, the reproducibility of halftones can be increased. Thus, display quality can be improved.

The display apparatus of one embodiment of the present invention can reproduce the color gamut of various standards. For example, the display apparatus of one embodiment of the present invention can reproduce the color gamut of the PAL (Phase Alternating Line) standard and the NTSC (National Television System Committee) standard for TV broadcasting; the sRGB (standard RGB) standard and the Adobe RGB standard widely used for display apparatuses used in electronic devices such as personal computers, digital cameras, and printers; the ITU-R BT.709 (International Telecommunication Union Radiocommunication Sector Broadcasting Service (Television) 709) standard for HDTV (High Definition Television, also referred to as Hi-Vision); the DCI-P3 (Digital Cinema Initiatives P3) standard for digital cinema projection; the ITU-R BT.2020 (REC.2020 (Recommendation 2020)) standard for UHDTV (Ultra High Definition Television, also referred to as Super Hi-Vision); and the like.

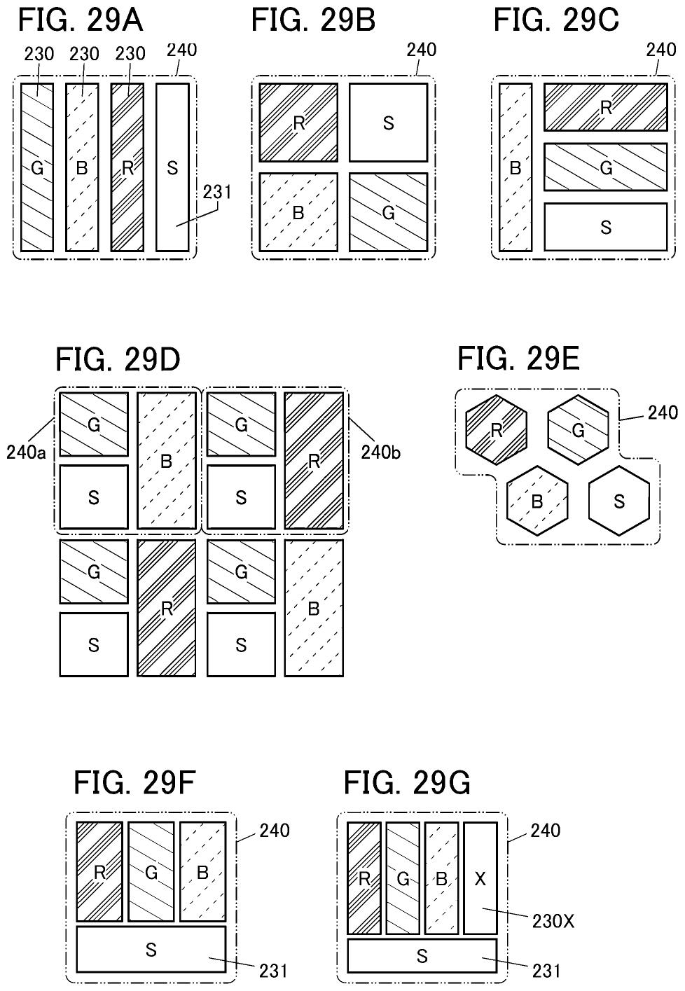

A pixel 231 including a light-receiving element in one pixel 240 may be provided. In the pixel 240 illustrated in FIG. 29A, a pixel 230(G) exhibiting green light, a pixel 230(B) exhibiting blue light, a pixel 230(R) exhibiting red light, and a pixel 231(S) including a light-receiving element are arranged in a stripe pattern. Note that in this specification and the like, the pixel 231 is also referred to as an “imaging pixel”.

A light-receiving element included in the pixel 231 is preferably an element that detects visible light and is further preferably an element that detects one or more of blue light, violet light, bluish violet light, green light, yellowish green light, yellow light, orange light, red light, and the like. The light-receiving element included in the pixel 231 may be an element that detects infrared light.

The pixel 240 illustrated in FIG. 29A employs a stripe arrangement. Note that in the case where the pixel 231 including a light-receiving element detects light of a specific color, the pixel 230 exhibiting light of the color is preferably disposed to be adjacent to the pixel 231, whereby detection accuracy can be increased.

Three pixels 230 and one pixel 231 are arranged in a matrix in the pixel 240 illustrated in FIG. 29B. Although FIG. 29B illustrates an example in which the pixel 230 exhibiting red light is adjacent to the pixel 231 including a light-receiving element in the row direction and the pixel 230 exhibiting blue light is adjacent to the pixel 230 exhibiting green light in the row direction, one embodiment of the present invention is not limited thereto.

The pixel 240 illustrated in FIG. 29C has a structure in which the pixel 231 is added to an S-stripe arrangement. The pixel 240 in FIG. 29C includes one vertically oriented pixel 230, two horizontally oriented pixels 230, and one horizontally oriented pixel 231. Note that the vertically oriented pixel 230 may be any one of R, G, and S, and there is no particular limitation on the arrangement order of the horizontally oriented subpixels.

FIG. 29D illustrates an example in which a pixel 240a and a pixel 240b are alternately arranged. The pixel 240a includes the pixel 230 exhibiting blue light, the pixel 230 exhibiting green light, and the pixel 231 including a light-receiving element. The pixel 240b includes the pixel 230 exhibiting red light, the pixel 230 exhibiting green light, and the pixel 231 including a light-receiving element. The pixel 240a and the pixel 240b function as one pixel 240. Although FIG. 29D illustrates the pixel 240a and the pixel 240b each including the pixel 230 exhibiting green light and the pixel 231, one embodiment of the present invention is not limited thereto. When the pixel 240a and the pixel 240b each include the pixel 231, the definition of an imaging pixel can be increased.

FIG. 29E illustrates an example in which a hexagonal lattice layout is employed for the arrangement of the pixels 230 and the pixel 231. The hexagonal lattice layout is preferable because the aperture ratio of each subpixel can be increased. In FIG. 29E, an example in which the top surface shapes of the pixels 230 and the pixel 231 are hexagonal is illustrated.

The pixel 240 illustrated in FIG. 29F is an example in which the pixels 230 are arranged horizontally in one line and the pixel 231 is placed beneath the pixels 230.

The pixel 240 illustrated in FIG. 29G is an example in which the pixels 230 and a pixel 230X are arranged horizontally in one line and the pixel 231 is placed beneath the pixels 230 and the pixel 230X.

As the pixel 230X, for example, the pixel 230 that exhibits infrared light (IR) can be used. That is, the pixel 230X includes the light-emitting element 61 that emits infrared light (IR). In that case, the pixel 231 preferably includes a light-receiving element that detects infrared light. For example, while an image is displayed by the pixel 230 emitting visible light, the pixel 231 can detect reflected light of infrared light emitted from a subpixel X.

A plurality of pixels 231 may be provided in one pixel 240. In that case, light detected by the plurality of pixels 231 may have the same wavelength range or different wavelength ranges. For example, part of the plurality of pixels 231 may detect visible light and another part may detect infrared light.

The pixel 231 is not necessarily provided in all the pixels 240. The pixel 240 including the pixel 231 may be provided for every certain number of pixels.

By using the pixel 231 or using the pixel 231 and the sensor 125, for example, information for personal authentication using a fingerprint, a palm print, an iris, a retina, a shape of a blood vessel (including the shape of a vein and a shape of an artery), face, or the like can be detected. Furthermore, by using the pixel 231 or using the pixel 231 and the sensor 125, the number of blinks, eyelid behavior, pupil size, body temperature, pulse, oxygen saturation in blood, or the like of the user may be measured, so that the user's fatigue level, health condition, and the like can be detected.

The electronic device can be operated using the motion of gaze, the number of blinks, the rhythm of blinks, and the like of the user. Specifically, by using the pixel 231 or using the pixel 231 and the sensor 125, information on the motion of gaze, the number of blinks, the rhythm of blinks, and the like of the user are detected, and one or more combinations of these information may be used as an operation signal of the electronic device. For example, it is possible to use a blink as a clicking of a mouse. When the motion of a gaze and a blink are detected, the user can perform an input operation of the electronic device with holding nothing in his/her hand. Thus, the operability of the electronic device can be improved.

When a plurality of imaging pixels (the pixels 231) are provided in the display apparatus 10, the plurality of imaging pixels can be used as the gaze detection portion 102. Thus, the number of components of the electronic device can be reduced. Accordingly, improvement in productivity, reductions in weight and costs, and the like of the electronic device can be achieved.

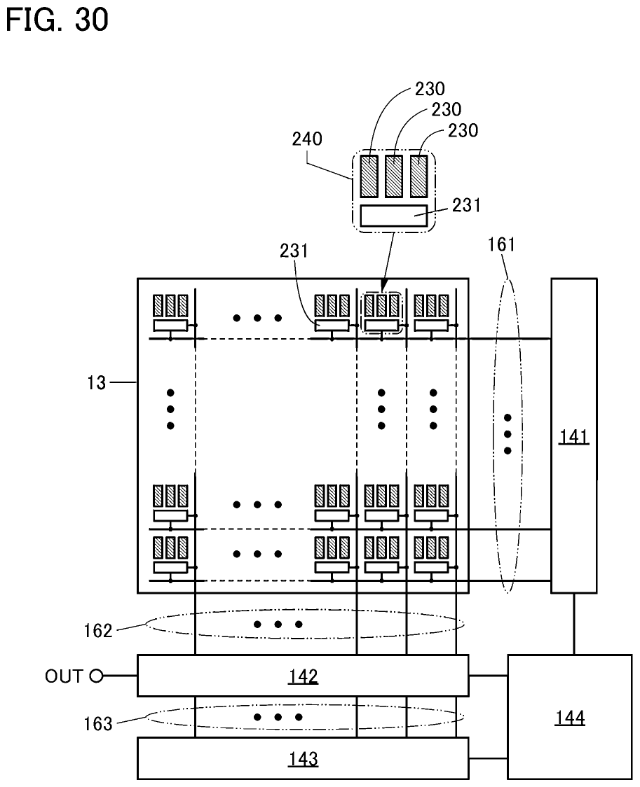

FIG. 30 illustrates a structure example of the display portion 13 in the case where the pixel 240 includes the pixel 231 including a light-receiving element. FIG. 30 is a block diagram illustrating the display portion 13 including the pixel 231. The display portion 13 includes a plurality of pixels 240 arranged in a matrix. FIG. 30 illustrates the pixel structure in FIG. 29F as the pixel 240.

In FIG. 30, the display portion 13 is electrically connected to a first driver portion 141, a second driver portion 143, and a reading portion 142. Specifically, the first driver portion 141 is electrically connected to the plurality of pixels 231 through a plurality of wirings 161. One wiring 161 is electrically connected to the plurality of pixels 231 arranged in one row. The reading portion 142 is electrically connected to the plurality of pixels 231 through a plurality of wirings 162. One wiring 162 is electrically connected to the plurality of pixels 231 arranged in one column. The second driver portion 143 is electrically connected to the reading portion 142 through a plurality of wirings 163.

Note that wirings connected to one pixel 231 are not limited to the wiring 161 and the wiring 162. A wiring other than the wiring 161 and the wiring 162 may be connected to the pixel 231.

The first driver portion 141, the reading portion 142, and the second driver portion 143 are electrically connected to a control portion 144. The control portion 144 has a function of controlling the operation of the first driver portion 141, the reading portion 142, and the second driver portion 143.

The first driver portion 141 has a function of selecting the pixels 231 row by row. The pixels 231 in the row selected by the first driver portion 141 output imaging data to the reading portion 142 through the wirings 162.

The reading portion 142 retains imaging data supplied from the pixels 231, and performs noise removal and the like. As the noise removal, for example, CDS (Correlated Double Sampling) treatment may be performed. The reading portion 142 may have a function of amplifying imaging data, an AD conversion function of imaging data, or the like.

The second driver portion 143 has a function of sequentially selecting imaging data retained in the reading portion 142 and outputting the imaging data from an output terminal OUT to the outside.

Note that the plurality of pixels 230 are electrically connected to the source driver circuit 31 and the gate driver circuit 33 as illustrated in FIG. 28, which is not illustrated in FIG. 30. Although FIG. 30 illustrates an example in which one first driver portion 141, one reading portion 142, one second driver portion 143, and one control portion 144 are provided in the display portion 13, they may be provided for each of the sub-display portions 19.

When the first driver portion 141, the reading portion 142, the second driver portion 143, and the control portion 144 are provided for each of the sub-display portions 19, the operation speed of the first driver portion 141, the reading portion 142, the second driver portion 143, and the control portion 144 in a region where an imaging operation is judged to be unnecessary can be decreased or the operation thereof can be stopped. Thus, power consumption of the display apparatus can be reduced.

The first driver portion 141, the reading portion 142, the second driver portion 143, and the control portion 144 may be provided in the layer 20, like the source driver circuit 31 and the gate driver circuit 33.

### <Circuit Structure Example of Pixel 231>

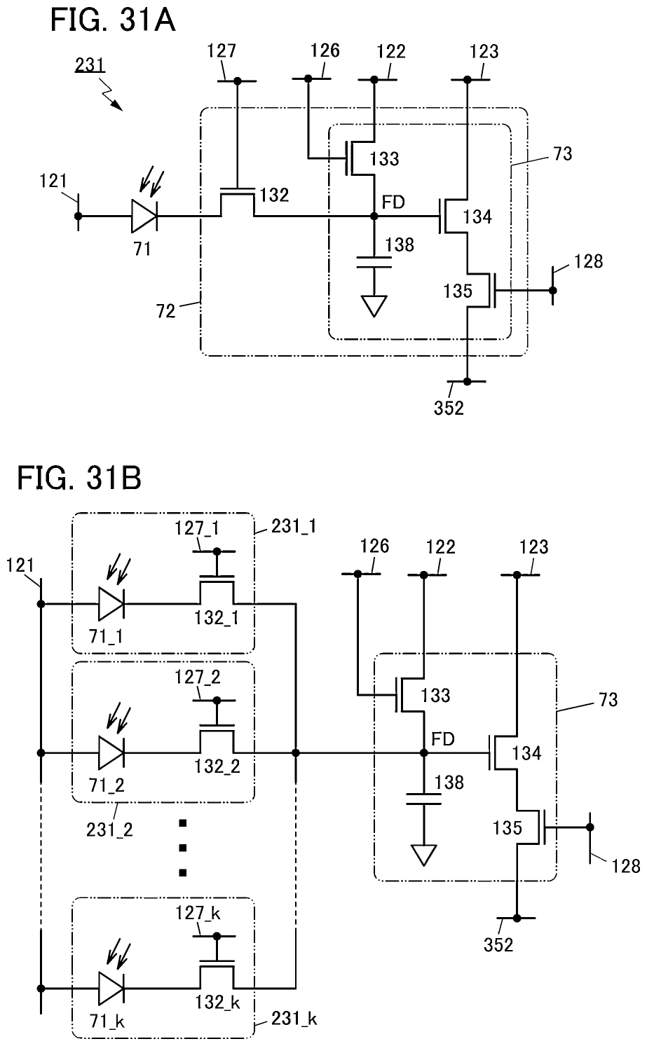

FIG. 31A is a circuit diagram illustrating a circuit structure example of the pixel 231. The pixel 231 includes a light-receiving element 71 (also referred to as a “photoelectric conversion element” or an “imaging element”) and a pixel circuit 72. Note that in this specification and the like, the pixel circuit 72 is referred to as an “imaging pixel circuit” in some cases.

The pixel circuit 72 includes a transistor 132 and a reading circuit 73. The reading circuit 73 includes a transistor 133, a transistor 134, a transistor 135, and a capacitor 138. Note that a structure in which the capacitor 138 is not provided may be employed.

One electrode (cathode) of the light-receiving element 71 is electrically connected to one of a source and a drain of the transistor 132. The other of the source and the drain of the transistor 132 is electrically connected to one of a source and a drain of the transistor 133. The one of the source and the drain of the transistor 133 is electrically connected to one electrode of the capacitor 138. The one electrode of the capacitor 138 is electrically connected to a gate of the transistor 134. One of a source and a drain of the transistor 134 is electrically connected to one of a source and a drain of the transistor 135.

Here, a wiring that connects the other of the source and the drain of the transistor 132, the one of the source and the drain of the transistor 133, the one electrode of the capacitor 138, and the gate of the transistor 134 is a node FD. The node FD can function as a charge detection portion.

The other electrode (anode) of the light-receiving element 71 is electrically connected to a wiring 121. A gate of the transistor 132 is electrically connected to a wiring 127. The other of the source and the drain of the transistor 133 is electrically connected to a wiring 122. The other of the source and the drain of the transistor 134 is electrically connected to a wiring 123. A gate of the transistor 133 is electrically connected to a wiring 126. A gate of the transistor 135 is electrically connected to a wiring 128. The other electrode of the capacitor 138 is electrically connected to a reference potential line such as a GND wiring, for example. The other of the source and the drain of the transistor 135 is electrically connected to a wiring 352.

The wiring 127, the wiring 126, and the wiring 128 each have a function of a signal line controlling on and off states of transistors. The wiring 352 has a function as an output line.

The wiring 121, the wiring 122, and the wiring 123 each have a function of a power supply line. In the structure illustrated in FIG. 31A, the cathode side of the light-receiving element 71 is electrically connected to the transistor 132, and the node FD can be reset to a high potential. Thus, the wiring 122 is at a high potential (a potential higher than that of the wiring 121).

Although the cathode side of the light-receiving element 71 is electrically connected to the node FD in FIG. 31A, the anode side of the light-receiving element 71 may be electrically connected to the one of the source and the drain of the transistor 132. In that case, since the node FD is reset to a low potential in the operation in the structure, the wiring 122 is set to a low potential (a potential lower than that of the wiring 121).

The transistor 132 has a function of controlling the potential of the node FD. The transistor 132 is also referred to as a “transfer transistor”. The transistor 133 has a function of resetting the potential of the node FD. The transistor 133 is also referred to as a “reset transistor”. The transistor 134 functions as a source follower circuit and can output the potential of the node FD as image data to the wiring 352. The transistor 135 has a function of selecting a pixel to which the image data is output. The transistor 134 is also referred to as an “amplifier transistor”. The transistor 135 is also referred to as a “selection transistor”.

With the light-receiving element 71 and the transistor 132 regarded as one set as illustrated in FIG. 31B, a plurality of sets of light-receiving elements 71 and transistors 132 may be electrically connected to one node FD. That is, the plurality of sets of light-receiving elements 71 and transistors 132 may be electrically connected to one reading circuit 73.

When one reading circuit 73 is shared by the plurality of sets of light-receiving elements 71 and transistors 132, the area occupied by one pixel 231 can be reduced. Thus, the packing density of the pixels 231 can be increased. For example, the reading circuit 73 may be formed in the layer 20 and the light-receiving element 71 and the transistor 132 may be formed in the layer 50. Alternatively, the light-receiving element 71 may be formed in the layer 60.

In FIG. 31B, the light-receiving element 71 and the transistor 132 in the first set are shown as a light-receiving element 71_1 and a transistor 132_1, respectively. A gate of the transistor 132_1 is electrically connected to a wiring 127_1. The light-receiving element 71 and the transistor 132 in the second set are shown as a light-receiving element 71_2 and a transistor 132_2, respectively. A gate of the transistor 132_2 is electrically connected to a wiring 1272. The light-receiving element 71 and the transistor 132 in the k-th set (k is an integer greater than or equal to 1) are shown as a light-receiving element 71_k and a transistor 132_k, respectively. A gate of the transistor 132_k is electrically connected to a wiring 127_k.

In the case of the structure illustrated in FIG. 31B, one set of the light-receiving element 71 and the transistor 132 can be regarded as one pixel 231. In FIG. 31B, the pixel 231 that includes the light-receiving element 71_1 and the transistor 132_1 is shown as a pixel 231_1. The pixel 231 that includes the light-receiving element 71_2 and the transistor 132_2 is shown as a pixel 231_2. The pixel 231 that includes the light-receiving element 71_k and the transistor 132_k is shown as a pixel 231_k. In the case of the structure illustrated in FIG. 31B, the transistor 132 corresponds to the pixel circuit 72.

### <Structure Example of Light-Emitting Element>

The light-emitting element 61 that can be used in the display apparatus according to one embodiment of the present invention will be described.

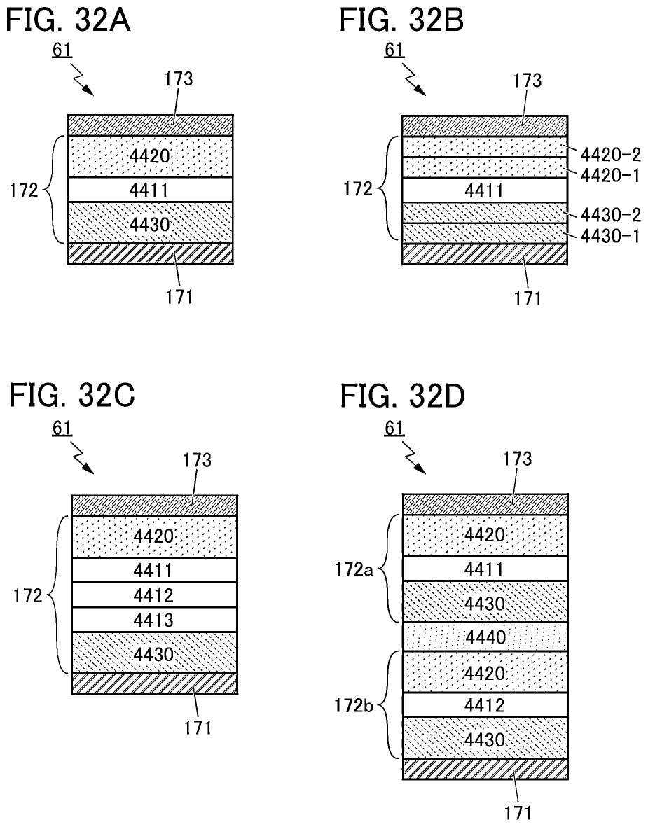

As illustrated in FIG. 32A, the light-emitting element 61 includes an EL layer 172 between a pair of electrodes (a conductor 171 and a conductor 173). The EL layer 172 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which are provided between the pair of electrodes, can function as a single light-emitting unit, and the structure in FIG. 32A is referred to as a single structure in this specification and the like.

FIG. 32B illustrates a modification example of the EL layer 172 included in the light-emitting element 61 illustrated in FIG. 32A. Specifically, the light-emitting element 61 illustrated in FIG. 32B includes a layer 4430-1 over the conductor 171, a layer 4430-2 over the layer 4430-1, the light-emitting layer 4411 over the layer 4430-2, a layer 4420-1 over the light-emitting layer 4411, a layer 4420-2 over the layer 4420-1, and the conductor 173 over the layer 4420-2. In the case where the conductor 171 is an anode and the conductor 173 is a cathode, for example, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the conductor 171 is a cathode and the conductor 173 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layered structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 32C is also an example of the single structure.

The structure in which a plurality of light-emitting units (an EL layer 172a and an EL layer 172b) are connected in series with an intermediate layer (charge-generation layer) 4440 therebetween as illustrated in FIG. 32D is referred to as a tandem structure or a stack structure in this specification and the like. The tandem structure enables a light-emitting element capable of high luminance light emission.

In the case where the light-emitting element 61 has the tandem structure illustrated in FIG. 32D, the EL layer 172a and the EL layer 172b may emit light of the same color. For example, the EL layer 172a and the EL layer 172b may both emit green light.

Note that full-color display can be achieved by using the light-emitting element 61 emitting red light (R), the light-emitting element 61 emitting green light (G), and the light-emitting element 61 emitting blue light (B) as subpixels and constituting one pixel with these three subpixels. In the case where one pixel includes three kinds of subpixels of R, G, and B, the light-emitting elements 61 may each have a tandem structure. Specifically, the EL layer 172a and the EL layer 172b in the subpixel of R each contain a material capable of emitting red light, the EL layer 172a and the EL layer 172b in the subpixel of G each contain a material capable of emitting green light, and the EL layer 172a and the EL layer 172b in the subpixel of B each contain a material capable of emitting blue light. In other words, the light-emitting layer 4411 and the light-emitting layer 4412 may contain the same material. When the EL layer 172a and the EL layer 172b emit light of the same color, the current density per unit emission luminance can be reduced. Thus, the reliability of the light-emitting element 61 can be increased.

The emission color of the light-emitting element can be red, green, blue, cyan, magenta, yellow, white, or the like depending on the material that constitutes the EL layer 172. Furthermore, the color purity can be further increased when the light-emitting element has a microcavity structure.

The light-emitting layer may contain two or more light-emitting substances that emit light of red (R), green (G), blue (B), yellow (Y), orange (O), or the like. The light-emitting element that emits white light preferably contains two or more kinds of light-emitting substances in the light-emitting layer. To obtain white light emission, two or more light-emitting substances are selected such that their emission colors are complementary colors. For example, when the emission color of a first light-emitting layer and the emission color of a second light-emitting layer have a relationship of complementary colors, it is possible to obtain a light-emitting element which emits white light as a whole. The same applies to a light-emitting element including three or more light-emitting layers.

The light-emitting layer preferably contains two or more light-emitting substances that emit light of R (red), G (green), B (blue), Y (yellow), O (orange), or the like. Alternatively, the light-emitting layer preferably contains two or more light-emitting substances that emit light containing two or more of spectral components of R, G, and B. Alternatively, as the light-emitting substance, a substance that emits near-infrared light can be used.

Examples of a light-emitting substance include a substance that emits fluorescent light (a fluorescent material), a substance that emits phosphorescent light (a phosphorescent material), an inorganic compound (a quantum dot material and the like), and a substance that exhibits thermally activated delayed fluorescence (a thermally activated delayed fluorescence (TADF) material).

### <Method for Forming Light-Emitting Element>

An example of a method for forming the light-emitting element 61 will be described below.

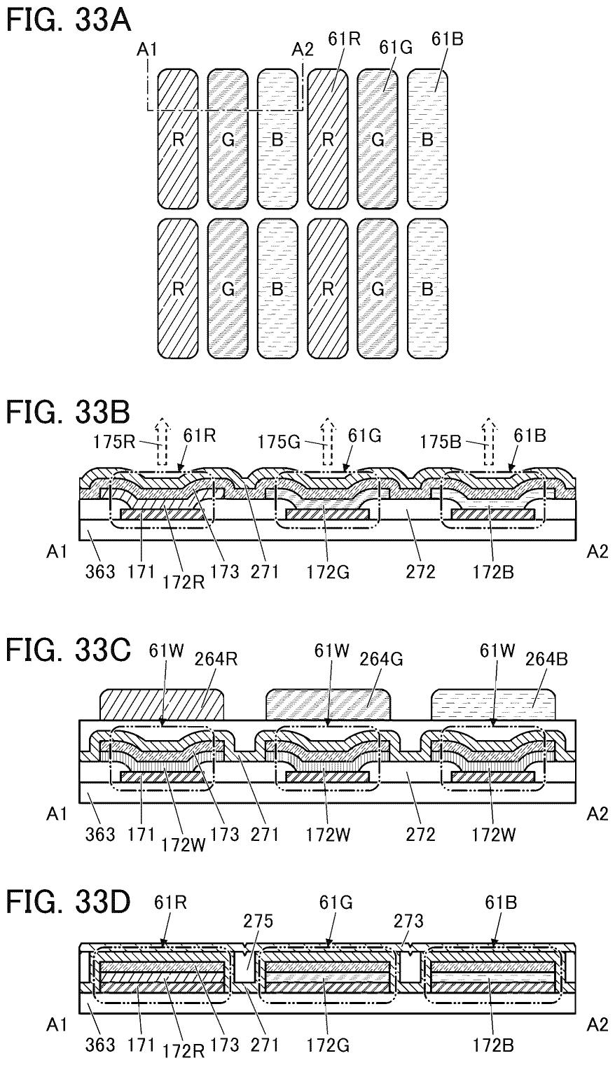

FIG. 33A illustrates a schematic top view of the light-emitting element 61. The light-emitting element 61 includes a plurality of light-emitting elements 61R exhibiting red, a plurality of light-emitting elements 61G exhibiting green, and a plurality of light-emitting elements 61B exhibiting blue. In FIG. 33A, light-emitting regions of the light-emitting elements are denoted by R, G, and B to easily differentiate the light-emitting elements. Although FIG. 33A illustrates the structure having three emission colors of red (R), green (G), and blue (B), one embodiment of the present invention is not limited thereto. For example, the structure may have four or more colors.

The light-emitting elements 61R, the light-emitting elements 61G, and the light-emitting elements 61B are arranged in a matrix. Although FIG. 33A illustrates what is called a stripe arrangement in which the light-emitting elements of the same color are arranged in one direction, the arrangement method of the light-emitting elements is not limited thereto.

As the light-emitting element 61R, the light-emitting element 61G, and the light-emitting element 61B, an EL device such as an OLED or a QOLED (Quantum-dot Organic Light Emitting Diode) is preferably used. As examples of a light-emitting substance contained in the EL element, a substance that emits fluorescent light (a fluorescent material), a substance that emits phosphorescent light (a phosphorescent material), an inorganic compound (e.g., a quantum dot material), a substance exhibiting thermally activated delayed fluorescence (a thermally activated delayed fluorescence (TADF) material), and the like can be given.

FIG. 33B is a cross-sectional schematic view taken along dashed-dotted line A1-A2 in FIG. 33A. FIG. 33B illustrates cross sections of the light-emitting element 61R, the light-emitting element 61G, and the light-emitting element 61B. The light-emitting element 61R, the light-emitting element 61G, and the light-emitting element 61B are each provided over an insulator 363 and include the conductor 171 functioning as a pixel electrode and the conductor 173 functioning as a common electrode. For the insulator 363, one or both of an inorganic insulating film and an organic insulating film can be used. An inorganic insulating film is preferably used as the insulator 363. Examples of the inorganic insulating film include an oxide insulating film and a nitride insulating film such as a silicon oxide film, a silicon oxynitride film, a silicon nitride oxide film, a silicon nitride film, an aluminum oxide film, an aluminum oxynitride film, and a hafnium oxide film.

The light-emitting elements 61R each include an EL layer 172R between the conductor 171 functioning as a pixel electrode and the conductor 173 functioning as a common electrode. The EL layer 172R contains at least a light-emitting organic compound that emits light with a peak in a red wavelength range. An EL layer 172G included in the light-emitting element 61G contains at least a light-emitting organic compound that emits light with a peak in a green wavelength range. An EL layer 172B included in the light-emitting element 61B contains at least a light-emitting organic compound that emits light with a peak in a blue wavelength range.

The EL layer 172R, the EL layer 172G, and the EL layer 172B may each include one or more of an electron-injection layer, an electron-transport layer, a hole-injection layer, and a hole-transport layer in addition to the layer containing a light-emitting organic compound (the light-emitting layer).

The conductor 171 functioning as a pixel electrode is provided in each of the light-emitting elements. The conductor 173 functioning as a common electrode is provided as a continuous layer shared by the light-emitting elements. A conductive film that has a property of transmitting visible light is used for either the conductor 171 functioning as a pixel electrode or the conductor 173 functioning as a common electrode, and a conductive film that has a reflective property is used for the other. When the conductor 171 functioning as a pixel electrode has a light-transmitting property and the conductor 173 functioning as a common electrode has a reflective property, a bottom-emission display apparatus can be obtained, whereas when the conductor 171 functioning as a pixel electrode has a reflective property and the conductor 173 functioning as a common electrode has a light-transmitting property, a top-emission display apparatus can be obtained. Note that when both the conductor 171 functioning as a pixel electrode and the conductor 173 functioning as a common electrode have a light-transmitting property, a dual-emission display apparatus can be obtained.

For example, in the case where the light-emitting element 61R has a top-emission structure, light 175R is emitted from the light-emitting element 61R to the conductor 173 side. In the case where the light-emitting element 61R has a top-emission structure, light 175G is emitted from the light-emitting element 61G to the conductor 173 side. In the case where the light-emitting element 61B has a top-emission structure, light 175B is emitted from the light-emitting element 61B to the conductor 173 side.

An insulator 272 is provided to cover end portions of the conductor 171 functioning as a pixel electrode. End portions of the insulator 272 are preferably tapered. That is, the insulator 272 preferably has a shape in which the thickness of the insulator 272 decreases toward the bottom surface of the insulator 272 at the end portions of the insulator 272. For the insulator 272, a material similar to the material that can be used for the insulator 363 can be used.

The insulator 272 is provided to prevent an unintentional electric short-circuit between adjacent light-emitting elements 61 and unintended light emission therefrom. The insulator 272 also has a function of preventing the contact of a metal mask with the conductor 171 in the case where the metal mask is used to form the EL layer 172.

The EL layer 172R, the EL layer 172G, and the EL layer 172B each include a region in contact with a top surface of the conductor 171 functioning as a pixel electrode and a region in contact with a surface of the insulator 272. End portions of the EL layer 172R, the EL layer 172G, and the EL layer 172B are positioned over the insulator 272.

As illustrated in FIG. 33B, there is a gap between the two EL layers of the light-emitting elements with different colors. In this manner, the EL layer 172R, the EL layer 172G, and the EL layer 172B are preferably provided so as not to be in contact with each other. This can suitably prevent unintentional light emission (also referred to as crosstalk) from being caused by current flowing through two adjacent EL layers. As a result, the contrast can be increased to achieve a display apparatus with high display quality.

The EL layer 172R, the EL layer 172G, and the EL layer 172B can be formed separately by a vacuum evaporation method or the like using a shadow mask such as a metal mask. Alternatively, these layers may be formed separately by a photolithography method. The use of a photolithography method achieves a display apparatus with high definition, which is difficult to obtain in the case of using a metal mask.

In this specification and the like, a device formed using a metal mask or an FMM (fine metal mask, high-resolution metal mask) may be referred to as a device having an MM (metal mask) structure. In addition, in this specification and the like, a device fabricated without using a metal mask or an FMM is sometimes referred to as a device having an MML (metal maskless) structure. A display apparatus having an MML structure is fabricated without using a metal mask and thus has higher flexibility in designing the pixel arrangement, the pixel shape, and the like than a display apparatus having an MM structure.

A protective layer 271 is provided over the conductor 173 functioning as a common electrode so as to cover the light-emitting element 61R, the light-emitting element 61G, and the light-emitting element 61B. The protective layer 271 has a function of preventing diffusion of impurities such as water into the light-emitting elements from above.

The protective layer 271 can have, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide (IGZO) may be used for the protective layer 271. Note that the protective layer 271 can be formed by an ALD (Atomic Layer Deposition) method, a CVD (Chemical Vapor Deposition) method, or a sputtering method. Although the protective layer 271 includes an inorganic insulating film in this example, one embodiment of the present invention is not limited thereto. For example, the protective layer 271 may have a stacked-layer structure of an inorganic insulating film and an organic insulating film.

Note that in this specification, a nitride oxide refers to a compound that contains more nitrogen than oxygen. An oxynitride refers to a compound that contains more oxygen than nitrogen. The content of each element can be measured by Rutherford backscattering spectrometry (RBS) or the like, for example.

In the case where an indium gallium zinc oxide is used for the protective layer 271, the indium gallium zinc oxide can be processed by a wet etching method or a dry etching method. For example, in the case where IGZO is used as the protective layer 271, a chemical solution of oxalic acid, phosphoric acid, a mixed chemical solution (e.g., a mixed chemical solution of phosphoric acid, acetic acid, nitric acid, and water, which is also referred to as a mixed acid aluminum etchant), or the like can be used. Note that the volume ratio of phosphoric acid, acetic acid, nitric acid, and water in the mixed acid aluminum etchant can be 53.3:6.7:3.3:36.7 or in the vicinity thereof.

Note that the structure illustrated in FIG. 33B may be referred to as an SBS structure described later.

FIG. 33C illustrates an example different from the above. Specifically, in FIG. 33C, light-emitting elements 61W that exhibit white light are provided. The light-emitting elements 61W each include an EL layer 172W that exhibits white light between the conductor 171 functioning as a pixel electrode and the conductor 173 functioning as a common electrode.

The EL layer 172W can have, for example, a structure in which two or more light-emitting layers that are selected so as to emit light of complementary colors are stacked. It is also possible to use a stacked EL layer in which a charge-generation layer is provided between light-emitting layers.

FIG. 33C illustrates three light-emitting elements 61W side by side. A coloring layer 264R is provided above the light-emitting element 61W on the left. The coloring layer 264R functions as a band path filter that transmits red light. Similarly, a coloring layer 264G that transmits green light is provided above the light-emitting element 61W in the middle, and a coloring layer 264B that transmits blue light is provided above the light-emitting element 61W on the right. Thus, the display apparatus can display an image with colors.

Here, the EL layer 172W and the conductor 173 functioning as a common electrode are each separated between two adjacent light-emitting elements 61W. This can prevent unintentional light emission from being caused by current flowing through the EL layers 172W of the two adjacent light-emitting elements 61W. Particularly when stacked EL layers in which a charge-generation layer is provided between two light-emitting layers are used as the EL layer 172W, crosstalk is more noticeable as the definition increases, i.e., as the distance between adjacent pixels decreases, leading to lower contrast. Thus, the above structure can achieve a display apparatus having both high definition and high contrast.

The EL layer 172W and the conductor 173 functioning as a common electrode are preferably separated by a photolithography method. This can reduce an interval between light-emitting elements, enabling a display apparatus with a higher aperture ratio than that formed using, for example, a shadow mask such as a metal mask.

Note that in the case of a bottom-emission light-emitting element, a coloring layer may be provided between the conductor 171 functioning as a pixel electrode and the insulator 363.

FIG. 33D illustrates an example different from the above. Specifically, in FIG. 33D, the insulators 272 are not provided between the light-emitting element 61R, the light-emitting element 61G, and the light-emitting element 61B. With such a structure, the display apparatus can have a high aperture ratio. When the insulators 272 are not provided, unevenness formed by the light-emitting elements 61 can be reduced, thereby improving the viewing angle of the display apparatus. Specifically, the viewing angle can be greater than or equal to 150 degrees and less than 180 degrees, preferably greater than or equal to 160 degrees and less than 180 degrees.

The protective layer 271 covers the side surfaces of the EL layer 172R, the EL layer 172G, and the EL layer 172B. With this structure, impurities (typically, water or the like) can be inhibited from entering the EL layer 172R, the EL layer 172G, and the EL layer 172B through their side surfaces. In addition, leakage current between adjacent light-emitting elements 61 is reduced, so that color saturation and contrast ratio are improved and power consumption is reduced.

In the structure illustrated in FIG. 33D, the top shapes of the conductor 171, the EL layer 172R, and the conductor 173 are substantially the same. This structure can be formed in a manner in which the conductor 171, the EL layer 172R, and the conductor 173 are formed and collectively processed using a resist mask or the like. In this process, the EL layer 172R and the conductor 173 are processed using the conductor 173 as a mask, and thus this process can be called self-alignment patterning. Although the EL layer 172R is described here, the EL layer 172G and the EL layer 172B can each have a similar structure.

In FIG. 33D, a protective layer 273 is further provided over the protective layer 271. For example, the protective layer 271 can be formed with an apparatus that can deposit a film with excellent coverage (typically, an ALD apparatus), and the protective layer 273 is formed with an apparatus that can deposit a film with coverage inferior to that of the protective layer 271 (typically, a sputtering apparatus), whereby a region 275 can be provided between the protective layer 271 and the protective layer 273. In other words, the regions 275 are positioned between the EL layer 172R and the EL layer 172G and between the EL layer 172G and the EL layer 172B.

Note that the region 275 includes, for example, any one or more selected from air, nitrogen, oxygen, carbon dioxide, and Group 18 elements (typically, helium, neon, argon, xenon, and krypton). Furthermore, for example, a gas used during the deposition of the protective layer 273 is sometimes included in the region 275. For example, in the case where the protective layer 273 is deposited using a sputtering method, any one or more of the above-described Group 18 elements is sometimes included in the region 275. In the case where a gas is included in the region 275, a gas can be identified with a gas chromatography method or the like. Furthermore, in the case where the protective layer 273 is deposited by a sputtering method, a gas used in the sputtering is sometimes contained in the protective layer 273. In this case, an element such as argon is sometimes detected when the protective layer 273 is analyzed by an energy dispersive X-ray analysis (EDX analysis (Energy Dispersive X-ray spectroscopy)) or the like.

In the case where the refractive index of the region 275 is lower than the refractive index of the protective layer 271, light emitted from the EL layer 172R, the EL layer 172G, or the EL layer 172B is reflected at the interface between the protective layer 271 and the region 275. Thus, light emitted from the EL layer 172R, the EL layer 172G, or the EL layer 172B can be inhibited from entering an adjacent pixel in some cases. This can inhibit color mixture of light emitted from adjacent pixels and thus can improve the display quality of the display apparatus.

In the case of the structure illustrated in FIG. 33D, a region between the light-emitting element 61R and the light-emitting element 61G or a region between the light-emitting element 61G and the light-emitting element 61B (hereinafter simply referred to as a distance between the light-emitting elements) can be small. Specifically, the distance between the light-emitting elements can be less than or equal to 1 m, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, a region is included in which an interval between the side surface of the EL layer 172R and the side surface of the EL layer 172G or an interval between the side surface of the EL layer 172G and the side surface of the EL layer 172B is less than or equal to 1 m, preferably less than or equal to 0.5 m (500 nm), further preferably less than or equal to 100 nm.

In the case where the region 275 includes a gas, the light-emitting elements can be separated from each other and color mixing of light or crosstalk between the light-emitting elements can be inhibited.

The region 275 may be a space or may be filled with a filler. Examples of the filler include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In addition, a photoresist may be used as the filler. The photoresist used as the filler may be a positive photoresist or a negative photoresist.

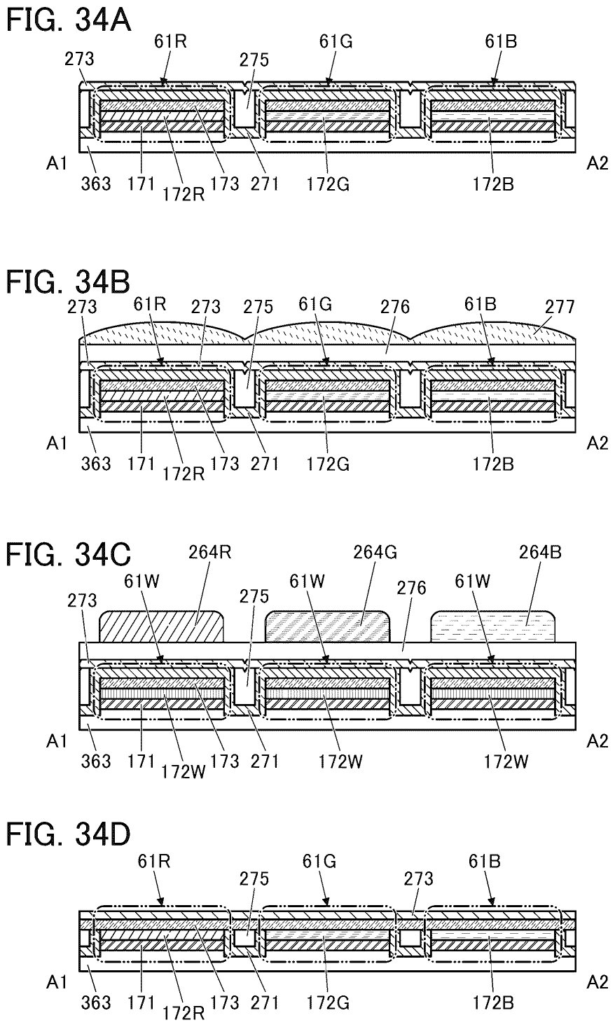

FIG. 34A illustrates an example different from the above. Specifically, the structure illustrated in FIG. 34A is different from the structure illustrated in FIG. 33D in the structure of the insulator 363. The top surface of the insulator 363 is partly removed when the light-emitting element 61R, the light-emitting element 61G, and the light-emitting element 61B are processed, so that the insulator 363 has a depressed portion. In addition, the protective layer 271 is formed in the depressed portion. In other words, in the cross-sectional view, a region is provided, in which the bottom surface of the protective layer 271 is positioned below the bottom surface of the conductor 171. With the region, impurities (typically, water or the like) can be suitably inhibited from entering the light-emitting element 61R, the light-emitting element 61G, and the light-emitting element 61B from the bottom. It is likely that the depressed portion can be formed when impurities (also referred to as residue) that may be attached to the side surfaces of the light-emitting element 61R, the light-emitting element 61G, and the light-emitting element 61B in processing of the light-emitting elements are removed by e.g., wet etching. After the residue is removed, the side surfaces of the light-emitting elements are covered with the protective layer 271, whereby a highly reliable display apparatus can be provided.

FIG. 34B illustrates an example different from the above. Specifically, the structure illustrated in FIG. 34B includes an insulator 276 and a microlens array 277 in addition to the structure illustrated in FIG. 34A. The insulator 276 functions as an adhesive layer. Note that when the refractive index of the insulator 276 is lower than that of the microlens array 277, the microlens array 277 can condense light emitted from the light-emitting element 61R, the light-emitting element 61G, and the light-emitting element 61B. This can increase the light extraction efficiency of the display apparatus. In particular, this is suitable, because a user can see bright images when the user sees the display surface from the front of the display apparatus. As the insulator 276, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet or the like may be used.

FIG. 34C illustrates an example different from the above. Specifically, the structure illustrated in FIG. 34C includes three light-emitting elements 61W instead of the light-emitting element 61R, the light-emitting element 61G, and the light-emitting element 61B in the structure illustrated in FIG. 34A. In addition, the insulator 276 is provided over the three light-emitting elements 61W, and the coloring layer 264R, the coloring layer 264G, and the coloring layer 264B are provided over the insulator 276. Specifically, the coloring layer 264R that transmits red light is provided at a position overlapping with the light-emitting element 61W on the left, the coloring layer 264G that transmits green light is provided at a position overlapping with the light-emitting element 61W in the middle, and the coloring layer 264B that transmits blue light is provided at a position overlapping with the light-emitting element 61W on the right. Thus, the display apparatus can display an image with colors. The structure illustrated in FIG. 34C is also a modification example of the structure illustrated in FIG. 33C.

FIG. 34D illustrates an example different from the above. Specifically, in the structure illustrated in FIG. 34D, the protective layer 271 is provided adjacent to the side surfaces of the conductor 171 and the EL layer 172. The conductor 173 is provided as a continuous layer shared by the light-emitting elements. In the structure illustrated in FIG. 34D, the region 275 is preferably filled with a filler.

Furthermore, the color purity of emitted light can be further increased when the light-emitting element 61 has a microcavity structure. In order that the light-emitting element 61 has a microcavity structure, a product of a distance d between the conductor 171 and the conductor 173 and a refractive index a of the EL layer 172 (optical path length) is set to b times half of a wavelength λ (b is an integer greater than or equal to 1). The distance d can be obtained by Formula 1.

d=b×λ/(2×a) Formula 1

According to Formula 1, in the light-emitting element 61 having the microcavity structure, the distance d is determined in accordance with the wavelength (emission color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G in some cases.

To be exact, the distance d is a distance from a reflection region in the conductor 171 functioning as a reflective electrode to a reflection region in the conductor 173 functioning as an electrode having properties of transmitting and reflecting emitted light (a semi-transmissive and semi-reflective electrode). For example, in the case where the conductor 171 is a stack of silver and ITO (Indium Tin Oxide) that is a transparent conductive film and the ITO is positioned on the EL layer 172 side, the distance d suitable for the emission color can be set by adjusting the thickness of the ITO. That is, even when the EL layer 172R, the EL layer 172G, and the EL layer 172B have the same thickness, the distance d suitable for the emission color can be obtained by adjusting the thickness of the ITO.

However, it is sometimes difficult to determine the exact position of the reflection region in each of the conductor 171 and the conductor 173. In that case, it is assumed that the effect of the microcavity structure can be fully obtained with a certain position in each of the conductor 171 and the conductor 173 being supposed as the reflection region.

The light-emitting element 61 includes a hole-injection layer, a hole-transport layer, a light-emitting layer, an electron-transport layer, an electron-injection layer, and the like. Note that a specific structure example of the light-emitting element 61 will be described in another embodiment. In order to increase the outcoupling efficiency in the microcavity structure, the optical path length from the conductor 171 functioning as a reflective electrode to the light-emitting layer is preferably set to an odd multiple of λ/4. In order to achieve this optical distance, the thicknesses of the layers in the light-emitting element 61 are preferably adjusted as appropriate.

In the case where light is emitted from the conductor 173 side, the reflectance of the conductor 173 is preferably higher than the transmittance thereof. The light transmittance of the conductor 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductor 173 is set low (the reflectance is set high), the effect of the microcavity can be enhanced.

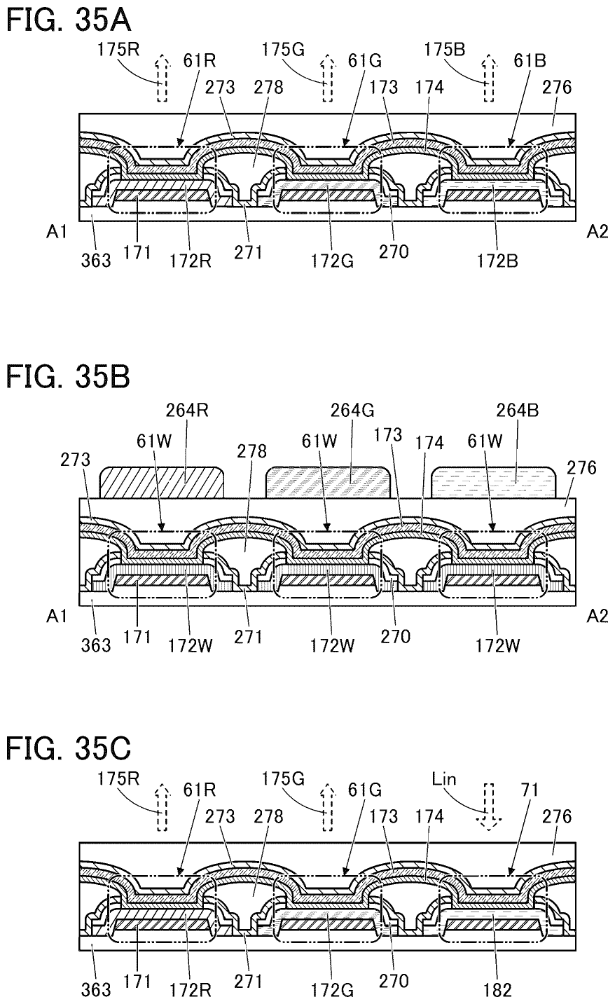

FIG. 35A illustrates an example different from the above. Specifically, in the structure illustrated in FIG. 35A, the EL layer 172 extends beyond the end portions of the conductor 171 in each of the light-emitting element 61R, the light-emitting element 61G, and the light-emitting element 61B. For example, in the light-emitting element 61R, the EL layer 172R extends beyond the end portions of the conductor 171. In the light-emitting element 61G, the EL layer 172G extends beyond the end portions of the conductor 171. In the light-emitting element 61B, the EL layer 172B extends beyond the end portions of the conductor 171.

The light-emitting element 61R, the light-emitting element 61G, and the light-emitting element 61B each include a region where the EL layer 172 overlaps with the protective layer 271 with an insulator 270 therebetween. In a region between adjacent light-emitting elements 61, an insulator 278 is provided over the protective layer 271.

Examples of the insulator 278 include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. Alternatively, a photoresist may be used as the insulator 278. The photoresist used as the insulator 278 may be a positive photoresist or a negative photoresist.

A common layer 174 is provided over the light-emitting element 61R, the light-emitting element 61G, the light-emitting element 61B, and the insulator 278, and the conductor 173 is provided over the common layer 174. The common layer 174 includes a region in contact with the EL layer 172R, a region in contact with the EL layer 172G, and a region in contact with the EL layer 172B. The common layer 174 is shared by the light-emitting element 61R, the light-emitting element 61G, and the light-emitting element 61B.

As the common layer 174, one or more of a hole-injection layer, a hole-transport layer, a hole-blocking layer, an electron-blocking layer, an electron-transport layer, and an electron-injection layer can be used. For example, the common layer 174 may be a carrier-injection layer (a hole-injection layer or an electron-injection layer). The common layer 174 can also be regarded as part of the EL layer 172. Note that the common layer 174 is provided as necessary. In the case where the common layer 174 is provided, a layer having the same function as the common layer 174 among the layers included in the EL layer 172 is not necessarily provided.

The protective layer 273 is provided over the conductor 173, and the insulator 276 is provided over the protective layer 273.

FIG. 35B illustrates an example different from the above. Specifically, the structure illustrated in FIG. 35B includes three light-emitting elements 61W instead of the light-emitting element 61R, the light-emitting element 61G, and the light-emitting element 61B in the structure illustrated in FIG. 35A. In addition, the insulator 276 is provided over the three light-emitting elements 61W, and the coloring layer 264R, the coloring layer 264G, and the coloring layer 264B are provided over the insulator 276. Specifically, the coloring layer 264R that transmits red light is provided at a position overlapping with the light-emitting element 61W on the left, the coloring layer 264G that transmits green light is provided at a position overlapping with the light-emitting element 61W in the middle, and the coloring layer 264B that transmits blue light is provided at a position overlapping with the light-emitting element 61W on the right. Thus, the display apparatus can display an image with colors. The structure illustrated in FIG. 35B is also a modification example of the structure illustrated in FIG. 34C.

As illustrated in FIG. 35C, the light-emitting element 61R, the light-emitting element 61G, and the light-receiving element 71 may be provided over the insulator 363. The light-receiving element 71 illustrated in FIG. 35C can be achieved by replacing the EL layer 172 of the light-emitting element 61 with an active layer 182 (also referred to as a “light-receiving layer”) functioning as a photoelectric conversion layer. The active layer 182 has a feature of changing a resistance value depending on the wavelength and intensity of the incident light. The active layer 182 can be formed with an organic compound similar to that of the EL layer 172. Note that an inorganic material such as silicon may be used for the active layer 182.

The light-receiving element 71 has a function of detecting light Lin entering from the outside of the display apparatus and passing through the protective layer 273, the conductor 173, and the common layer 174. A coloring layer transmitting light in a given wavelength range may be provided on the incident side of the light Lin so as to overlap with the light-emitting element 71.

<Materials that can be Used for Light-Emitting Element and Light-Receiving Element>

Materials that can be used for the light-emitting element and the light-receiving element will be described.

The hole-injection layer is a layer injecting holes from an anode to the hole-transport layer, and a layer containing a material having a high hole-injection property. Examples of a material having a high hole-injection property include an aromatic amine compound and a composite material containing a hole-transport material and an acceptor material (electron-accepting material).

The hole-transport layer is a layer transporting holes, which are injected from the anode by the hole-injection layer, to the light-emitting layer. The hole-transport layer is a layer containing a hole-transport material. For the hole-transport material, a substance having a hole mobility higher than or equal to 1×10⁶ cm²/Vs is preferable. Note that other substances can also be used as long as they have a property of transporting more holes than electrons. As the hole-transport material, materials having a high hole-transport property, such as a Tc-electron rich heteroaromatic compound (e.g., a carbazole derivative, a thiophene derivative, and a furan derivative) and an aromatic amine (a compound having an aromatic amine skeleton), are preferable.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a Tc-electron deficient heteroaromatic compound such as a nitrogen-containing heteroaromatic compound.

The electron-injection layer is a layer injecting electrons from the cathode to the electron-transport layer and a layer containing a material having a high electron-injection property. As the material having a high electron-injection property, an alkali metal, an alkaline earth metal, or a compound thereof can be used. As the material having a high electron-injection property, a composite material containing an electron-transport material and a donor material (an electron-donating material) can also be used.

As the electron-injection layer, an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate can be used, for example. In addition, the electron-injection layer may have a stacked-layer structure of two or more layers. For example, it is possible to employ a structure where lithium fluoride is used for a first layer and ytterbium is used for a second layer as the stacked-layer structure.

Alternatively, the electron-injection layer may be formed using an electron-transport material. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

The light-receiving element includes at least an active layer that functions as a photoelectric conversion layer between a pair of electrodes. In this specification and the like, one of the pair of electrodes may be referred to as a pixel electrode and the other may be referred to as a common electrode.

One of the pair of electrodes of the light-receiving element functions as an anode, and the other electrode functions as a cathode. The case where the pixel electrode functions as an anode and the common electrode functions as a cathode is described below as an example. When the light-receiving element is driven by application of reverse bias between the pixel electrode and the common electrode, light entering the light-receiving element can be detected and charge can be generated and extracted as current. Alternatively, the pixel electrode may function as a cathode and the common electrode may function as an anode.

The active layer included in the light-receiving element includes a semiconductor. Examples of the semiconductor include an inorganic semiconductor such as silicon and an organic semiconductor including an organic compound. This embodiment shows an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When Tc-electron conjugation (resonance) spreads on a plane as in benzene, an electron-donating property (donor property) usually increases; however, fullerene has a spherical shape, and thus has a high electron-accepting property although Tc-electron conjugation widely spreads. The high electron-accepting property efficiently causes rapid charge separation and is useful for a light-receiving element. Both C₆₀ and C₇₀ have a wide absorption band in the visible light region, and C₇₀ is especially preferable because of having a larger T-electron conjugation system and a wider absorption band in the long wavelength region than C₆₀. Other examples of fullerene derivatives include [6,6]-phenyl-C₇₁-butyric acid methyl ester (abbreviation: PC70BM), [6,6]-phenyl-C₆₁-butyric acid methyl ester (abbreviation: PC60BM), and 1′,1″,4′,4″-tetrahydro-di[1,4]methanonaphthaleno[1,2:2′,3′,56,60:2″,3″][5,6]fullerene-C₆₀ (abbreviation: ICBA).

Another example of an n-type semiconductor material is a perylenetetracarboxylic derivative such as N,N-dimethyl-3,4,9,10-perylenetetracarboxylic diimide (abbreviation: Me-PTCDI).

Another example of an n-type semiconductor material is 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Examples of a p-type semiconductor material include a carbazole derivative, a thiophene derivative, a furan derivative, and a compound having an aromatic amine skeleton. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase a carrier-transport property.

For example, the active layer is preferably formed by co-evaporation of an n-type semiconductor and a p-type semiconductor. Alternatively, the active layer may be formed by stacking an n-type semiconductor and a p-type semiconductor.

In addition to the active layer, the light-receiving element may further include a layer containing any of a substance having a high hole-transport property, a substance having a high electron-transport property, a substance having a bipolar property (a substance having a high electron-transport property and a high hole-transport property), and the like. Without limitation to the above, the light-receiving element may further include a layer containing any of a substance having a high hole-injection property, a hole-blocking material, a material having a high electron-injection property, an electron-blocking material, and the like.

Either a low molecular compound or a high molecular compound can be used for the light-receiving element, and an inorganic compound may be contained. Each of the layers included in the light-receiving element can be formed by an evaporation method (including a vacuum evaporation method), a transfer method, a printing method, an inkjet method, a coating method, or the like.

As the hole-transport material or the electron-blocking material, a high molecular compound such as poly(3,4-ethylenedioxythiophene)/(polystyrenesulfonic acid) (abbreviation: PEDOT/PSS), or an inorganic compound such as a molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving element may include a mixed film of PEIE and ZnO, for example.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer may contain a mixture of three or more kinds of materials. For example, a third material may be mixed with an n-type semiconductor material and a p-type semiconductor material in order to extend the wavelength range. In this case, the third material may be a low molecular compound or a high molecular compound.

At least part of the structure examples, the drawings corresponding thereto, and the like described in this embodiment as an example can be combined with any of the other structure examples, the other drawings, and the like as appropriate.

### Embodiment 4

In this embodiment, a cross-sectional structure example of the display apparatus 10 (the display apparatus 10A, the display apparatus 10B, or the display apparatus 10C) of one embodiment of the present invention will be described.

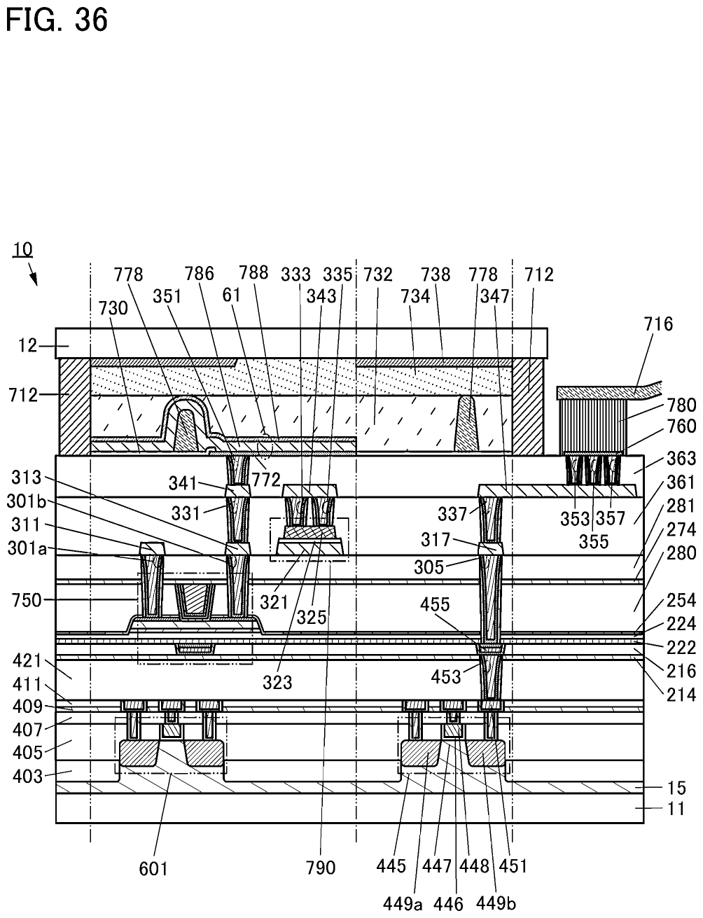

FIG. 36 is a cross-sectional view illustrating a structure example of the display apparatus 10. The display apparatus 10 includes the substrate 11 and the substrate 12, and the substrate 11 and the substrate 12 are attached to each other with a sealant 712.

As the substrate 11, for example, a substrate such as a glass substrate or a single crystal silicon substrate can be used.

A semiconductor substrate 15 is provided over the substrate 11, and provided with a transistor 445 and a transistor 601. The transistor 445 and the transistor 601 can each be the transistor 21 provided in the layer 20 described in Embodiment 1.

The transistor 445 is formed of a conductor 448 having a function of a gate electrode, an insulator 446 having a function of a gate insulator, and part of the substrate 11 and includes a semiconductor region 447 including a channel formation region, a low-resistance region 449a having a function of one of a source region and a drain region, and a low-resistance region 449b having a function of the other of the source region and the drain region. The transistor 445 can be a p-channel transistor or an n-channel transistor.

The transistor 445 is electrically isolated from other transistors by an element isolation layer 403. FIG. 36 illustrates the case where the transistor 445 and the transistor 601 are electrically isolated from each other by the element isolation layer 403. The element isolation layer 403 can be formed by a LOCOS (LOCal Oxidation of Silicon) method, an STI (Shallow Trench Isolation) method, or the like.

Here, in the transistor 445 illustrated in FIG. 36, the semiconductor region 447 has a projecting shape. Moreover, the conductor 448 is provided to cover the side surface and the top surface of the semiconductor region 447 with the insulator 446 therebetween. Note that FIG. 36 does not illustrate the state where the conductor 448 covers the side surface of the semiconductor region 447. A material for adjusting a work function can be used for the conductor 448.

A transistor having a projecting semiconductor region, like the transistor 445, can be referred to as a fin-type transistor because a projecting portion of a semiconductor substrate is used. An insulator having a function of a mask for forming a projecting portion may be provided in contact with the top surface of the projecting portion. Although FIG. 36 illustrates the structure in which the projecting portion is formed by processing part of the substrate 11, a semiconductor having a projecting shape may be formed by processing an SOI substrate.

Note that the structure of the transistor 445 illustrated in FIG. 36 is an example; the structure of the transistor 445 is not limited thereto and can be changed as appropriate in accordance with the circuit structure, an operation method of the circuit, or the like. For example, the transistor 445 may be a planar transistor.

The transistor 601 can have a structure similar to that of the transistor 445.

An insulator 405, an insulator 407, an insulator 409, and an insulator 411 are provided over the substrate 11, in addition to the element isolation layer 403, the transistor 445, and the transistor 601. A conductor 451 is embedded in the insulator 405, the insulator 407, the insulator 409, and the insulator 411. Here, the top surface of the conductor 451 and the top surface of the insulator 411 can be substantially level with each other.

An insulator 421 and an insulator 214 are provided over the conductor 451 and the insulator 411. A conductor 453 is embedded in the insulator 421 and the insulator 214. Here, the top surface of the conductor 453 and the top surface of the insulator 214 can be substantially level with each other.

An insulator 216 is provided over the conductor 453 and the insulator 214. A conductor 455 is embedded in the insulator 216. Here, the top surface of the conductor 455 and the top surface of the insulator 216 can be substantially level with each other.

An insulator 222, an insulator 224, an insulator 254, an insulator 280, an insulator 274, and an insulator 281 are provided over the conductor 455 and the insulator 216. A conductor 305 is embedded in the insulator 222, the insulator 224, the insulator 254, the insulator 280, the insulator 274, and the insulator 281. Here, the top surface of the conductor 305 and the top surface of the insulator 281 can be substantially level with each other.

An insulator 361 is provided over the conductor 305 and the insulator 281. A conductor 317 and a conductor 337 are embedded in the insulator 361. Here, the top surface of the conductor 337 and the top surface of the insulator 361 can be substantially level with each other.

An insulator 363 is provided over the conductor 337 and the insulator 361. A conductor 347, a conductor 353, a conductor 355, and a conductor 357 are embedded in the insulator 363. Here, the top surfaces of the conductor 353, the conductor 355, and the conductor 357 and the top surface of the insulator 363 can be substantially level with each other.

A connection electrode 760 is provided over the conductor 353, the conductor 355, the conductor 357, and the insulator 363. In addition, an anisotropic conductor 780 is provided to be electrically connected to the connection electrode 760, and an FPC (Flexible Printed Circuit) 716 is provided to be electrically connected to the anisotropic conductor 780. A variety of signals and the like are supplied to the display apparatus 10 from the outside of the display apparatus 10 through the FPC 716.

As illustrated in FIG. 36, the low-resistance region 449b having a function of the other of the source region and the drain region of the transistor 445 is electrically connected to the FPC 716 through the conductor 451, the conductor 453, the conductor 455, the conductor 305, the conductor 317, the conductor 337, the conductor 347, the conductor 353, the conductor 355, the conductor 357, the connection electrode 760, and the anisotropic conductor 780. Although FIG. 36 illustrates three conductors, the conductor 353, the conductor 355, and the conductor 357, as conductors that electrically connect the connection electrode 760 and the conductor 347, one embodiment of the present invention is not limited thereto. The number of conductors having a function of electrically connecting the connection electrode 760 and the conductor 347 may be one, two, or four or more. Providing a plurality of conductors having a function of electrically connecting the connection electrode 760 and the conductor 347 can reduce the contact resistance.

A transistor 750 is provided over the insulator 214. The transistor 750 can be the transistor 52 provided in the layer 50 described in Embodiment 1. For example, the transistor 750 can be the transistor provided in the pixel circuit 51. An OS transistor can be suitably used as the transistor 750. The OS transistor has a feature of an extremely low off-state current. Consequently, the retention time for image data or the like can be increased, so that the frequency of the refresh operation can be reduced. For example, the frame frequency or the refresh rate for displaying a still image can be less than or equal to 1 Hz, preferably less than or equal to 0.1 Hz. Thus, power consumption of the display apparatus 10 can be reduced.

A conductor 301a and a conductor 301b are embedded in the insulator 254, the insulator 280, the insulator 274, and the insulator 281. The conductor 301a is electrically connected to one of a source and a drain of the transistor 750, and the conductor 301b is electrically connected to the other of the source and the drain of the transistor 750. Here, the top surfaces of the conductor 301a and the conductor 301b and the top surface of the insulator 281 can be substantially level with each other.

A conductor 311, a conductor 313, a conductor 331, a capacitor 790, a conductor 333, and a conductor 335 are embedded in the insulator 361. The conductor 311 and the conductor 313 are electrically connected to the transistor 750 and have a function of a wiring. The conductor 333 and the conductor 335 are electrically connected to the capacitor 790. Here, the top surfaces of the conductor 331, the conductor 333, and the conductor 335 and the top surface of the insulator 361 can be substantially level with each other.

A conductor 341, a conductor 343, and a conductor 351 are embedded in the insulator 363. Here, the top surface of the conductor 351 and the top surface of the insulator 363 can be substantially level with each other.

The insulator 405, the insulator 407, the insulator 409, the insulator 411, the insulator 421, the insulator 214, the insulator 280, the insulator 274, the insulator 281, the insulator 361, and the insulator 363 have a function of an interlayer film and may also have a function of a planarization film that covers unevenness thereunder. For example, the top surface of the insulator 363 may be planarized by planarization treatment using a chemical mechanical polishing (CMP) method or the like to have increased planarity.

As illustrated in FIG. 36, the capacitor 790 includes a lower electrode 321 and an upper electrode 325. An insulator 323 is provided between the lower electrode 321 and the upper electrode 325. That is, the capacitor 790 has a stacked-layer structure in which the insulator 323 functioning as a dielectric is held between the pair of electrodes. Although FIG. 36 illustrates an example in which the capacitor 790 is provided over the insulator 281, the capacitor 790 may be provided over an insulator different from the insulator 281.

In the example illustrated in FIG. 36, the conductor 301a, the conductor 301b, and the conductor 305 are formed in the same layer. The conductor 311, the conductor 313, and the conductor 317 and the lower electrode 321 are formed in the same layer in the illustrated example. The conductor 331, the conductor 333, the conductor 335, and the conductor 337 are formed in the same layer in the illustrated example. The conductor 341, the conductor 343, and the conductor 347 are formed in the same layer in the illustrated example. The conductor 351, the conductor 353, the conductor 355, and the conductor 357 are formed in the same layer in the illustrated example. Forming a plurality of conductors in the same layer simplifies the manufacturing process of the display apparatus 10 and thus the manufacturing cost of the display apparatus 10 can be reduced. Note that these conductors may be formed in different layers or may contain different types of materials.

The display apparatus 10 illustrated in FIG. 36 includes the light-emitting element 61. The light-emitting element 61 includes a conductor 772, an EL layer 786, and a conductor 788. The EL layer 786 contains an organic compound or an inorganic compound such as quantum dots.

Examples of materials that can be used as an organic compound include a fluorescent material and a phosphorescent material. Examples of materials that can be used as quantum dots include a colloidal quantum dot material, an alloyed quantum dot material, a core-shell quantum dot material, and a core quantum dot material.

The conductor 772 is electrically connected to the other of the source and the drain of the transistor 750 through the conductor 351, the conductor 341, the conductor 331, the conductor 313, and the conductor 301b. The conductor 772 is formed over the insulator 363 and has a function of a pixel electrode.

A material having a visible-light-transmitting property or a material having a visible-light-reflecting property can be used for the conductor 772. As a light-transmitting material, for example, an oxide material containing indium, zinc, tin, or the like is preferably used. As a reflective material, for example, a material containing aluminum, silver, or the like is preferably used.

Although not illustrated in FIG. 36, an optical member (optical substrate) such as a polarizing member, a retardation member, or an anti-reflection member can be provided in the display apparatus 10, for example.

On the substrate 12 side, a light-blocking layer 738 and an insulator 734 that is in contact with the light-blocking layer 738 are provided. The light-blocking layer 738 has a function of blocking light emitted from adjacent regions. Alternatively, the light-blocking layer 738 has a function of preventing external light from reaching the transistor 750 or the like.

In the display apparatus 10 illustrated in FIG. 36, an insulator 730 is provided over the insulator 363. Here, the insulator 730 can cover part of the conductor 772. Here, the light-emitting element 61 is a top-emission light-emitting element, which includes the conductor 788 having a light-transmitting property.

The light-blocking layer 738 is provided to include a region overlapping with the insulator 730. The light-blocking layer 738 is covered with the insulator 734. A space between the light-emitting element 61 and the insulator 734 is filled with a sealing layer 732.

A component 778 is provided between the insulator 730 and the EL layer 786. Moreover, the component 778 is provided between the insulator 730 and the insulator 734.

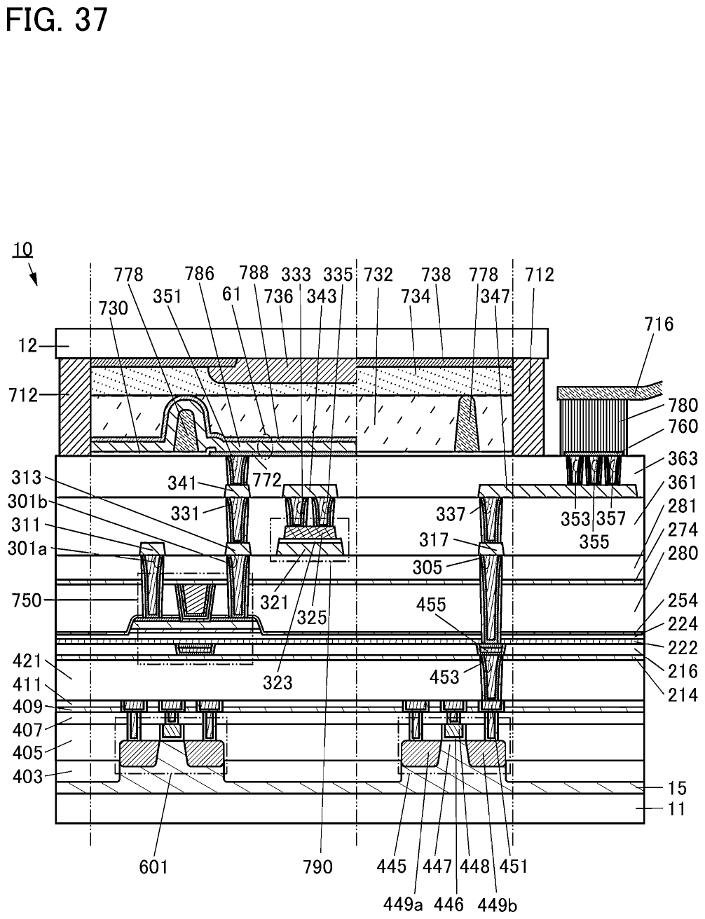

FIG. 37 illustrates a modification example of the display apparatus 10 illustrated in FIG. 36. The display apparatus 10 illustrated in FIG. 37 is different from the display apparatus 10 illustrated in FIG. 36 in that a coloring layer 736 is provided. Note that the coloring layer 736 is provided to have a region overlapping with the light-emitting element 61. Providing the coloring layer 736 can increase the color purity of light extracted from the light-emitting element 61. Thus, the display apparatus 10 can display high-quality images. Furthermore, all the light-emitting elements 61, for example, in the display apparatus 10 can be light-emitting elements that emit white light; hence, the EL layers 786 are not necessarily formed separately for each color, leading to higher definition of the display apparatus 10.

The light-emitting element 61 can have a micro-optical resonator (microcavity) structure. Thus, light of predetermined colors (e.g., RGB) can be extracted without a coloring layer, and the display apparatus 10 can perform color display. The structure without a coloring layer can prevent light absorption by the coloring layer. As a result, the display apparatus 10 can display high-luminance images, and power consumption of the display apparatus 10 can be reduced. Note that a structure without a coloring layer can be employed even when the EL layer 786 is formed into an island shape for each pixel or formed into a stripe shape for each pixel column, i.e., the EL layers 786 are formed separately for each color. Note that the luminance of the display apparatus 10 can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m².

At least part of the structure examples, the drawings corresponding thereto, and the like described in this embodiment as an example can be combined with the other structure examples, the other drawings, and the like as appropriate.

### Embodiment 5

In this embodiment, a cross-sectional structure example of the display apparatus 10 that is different from that in Embodiment 4 will be described.

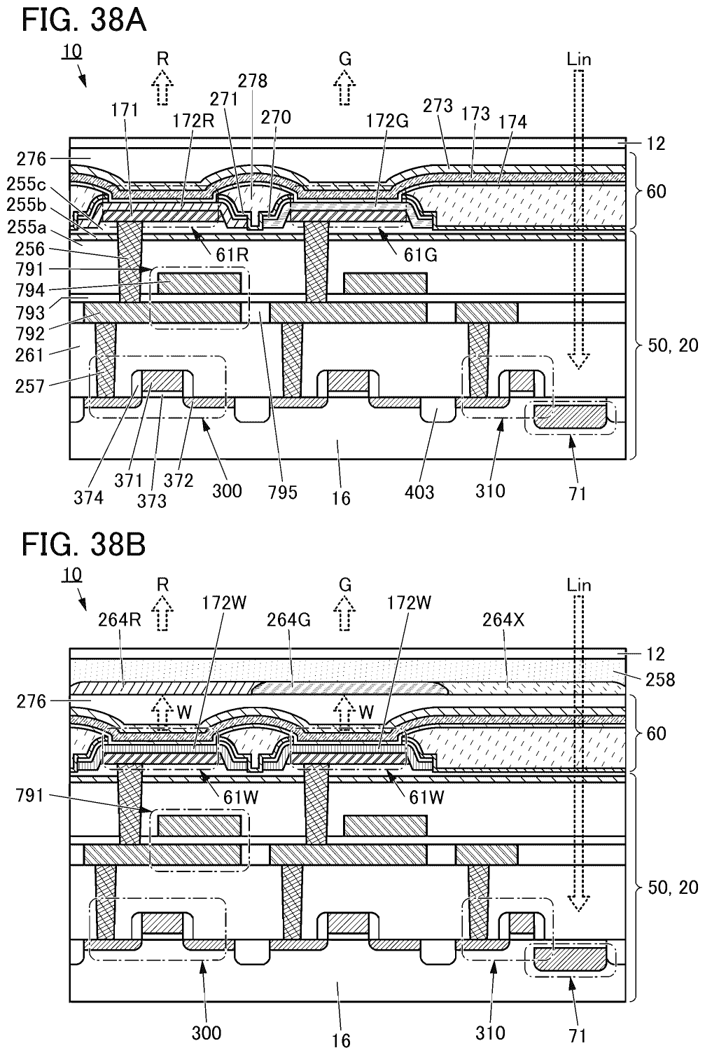

FIG. 38A illustrates a cross-sectional structure example of the display apparatus 10. The display apparatus 10 illustrated in FIG. 38A includes a substrate 16, the light-emitting element 61R, the light-emitting element 61G, the light-receiving element 71, a transistor 300, and a transistor 310.

The light-emitting element 61R has a function of exhibiting red light (R). The light-emitting element 61G has a function of exhibiting green light (G). The transistor 300 and the transistor 310 include a channel formation region in the substrate 16. As the substrate 16, a semiconductor substrate such as a single crystal silicon substrate can be used, for example. The transistor 300 and transistor 310 each include part of the substrate 16, a conductor 371, a low-resistance region 372, an insulator 373, and an insulator 374. The conductor 371 functions as a gate electrode. The insulator 373 is positioned between the substrate 16 and the conductor 371 and functions as a gate insulator. The low-resistance region 372 is a region where the substrate 16 is doped with an impurity, and functions as a source or a drain. The insulator 374 is provided to cover the side surface of the conductor 371.

The transistor 300, for example, corresponds to the transistor 52B described in the above embodiment. The transistor 310, for example, corresponds to the transistor 132 described in the above embodiment.

The element isolation layer 403 is provided between two adjacent transistors 300 to be embedded in the substrate 16.

An insulator 261 is provided to cover the transistor 310, and a capacitor 791 is provided over the insulator 261.

The capacitor 791 includes a conductor 792, a conductor 794, and an insulator 793 positioned therebetween. The conductor 792 functions as one electrode of the capacitor 791, the conductor 794 functions as the other electrode of the capacitor 791, and the insulator 793 functions as a dielectric of the capacitor 791.

The conductor 792 is provided over the insulator 261 and is embedded in a conductor 795. The conductor 792 is electrically connected to one of a source and a drain of the transistor 300 through a plug 257 embedded in the insulator 261. The insulator 793 is provided to cover the conductor 792. The conductor 792 has a region overlapping with the conductor 794 with the insulator 793 provided therebetween.

An insulator 255a is provided to cover the capacitor 791, an insulator 255b is provided over the insulator 255a, and an insulator 255c is provided over the insulator 255b. The light-emitting element 61R and the light-emitting element 61G are provided over the insulator 255c. An insulator is provided in a region between adjacent light-emitting devices and a region between a light-emitting device and a light-receiving device adjacent to each other. In FIG. 38A and the like, the protective layer 271 and the insulator 278 over the protective layer 271 are provided in the region.

The insulator 270 is provided over each of the EL layer 172R included in the light-emitting element 61R and the EL layer 172G included in the light-emitting element 61G. The common layer 174 is provided over the EL layer 172R, the EL layer 172G, and the insulator 278, and the conductor 173 is provided over the common layer 174. The protective layer 273 is provided over the conductor 173.

The conductor 171 is electrically connected to one of a source and a drain of the transistor 310 through a plug 256 embedded in the insulator 793, the insulator 255a, the insulator 255b, and the insulator 255c, the conductor 792 embedded in the conductor 795, and the plug 257 embedded in the insulator 261. The level of the top surface of the insulator 255c is equal to or substantially equal to the level of the top surface of the plug 256. A variety of conductive materials can be used for the plugs.

The insulator 276 is provided over the light-emitting element 61R, the light-emitting element 61G, and the light-receiving element 71. The components from the conductor 171 to the insulator 276 corresponds to the layer 60. The substrate 12 is provided over the insulator 276. The insulator 276 functions as an adhesive layer. A stacked-layer structure from the substrate 16 to the insulator 255c corresponds to the layer 50 of the display apparatus 10A and the display apparatus 10B, and the layer 20 of the display apparatus 10C.

In the structure example illustrated in FIG. 38A, a light-emitting element is formed in the layer 60, and a light-receiving element is formed in the layer 50 or the layer 20.

The light-receiving element 71 has a function of detecting light Lin entering from the outside of the display apparatus through the insulator 276, the insulator 255a, the insulator 261, and the like.

FIG. 38B illustrates a cross-sectional structure example that is different from the cross-sectional structure example of the display apparatus 10 illustrated in FIG. 38A. FIG. 38B is a modification example of FIG. 38A. The display apparatus 10 illustrated in FIG. 38B is provided with the light-emitting elements 61W instead of the light-emitting element 61R and the light-emitting element 61G and includes coloring layers in regions overlapping with the light-emitting elements 61W over the insulator 276. FIG. 38B illustrates a cross-sectional structure example of the display apparatus 10 including the coloring layer 264R overlapping with one light-emitting element 61W and the coloring layer 264G overlapping with another light-emitting element 61W.

The light-emitting element 61W has a function of exhibiting white light. The coloring layer 264R has a function of transmitting red light, and the coloring layer 264G has a function of transmitting green light. White light (W) emitted from the light-emitting element 61W is emitted as red light to the outside of the display apparatus through the coloring layer 264R. Furthermore, white light (W) emitted from the light-emitting element 61W is emitted as green light to the outside of the display apparatus through the coloring layer 264G. Although not illustrated in FIG. 38B, a coloring layer that transmits light in a wavelength range other than red light and green light, such as blue light, may be used.

A coloring layer 264X may be provided in a region overlapping with the light-receiving element 71 over the insulator 276. As the coloring layer 264X, a coloring layer that transmits light in a given wavelength range can be provided. By providing the coloring layer 264X, the light-receiving element 71 can detect only light passing through the coloring layer 264X.

The display apparatus 10 illustrated in FIG. 38B includes an insulator 258 over the coloring layer 264R, the coloring layer 264G, and the coloring layer 264X, and includes the substrate 12 over the insulator 258. The insulator 258 functions as an adhesive layer.

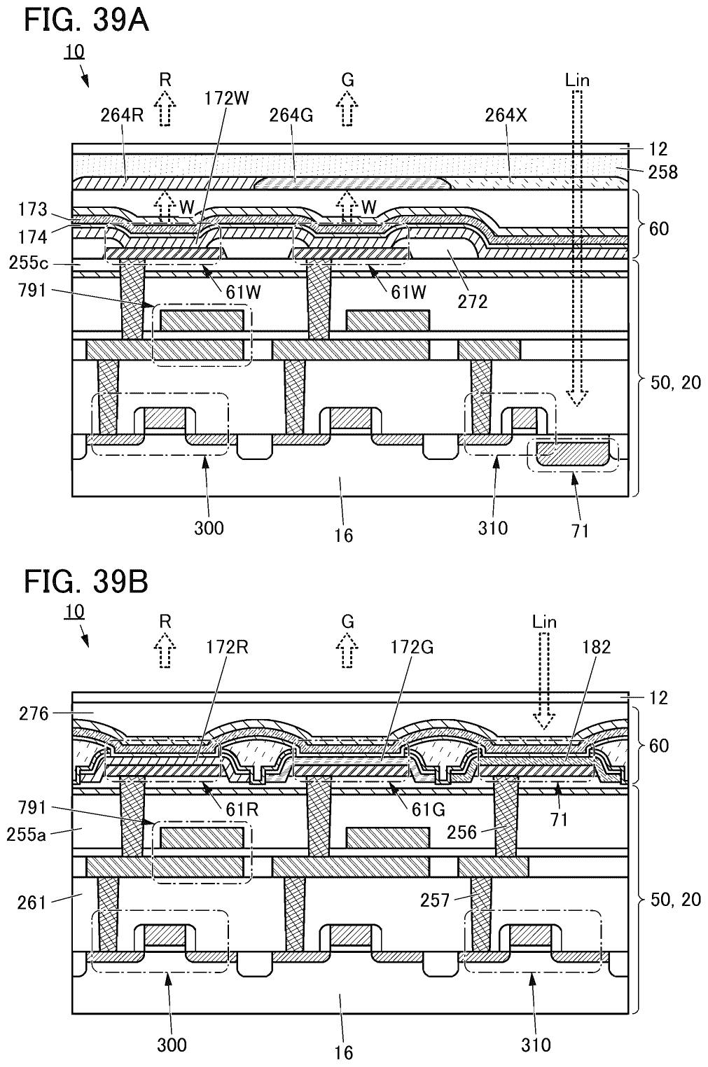

FIG. 39A illustrates a modification example of the display apparatus 10 illustrated in FIG. 38B. The display apparatus 10 illustrated in FIG. 39A has a structure in which the EL layer 172W is shared by adjacent light-emitting elements 61W. Furthermore, the EL layer 172W remains also in a region overlapping with the light-receiving element 71. When the EL layer 172W has a thickness that allows transmission of the light Lin, the light Lin can be detected even when the EL layer 172W remains in the region overlapping with the light-receiving element 71.

FIG. 39B illustrates a modification example of the display apparatus 10 illustrated in FIG. 38A. As described in the above embodiment, the light-receiving element 71 can be obtained by replacing the EL layer 172 of the light-emitting element 61 with the active layer 182 functioning as a photoelectric conversion layer.

In the display apparatus 10 illustrated in FIG. 39B, the light-emitting element 61 and the light-receiving element 71 are provided in the layer 60. The light-receiving element 71 provided in the layer 60 is electrically connected to the one of the source and the drain of the transistor 310 through the plug 256 and the plug 257.

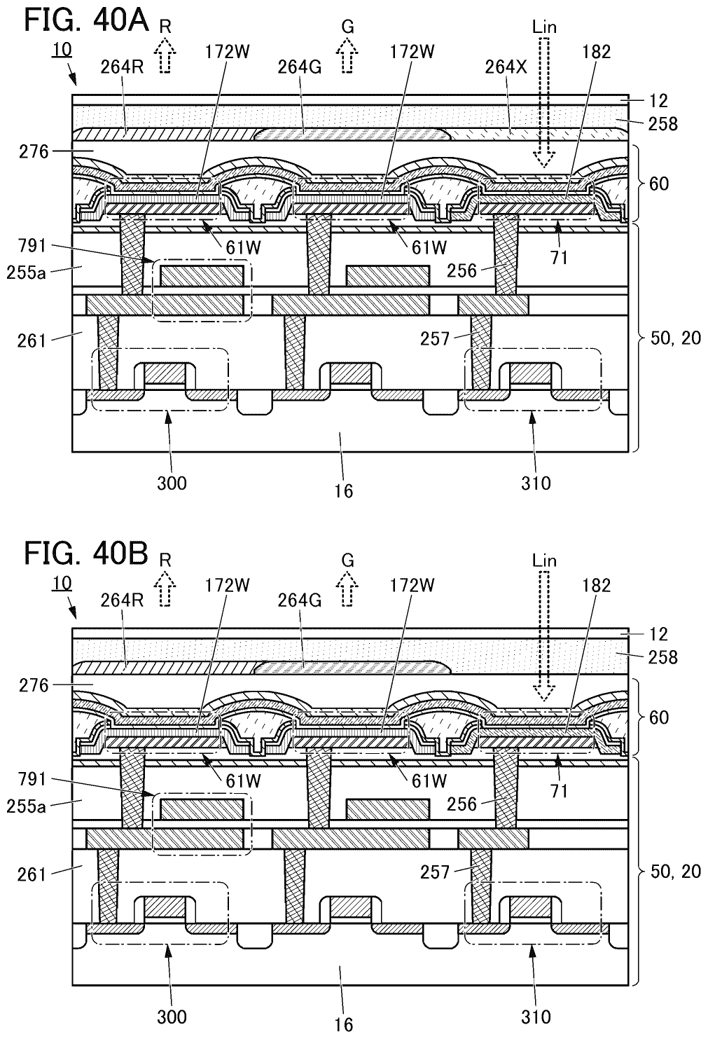

As illustrated in FIG. 40A, the coloring layer 264R and the coloring layer 264G may be provided to overlap with the light-emitting element 61W, and the coloring layer 264X may be provided to overlap with the light-receiving element 71.

Alternatively, as illustrated in FIG. 40B, a structure in which the coloring layer 264R and the coloring layer 264G are provided to overlap with the light-emitting element 61W and no coloring layer is provided over the light-receiving element 71 may be employed.

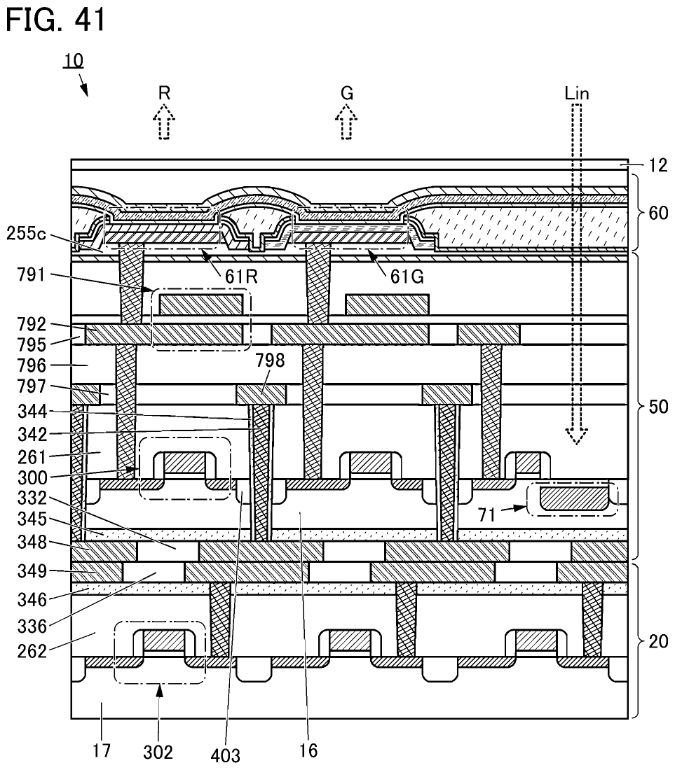

FIG. 41 illustrates a modification example of the display apparatus 10 illustrated in FIG. 38A. The display apparatus 10 illustrated in FIG. 41 has a structure in which the transistor 300 and a transistor 302 are stacked. In the transistor 300, a channel is formed in the substrate 16. In the transistor 302, a channel is formed in a substrate 17. Semiconductor substrates are used as both the substrate 16 and the substrate 17.

In the display apparatus 10 illustrated in FIG. 41, the substrate 16 provided with the transistor 300, the capacitor 791, and light-receiving element 71 is bonded to the substrate 17 provided with the transistor 302.

Here, an insulator 345 is preferably provided on the bottom surface of the substrate 16. An insulator 346 is preferably provided over the insulator 262 provided over the substrate 17. The insulator 345 and the insulator 346 are insulators functioning as protective layers and can inhibit diffusion of impurities into the substrate 16 and the substrate 17.

An insulator 796 and an insulator 797 may be provided between the insulator 261 and the conductor 792. A conductor 798 may be provided over the insulator 261. The conductor 798 is preferably provided to be embedded in the insulator 797.

The substrate 16 is provided with a plug 342 that penetrates the substrate 16 and the insulator 345. An insulator 344 is preferably provided to cover the side surface of the plug 342. The insulator 344 functions as a protective layer and can inhibit diffusion of impurities into the substrate 16. In the case where the substrate 16 is a silicon substrate, the plug 342 is also referred to as a through silicon via (TSV).

A conductor 348 is provided under the insulator 345 on the rear surface of the substrate 16 (the surface opposite to the substrate 12). The conductor 348 is preferably provided to be embedded in an insulator 332. The bottom surfaces of the conductor 348 and the insulator 332 are preferably planarized. Here, the conductor 348 is electrically connected to the conductor 798 through the plug 342.

Over the substrate 17, a conductor 349 is provided over the insulator 346. The conductor 349 is preferably provided to be embedded in the insulator 336. The top surfaces of the conductor 349 and the insulator 336 are preferably planarized.

The conductor 348 and the conductor 349 are bonded to each other, whereby the substrate 17 and the substrate 16 are electrically connected to each other. Here, improving the planarity of a plane formed by the conductor 348 and the insulator 332 and a plane formed by the conductor 349 and the insulator 336 allows the conductor 348 and the conductor 349 to be bonded to each other favorably.

For the conductor 348 and the conductor 349, the same conductive material is preferably used. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductor 348 and the conductor 349. In that case, it is possible to employ Cu-to-Cu (copper-to-copper) direct bonding (a technique for achieving electrical continuity by connecting Cu (copper) electrode pads).

In the display apparatus 10 illustrated in FIG. 41, a stacked-layer structure from the conductor 348 and the insulator 332 to the insulator 255c corresponds to the layer 50 of the display apparatus 10A and the display apparatus 10B. Furthermore, a stacked-layer structure from the substrate 17 to the conductor 349 and the insulator 336 corresponds to the layer 20 of the display apparatus 10A and the display apparatus 10B.

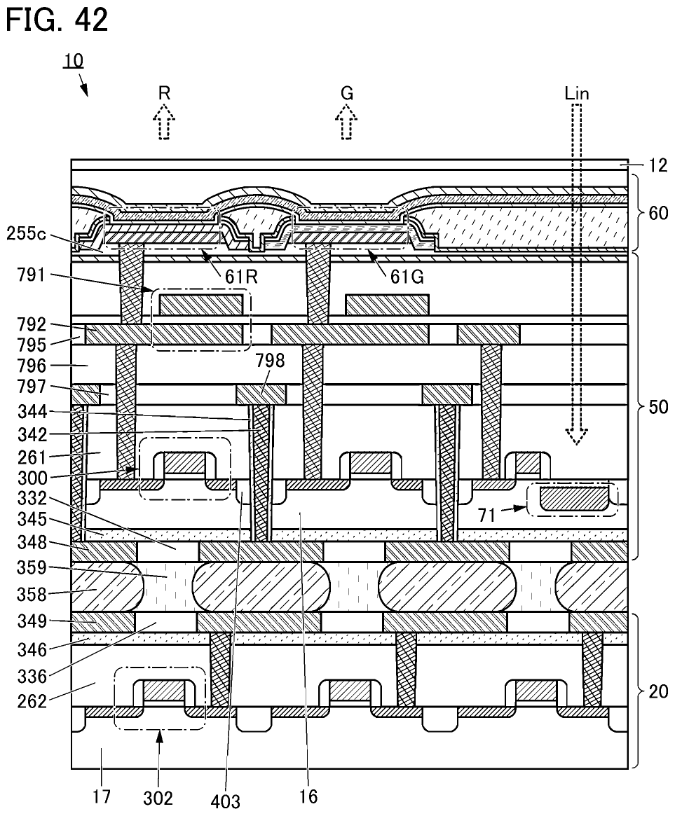

As in the display apparatus 10 illustrated in FIG. 42, a bump 358 may be provided between the conductor 348 and the conductor 349, and the conductor 348 and the conductor 349 may be electrically connected to each other through the bump 358. The bump 358 can be formed using a conductive material containing gold (Au), nickel (Ni), indium (In), tin (Sn), or the like, for example. For another example, solder may be used for the bump 358. A bonding layer 359 may be provided between the insulator 332 and the insulator 336. In the case where the bump 358 is provided, the insulator 332 and the insulator 336 are not necessarily provided.

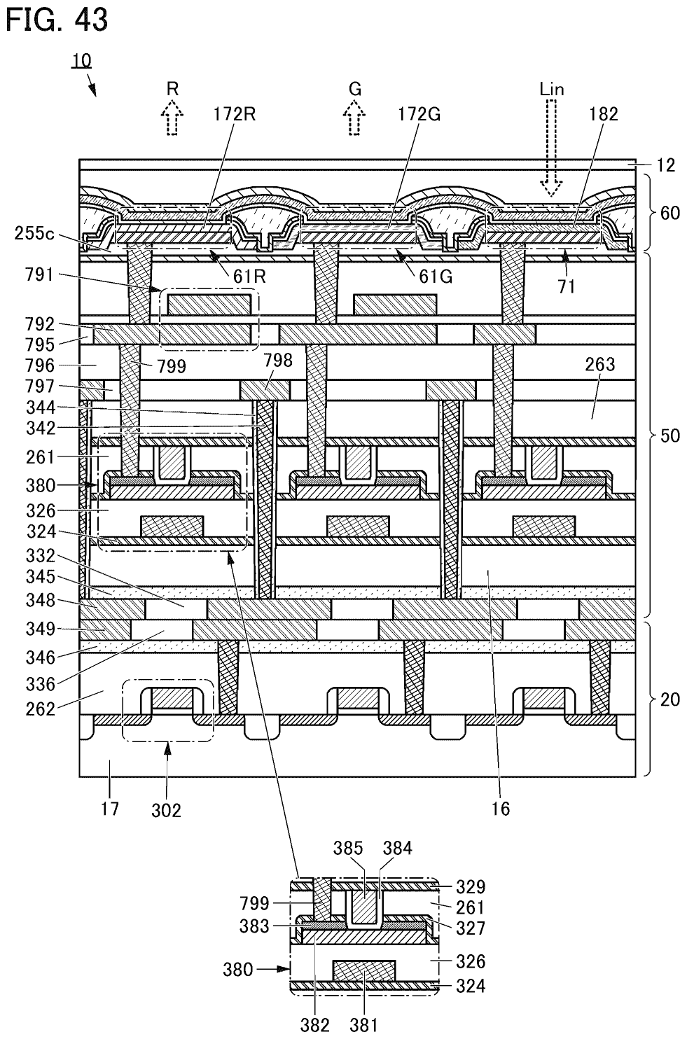

FIG. 43 illustrates a modification example of the display apparatus 10 illustrated in FIG. 41. The display apparatus 10 illustrated in FIG. 43 includes a transistor 380 over the substrate 16. Accordingly, the display apparatus 10 illustrated in FIG. 43 has a structure in which the transistor 380 and the transistor 302 are stacked. The transistor 380 is a transistor having a back gate. A semiconductor substrate may be used as the substrate 16, or a substrate of another material may be used.

In FIG. 43, the light-receiving element 71 illustrated in FIG. 39B is used as the light-receiving element 71. Specifically, an organic semiconductor is used for an active layer functioning as a photoelectric conversion layer.

The transistor 380 includes a semiconductor 382, an insulator 384, a conductor 385, a pair of conductors 383, an insulator 326, and a conductor 381. An oxide semiconductor may be used as the semiconductor 382, for example.

In the display apparatus 10 illustrated in FIG. 43, an insulator 324 is provided over the substrate 16. The insulator 324 functions as a barrier layer that prevents diffusion of impurities such as water or hydrogen from the substrate 16 side into the transistor 380 and release of oxygen from the semiconductor 382 to the insulator 324 side. As the insulator 324, for example, a film through which hydrogen or oxygen is less likely to diffuse than in a silicon oxide film, such as an aluminum oxide film, a hafnium oxide film, or a silicon nitride film, can be used.

The conductor 381 is provided over the insulator 324, and the insulator 326 is provided to cover the conductor 381. An oxide insulating film such as a silicon oxide film is preferably used as at least part of the insulator 326 that is in contact with the semiconductor 382. The top surface of the insulator 326 is preferably planarized.

The semiconductor 382 is provided over the insulator 326. The pair of conductors 383 are provided over and in contact with the semiconductor 382 and function as a source electrode and a drain electrode.

An insulator 327 is provided to cover the top and side surfaces of the pair of conductors 383, the side surface of the semiconductor 382, and the like, and the insulator 261 is provided over the insulator 327. The insulator 327 functions as a barrier layer that prevents diffusion of impurities such as water or hydrogen from the insulator 261 and the like into the semiconductor 382 and release of oxygen from the semiconductor 382. As the insulator 327, an insulating film similar to the insulator 324 can be used.

An opening reaching the semiconductor 382 is provided in the insulator 327 and the insulator 261. The insulator 384 in contact with the side surfaces of the insulator 261, the insulator 327, and the conductors 383 and the top surface of the semiconductor 382, and the conductor 385 in contact with the insulator 384 are embedded in the opening.

The conductor 385 functions as a first gate electrode of the transistor 380 and the insulator 384 functions as a first gate insulator. The conductor 381 functions as a second gate electrode of the transistor 380 and part of the insulator 326 functions as a second gate insulator.

In the case where one of the first gate electrode and the second gate electrode is referred to as a “gate” or a “gate electrode”, the other of the first gate electrode and the second gate electrode is referred to as a “back gate” or a “back gate electrode” in some cases.

The top surface of the conductor 385, the top surface of the insulator 384, and the top surface of the insulator 261 are subjected to planarization treatment so that their levels are equal to or substantially equal to each other, and an insulator 329 and an insulator 263 are provided to cover these surfaces.

The insulator 261 and the insulator 263 each function as an interlayer insulator. The insulator 329 functions as a barrier layer that prevents diffusion of impurities such as water or hydrogen from the insulator 263 side or the like into the transistor 380. As the insulator 329, an insulating film similar to the insulator 327 and the insulator 324 can be used.

A plug 799 electrically connected to one of the pair of conductors 383 is provided to be embedded in an opening provided in the insulator 796, the insulator 797, the insulator 263, the insulator 329, the insulator 261, and the insulator 327.

Here, the plug 799 is preferably formed using a conductive material through which hydrogen and oxygen are less to likely to diffuse into a portion in contact with the side surfaces of the opening in the insulator 796, the insulator 797, the insulator 263, the insulator 329, the insulator 261, and the insulator 327 and a portion in contact with part of the conductor 383 in the bottom portion of the opening.

In the display apparatus 10 illustrated in FIG. 43, the plug 342 is provided to penetrate the insulator 263, the insulator 329, the insulator 261, the insulator 327, the insulator 326, the insulator 324, the substrate 16, and the insulator 345. As described above, the insulator 344 is preferably provided to cover the side surface of the plug 342.

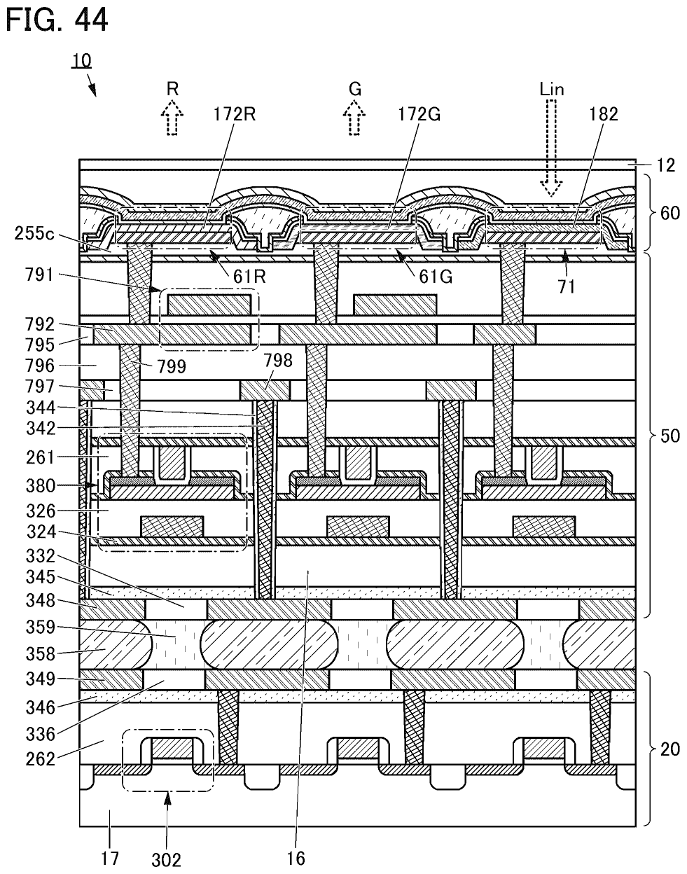

As in the display apparatus 10 illustrated in FIG. 44, the bump 358 may be provided between the conductor 348 and the conductor 349, and the conductor 348 and the conductor 349 may be electrically connected to each other through the bump 358. A bonding layer 359 may be provided between the insulator 332 and the insulator 336. The display apparatus 10 illustrated in FIG. 44 is a modification example of the display apparatus 10 illustrated in FIG. 43 but also a modification example of the display apparatus 10 illustrated in FIG. 41.

As illustrated in FIG. 39A, the coloring layer 264X may be provided to overlap with the light-receiving element 71.

At least part of the structure examples, the drawings corresponding thereto, and the like described in this embodiment as an example can be combined with any of the other structure examples, the other drawings, and the like as appropriate.

### Embodiment 6

### <Structure Example of OS Transistor>

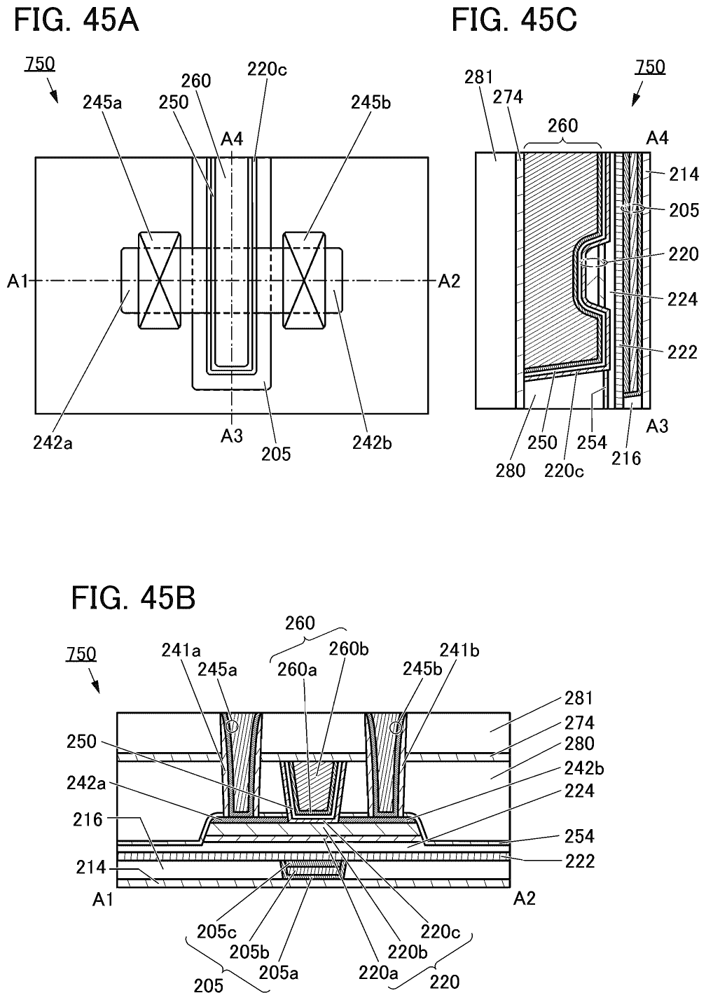

In this embodiment, a structure example of an OS transistor that can be used in the display apparatus of one embodiment of the present invention will be described. FIG. 45A, FIG. 45B, and FIG. 45C are a plan view and cross-sectional views of the transistor 750 that can be used in the display apparatus of one embodiment of the present invention, and the periphery of the transistor 750. The transistor 750 can also be used as the transistor 380 or the like.

FIG. 45A is the plan view of the transistor 750. FIG. 45B and FIG. 45C are the cross-sectional views of the transistor 750. FIG. 45B is a cross-sectional view taken along dashed-dotted line A1-A2 in FIG. 45A, which corresponds to a cross-sectional view of the transistor 750 in the channel length direction. FIG. 45C is a cross-sectional view taken along the dashed-dotted line A3-A4 in FIG. 45A, which corresponds to a cross-sectional view of the transistor 750 in the channel width direction. Note that for simplification of the drawing, some components are not illustrated in the plan view in FIG. 45A.

As illustrated in FIG. 45A to FIG. 45C, the transistor 750 includes a metal oxide 220a placed over a substrate (not illustrated); a metal oxide 220b placed over the metal oxide 220a; a conductor 242a and a conductor 242b that are placed apart from each other over the metal oxide 220b; the insulator 280 that is placed over the conductor 242a and the conductor 242b and has an opening between the conductor 242a and the conductor 242b; a conductor 260 placed in the opening; an insulator 250 placed between the conductor 260 and the metal oxide 220b, the conductor 242a, the conductor 242b, and the insulator 280; and a metal oxide 220c placed between the insulator 250 and the metal oxide 220b, the conductor 242a, the conductor 242b, and the insulator 280. Here, it is preferable that the top surface of the conductor 260 be substantially aligned with the top surfaces of the insulator 250, the insulator 254, the metal oxide 220c, and the insulator 280 as illustrated in FIG. 45B and FIG. 45C. Hereinafter, the metal oxide 220a, the metal oxide 220b, and the metal oxide 220c may be collectively referred to as a metal oxide 220. The conductor 242a and the conductor 242b may be collectively referred to as a conductor 242.

In the transistor 750 illustrated in FIG. 45A to FIG. 45C, the side surfaces of the conductor 242a and the conductor 242b on the conductor 260 side are substantially perpendicular. Note that the transistor 750 illustrated in FIG. 45A to FIG. 45C is not limited thereto, and the angle formed between the side surfaces and the bottom surfaces of the conductor 242a and the conductor 242b may be greater than or equal to 100 and less than or equal to 80°, preferably greater than or equal to 30° and less than or equal to 60°. The side surfaces of the conductor 242a and the conductor 242b that face each other may have a plurality of surfaces.

As illustrated in FIG. 45A to FIG. 45C, the insulator 254 is preferably provided between the insulator 280 and the insulator 224, the metal oxide 220a, the metal oxide 220b, the conductor 242a, the conductor 242b, and the metal oxide 220c. Here, as illustrated in FIG. 45B and FIG. 45C, the insulator 254 is preferably in contact with the side surface of the metal oxide 220c, the top surface and the side surface of the conductor 242a, the top surface and the side surface of the conductor 242b, the side surfaces of the metal oxide 220a and the metal oxide 220b, and the top surface of the insulator 224.

In the transistor 750, three layers of the metal oxide 220a, the metal oxide 220b, and the metal oxide 220c are stacked in and around the region where the channel is formed (hereinafter also referred to as channel formation region); however, the present invention is not limited thereto. For example, a two-layer structure of the metal oxide 220b and the metal oxide 220c or a stacked-layer structure of four or more layers may be employed. Alternatively, each of the metal oxide 220a, the metal oxide 220b, and the metal oxide 220c may have a stacked-layer structure of two or more layers.

For example, when the metal oxide 220c has a stacked-layer structure including a first metal oxide and a second metal oxide over the first metal oxide, the first metal oxide preferably has a composition similar to that of the metal oxide 220b and the second metal oxide preferably has a composition similar to that of the metal oxide 220a.

Here, the conductor 260 functions as a gate electrode of the transistor and the conductor 242a and the conductor 242b each function as a source electrode or a drain electrode. As described above, the conductor 260 is formed to be embedded in the opening of the insulator 280 and the region between the conductor 242a and the conductor 242b. Here, the positions of the conductor 260, the conductor 242a, and the conductor 242b with respect to the opening of the insulator 280 are selected in a self-aligned manner. That is, in the transistor 750, the gate electrode can be placed between the source electrode and the drain electrode in a self-aligned manner. Thus, the conductor 260 can be formed without an alignment margin, resulting in a reduction in the area occupied by the transistor 750. Accordingly, the display apparatus can have high definition. In addition, the bezel of the display apparatus can be narrowed.

As illustrated in FIG. 45A to FIG. 45C, the conductor 260 preferably includes a conductor 260a provided on the inner side of the insulator 250 and a conductor 260b provided to be embedded on the inner side of the conductor 260a. Although the conductor 260 has a two-layer structure in the transistor 750, the present invention is not limited thereto. For example, the conductor 260 may have a single-layer structure or a stacked-layer structure of three or more layers.

As illustrated in FIG. 45A to FIG. 45C, the insulator 254 is preferably provided between the insulator 280 and the insulator 222, the insulator 224, the metal oxide 220a, the metal oxide 220b, the conductor 242a, and the conductor 242b. Here, as illustrated in FIG. 45B and FIG. 45C, the insulator 254 is preferably in contact with the insulator 250, the top surface and the side surface of the conductor 242a, the top surface and the side surface of the conductor 242b, the side surfaces of the metal oxide 220a, the metal oxide 220b, and the insulator 224, and the top surface of the insulator 222.

The transistor 750 preferably includes the insulator 214 placed over the substrate (not illustrated); the insulator 216 placed over the insulator 214; a conductor 205 placed to be embedded in the insulator 216; the insulator 222 placed over the insulator 216 and the conductor 205; and the insulator 224 placed over the insulator 222. The metal oxide 220a is preferably placed over the insulator 224.

The insulator 274 and the insulator 281 functioning as interlayer films are preferably placed over the transistor 750. Here, the insulator 274 is preferably placed in contact with the top surfaces of the conductor 260, the insulator 250, the insulator 254, the metal oxide 220c, and the insulator 280.

The insulator 222, the insulator 254, and the insulator 274 preferably have a function of inhibiting diffusion of hydrogen (e.g., at least one of a hydrogen atom and a hydrogen molecule). For example, the insulator 222, the insulator 254, and the insulator 274 preferably have lower hydrogen permeability than the insulator 224, the insulator 250, and the insulator 280. Moreover, the insulator 222 and the insulator 254 preferably have a function of inhibiting diffusion of oxygen (e.g., at least one of an oxygen atom and an oxygen molecule). For example, the insulator 222 and the insulator 254 preferably have lower oxygen permeability than the insulator 224, the insulator 250, and the insulator 280.

Here, the insulator 224, the metal oxide 220, and the insulator 250 are separated by the insulator 222 and the insulator 274. This can inhibit entry of excess oxygen and impurities such as hydrogen contained in layers above the insulator 274 and layers below the insulator 222 into the insulator 224, the metal oxide 220, and the insulator 250.

A conductor 245 (a conductor 245a and a conductor 245b) that is electrically connected to the transistor 750 and functions as a plug is preferably provided. Note that an insulator 241 (an insulator 241a and an insulator 241b) is provided in contact with the side surface of the conductor 245 functioning as a plug. In other words, the insulator 241 is provided in contact with the inner wall of an opening in the insulator 254, the insulator 280, the insulator 274, and the insulator 281. A structure may be employed in which a first conductor of the conductor 245 is provided in contact with the side surface of the insulator 241 and a second conductor of the conductor 245 is provided on the inner side of the first conductor. Here, the top surface of the conductor 245 and the top surface of the insulator 281 can be substantially level with each other. Although the first conductor of the conductor 245 and the second conductor of the conductor 245 are stacked in the transistor 750, the present invention is not limited thereto. For example, the conductor 245 may have a single-layer structure or a stacked-layer structure of three or more layers. In the case where a component has a stacked-layer structure, layers may be distinguished by ordinal numbers corresponding to the formation order.

In the transistor 750, a metal oxide functioning as an oxide semiconductor (hereinafter also referred to as an oxide semiconductor) is preferably used for the metal oxide 220 including the channel formation region (the metal oxide 220a, the metal oxide 220b, and the metal oxide 220c). For example, it is preferable to use a metal oxide having a band gap of 2 eV or more, preferably 2.5 eV or more as the metal oxide to be the channel formation region of the metal oxide 220.

The metal oxide preferably contains at least indium (In) or zinc (Zn). In particular, the metal oxide preferably contains indium (In) and zinc (Zn). In addition to them, the element M is preferably contained. As the element M, one or more of aluminum (Al), gallium (Ga), yttrium (Y), tin (Sn), boron (B), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and cobalt (Co) can be used. In particular, the element M is preferably one or more of aluminum (Al), gallium (Ga), yttrium (Y), and tin (Sn). Furthermore, the element M preferably contains one or both of Ga and Sn.

In addition, the metal oxide 220b may have a smaller thickness in a region not overlapping with the conductor 242 than in a region overlapping with the conductor 242. The thin region is formed when part of the top surface of the metal oxide 220b is removed at the time of forming the conductor 242a and the conductor 242b. When a conductive film to be the conductor 242 is formed, a low-resistance region is sometimes formed on the top surface of the metal oxide 220b in the vicinity of the interface with the conductive film. Removing the low-resistance region positioned between the conductor 242a and the conductor 242b on the top surface of the metal oxide 220b in this manner can prevent formation of the channel in the region.

According to one embodiment of the present invention, a display apparatus that includes small-size transistors and has high definition can be provided. A display apparatus that includes a transistor with a high on-state current and has high luminance can be provided. A display apparatus that includes a transistor operating at high speed and operates at high speed can be provided. A display apparatus that includes a transistor having stable electrical characteristics and is highly reliable can be provided. A display apparatus that includes a transistor with a low off-state current and has low power consumption can be provided.

The structure of the transistor 750 that can be used in the display apparatus of one embodiment of the present invention is described in detail.

The conductor 205 is placed to include a region overlapping with the metal oxide 220 and the conductor 260. Furthermore, the conductor 205 is preferably provided to be embedded in the insulator 216.

The conductor 205 includes a conductor 205a, a conductor 205b, and a conductor 205c. The conductor 205a is provided in contact with the bottom surface and the side wall of the opening provided in the insulator 216. The conductor 205b is provided to be embedded in a depressed portion formed by the conductor 205a. Here, the level of the top surface of the conductor 205b is lower than the levels of the top surfaces of the conductor 205a and the insulator 216. The conductor 205c is provided in contact with the top surface of the conductor 205b and the side surface of the conductor 205a. Here, the top surface of the conductor 205c is substantially level with the top surfaces of the conductor 205a and the insulator 216. In other words, the conductor 205b is surrounded by the conductor 205a and the conductor 205c.

The conductor 205a and the conductor 205c are preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 205a and the conductor 205c are preferably formed using a conductive material having a function of inhibiting diffusion of oxygen (e.g., at least one of an oxygen atom, an oxygen molecule, and the like).

When the conductor 205a and the conductor 205c are formed using a conductive material having a function of inhibiting diffusion of hydrogen, impurities such as hydrogen contained in the conductor 205b can be inhibited from diffusing into the metal oxide 220 through the insulator 224 and the like. When the conductor 205a and the conductor 205c are formed using a conductive material having a function of inhibiting diffusion of oxygen, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, ruthenium oxide, or the like is preferably used. Thus, the conductor 205a may be a single layer or a stacked layer of the above conductive materials. For example, titanium nitride may be used for the conductor 205a.

A conductive material containing tungsten, copper, or aluminum as its main component is preferably used for the conductor 205b. For example, tungsten may be used for the conductor 205b.

The conductor 260 sometimes functions as a first gate (also referred to as top gate) electrode. The conductor 205 sometimes functions as a second gate (also referred to as bottom gate) electrode. In that case, by changing a potential applied to the conductor 205 independently of a potential applied to the conductor 260, Vₜₕ of the transistor 750 can be controlled. In particular, by applying a negative potential to the conductor 205, Vₜₕ of the transistor 750 can be heightened and the off-state current can be reduced. Thus, a drain current at the time when a potential applied to the conductor 260 is 0 V can be lower in the case where a negative potential is applied to the conductor 205 than in the case where the negative potential is not applied to the conductor 205.

The conductor 205 is preferably provided to be larger than the channel formation region in the metal oxide 220. In particular, it is preferable that the conductor 205 extend beyond an end portion of the metal oxide 220 that intersects with the channel width direction, as illustrated in FIG. 45C. In other words, the conductor 205 and the conductor 260 preferably overlap with each other with the insulator positioned therebetween, in a region on the outer side of the side surface of the metal oxide 220 in the channel width direction.

With the above structure, the channel formation region in the metal oxide 220 can be electrically surrounded by an electric field of the conductor 260 having a function of the first gate electrode and an electric field of the conductor 205 having a function of the second gate electrode.

As illustrated in FIG. 45C, the conductor 205 extends to function as a wiring as well. However, without limitation to this structure, a structure in which a conductor functioning as a wiring is provided below the conductor 205 may be employed.

The insulator 214 preferably functions as a barrier insulating film that inhibits entry of an impurity such as water or hydrogen to the transistor 750 from the substrate side. Accordingly, it is preferable to use, for the insulator 214, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the above impurities are less likely to pass). Alternatively, it is preferable to use an insulating material having a function of inhibiting diffusion of oxygen (e.g., at least one of an oxygen atom, an oxygen molecule, and the like) (an insulating material through which the oxygen is less likely to pass).

For example, aluminum oxide, silicon nitride, or the like is preferably used for the insulator 214. Accordingly, it is possible to inhibit diffusion of an impurity such as water or hydrogen to the transistor 750 side from the substrate side through the insulator 214. Alternatively, it is possible to inhibit diffusion of oxygen contained in the insulator 224 and the like to the substrate side through the insulator 214.

The permittivity of each of the insulator 216, the insulator 280, and the insulator 281 functioning as an interlayer film is preferably lower than that of the insulator 214. When a material with a low permittivity is used for an interlayer film, the parasitic capacitance generated between wirings can be reduced. For example, for the insulator 216, the insulator 280, and the insulator 281, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like may be used as appropriate.

The insulator 222 and the insulator 224 each have a function of a gate insulator.

Here, the insulator 224 in contact with the metal oxide 220 preferably releases oxygen by heating. In this specification, oxygen that is released by heating is referred to as excess oxygen in some cases. For example, silicon oxide, silicon oxynitride, or the like can be used as appropriate for the insulator 224. When an insulator containing oxygen is provided in contact with the metal oxide 220, oxygen vacancies in the metal oxide 220 can be reduced, leading to improved reliability of the transistor 750.

Specifically, an oxide material that releases part of oxygen by heating is preferably used for the insulator 224. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the surface temperature of the film in the TDS analysis is preferably in the range of 100° C. to 700° C. or 100° C. to 400° C.

As illustrated in FIG. 45C, the insulator 224 is sometimes thinner in a region overlapping with neither the insulator 254 nor the metal oxide 220b than in the other regions. In the insulator 224, the region overlapping with neither the insulator 254 nor the metal oxide 220b preferably has a thickness with which the above oxygen can be adequately diffused.

Like the insulator 214 or the like, the insulator 222 preferably functions as a barrier insulating film that inhibits entry of an impurity such as water or hydrogen into the transistor 750 from the substrate side. For example, the insulator 222 preferably has lower hydrogen permeability than the insulator 224. When the insulator 224, the metal oxide 220, the insulator 250, and the like are surrounded by the insulator 222, the insulator 254, and the insulator 274, entry of an impurity such as water or hydrogen into the transistor 750 from the outside can be inhibited.

Furthermore, it is preferable that the insulator 222 have a function of inhibiting diffusion of oxygen (e.g., at least one of an oxygen atom, an oxygen molecule, and the like) (the above oxygen is less likely to pass through the insulator 222). For example, the insulator 222 preferably has lower oxygen permeability than the insulator 224. The insulator 222 preferably has a function of inhibiting diffusion of oxygen and impurities in which case oxygen contained in the metal oxide 220 can be inhibited from diffusing to the substrate side. Moreover, the conductor 205 can be inhibited from reacting with oxygen contained in the insulator 224 or the metal oxide 220.

As the insulator 222, an insulator containing an oxide of one or both of aluminum and hafnium, which is an insulating material, is preferably used. As the insulator containing an oxide of one or both of aluminum and hafnium, aluminum oxide, hafnium oxide, an oxide containing aluminum and hafnium (hafnium aluminate), or the like is preferably used. In the case where the insulator 222 is formed using such a material, the insulator 222 functions as a layer inhibiting release of oxygen from the metal oxide 220 and entry of impurities such as hydrogen into the metal oxide 220 from the periphery of the transistor 750.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the above insulator. For example, a three-layer structure in which silicon nitride, silicon oxide, and aluminum oxide are stacked in this order can be used as the insulator 222.

The insulator 222 may be a single layer or a stacked layer formed using an insulator containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST). As miniaturization and high integration of transistors progress, a problem such as a leakage current may arise because of a thinner gate insulator. When a high-k material is used for the insulator functioning as a gate insulator, a gate potential at the time of operation of the transistor can be reduced while the physical thickness is maintained.

Note that the insulator 222 and the insulator 224 may each have a stacked-layer structure of two or more layers. In that case, without limitation to a stacked-layer structure formed of the same material, a stacked-layer structure formed of different materials may be employed. For example, an insulator similar to the insulator 224 may be provided below the insulator 222.

The metal oxide 220 includes the metal oxide 220a, the metal oxide 220b over the metal oxide 220a, and the metal oxide 220c over the metal oxide 220b. When the metal oxide 220 includes the metal oxide 220a under the metal oxide 220b, it is possible to inhibit diffusion of impurities into the metal oxide 220b from the components formed below the metal oxide 220a. Moreover, when the metal oxide 220 includes the metal oxide 220c over the metal oxide 220b, it is possible to inhibit diffusion of impurities into the metal oxide 220b from the components formed above the metal oxide 220c.

Note that the metal oxide 220 preferably has a stacked-layer structure of a plurality of oxide layers that differ in the atomic ratio of metal atoms. For example, in the case where the metal oxide 220 contains at least indium (In) and the element M, the proportion of the number of atoms of the element M contained in the metal oxide 220a to the number of atoms of all elements that constitute the metal oxide 220a is preferably higher than the proportion of the number of atoms of the element M contained in the metal oxide 220b to the number of atoms of all elements that constitute the metal oxide 220b. In addition, the atomic ratio of the element M to In in the metal oxide 220a is preferably higher than the atomic ratio of the element M to In in the metal oxide 220b. Here, a metal oxide that can be used as the metal oxide 220a or the metal oxide 220b can be used as the metal oxide 220c.

The energy of the conduction band minimum of each of the metal oxide 220a and the metal oxide 220c is preferably higher than that of the metal oxide 220b. In other words, the electron affinity of each of the metal oxide 220a and the metal oxide 220c is preferably smaller than that of the metal oxide 220b. In that case, a metal oxide that can be used as the metal oxide 220a is preferably used as the metal oxide 220c. Specifically, the proportion of the number of atoms of the element M contained in the metal oxide 220c to the number of atoms of all elements that constitute the metal oxide 220c is preferably higher than the proportion of the number of atoms of the element M contained in the metal oxide 220b to the number of atoms of all elements that constitute the metal oxide 220b. In addition, the atomic ratio of the element M to In in the metal oxide 220c is preferably higher than the atomic ratio of the element M to In in the metal oxide 220b.

Here, the energy level of the conduction band minimum gently changes at junction portions between the metal oxide 220a, the metal oxide 220b, and the metal oxide 220c. In other words, the energy level of the conduction band minimum at junction portions between the metal oxide 220a, the metal oxide 220b, and the metal oxide 220c continuously changes or is continuously connected. This can be achieved by decreasing the density of defect states in a mixed layer formed at the interface between the metal oxide 220a and the metal oxide 220b and the interface between the metal oxide 220b and the metal oxide 220c.

Specifically, when the metal oxide 220a and the metal oxide 220b or the metal oxide 220b and the metal oxide 220c contain the same element (as a main component) in addition to oxygen, a mixed layer with a low density of defect states can be formed. For example, in the case where the metal oxide 220b is In—Ga—Zn oxide, as the metal oxide 220a and the metal oxide 220c, In—Ga—Zn oxide, Ga—Zn oxide, gallium oxide, or the like may be used. The metal oxide 220c may have a stacked-layer structure. For example, a stacked-layer structure of In—Ga—Zn oxide and Ga—Zn oxide over the In—Ga—Zn oxide or a stacked-layer structure of In—Ga—Zn oxide and gallium oxide over the In—Ga—Zn oxide can be employed. In other words, the metal oxide 220c may have a stacked-layer structure of In—Ga—Zn oxide and an oxide that does not contain In.

Specifically, as the metal oxide 220a, a metal oxide having In:Ga:Zn=1:3:4 [atomic ratio] or a composition in the vicinity thereof, or 1:1:0.5 [atomic ratio] or a composition in the vicinity thereof may be used. As the metal oxide 220b, a metal oxide having a composition of In:Ga:Zn=4:2:3 [atomic ratio] or a composition in the vicinity thereof, 3:1:2 [atomic ratio] or a composition in the vicinity thereof, or a composition of In:Ga:Zn=1:1:1 [atomic ratio] or a composition in the vicinity thereof may be used. As the metal oxide 220c, a metal oxide having In:Ga:Zn=1:3:4 [atomic ratio] or a composition in the vicinity thereof, In:Ga:Zn=4:2:3 [atomic ratio] or a composition in the vicinity thereof, Ga:Zn=2:1 [atomic ratio] or a composition in the vicinity thereof, or Ga:Zn=2:5 [atomic ratio] or a composition in the vicinity thereof may be used. Specific examples of a stacked-layer structure of the metal oxide 220c include a stacked-layer structure of a layer with In:Ga:Zn=4:2:3 [atomic ratio] or a composition in the vicinity thereof and a layer with Ga:Zn=2:1 [atomic ratio] or a composition in the vicinity thereof, a stacked-layer structure of a layer with In:Ga:Zn=4:2:3 [atomic ratio] or a composition in the vicinity thereof and a layer with Ga:Zn=2:5 [atomic ratio] or a composition in the vicinity thereof, and a stacked-layer structure of a layer with In:Ga:Zn=4:2:3 [atomic ratio] or a composition in the vicinity thereof and a layer of gallium oxide.

At this time, the metal oxide 220b serves as a main carrier path. When the metal oxide 220a and the metal oxide 220c have the above structure, the density of defect states at the interface between the metal oxide 220a and the metal oxide 220b and the interface between the metal oxide 220b and the metal oxide 220c can be made low. This reduces the influence of interface scattering on carrier conduction, and the transistor 750 can have a high on-state current and high frequency characteristics. Note that in the case where the metal oxide 220c has a stacked-layer structure, not only the effect of reducing the density of defect states at the interface between the metal oxide 220b and the metal oxide 220c, but also the effect of inhibiting diffusion of the constituent element of the metal oxide 220c to the insulator 250 side can be expected. Specifically, the metal oxide 220c has a stacked-layer structure in which the upper layer is an oxide that does not contain In, whereby the amount of In that would diffuse to the insulator 250 side can be reduced. Since the insulator 250 functions as a gate insulator, the transistor would show poor characteristics when In diffuses into the insulator 250. Thus, the metal oxide 220c having a stacked-layer structure allows a highly reliable display apparatus to be provided.

The conductor 242 (the conductor 242a and the conductor 242b) functioning as the source electrode and the drain electrode is provided over the metal oxide 220b. For the conductor 242, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even when absorbing oxygen.

When the conductor 242 is provided in contact with the metal oxide 220, the oxygen concentration of the metal oxide 220 in the vicinity of the conductor 242 sometimes decreases. In addition, a metal compound layer that contains the metal contained in the conductor 242 and the component of the metal oxide 220 is sometimes formed in the metal oxide 220 in the vicinity of the conductor 242. In such a case, the carrier concentration of the region in the metal oxide 220 in the vicinity of the conductor 242 increases, and the region becomes a low-resistance region.

Here, the region between the conductor 242a and the conductor 242b is formed to overlap with the opening of the insulator 280. Accordingly, the conductor 260 can be formed in a self-aligned manner between the conductor 242a and the conductor 242b.

The insulator 250 functions as a gate insulator. The insulator 250 is preferably placed in contact with the top surface of the metal oxide 220c. For the insulator 250, any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide can be used. In particular, silicon oxide and silicon oxynitride are preferable because of their thermal stability.

As in the insulator 224, the concentration of an impurity such as water or hydrogen is preferably reduced in the insulator 250. The thickness of the insulator 250 is preferably greater than or equal to 1 nm and less than or equal to 20 nm.

A metal oxide may be provided between the insulator 250 and the conductor 260. The metal oxide preferably inhibits oxygen diffusion from the insulator 250 into the conductor 260. Accordingly, oxidation of the conductor 260 due to oxygen in the insulator 250 can be inhibited.

The metal oxide has a function of part of the gate insulator in some cases. Therefore, when silicon oxide, silicon oxynitride, or the like is used for the insulator 250, a metal oxide that is a high-k material with a high dielectric constant is preferably used as the metal oxide. When the gate insulator has a stacked-layer structure of the insulator 250 and the metal oxide, the stacked-layer structure can be thermally stable and have a high dielectric constant. Accordingly, a gate potential applied during operation of the transistor can be lowered while the physical thickness of the gate insulator is maintained. In addition, the equivalent oxide thickness (EOT) of the insulator functioning as the gate insulator can be reduced.

Specifically, a metal oxide containing one or more of hafnium, aluminum, gallium, yttrium, zirconium, tungsten, titanium, tantalum, nickel, germanium, magnesium, and the like can be used. It is preferable to use an insulator containing an oxide of one or both of aluminum and hafnium, such as aluminum oxide, hafnium oxide, or an oxide containing aluminum and hafnium (hafnium aluminate), in particular.

Although FIG. 45A to FIG. 45C illustrates the conductor 260 having a two-layer structure, the conductor 260 may have a single-layer structure or a stacked-layer structure of three or more layers.

The conductor 260a is preferably formed using the aforementioned conductor having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 260a is preferably formed using a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen contained in the insulator 250. As a conductive material having a function of inhibiting oxygen diffusion, for example, tantalum, tantalum nitride, ruthenium, ruthenium oxide, or the like is preferably used.

A conductive material containing tungsten, copper, or aluminum as its main component is preferably used for the conductor 260b. The conductor 260 also functions as a wiring and thus is preferably formed using a conductor having high conductivity. For example, a conductive material containing tungsten, copper, or aluminum as its main component can be used. The conductor 260b may have a stacked-layer structure, for example, a stacked-layer structure of any of the above conductive materials and titanium or titanium nitride.

As illustrated in FIG. 45A and FIG. 45C, the side surface of the metal oxide 220 is covered with the conductor 260 in a region where the metal oxide 220b does not overlap with the conductor 242, that is, the channel formation region of the metal oxide 220. Accordingly, the electric field of the conductor 260 functioning as the first gate electrode is likely to act on the side surface of the metal oxide 220. Hence, the transistor 750 can have a higher on-state current and higher frequency characteristics.

Like the insulator 214 or the like, the insulator 254 preferably functions as a barrier insulating film that inhibits entry of an impurity such as water or hydrogen into the transistor 750 from the insulator 280 side. The insulator 254 preferably has lower hydrogen permeability than the insulator 224, for example. Furthermore, as illustrated in FIG. 45B and FIG. 45C, the insulator 254 is preferably in contact with the side surface of the metal oxide 220c, the top surface and the side surface of the conductor 242a, the top surface and the side surface of the conductor 242b, the side surfaces of the metal oxide 220a and the metal oxide 220b, and the top surface of the insulator 224. Such a structure can inhibit entry of hydrogen contained in the insulator 280 into the metal oxide 220 through the top surfaces or the side surfaces of the conductor 242a, the conductor 242b, the metal oxide 220a, the metal oxide 220b, and the insulator 224.

Furthermore, it is preferable that the insulator 254 have a function of inhibiting diffusion of oxygen (e.g., at least one of an oxygen atom, an oxygen molecule, and the like) (the above oxygen be less likely to pass through the insulator 254). For example, the insulator 254 preferably has lower oxygen permeability than the insulator 280 or the insulator 224.

The insulator 254 is preferably formed by a sputtering method. When the insulator 254 is formed by a sputtering method in an oxygen-containing atmosphere, oxygen can be added to the vicinity of a region of the insulator 224 which is in contact with the insulator 254. Thus, oxygen can be supplied from the region into the metal oxide 220 through the insulator 224. Here, with the insulator 254 having a function of inhibiting upward oxygen diffusion, oxygen can be prevented from diffusing from the metal oxide 220 into the insulator 280. Moreover, with the insulator 222 having a function of inhibiting downward oxygen diffusion, oxygen can be prevented from diffusing from the metal oxide 220 to the substrate side. In the above manner, oxygen is supplied to the channel formation region of the metal oxide 220. Accordingly, oxygen vacancies in the metal oxide 220 can be reduced, so that the transistor can be inhibited from having normally-on characteristics.

As the insulator 254, an insulator containing an oxide of one or both of aluminum and hafnium can be formed, for example. As the insulator containing an oxide of one or both of aluminum and hafnium, aluminum oxide, hafnium oxide, an oxide containing aluminum and hafnium (hafnium aluminate), or the like is preferably used.

The insulator 280 is provided over the insulator 224, the metal oxide 220, and the conductor 242 with the insulator 254 therebetween. The insulator 280 preferably includes, for example, silicon oxide, silicon oxynitride, silicon nitride oxide, silicon oxide to which fluorine is added, silicon oxide to which carbon is added, silicon oxide to which carbon and nitrogen are added, or porous silicon oxide. Silicon oxide and silicon oxynitride are particularly preferable because of their thermal stability. In particular, materials such as silicon oxide, silicon oxynitride, and porous silicon oxide are preferably used, in which case a region containing oxygen to be released by heating can be easily formed.

The concentration of an impurity such as water or hydrogen in the insulator 280 is preferably reduced. In addition, the top surface of the insulator 280 may be planarized.

Like the insulator 214 or the like, the insulator 274 preferably functions as a barrier insulating film that inhibits entry of an impurity such as water or hydrogen into the insulator 280 from above. As the insulator 274, for example, the insulator that can be used as the insulator 214, the insulator 254, and the like can be used.

The insulator 281 functioning as an interlayer film is preferably provided over the insulator 274. As in the insulator 224 or the like, the concentration of an impurity such as water or hydrogen is preferably reduced in the insulator 281.

The conductor 245a and the conductor 245b are placed in an opening formed in the insulator 281, the insulator 274, the insulator 280, and the insulator 254. The conductor 245a and the conductor 245b are provided to face each other with the conductor 260 therebetween. Note that the top surfaces of the conductor 245a and the conductor 245b may be level with the top surface of the insulator 281.

The insulator 241a is provided in contact with the inner wall of the opening in the insulator 281, the insulator 274, the insulator 280, and the insulator 254, and a first conductor of the conductor 245a is formed in contact with the side surface of the insulator 241a. The conductor 242a is positioned on at least part of the bottom portion of the opening, and the conductor 245a is in contact with the conductor 242a. Similarly, the insulator 241b is provided in contact with the inner wall of the opening in the insulator 281, the insulator 274, the insulator 280, and the insulator 254, and a first conductor of the conductor 245b is formed in contact with the side surface of the insulator 241b. The conductor 242b is positioned on at least part of the bottom portion of the opening, and the conductor 245b is in contact with the conductor 242b.

The conductor 245a and the conductor 245b are preferably formed using a conductive material containing tungsten, copper, or aluminum as its main component. The conductor 245a and the conductor 245b may each have a stacked-layer structure.

In the case where the conductor 245 has a stacked-layer structure, the aforementioned conductor having a function of inhibiting diffusion of an impurity such as water or hydrogen is preferably used as the conductor in contact with the metal oxide 220a, the metal oxide 220b, the conductor 242, the insulator 254, the insulator 280, the insulator 274, and the insulator 281. For example, tantalum, tantalum nitride, titanium, titanium nitride, ruthenium, ruthenium oxide, or the like is preferably used. The conductive material having a function of inhibiting diffusion of an impurity such as water or hydrogen can be used as a single layer or stacked layers. The use of the conductive material can inhibit oxygen added to the insulator 280 from being absorbed by the conductor 245a and the conductor 245b. Moreover, an impurity such as water or hydrogen can be inhibited from entering the metal oxide 220 through the conductor 245a and the conductor 245b from a layer above the insulator 281.

As the insulator 241a and the insulator 241b, the insulator that can be used as the insulator 254 or the like can be used, for example. Since the insulator 241a and the insulator 241b are provided in contact with the insulator 254, an impurity such as water or hydrogen in the insulator 280 or the like can be inhibited from entering the metal oxide 220 through the conductor 245a and the conductor 245b. Furthermore, oxygen contained in the insulator 280 can be inhibited from being absorbed by the conductor 245a and the conductor 245b.

Although not illustrated, a conductor functioning as a wiring may be provided in contact with the top surface of the conductor 245a and the top surface of the conductor 245b. For the conductor functioning as a wiring, a conductive material containing tungsten, copper, or aluminum as its main component is preferably used. Furthermore, the conductor may have a stacked-layer structure and may be a stack of any of the above conductive materials and titanium or titanium nitride. Note that the conductor may be formed to be embedded in an opening provided in an insulator.

### Modification Example of OS Transistor

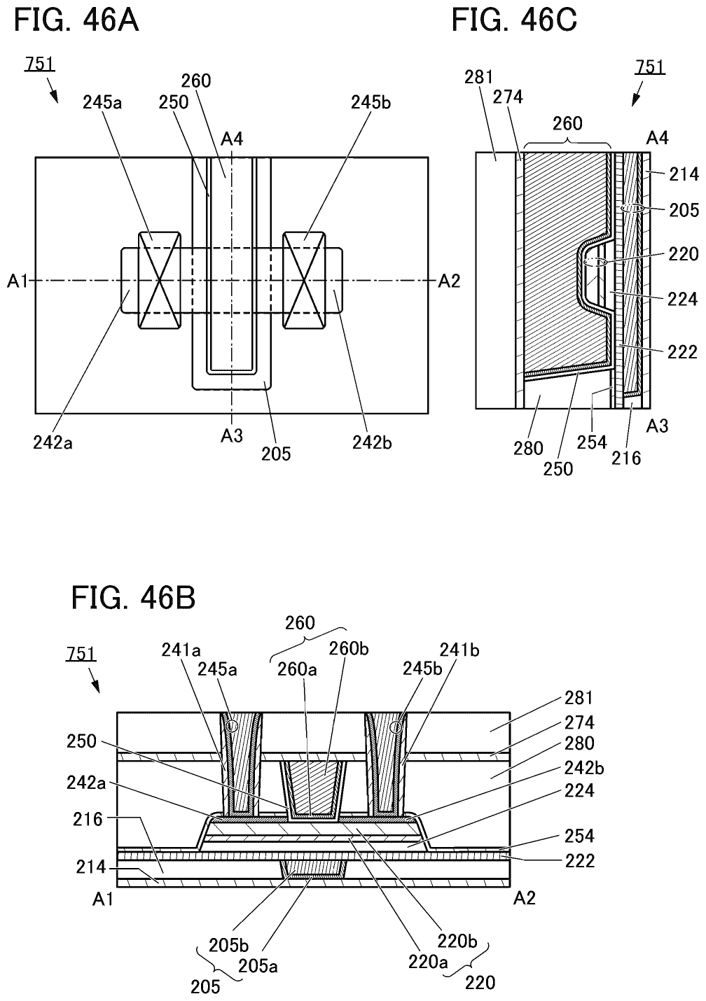

FIG. 46 illustrates a modification example of the transistor 750 illustrated in FIG. 45. FIG. 46A, FIG. 46B, and FIG. 46C are a plan view and a cross-sectional view of a transistor 751, which is a modification example of the transistor 750. The transistor 751 is a modification example of the transistor 750; thus, different points of the transistor 751 from the transistor 750 are mainly described. The transistor 751 can also be used as the transistor 380 or the like.

The transistor 751 has a structure in which the metal oxide 220c and the conductor 205c are removed from the structure of the transistor 750. A reduction in the number of components of a transistor can reduce the manufacturing cost. Furthermore, the manufacturing process is shortened when the number of components of the transistor is reduced, leading to an improvement of the manufacturing yield.

The transistor 751 includes a region where the insulator 254 and the insulator 222 are in contact with each other outside the metal oxide 220, and has a structure in which the side surface of the insulator 224 is covered with the insulator 254. When the side surface of the insulator 224 is covered with the insulator 254, oxygen can be prevented from diffusing to the outside through the insulator 224, and excess oxygen supply from the insulator 224 side to the metal oxide 220 can be prevented as well.

An insulator may be provided between the insulator 250 and the insulator 280, the insulator 254, the conductor 242, and the metal oxide 220b. Aluminum oxide, hafnium oxide, or the like is preferably used for the insulator. Providing the insulator can suppress release of oxygen from the metal oxide 220 to the insulator 250 side, supply of excess oxygen from the insulator 250 side to the metal oxide 220, oxidation of the conductor 242, and the like.

### <Materials for Transistor>

Materials that can be used for the transistor will be described.

### [Substrate]

As a substrate over which the transistor is formed, for example, an insulator substrate, a semiconductor substrate, or a conductor substrate may be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate of silicon carbide, silicon germanium, gallium arsenide, indium phosphide, zinc oxide, gallium oxide, or gallium nitride. Other examples include any of the above semiconductor substrates including an insulator region, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the elements provided over the substrates include a capacitor element, a resistor, a switching element, a light-emitting element, and a memory element.

### [Insulator]

Examples of an insulator include an oxide, a nitride, an oxynitride, a nitride oxide, a metal oxide, a metal oxynitride, and a metal nitride oxide, each of which has an insulating property.

As miniaturization and high integration of transistors progress, for example, a problem such as a leakage current may arise because of a thinner gate insulator. When a high-k material is used for the insulator functioning as a gate insulator, the voltage at the time of operation of the transistor can be reduced while the physical thickness is maintained. By contrast, when a material with a low dielectric constant is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including an oxide semiconductor is surrounded by insulators having a function of inhibiting the passage of oxygen and impurities such as hydrogen (e.g., the insulator 214, the insulator 222, the insulator 254, and the insulator 274), the electrical characteristics of the transistor can be stable. An insulator having a function of inhibiting the passage of oxygen and impurities such as hydrogen can be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, aluminum titanium nitride, titanium nitride, silicon nitride oxide, or silicon nitride can be used.

An insulator functioning as a gate insulator preferably includes a region containing oxygen to be released by heating. For example, a structure where silicon oxide or silicon oxynitride that includes a region containing oxygen to be released by heating is provided in contact with the metal oxide 220 can compensate for oxygen vacancies in the metal oxide 220.

### [Conductor]

For a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even when absorbing oxygen. A semiconductor having high electrical conductivity, typified by polycrystalline silicon containing an impurity element such as phosphorus, or silicide such as nickel silicide may be used.

A plurality of conductors formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Alternatively, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where the channel is formed. A conductive material containing any of the above metal elements and nitrogen may also be used. For example, a conductive material containing nitrogen such as titanium nitride or tantalum nitride may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an outer insulator or the like can be captured in some cases.

### <Classification of Crystal Structure of Oxide Semiconductor>

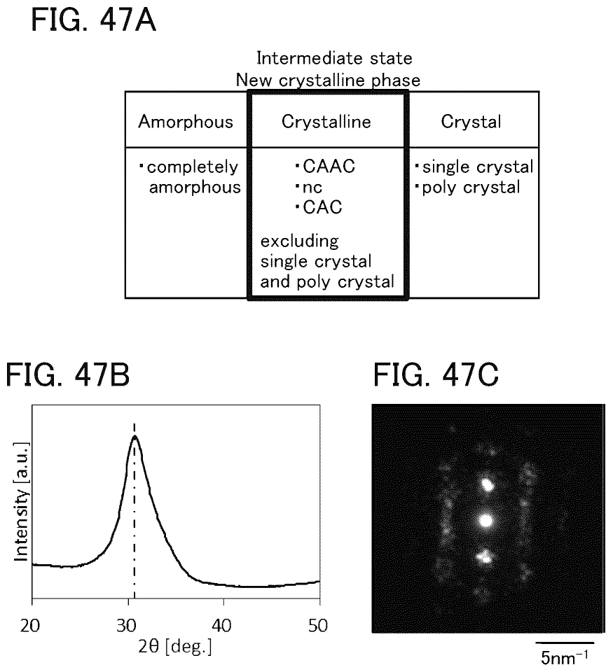

The classification of crystal structures of an oxide semiconductor will be described with reference to FIG. 47A. FIG. 47A shows the classification of crystal structures of an oxide semiconductor, typically IGZO (a metal oxide containing In, Ga, and Zn).

As shown in FIG. 47A, oxide semiconductors are roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (cloud-aligned composite) (excluding single crystal and poly crystal). Note that the term “Crystalline” excludes single crystal, poly crystal, and completely amorphous structures. The term “Crystal” includes single crystal and poly crystal.

Note that the structures in the thick frame in FIG. 47A are in an intermediate state between “Amorphous” and “Crystal”, and belong to a new crystalline phase. That is, these structures are completely different from “Amorphous”, which is energetically unstable, and “Crystal”.

Note that a crystal structure of a film or a substrate can be evaluated with an X-ray diffraction (XRD) spectrum. Here, FIG. 47B shows an XRD spectrum, which is obtained by GIXD (Grazing-Incidence XRD) measurement, of a CAAC-IGZO film classified into “Crystalline”. Note that a GIXD method is also referred to as a thin film method or a Seemann-Bohlin method. The XRD spectrum that is shown in FIG. 47B and obtained by GIXD measurement is hereinafter simply referred to as an XRD spectrum. The CAAC-IGZO film in FIG. 47B has a composition of In:Ga:Zn=4:2:3 [atomic ratio] or the vicinity thereof. The CAAC-IGZO film in FIG. 47B has a thickness of 500 nm.

In FIG. 47B, the horizontal axis represents 20 [deg.], and the vertical axis represents intensity (Intensity) [a.u.]. As shown in FIG. 47B, a clear peak indicating crystallinity is detected in the XRD spectrum of the CAAC-IGZO film. Specifically, a peak indicating c-axis alignment is detected at or around 2θ=310 in the XRD spectrum of the CAAC-IGZO film. As shown in FIG. 47B, the peak at or around 2θ=31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 47C shows a diffraction pattern of the CAAC-IGZO film. FIG. 47C shows a diffraction pattern obtained by the NBED method in which an electron beam is incident in the direction parallel to the substrate. The CAAC-IGZO film in FIG. 47C has a composition of In:Ga:Zn=4:2:3 [atomic ratio] or the vicinity thereof. In the nanobeam electron diffraction method, electron diffraction is performed with a probe diameter of 1 nm.

As shown in FIG. 47C, a plurality of spots indicating c-axis alignment are observed in the diffraction pattern of the CAAC-IGZO film.

### [Structure of Oxide Semiconductor]

Oxide semiconductors, which is one kind of a metal oxide, might be classified in a manner different from the one in FIG. 47A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

In the case of an In-M-Zn oxide (the element M is one or more of aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of a lattice arrangement. This is probably because the CAAC-OS can tolerate distortion owing to a low arrangement density of oxygen atoms in the a-b plane direction, an interatomic bond distance changed by substitution of a metal atom, and the like.

A crystal structure in which a clear grain boundary is observed is what is called a polycrystal structure. It is highly probable that the grain boundary becomes a recombination center and traps carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, In—Zn oxide and In—Ga—Zn oxide are suitable because they can inhibit generation of a grain boundary as compared with In oxide.

The CAAC-OS is an oxide semiconductor with high crystallinity in which no clear grain boundary is observed. Thus, in the CAAC-OS, a reduction in electron mobility due to the grain boundary is less likely to occur. Entry of impurities, formation of defects, or the like might decrease the crystallinity of an oxide semiconductor; thus, the CAAC-OS can be referred to as an oxide semiconductor having a small amount of impurities and defects (e.g., oxygen vacancies). Therefore, an oxide semiconductor including the CAAC-OS is physically stable. Accordingly, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. There is no regularity of crystal orientation between different nanocrystals in the nc-OS. Hence, the orientation in the whole film is not observed. Accordingly, the nc-OS cannot be distinguished from an a-like OS and an amorphous oxide semiconductor by some analysis methods. For example, when an nc-OS film is subjected to structural analysis by out-of-plane XRD measurement with an XRD apparatus using θ/2θ scanning, a peak indicating crystallinity is not observed. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., larger than or equal to 1 nm and smaller than or equal to 30 nm).

### [A-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has higher hydrogen concentration in the film than the nc-OS and the CAAC-OS.

### [Composition of Oxide Semiconductor]

Next, the CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in In—Ga—Zn oxide are denoted with [In], [Ga], and [Zn], respectively. For example, the first region in the CAC-OS in the In—Ga—Zn oxide has [In] higher than that in the composition of the CAC-OS film. Moreover, the second region has [Ga] higher than [Ga] in the composition of the CAC-OS film. Alternatively, for example, the first region has [In] higher than [In] in the second region and [Ga] lower than [Ga] in the second region. Moreover, the second region has [Ga] higher than [Ga] in the first region and [In] lower than [In] in the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where intentional substrate heating is not performed, for example. Moreover, in the case of forming the CAC-OS by a sputtering method, any one or more selected from an inert gas (typically, argon), an oxygen gas, and a nitrogen gas are used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, in EDX mapping obtained by EDX analysis, it is confirmed that the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, leakage current can be reduced.

Accordingly, in the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), high field-effect mobility (μ), and favorable switching operation can be achieved.

A transistor using the CAC-OS has high reliability. Thus, the CAC-OS is most suitable for a variety of semiconductor devices such as display apparatuses.

An oxide semiconductor can have any of various structures that show various different properties. Two or more of an amorphous oxide semiconductor, a polycrystalline oxide semiconductor, an a-like OS, the CAC-OS, an nc-OS, and the CAAC-OS may be included in an oxide semiconductor of one embodiment of the present invention.

### <Transistor Including Oxide Semiconductor>

Next, a transistor including the above oxide semiconductor is described.

When the oxide semiconductor is used for a transistor, the transistor can have high field-effect mobility. In addition, the transistor can have high reliability.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charge trapped by the trap states in an oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, the impurity concentration in a film that is adjacent to the oxide semiconductor is preferably reduced. Examples of impurities include hydrogen, nitrogen, an alkali metal, an alkaline earth metal, iron, nickel, and silicon. Note that impurities in an oxide semiconductor refer to, for example, elements other than the main components of an oxide semiconductor. For example, an element with a concentration lower than 0.1 atomic % can be regarded as an impurity.

### <Impurity>

The influence of impurities in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor (the concentration obtained by SIMS: Secondary Ion Mass Spectrometry) is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. A transistor including an oxide semiconductor that contains nitrogen tends to have normally-on characteristics. When nitrogen is contained in the oxide semiconductor, a trap state is sometimes formed. This makes the electrical characteristics of the transistor unstable in some cases. Thus, the concentration of nitrogen in the oxide semiconductor, which is measured by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in an oxide semiconductor reacts with oxygen bonded to a metal atom to be water, and thus causes an oxygen vacancy in some cases. Entry of hydrogen into the oxygen vacancy generates an electron serving as a carrier in some cases. Furthermore, some hydrogen may be bonded to oxygen bonded to a metal atom and generate an electron serving as a carrier. Thus, a transistor including an oxide semiconductor that contains hydrogen tends to have normally-on characteristics. For this reason, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

At least part of the structure examples, the drawings corresponding thereto, and the like described in this embodiment as an example can be combined with any of the other structure examples, the other drawings, and the like as appropriate.

### Embodiment 7

This embodiment describes a relation between the size of the display portion 13 of the display apparatus 10 (also referred to as a “size of a display region”) and a light-exposure region 99 of the light-exposure apparatus, and the relation of the size, the resolution, and the definition of the display portion 13 in each screen ratio (aspect ratio) with a constant diagonal size of the display portion 13 is described.

### <Size of Display Region and Light-Exposure Region>

By considering the size of the display region of the display apparatus based on the light-exposure region 99 of the light-exposure apparatus, a display apparatus with an optimal manufacturing cost can be manufactured. For example, as the light-exposure apparatus, a stepper, a scanner, and the like can be used. A light source that can be used for the light-exposure apparatus has a wavelength of 13 nm (EUV (Extreme Ultra Violet)), 157 nm (F₂), 193 nm (ArF), 248 nm (KrF), 308 nm (XeCl), 365 nm (an i-line), 436 nm (a g-line), and the like. With the light source having a short wavelength, a high definition display apparatus or a miniaturized display apparatus can be obtained.

Note that as the maximum value of the light-exposure region 99 of the light-exposure apparatus, [26 mm×33 mm] is a current mainstream; therefore, the description below is considered with reference to [26 mm×33 mm]. When the maximum value of the light-exposure region 99 of the light-exposure apparatus is [26 mm×33 mm], the size of the display region of the display apparatus that can be obtained with one light exposure (1 shot) is [26 mm×33 mm]. In addition, the size of the display region of the display apparatus that can be obtained with two light exposures (2 shots) is [52 mm×33 mm] or [26 mm×66 mm]. Note that by setting the size of the display region of the display apparatus within the range operable by one light exposure, the manufacturing cost can be reduced.

As described in the above embodiment, there is no limitation on the screen ratio (aspect ratio) of the display portion 13. The aspect ratio of the display portion 13 can be 1:1, 4:3, 16:9, 16:10, or the like.

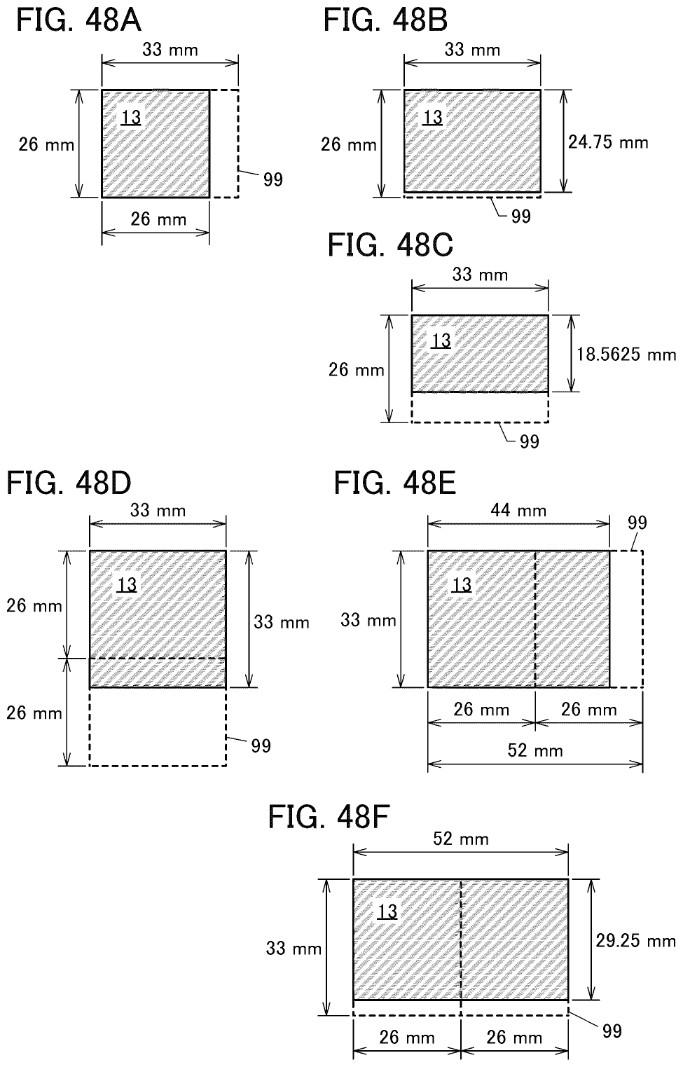

As illustrated in FIG. 48A to FIG. 48C, in the case where the maximum value of the light-exposure region 99 of a light-exposure apparatus is [26 mm×33 mm], the maximum size of a display region of a display apparatus that can be manufactured in one light exposure is [26 mm×26 mm] when the aspect ratio is 1:1, [33 mm×24.75 mm] when the aspect ratio is 4:3, and [33 mm×18.5625 mm] when the aspect ratio is 16:9.

As illustrated in FIG. 48D to FIG. 48F, in the case where the maximum value of the light-exposure region 99 of the light-exposure apparatus is [26 mm×33 mm], the maximum size of the display region of the display apparatus that can be manufactured in two light exposures is [33 mm×33 mm] when the aspect ratio is 1:1, [44 mm×33 mm] when the aspect ratio is 4:3, and [52 mm×29.25 mm] when the aspect ratio is 16:9.

Note that the above values are each the maximum size of the display region of the display apparatus; thus, the actual external dimension of the display apparatus is larger than or equal to that of the size of the display region of the display apparatus. In addition, the aspect ratio of the external dimension of the display apparatus may be the same as or different from the aspect ratio of the display region of the display apparatus.

Here, Table 1 and Table 2 shown below list the specifications of the display portion 13 (display region) of the display apparatus 10 of one embodiment of the present invention as an example. As illustrated in Table 1 and Table 2, the display portion has 4K3K (number of pixels: 3840×2880) which is extremely high resolution.

TABLE 1

| Specification items | | |
|---|---|---|
| of display region | Specifications | |
| Size | Diagonal size 1.57 inches | |
| | 31.9 mm × 23.9 mm | |
| Definition | 3060 | ppi |
| Aspect ratio | 4:3 | |
| Number of pixels | 3840 × 2880 | |
| Aperture ratio | Higher than or equal to 30% | |
| Duty driving | Performed | |
| Luminance | >5000 | cd/m² |

TABLE 2

| Specification items | | |
|---|---|---|
| of display region | Specifications | |
| Size | Diagonal size 1.57 inches | |
| Number of pixels | 3840 × 2880 | |
| Pixel size | 2.76 μm × RGB (H) × 8.3 μm (V) | |
| Definition | 3057 | ppi |
| Display element | OLED | |
| Pixel layout | RGB stripe | |
| Coloring method | SBS (side by side) | |
| Driving frequency | 90 | Hz |

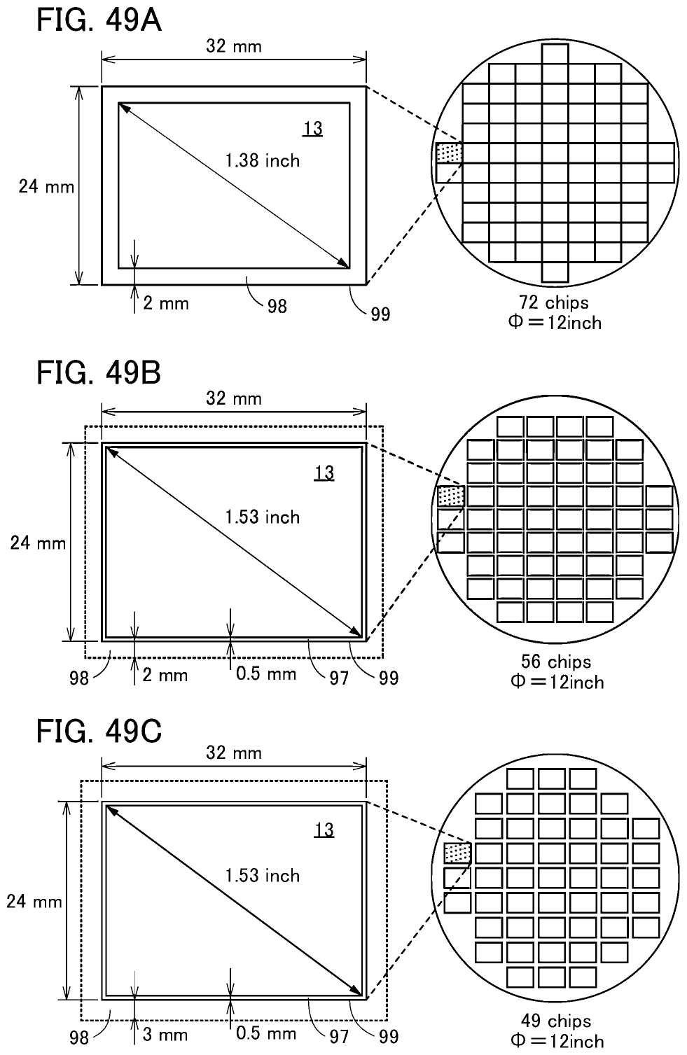

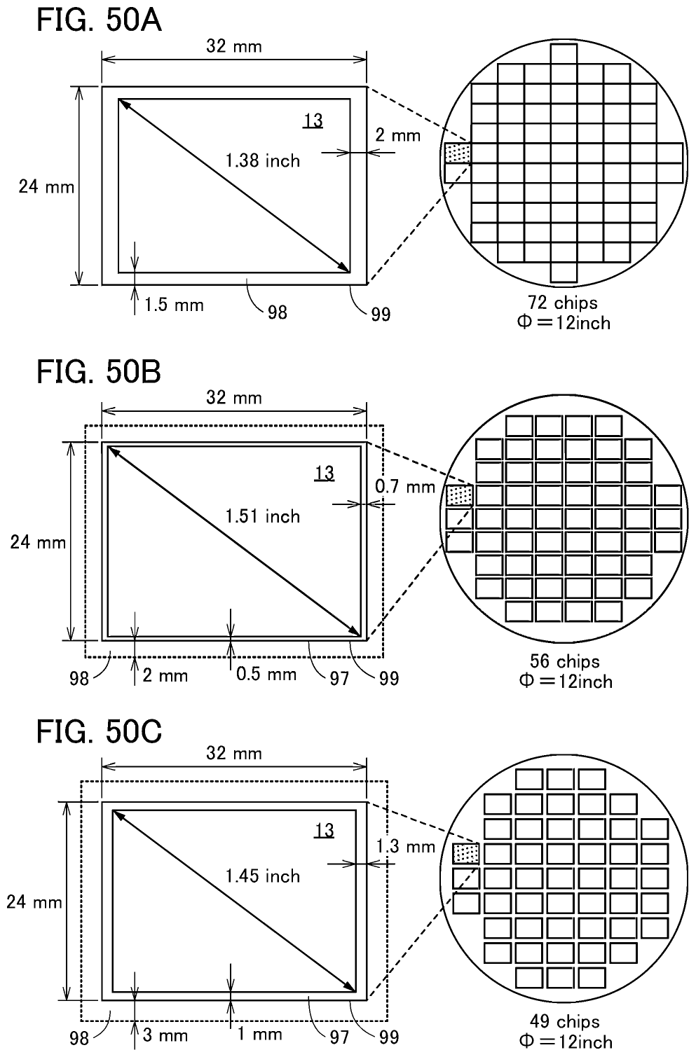

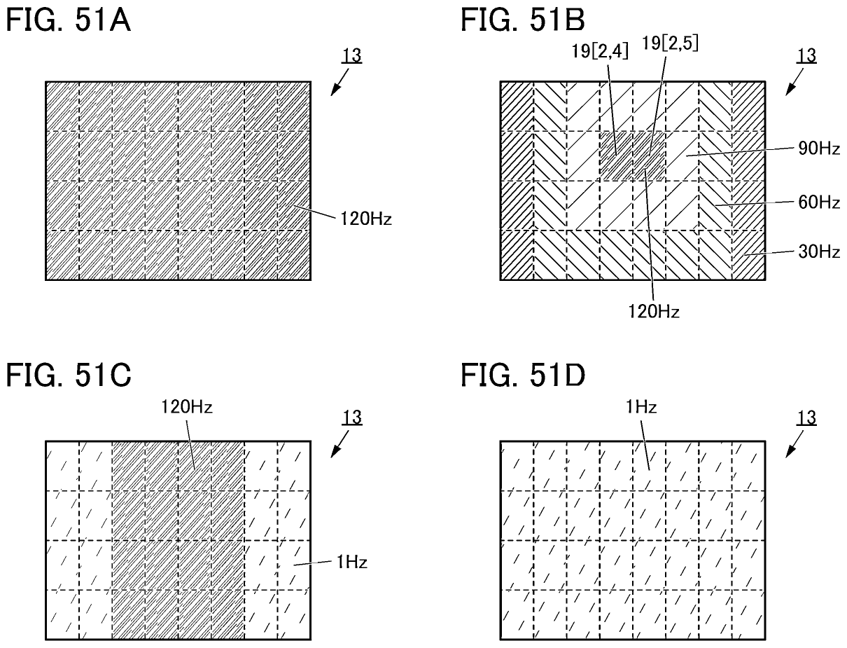

FIG. 49A to FIG. 49C and FIG. 50A to FIG. 50C illustrate examples of the number of display apparatuses taken from one substrate (wafer) with a diameter (D 12 inches. FIG. 49A to FIG. 49C and FIG. 50A to FIG. 50C perform an estimation, assuming that an external connection terminal is extracted from a rear surface with use of a through electrode. Thus, a display region can be set large. Note that an electrode pad for making an electrical connection with the outside may be provided in the light-exposure region. In this case, the display region is reduced in size, but the manufacturing cost for the structure of extracting the external connection terminal can be reduced.

FIG. 49A illustrates an example in which a sealing region 98 with a width of 2 mm is provided inside the light-exposure region 99 of 32 mm×24 mm. Note that here, the sealing region 98 indicates a region from an edge portion of a display region (the display portion 13) to a dividing position of a substrate or a position of a terminal, and not necessarily a region to which the sealant is applied. In this case, the size of the display region of a display apparatus is 28 mm×20 mm and a diagonal size is approximately 1.38 inches. The number of display apparatuses taken out from one substrate is 72. Note that when the width of the sealing region 98 is shortened to 1 mm, the diagonal size of the display region of the display apparatus can be approximately 1.5 inches.

FIG. 49B and FIG. 49C illustrate an example in which the sealing region 98 is provided outside 32 mm×24 mm in the light-exposure region 99. In this case, the region except a space for the sealing region 98 is exposed to light. A marker region 97 is provided inside the exposed region 99. FIG. 49B shows an example of a case where the width of the marker region 97 is 0.5 mm and the width of the sealing region 98 is 2 mm. At this time, the diagonal size of the display portion 13 (the display region) of the display apparatus is approximately 1.53 inches. The number of display apparatuses taken out from one substrate is 56. Note that when the width of the marker region 97 is 1 mm, the display region has a diagonal size of approximately 1.47 inches. FIG. 49C shows an example of a case where the width of the marker region 97 is 0.5 mm and the width of the sealing region 98 is 3 mm. In this case, the display region of the display apparatus has a diagonal size of approximately 1.53 inches, and has the same structure as that in FIG. 49B. The number of display apparatuses taken out of one substrate is 49, which is lower by approximately 13% than that in FIG. 49B.

FIG. 50A to FIG. 50C illustrate examples of a case where the aspect ratio of each display region is 4:3.

FIG. 50A is an example where the sealing region 98 is provided inside the light-exposure region 99 (32 mm×24 mm) of a light-exposure apparatus. In the example of FIG. 50A, the width of the sealing region 98 in the vertical direction is 1.5 mm and that in the horizontal direction is 2 mm. In this case, the display region has a size of 28 mm×21 mm (the aspect ratio is 4:3) and a diagonal size of approximately 1.38 inches. The number of display apparatuses taken out from one substrate is 72. When the width of the sealing region 98 in the vertical direction is 2 mm and that in the horizontal direction is 2.65 mm, the display region has a size of 26.7 mm×20 mm (the aspect ratio is 4:3) and a diagonal size of approximately 1.32 inches. Alternatively, when the width of the sealing region 98 in the vertical direction is 3 mm and that in the horizontal direction is 4 mm, the display region has a size of 24 mm×18 mm (the aspect ratio is 4:3) and a diagonal size of approximately 1.18 inches. In each case, the number of display apparatuses taken out from one substrate is 72.

FIG. 50B and FIG. 50C illustrate examples where the sealing region 98 is provided outside a light-exposure region (32 mm×24 mm) of a light-exposure apparatus. In this case, the region except a space for the sealing region 98 is exposed to light. The marker region 97 is provided inside the light-exposure region 99. FIG. 50B illustrates an example of a case where the width of the marker region 97 in the vertical direction is 0.5 mm and that in the horizontal direction is 0.7 mm, and the width of the sealing region 98 is 2 mm. In this case, the display region of the display apparatus has a diagonal size of approximately 1.51 inches. The number of display apparatuses taken out from one substrate is 56. When the width of the marker region 97 in the vertical direction is 1 mm and that in the horizontal direction is 1.3 mm, the display region has a diagonal size of approximately 1.45 inches. FIG. 50C shows an example of a case where the width of the marker region 97 in the vertical direction is 1 mm and that in the horizontal direction is 1.3 mm, and the width of the sealing region is 3 mm. In this case, the display region of the display apparatus has a diagonal size of approximately 1.45 inches. The number of display apparatuses taken from one substrate is 49, which is approximately 13% lower than that in the structure in FIG. 50B.

Note that when the size of the display region of each of the pair of display apparatuses 10 (a display apparatus 10_L and a display apparatus 10_R) used in the electronic device 100 is greater than or equal to the size (approximately 23 to 24 mm) of the human eyeball, the display apparatus 10 can be placed to cover the whole area for eyes or the whole field of view. For example, when the display region of the display apparatus has a diagonal size of greater than or equal to 1.0 inches and less than or equal to 2.5 inches, preferably greater than or equal to 1.4 inches and less than or equal to 2.5 inches, further preferably greater than or equal to 1.5 inches and less than or equal to 2.5 inches, the display apparatus 10 can be placed such that the user's field of view is entirely covered with the display region. Thus, the use of the display apparatus or the display system of one embodiment of the present invention can provide a higher level of one or more of immersion, realistic sensation, and sense of depth.

### <Size, Resolution, and Definition of Display Region of Each Aspect Ratio>

With the display region with higher resolution or definition, the pixels can be imperceptible (e.g., lines between pixels can be invisible) to the user and accordingly can provide a higher level of one or more of immersion, realistic sensation, and sense of depth.

Table 3 shows the resolution and definition in the aspect ratios of 1:1, 4:3, and 16:9 of the display region with a diagonal size of 1.0 inch.

TABLE 3

| Aspect ratio | 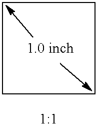 | 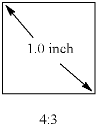 | 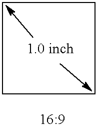 |
|---|---|---|---|
| Size of display | 17.96 × | 20.32 × | 22.14 × |
| region | 17.96 mm | 15.24 mm | 12.45 mm |
| 2K pixels in | 2715 ppi | 2400 ppi | 2203 ppi |
| vertical | | | |
| direction | | | |
| 4K pixels in | 5430 ppi | 4800 ppi | 4405 ppi |
| vertical | | | |
| direction | | | |
| 8K pixels in | 10861 ppi | 9600 ppi | 8811 ppi |
| vertical | | | |
| direction | | | |

In the case where the aspect ratio is 1:1, the size of the display region with a diagonal size of 1.0 inch is 17.96×17.96 mm. When the resolution of one side (which is any one of the sides surrounding the display region in the case of the aspect ratio of 1:1) is 2K pixels (1920 pixels), the definition is 2715 ppi. When the resolution of one side is 4K pixels (3840 pixels), the definition is 5430 ppi. When the resolution of one side is 8K pixels (7680 pixels), the definition is 10861 ppi.

In the case where the aspect ratio is 4:3, the size of the display region with a diagonal size of 1.0 inch is 20.32×15.24 mm. When the resolution in the vertical direction is set to 2K pixels, the definition is 2400 ppi. When the resolution in the vertical direction is set to 4K pixels, the definition is 4800 ppi. When the resolution in the vertical direction is set to 8K pixels, the definition is 9600 ppi.

In the case where the aspect ratio is 16:9, the size of the display region with a diagonal size of 1.0 inch is 22.14×12.45 mm. When the resolution in the vertical direction is set to 2K pixels, the definition is 2203 ppi. When the resolution in the vertical direction is set to 4K pixels, the definition is 4405 ppi. When the resolution in the vertical direction is set to 8K pixels, the definition is 8811 ppi.

Table 3 shows that the definition is increased as the resolution becomes higher. It is also found that the higher definition is required as the aspect ratio becomes smaller.

At least part of the structure examples, the drawings corresponding thereto, and the like described in this embodiment can be combined with any of the other structure examples, the other drawings, and the like as appropriate.

<Supplementary Notes on Description in this Specification and the Like>

The following are notes on the description of the foregoing embodiments and the structures in the embodiments.

The structure described in each embodiment can be combined with any of the structures described in the other embodiments as appropriate to constitute one embodiment of the present invention. In addition, in the case where a plurality of structure examples are described in one embodiment, some of the structure examples can be combined as appropriate.

Note that a content (or part thereof) described in one embodiment can be applied to, combined with, or replaced with another content (or part thereof) in the same embodiment or a content (or part thereof) described in another embodiment or other embodiments, for example.

Note that in each embodiment, a content described in the embodiment is a content described with reference to a variety of diagrams or a content described with text disclosed in the specification.

Note that by combining a diagram (or part thereof) described in one embodiment with another part of the diagram, a different diagram (or part thereof) described in the embodiment, or a diagram (or part thereof) described in another embodiment or other embodiments, much more diagrams can be formed.

In this specification and the like, components are classified on the basis of the functions, and shown as blocks independent of one another in block diagrams. However, in an actual circuit and the like, such components are sometimes hard to classify functionally, and there is a case where one circuit is associated with a plurality of functions and a case where a plurality of circuits are associated with one function. Therefore, the blocks in the block diagrams are not limited by the components described in the specification, and the description can be changed appropriately depending on the situation.

In drawings, the size, the layer thickness, or the region is shown arbitrarily for description convenience. Therefore, the size, the layer thickness, or the region is not limited to the illustrated scale. Note that the drawings are schematically shown for clarity, and embodiments of the present invention are not limited to shapes, values, or the like shown in the drawings. For example, variation in signal, voltage, or current due to noise or variation in signal, voltage, or current due to difference in timing can be included.

In this specification and the like, the terms “one of a source and a drain” (or a first electrode or a first terminal) and “the other of the source and the drain” (or a second electrode or a second terminal) are used to describe the connection relationship of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In this specification and the like, the terms such as “electrode” and “wiring” do not limit the functions of the components. For example, an “electrode” is used as part of a “wiring” in some cases, and vice versa. Furthermore, the terms such as “electrode” and “wiring” also include the case where a plurality of “electrodes” and “wirings” are formed in an integrated manner, for example.

In this specification and the like, voltage and potential can be replaced with each other as appropriate. The term voltage refers to a potential difference from a reference potential, and when the reference potential is a ground potential, for example, voltage can be replaced with potential. The ground potential does not necessarily mean 0 V. Potentials are relative values, and a potential supplied to a wiring or the like is sometimes changed depending on the reference potential.

In this specification and the like, the terms “film” and “layer” can be interchanged with each other depending on the case or circumstances. For example, the term “conductive layer” can be changed into the term “conductive film” in some cases. Also, for example, the term “insulating film” can be changed into the term “insulating layer” in some cases.

In this specification and the like, a switch has a function of controlling whether a current flows or not by being in a conduction state (an on state) or a non-conduction state (an off state). Alternatively, a switch has a function of selecting and changing a current path.

In this specification and the like, the channel length refers to, for example, the distance between a source and a drain in a region where a semiconductor (or a portion where a current flows in a semiconductor when a transistor is on) and a gate overlap with each other or a region where a channel is formed in a plan view of the transistor.

In this specification and the like, the channel width refers to, for example, the length of a region where a channel is formed in a direction orthogonal to a channel length direction in a region where a semiconductor (or a portion where current flows in a semiconductor when a transistor is in an on state) and a gate electrode overlap with each other or a region where a channel is formed.

In this specification and the like, the expression “A and B are connected” means the case where A and B are electrically connected to each other as well as the case where A and B are directly connected to each other. Here, the expression “A and B are electrically connected” means the case where electrical signals can be transmitted and received between A and B when an object having an electric action exists between A and B.

In this specification and the like, a structure in which light-emitting layers in light-emitting devices of different colors (e.g., blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of a white light-emitting device with a coloring layer (e.g., a color filter) enables a full-color display apparatus.

Light-emitting devices can be classified roughly into a single structure and a tandem structure. A device having a single structure includes one light-emitting unit between a pair of electrodes, and the light-emitting unit preferably includes one or more light-emitting layers. When white light emission is obtained using two light-emitting layers, the two light-emitting layers are selected such that emission colors of the two light-emitting layers are complementary colors. For example, when the emission color of a first light-emitting layer and the emission color of a second light-emitting layer have a relationship of complementary colors, it is possible to obtain a structure where the light-emitting device emits white light as a whole. To obtain white light emission by using three or more light-emitting layers, the light-emitting device is configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, white light may be obtained by combining light emitted from light-emitting layers of a plurality of light-emitting units. Note that a structure for obtaining white light emission is similar to a structure in the case of a single structure. In the device having a tandem structure, it is favorable that an intermediate layer such as a charge-generation layer is provided between a plurality of light-emitting units.

When the white-light-emitting device (having a single structure or a tandem structure) and a light-emitting device having an SBS structure are compared with each other, the light-emitting device having an SBS structure can have lower power consumption than the white-light-emitting device. To reduce power consumption, the light-emitting device having an SBS structure is preferably used. Meanwhile, the white-light-emitting device is preferable in terms of lower manufacturing cost or higher manufacturing yield because the manufacturing process of the white-light-emitting device is simpler than that of the light-emitting device having an SBS structure.

Ordinal numbers such as “first” and “second” in this specification and the like are used in order to avoid confusion among components and do not denote the priority or the order such as the order of steps, the stacking order, or the order of placement. A term without an ordinal number in this specification and the like may be provided with an ordinal number in the scope of claims in order to avoid confusion among components. Furthermore, a term with an ordinal number in this specification and the like may be provided with a different ordinal number in the scope of claims. Moreover, even when a term is provided with an ordinal number in this specification and the like, the ordinal number might be omitted in the scope of claims and the like.

In general, a “capacitor” has a structure where two electrodes face each other with an insulator (dielectric) therebetween. This specification and the like include a case where a “capacitor element” is the above-described “capacitor”. That is, this specification and the like include cases where a “capacitor element” is one having a structure in which two electrodes face each other with an insulator therebetween, one having a structure in which two wirings face each other with an insulator therebetween, or one in which two wirings are positioned with an insulator therebetween.

### Example 1

In this example, a reduction in power consumption by changing frame frequency for each of the sub-display portions 19 will be described.

In this example, a display apparatus was assumed to include the display portion 13 that was divided into the sub-display portions 19 in four rows and eight columns, had a diagonal size of the display portion 13 of 1.5 inches and a resolution of 3840×2160 pixels, and power consumption was calculated in the case where frame frequency is changed for each of the sub-display portions 19. The simulation software SPICE was used for the power consumption calculation.

In this example, power consumption was calculated for four modes A to D. FIG. 51A to FIG. 51D show an operation state of the display portion 13 in each mode.

As Mode A, it is assumed that the frame frequencies of all the sub-display portions 19 are 120 Hz (see FIG. 51A).

As Mode B, it is assumed that the frame frequency of the sub-display portion 19 in the second row and the fourth column (a sub-display portion 19[2,4]) and the frame frequency of the sub-display portion 19 in the second row and the fifth column (a sub-display portion 19[2,5]) are 120 Hz, the frame frequency of each of the sub-display portions 19 adjacent to the outside of the sub-display portion 19[2,4] or the sub-display portion 19[2,5] is 90 Hz, the frame frequency of each of the sub-display portions 19 adjacent to further outside of the sub-display portions 19 with the frame frequency of 90 Hz is 60 Hz, and the frame frequency of each of the sub-display portions 19 in the first column and the eighth column is 30 Hz (see FIG. 51B).

As Mode C, it is assumed that the frame frequency of each of the sub-display portions 19 in third column to the sixth column is 120 Hz, and the frame frequency of each of the sub-display portions 19 in the first column, the second column, the seventh column, and the eighth column is 1 Hz (see FIG. 51C).

As Mode D, it is assumed that the frame frequencies of all the sub-display portions 19 are 1 Hz (see FIG. 51D).

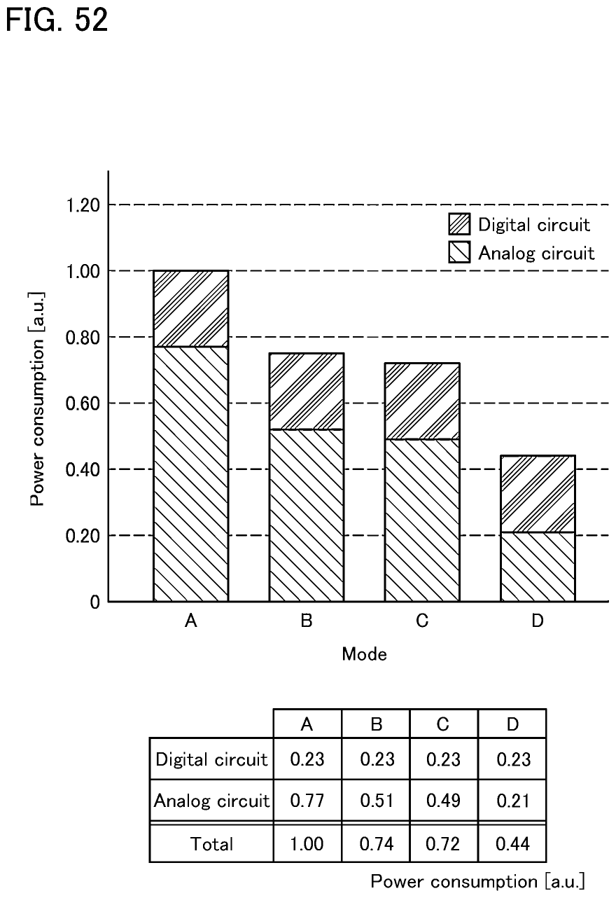

FIG. 52 is a graph showing calculation results of power consumption of each mode. The horizontal axis in FIG. 52 shows each mode. The vertical axis in FIG. 52 shows a normalized value of calculation results of each mode on the basis of calculation results of Mode A. Note that a value of normalized power consumption of each mode is shown in FIG. 52.

In FIG. 52, the power consumption of each mode is divided into the power consumption of a digital circuit and the power consumption of an analog circuit. The digital circuit described in this example is mainly a circuit relating to data transmission and includes a gate driver circuit, a source driver circuit, and the like. The analog circuit is a circuit relating to processing for displaying an image by converting image data into an analog signal and includes a digital-analog converter circuit, an operational amplifier, and the like.

As apparent from FIG. 52, although the power consumption of the digital circuit do not change in each mode, the power consumption of the analog circuit has changed according to Mode. It is shown that power consumption of Mode B and Mode C is approximately 30% lower than that of Mode A. It is shown that power consumption of Mode D is approximately 60% lower than that of Mode A.

### Example 2

In this example, calculation results of power consumption in the same display apparatus as that in Example 1 in the case where the structures of the backplane and the front plane are changed are described. In this example and the like, “backplane” refers to a transistor or the whole layer including the transistor. Thus, the backplane includes a gate driver, a source driver, a pixel circuit, and the like. In this example and the like, “frontplane” refers to the light-emitting element 61 or the whole layer including the light-emitting element 61.

Table 4 shows estimation results of power consumption in combination of the following assumed cases: a case in which the backplane is configured to include Si transistors and OS transistors; a case in which the backplane is configured to include Si transistors only; a case in which the frontplane has an SBS structure; and a case in which the frontplane has a tandem structure. Note that the frontplane of the tandem structure is assumed to be a combination of a white light-emitting device (light-emitting element) containing light-emitting substances of B (blue) and Y (yellow) with a color filter (CF).

As the calculation condition of the power consumption, the luminance of light emitted when white display is performed on the entire display portion with the aperture ratio of the pixel being 40% and without a circularly polarizing plate is assumed to be 5000 cd/m². The power consumption is calculated on two circuit blocks: a pixel portion (the display portion 13 including the plurality of pixels 230) and a portion including a gate driver, a source driver, and the like (the driver circuit 30).

First, power consumption in operation of the display apparatus in each operation mode of Mode A (see FIG. 51A), Mode B (see FIG. 51B), and Mode C (see FIG. 51C) described in Example 1 is calculated. Table 4 shows calculation results of power consumption. Note that as the display apparatus including only Si transistors in the backplane, a display apparatus in which the display portion is not divided into a plurality of sub-display portions is assumed. Thus, in the display apparatus including only Si transistors in the backplane, the operations of Mode B and Mode C cannot be performed.

TABLE 4

| Backplane | Frontplane | Circuit block | Mode A | Mode B | | Mode C | |
|---|---|---|---|---|---|---|---|
| Si\OS | Side-by- | Pixel portion | 0.7 W | 0.7 | W | 0.7 | W |
| | side OEL | (EL + Driving | | | | | |
| | | OSFET) | | | | | |
| | | Source driver, | 0.9 W | 0.61 | W | 0.63 | W |
| | | Gate driver, | | | | | |
| | | etc. | | | | | |
| Si | Side-by- | Pixel portion | 0.5 W | — | | — | |
| | side OEL | (EL + Driving | | | | | |
| | | OSFET) | | | | | |
| | | Source driver, | 1.0 W | — | | — | |
| | | Gate driver, | | | | | |
| | | etc. | | | | | |
| Si\OS | White | Pixel portion | 2.3 W | 2.3 | W | 2.3 | W |
| | (B\Y | (EL + Driving | | | | | |
| | Tandem + | Si FET) | | | | | |
| | CF) | Source driver, | 0.9 W | 0.61 | W | 0.63 | W |
| | | Gate driver, | | | | | |
| | | etc. | | | | | |

| | | | | | |
|---|---|---|---|---|---|
| Si | White | Pixel portion | 2.1 W | — | — |
| | (B\Y | (EL + Driving | | | |
| | Tandem + | OSFET) | | | |
| | CF) | Source driver, | 1.0 W | — | — |
| | | Gate driver, | | | |
| | | etc. | | | |

According to Table 4, the power consumption of Mode B or Mode C is lower than that of Mode A, in the case in which the backplane includes OS transistors. It is found that the power consumption of the portion including the gate driver circuit, the source driver circuit, etc. in the circuit block in the operation of the display apparatus in Mode B or Mode C is approximately 30% lower than that in the operation in Mode A.

Next, the power consumption of every frame frequency was calculated on the assumption that the entire display portion performs white display. The calculation of the power consumption was performed on each of a moving image mode with a frame frequency of 120 Hz, a low-refresh rate mode with 1 Hz, and a low-refresh rate mode with 0.1 Hz. Table 5 shows calculation results of power consumption.

Note that the moving image mode with a frame frequency of 120 Hz in Table 5 corresponds to Mode A shown in Example 1 (see FIG. 51A). In addition, the low-refresh rate mode with a frame frequency of 1 Hz or lower in Table 5 corresponds to Mode D shown in Example 1 (see FIG. 51D).

TABLE 5

| | | | 120 Hz | 1 Hz | | 0.1 Hz | |
|---|---|---|---|---|---|---|---|
| | | | (Moving image | (Low-refresh | | (Low-refresh | |
| Backplane | Frontplane | Circuit block | mode) | rate mode) | | rate mode) | |
| Si\OS | Side-by- | Pixel portion | 0.7 W | 0.7 | W | 0.7 | W |
| | side OEL | (EL + driving | | | | | |
| | | OSFET) | | | | | |
| | | Source driver, | 0.9 W | 0.246 | W | 0.244 | W |
| | | Gate driver, | | | | | |
| | | etc. | | | | | |
| Si | Side-by- | Pixel portion | 0.5 W | — | | — | |
| | side OEL | (EL + driving | | | | | |
| | | OSFET) | | | | | |
| | | Source driver, | 1.0 W | — | | — | |
| | | Gate driver, | | | | | |
| | | etc. | | | | | |
| Si\OS | White | Pixel portion | 2.3 W | 2.3 | W | 2.3 | W |
| | (B\Y | (EL + driving | | | | | |
| | Tandem + | Si FET) | | | | | |
| | CF) | Source driver, | 0.9 W | 0.246 | W | 0.244 | W |
| | | Gate driver, | | | | | |
| | | etc. | | | | | |

| | | | | | |
|---|---|---|---|---|---|
| Si | White | Pixel portion | 2.1 W | — | — |
| | (B\Y | (EL + driving | | | |
| | Tandem + | OSFET) | | | |
| | CF) | Source driver, | 1.0 W | — | — |
| | | Gate driver, | | | |
| | | etc. | | | |

According to Table 5, the power consumption of the pixel portion in the frontplane having the SBS structure is lower than that in the frontplane having the tandem structure. When the structure of the frontplane is changed from the tandem structure to the SBS structure, the power consumption of the pixel portion in the moving image mode is reduced to approximately one fourth.

As described in the above embodiments, the OS transistor has an extremely low off-state current and thus can achieve long-term retention of image data supplied to the pixel circuit. In general, in the case where the backplane includes only Si transistors, image display cannot be normally performed when the frame frequency becomes lower than or equal to 30 Hz. When an OS transistor is used in a pixel portion, favorable image display can be achieved even with a frame frequency of 1 Hz or less.

As apparent from Table 5, in the case where the backplane includes OS transistors, the power consumption of the portion including the gate driver, the source driver, etc. in the circuit block in the case of the frame frequency of 1 Hz or lower is lower than that in the case of the frame frequency of 120 Hz. By changing the frame frequency from 120 Hz to 1 Hz or lower, the power consumption of the portion including the gate driver, the source driver, etc. in the circuit block is reduced to approximately one fourth.

As shown in Table 4 and Table 5, the display apparatus including the Si transistors and the OS transistors in the backplane and having the SBS structure in the frontplane has a high effect of reduction in power consumption, and can achieve high-speed display of a moving image and display of a still image with low power consumption.

### Example 3

In this example, the numbers of the display apparatuses DPA and the display apparatuses DPB which are fabricated on one 12-inch wafer and which are assumed to have a diagonal size of 1.0 inch, an aspect ratio of 16:9, a 4K resolution (3840×2160 pixels), and a definition of 4406 ppi (the number is also referred to as “the number of chips obtained”) are estimated, and the estimation results are described. Note that in this example and the like, a display apparatus obtained by cutting a wafer is referred to as a “chip” in some cases. The size of the display apparatus obtained by cutting the wafer is referred to as a “chip size” in some cases.

The display apparatus DPA is assumed to have a structure in which the driver circuit 30 and the pixel circuit group 55 are configured with only Si transistors and the plurality of light-emitting elements 61 are provided thereover (also referred to as a “Si\OEL structure”). The display apparatus DPA corresponds to, for example, the display apparatus 10C described in the above embodiment.

The display apparatus DPB is assumed to have a structure in which the driver circuit 30 is configured with Si transistors, the pixel circuit group 55 thereover is configured with OS transistors, and the plurality of light-emitting elements 61 are provided over the pixel circuit group 55 (the structure is also referred to as an “Si\OS\OEL structure”). The display apparatus DPB corresponds to, for example, the display apparatus 10A described in the above embodiment.

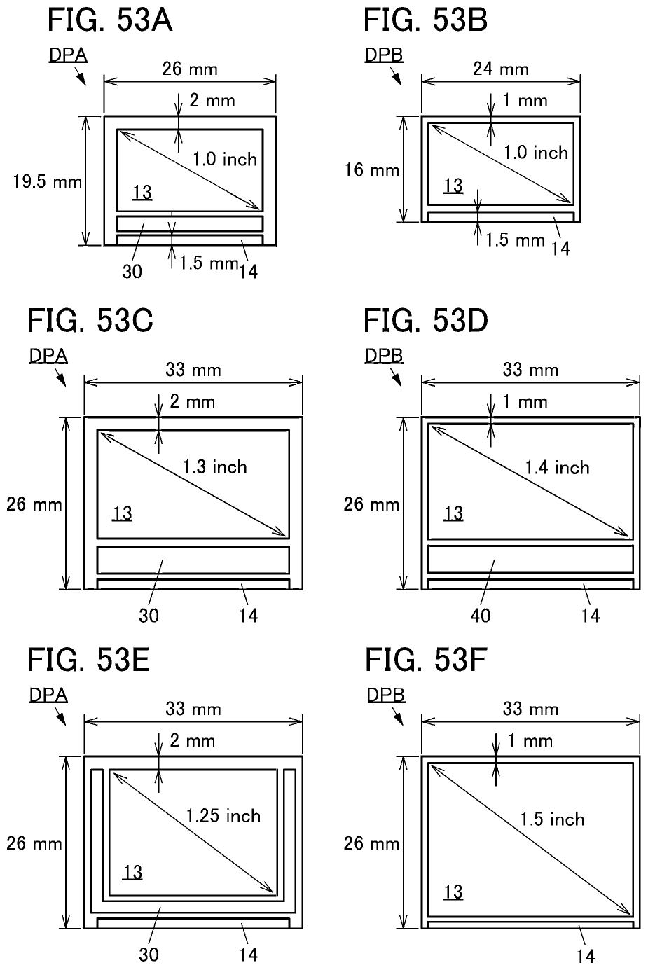

FIG. 53A shows the external size of the assumed display apparatus DPA. FIG. 53B shows the external size of the assumed display apparatus DPB. In both the display apparatus DPA and the display apparatus DPB, the diagonal size of the display portion 13 is 1.0 inch and the width of the terminal portion 14 is 1.5 mm. The external size of the display apparatus DPA is 19.5 mm×26 mm and the bezel width is 2 mm. The external size of the display apparatus DPB is 16 mm×24 mm and the bezel width is 1 mm. A gate driver is provided at a bezel portion of 2 mm in the display apparatus DPA.

In the display apparatus DPA having the Si\OEL structure, the driver circuit 30 and the pixel circuit group 55 included in the display portion 13 are arranged side by side over the wafer. In other words, the display portion 13 and the driver circuit 30 cannot overlap with each other. On the other hand, in the display apparatus DPB having the Si\OS\OEL structure, the driver circuit 30 can be provided so as to overlap with and be placed under the display portion 13. It is also possible that the functional circuit 40 is provided under the display portion 13 in the display apparatus DPB. Thus, a larger number of peripheral circuits or the like can be provided in the display apparatus DPB than in the display apparatus DPA. In addition, the external size of the display apparatus DPB can be smaller than that of the display apparatus DPA.

The number of chips obtained as the display apparatuses DPA is estimated to be 121 and the number of chips obtained as the display apparatuses DPB is estimated to be 161 on the basis of the external sizes illustrated in FIG. 53A and FIG. 53B. Accordingly, it can be said that the final manufacturing cost of the display apparatus DPB having the Si\OS\OEL structure can be easily reduced as compared to the display apparatus DPA having the Si\OEL structure.

Table 6 summarizes the estimation results of the manufacturing cost, the number of chips obtained, and the cost of one chip (cost per chip) of the display apparatus DPA and the display apparatus DPB.

TABLE 6

| | Manufacturing | Number of | Cost |
|---|---|---|---|
| | cost | chips obtained | per chip |
| DPA (Si\OEL) | 1 | 121 | 1 |
| DPB (Si\OS\OEL) | 1.2 | 161 | 0.9 |
| DPB (Si\OS\OEL) | 1.3 | 161 | 1.0 |
| DPB (Si\OS\OEL) | 1.5 | 161 | 1.1 |

Assuming that the manufacturing cost and the cost per chip of the display apparatus DPA are each 1, the manufacturing cost and the cost per chip of the display apparatus DPB are 1.2 and 0.9, respectively. In addition, when the manufacturing cost of the display apparatus DPB is 1.3, the cost per chip of the display apparatus DPB is 1. In addition, when the manufacturing cost of the display apparatus DPB is 1.5, the cost per chip of the display apparatus DPB is 1.1.

Table 6 shows that the manufacturing cost of the display apparatus DPB is lower than that of the display apparatus DPA when the manufacturing cost of the display apparatus DPB is 1.3 times or less that of the display apparatus DPA. It is also shown that the cost per chip increases by only 10% even when the manufacturing cost of the display apparatus DPB is 1.5 times that of the display apparatus DPA.

FIG. 53C to FIG. 53F show estimation results of the diagonal size of the display portion 13 of each of the display apparatus DPA and the display apparatus DPB, which can be manufactured by one time light exposure (one shot of 26 mm×33 mm).

In the case where the aspect ratio is 16:9, the maximum diagonal size of the display portion 13 of the display apparatus DPA is estimated to be 1.3 inches (see FIG. 53C), and the maximum diagonal size of the display portion 13 of the display apparatus DPB is estimated to be 1.4 inches (see FIG. 53D). Note that in the case where the aspect ratio is 16:9, a region other than the display portion 13 and the terminal portion 14 may extend in the display apparatus DPB; thus, the functional circuit 40 and the like may be formed in the region.

In the case where the aspect ratio is 4:3, the maximum diagonal size of the display portion 13 of the display apparatus DPA is estimated to be 1.25 inches (see FIG. 53E), and the maximum diagonal size of the display portion 13 of the display apparatus DPB is estimated to be 1.5 inches (see FIG. 53F). Note that in the case where the aspect ratio is 4:3, the bezel width on the side of the display portion 13 is widened in the display apparatus DPA; thus, the formation area of the driver circuit 30 can be increased.

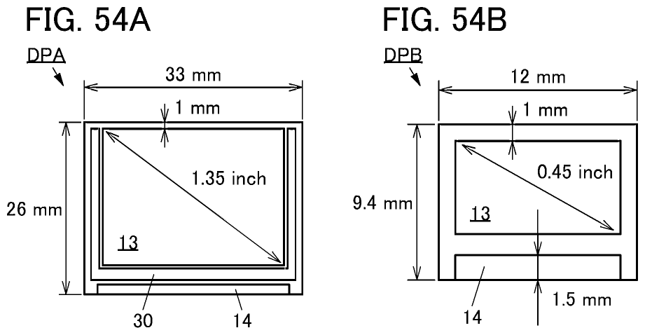

In the case where the aspect ratio is 4:3 and the bezel width is 1 mm, the maximum diagonal size of the display portion 13 of the display apparatus DPA is estimated to be 1.35 inches (see FIG. 54A).

Meanwhile, since the driver circuit 30 can be provided under and overlap with the display portion 13 in the display apparatus DPB, even a display apparatus whose maximum diagonal size is small can have an external size smaller than the display apparatus DPA. For example, in the case where the display portion 13 has a maximum diagonal size of 0.45 inches and an aspect ratio of 16:9, the external size of the display apparatus DPB can be 12 mm×9.4 mm (see FIG. 54B).

The display apparatus used for VR or AR applications preferably has a large display portion. In the display apparatus DPA with the Si\OEL structure, the maximum diagonal size that can be manufactured by one-time light exposure is 1.35 inches. On the other hand, the display apparatus DPB having the Si\OS\OEL structure enables a peripheral circuit or the like to be provided to overlap with the display portion, and thus, the diagonal size of the display portion that can be manufactured by one-time light exposure can be increased to 1.5 inches. The display apparatus DPB can also include a circuit other than a peripheral circuit so as to overlap with the display portion. When the display apparatus has the Si\OS\OEL structure, addition of various functions can be achieved at low cost as well as a large size of the display portion.

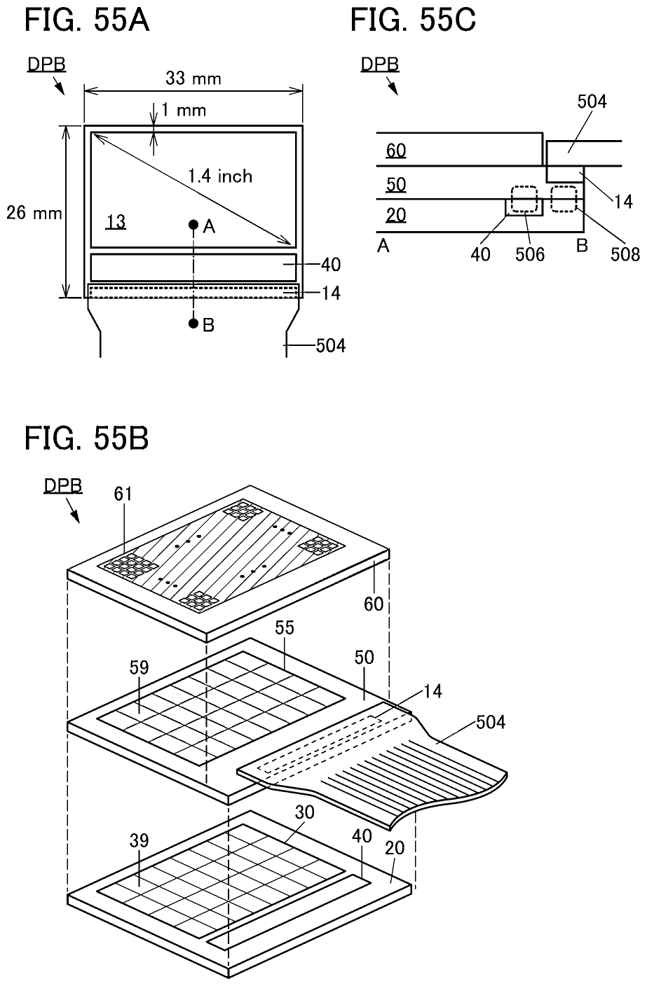

Next, a specific structure of the display apparatus DPB illustrated in FIG. 53D is described with reference to FIG. 55A, FIG. 55B, and FIG. 55C.

FIG. 55A is a diagram illustrating a structure in which the FPC 504 is connected to the display apparatus DPB illustrated in FIG. 53D, and FIG. 55B is a perspective view for describing the structure of the layers in the display apparatus DPB illustrated in FIG. 55A. FIG. 55C is a schematic view illustrating a cross section of the display apparatus DPB in a portion corresponding to the dashed-dotted line A-B in FIG. 55A.

As illustrated in FIG. 55A to FIG. 55C, the display apparatus DPB includes the layer 20, the layer 50 provided over the layer 20, and the layer 60 provided over the layer 50.

The layer 20 includes the driver circuit 30 and the functional circuit 40. The layer 20 includes Si transistors. The driver circuit 30 is divided into a plurality of sections 39. The plurality of sections 39 each include a source driver circuit and a gate driver circuit. The layer 50 includes the pixel circuit group 55 including the plurality of pixel circuits and the terminal portion 14. The layer 50 includes OS transistors. The pixel circuit group 55 is divided into a plurality of sections 59. Note that in the structure example illustrated in FIG. 55A to FIG. 55C, the FPC 504 is connected to the terminal portion 14. The layer 60 includes the plurality of light-emitting elements 61. An EL element can be suitably used as the light-emitting element 61.

As illustrated in FIG. 55A to FIG. 55C, the Si transistors are provided in the layer 20, the OS transistors are provided in the layer 50, and the EL elements are provided in the layer 60, whereby a three-layer structure of Si\OS\OEL can be formed.

FIG. 55C illustrates a region 506 and a region 508 in a stacked portion of the layer 20 and the layer 50. The region 506 can be referred to as a system utilizing a stacked-layer structure of Si\OS including the functional circuit 40, for example. The region 508 has the stacked-layer structure of Si\OS, and can include a variety of functional circuits accordingly. Furthermore, an external memory (e.g., a NAND, an OS memory with a three-dimensional structure (also referred to as a 3D OS memory or a 3D DOSRAM) may be bonded to the region 508 by bonding or the like.

Typical preferred examples of the functional circuit 40 include an inspection circuit, a source driver circuit, a gate driver circuit, a video distribution circuit, a video generation circuit, a digital-analog converter circuit (DA converter), a timing generation circuit (also referred to as a timing controller), a power supply circuit, a luminance correction circuit, and a pixel correction circuit.

Note that the luminance correction circuit may include a circuit for feeding back information from a temperature sensor. The pixel correction circuit can function in conjunction with one or both of a source driver circuit and a gate driver circuit.

In such an electronic device of one embodiment of the present invention, the stacked-layer structure of Si\OS, a display element (typically, an EL element), a driver circuit for driving the display element, and the like are monolithically formed, whereby an on-chip system or a system display can be provided. Furthermore, an external memory or the like can be connected to the system display so that a variety of functions can be provided.

### Example 4

The display apparatus DPX having the Si\OS\OEL structure, which corresponds to the display apparatus 10A described in the above embodiment, was fabricated and displayed an image. In this example, specifications and image display results of the display apparatus DPX are described. Note that the above embodiments or the like are referred to for the matters that are not described in this example.

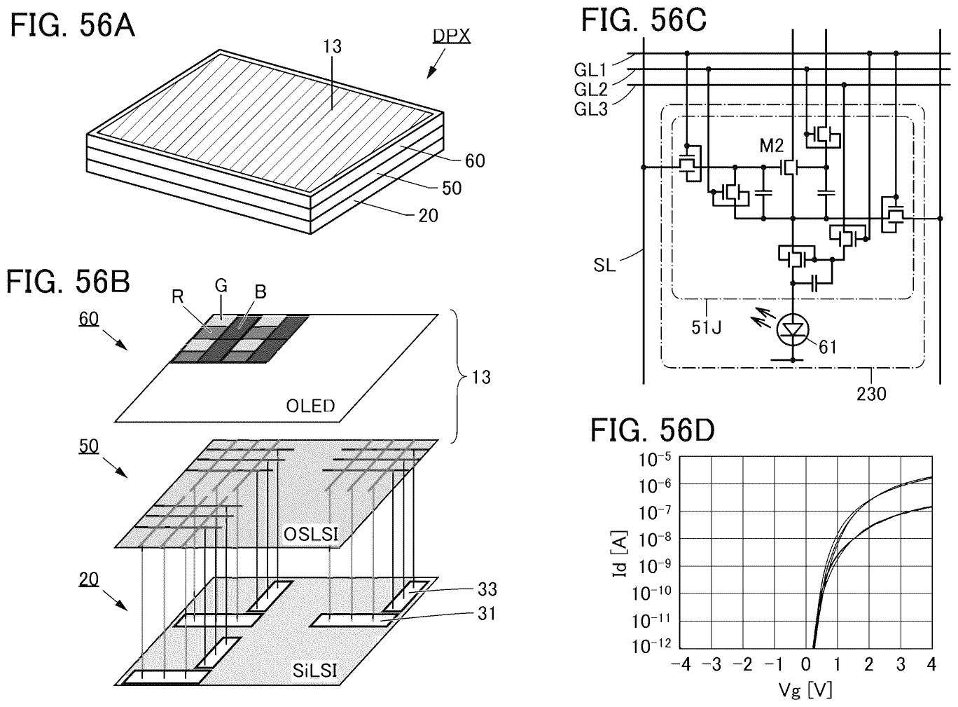

FIG. 56A and FIG. 56B are schematic perspective views of the display apparatus DPX. Like the display apparatus 10A (see FIG. 3) described in the above embodiment, the display apparatus DPX includes the layer 20 including the driver circuit 30 (a gate driver, a source driver, and the like) and the functional circuit 40 (an input/output circuit, a timing generation circuit, and the like), the layer 50 including the pixel circuit 51, and the layer 60 including the light-emitting element 61.

Like the display apparatus 10A, the layer 20 of the display apparatus DPX includes a Si transistor (SiFET), and the layer 50 includes an OS transistor (OSFET). That is, the driver circuit and the functional circuit are configured with SiFETs, and the pixel circuit 51 is configured with OSFETs. An integrated circuit configured with SiFETs, as in the layer 20, is also referred to as a “SiLSI”. An integrated circuit configured with OS FETs, as in the layer 50, is also referred to as an “OSLSI”. An integrated circuit having a monolithic structure in which SiLSI and OSLSI are stacked is also referred to as “Si\OSLSI”. In the fabricated display apparatus DPX, single crystal silicon was used as a semiconductor in which a channel of the SiFET was formed. In addition, CAAC-IGZO was used as a semiconductor where a channel of the OSFET was formed.

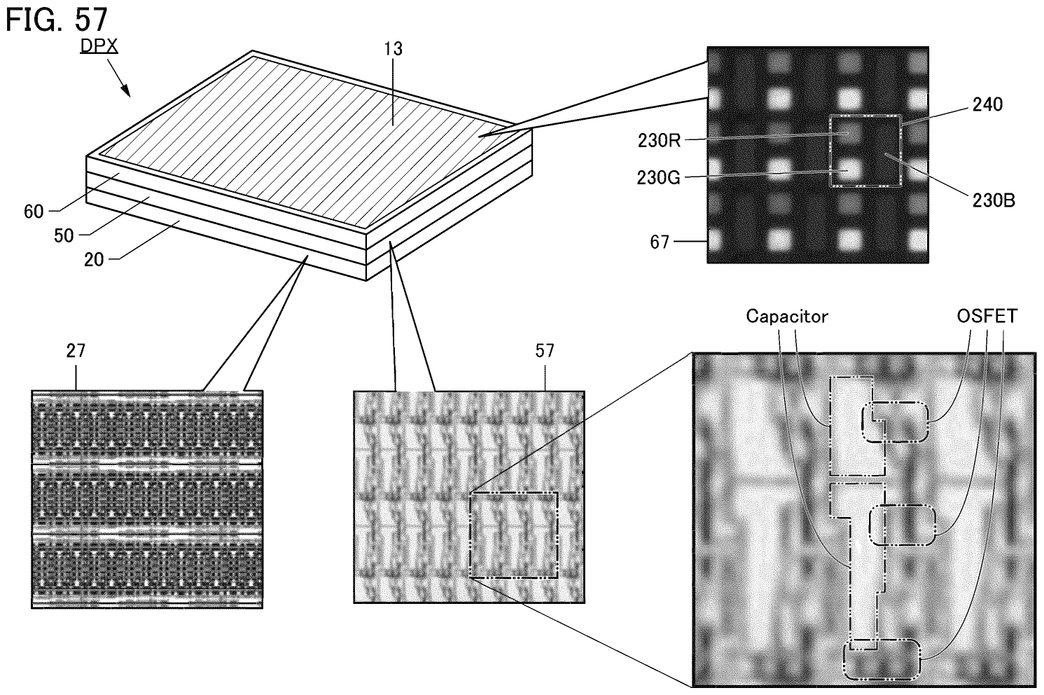

FIG. 57 shows a schematic perspective view of the fabricated display apparatus DPX, an enlarged plan optical micrograph 67 of part of the layer 60, an enlarged plan optical micrograph 57 of part of the layer 50, and an enlarged plan layout 27 of part of the layer 20. Note that in FIG. 57, an enlarged photograph of a portion including capacitors (Capacitor) and OSFETs in the plan optical micrograph 57 is also shown.

As shown in the plan optical micrograph 67, in the fabricated display apparatus DPX, one pixel 240 includes three subpixels (pixels 230) arranged in an S-stripe arrangement. The three subpixels included in the pixel 240 are the pixel 230 (pixel 230R) that controls red light, the pixel 230 (pixel 230G) that controls green light, and the pixel 230 (pixel 230B) that controls blue light.

FIG. 56C illustrates a circuit configuration of the pixel 230 in the fabricated display apparatus DPX. The pixel 230 of the display apparatus DPX includes a pixel circuit 51J including seven OSFETs and three capacitors (7Tr3C) as the pixel circuit 51. The pixel circuit 51J is controlled by three wirings GL (the wiring GL1, the wiring GL2, and the wiring GL3). Since the OSFET has an extremely low off-state current, the gate potential of the transistor M2 can be retained for a long time. Therefore, it is easy to achieve IDS driving.

FIG. 56D shows the Id-Vg characteristics of the OSFET using CAAC-IGZO. Note that Id is the value of current flowing between a source and a drain, and Vg is a voltage between the source and a gate. The channel length of the OSFET used for measuring Id-Vg characteristics is 200 nm and the channel width is 130 nm. FIG. 56D shows the Id-Vg characteristics at the source-drain voltage of 0.1 V and the Id-Vg characteristics at the source-drain voltage of 1.2 V. As apparent from FIG. 56D, the OSFET exhibits favorable characteristics even when having the channel length of 200 nm. It is also found that the off-state current is lower than or equal to the lower measurement limit (1×10⁻¹² A), meaning that the off-state current is adequately low. The low off-state current can significantly reduce a current flowing through an OLED in displaying black. Thus, black can be surely displayed and the display quality is improved. In addition, the OSFET can operate without being broken even with voltage application of approximately 10 V between a source and a drain, exhibiting high reliability.

Here, Table 7 shows a comparison table of the SiFET and the OSFET.

TABLE 7

| | | Advantages | | Disadvantages | |
|---|---|---|---|---|---|
| Semiconductor | Effective | Physical | Operating | Physical | Operating |
| device | mass | properties | characteristics | properties | characteristics |
| SiFET | Electron: | Substantially equal | Formation of | Large hot carrier | Low breakdown |
| Eg[eV] = 1.12 | 0.19 to | effective masses | CMOS is possible | degradation | voltage |
| | 0.98, | of holes and | | Large short | Further scaling |
| | inclusive | electrons | | channel effect | is impossible |
| | Hole: | | | | Large drain |
| | 0.16 to | | | | leakage |
| | 0.49, | | | | |
| | inclusive | | | | |
| Ceramics | Electron: | Hole effective | High breakdown | Electron effective | Frequency |
| OSFET | 0.23 to | mass is extremely | voltage is possible | mass is larger than | characteristics |
| Eg[eV] = 3.2 | 0.25, | large | Scaling is possible | that that of Si | are a fraction |
| | inclusive | No hot carrier | I_{off} of 10⁻²⁴ | | of that of Si |
| | Hole: | degradation | A/FET | | Only fabrication |
| | 11 to 40, | No short channel | | | of NMOS is |
| | inclusive | effect | | | possible |
| | | Low I_{off} | | | |

As described above, the off-state current of the OSFET is low. Since the carrier concentration of the OSFET is extremely low, the OSFET can achieve an extremely low off-state current, which is in the order of yA (10⁻²⁴ A) as the current value per FET. Furthermore, the OSFET is less likely to be affected by the short-channel effect; thus, miniaturization and high withstand voltage of the transistor are possible. For example, a high-definition display with a definition exceeding 5000 ppi can be achieved using an OSFET in which a channel length is reduced to several hundreds to several tens of nanometers.

Meanwhile, since p-channel transistors cannot be fabricated using OSFETs, CMOS cannot be achieved with only OSFETs. Thus, formation of CMOS is possible in a combination of OSFETs and SiFETs. A composite structure in which SiFETs and OSFETs are combined is suitable.

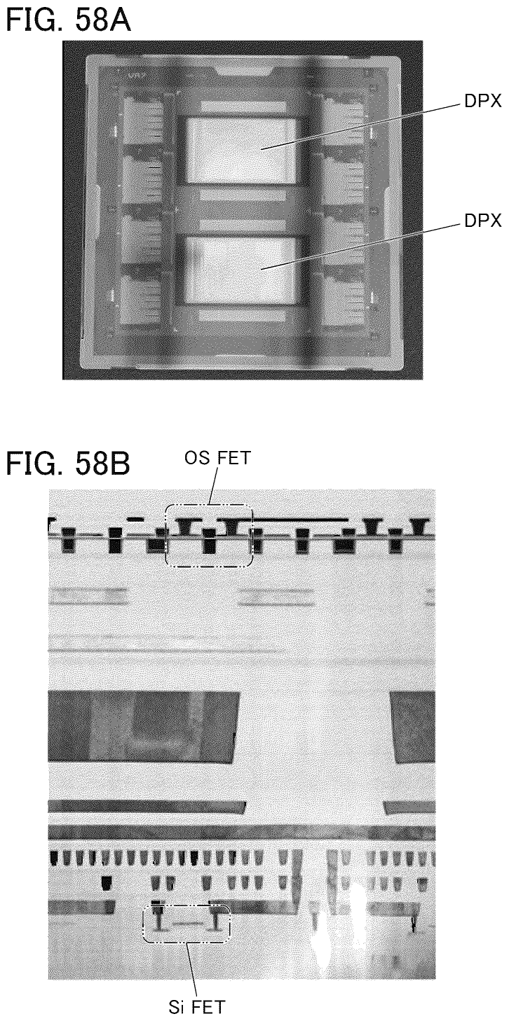

FIG. 58A shows a photograph of an appearance of the display apparatuses DPX formed over a rectangular single crystal silicon substrate. Two display apparatuses DPX are formed over one rectangular single crystal silicon substrate. Note that the photograph in FIG. 58A show the halfway of the manufacturing process, and the two display apparatuses DPX are later separated from each other and an FPC is connected to the terminal portion 14 of each of the separated display apparatuses DPX.

FIG. 58B is a cross-sectional TEM photograph showing a stacked-layer structure of the fabricated display apparatus DPX. FIG. 58B shows that the fabricated display apparatus DPX has a monolithic structure in which the SiFET and the OSFET are stacked.

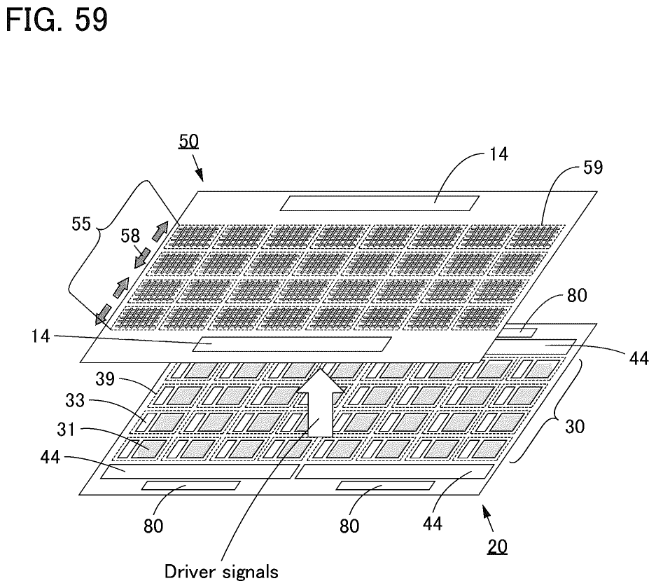

FIG. 59 is a schematic perspective view of the layer 20 and the layer 50 included in the fabricated display apparatus DPX. The fabricated display apparatus DPX includes the driver circuit 30 including 32 sections 39, four timing generation circuits 44 (Timing generater), and four input/output circuits 80 in the layer 20. One section 39 includes one source driver circuit 31 and one gate driver circuit 33. The input/output circuit 80 includes an I2C interface and an LVDS circuit. The LVDS circuit includes one lane of clock and ten lanes of data, and can transfer data necessary for driving 1920×1440 pixels with 120 Hz.

The fabricated display apparatus DPX has a function of generating control signals and adjusting the timing of data transfer on eight sections 39 with one timing generation circuit 44 and one input/output circuit 80. In the fabricated display apparatus DPX, one driver block is configured with one timing generation circuit 44, one input/output circuit 80, and eight sections 39. That is, the fabricated display apparatus DPX is configured with four driver blocks.

The fabricated display apparatus DPX includes a pixel circuit group 55 including 32 sections 59 and two terminal portions 14 in the layer 50. One section 39 included in the layer 20 is electrically connected to one section 59 included in the layer 50 provided directly above the section 39. Thus, the operation signals (Driver signals) are supplied from the section 39 to the section 59 in the shortest distance. In addition, the scan direction 58 of the gate driver circuit 33 is controlled so that the gate lines (the wirings GL) in the sections 39 (the sections 59) adjacent to each other in the column direction can be selected at the same timing.

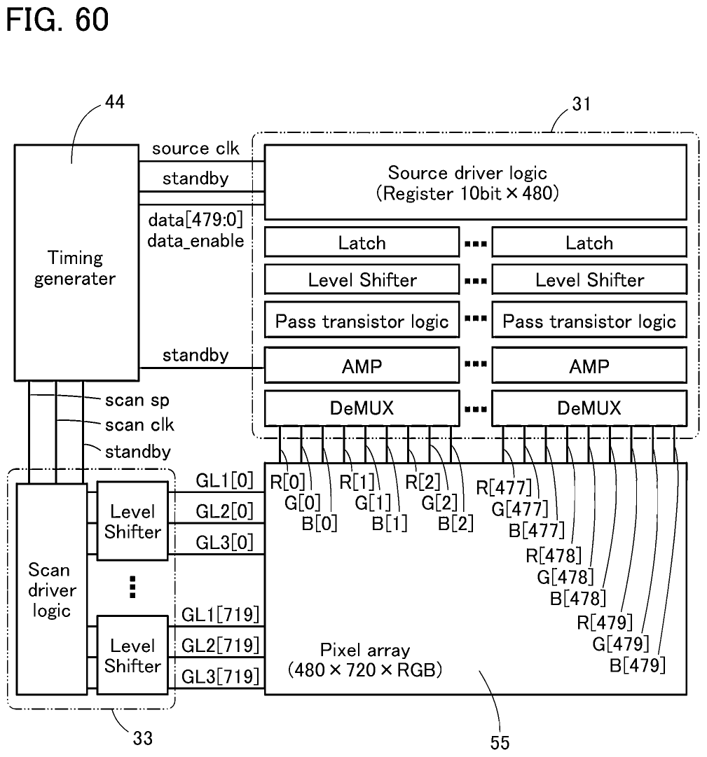

FIG. 60 illustrates a detailed block diagram of the source driver circuit 31 and the gate driver circuit 33. One source driver circuit 31 and one gate driver circuit 33 have a function of controlling the pixel circuit group 55 (Pixel array) of 480×720×RGB.

The source driver circuit 31 includes a source driver logic circuit (Source driver logic), a latch circuit (Latch), a level shifter circuit (Level Shifer), a pass transistor logic circuit (Pass transistor logic), an amplifier circuit (AMP), and a demultiplexer (DeMUX).

The gate driver circuit 33 includes a gate driver logic circuit (Scan driver logic) and a level shifter circuit (Level Shifer). The gate driver circuit 33 is electrically connected to 720 wirings GL1 (a wiring GL1[0] to a wiring GL1[719]), 720 wirings GL2 (a wiring GL2[0] to a wiring GL2[719]), and 720 wirings GL3 (a wiring GL3[0] to a wiring GL3[719]).

The timing generation circuit 44 has a function of supplying a source clock signal (source clk), a standby signal (standby), image signals (data[479:0]) for 480 pixels, and an enable signal (data_enable) to a source driver logic circuit. The timing generation circuit 44 has a function of supplying a standby signal to an amplifier circuit. The timing generation circuit 44 has a function of supplying a start pulse signal (scan sp), a gate clock signal (scan clk), and a standby signal to the gate driver logic circuit.

In the fabricated display apparatus DPX, the total 15360 AMPs are mounted on the 32 sections 39 as a whole. The output of each AMP is supplied to three wirings SL through the DeMUX. Finally, 480 red image signals R (a red image signal R[0] to a red image signal R[479]), 480 green image signals G (a green image signal G[0] to a green image signal G[479]), and 480 blue image signals B (a blue image signal B[0] to a blue image signal B[479]) are supplied from the source driver circuit 31 to the pixel circuit group 55.

The fabricated display apparatus DPX includes, in the source driver logic circuit included in the source driver circuit 31, a register (Register) capable of retaining 10-bit grayscale image data for 480 pixels. When the 10-bit grayscale image data for 480 pixels (4800 bits) are supplied to the source driver circuit 31, the gate driver circuit 33 starts a selection operation of the gate lines (wirings GL). In the fabricated display apparatus DPX, since the display portion 13 is divided into four parts in the column direction, and thus the source lines (the wirings SL) are also regarded to be divided into four parts. The gate driver circuit 33 is provided in each of the divided display portions 13. Thus, four gate lines can be selected at the same time when the display portion 13 is seen in the column direction. Accordingly, as compared with the case where the source lines are not divided, the number of gate lines selected by one gate driver circuit in one frame can be reduced to one fourth. Alternatively, the horizontal selection period can be approximately 4 times.

In the fabricated display apparatus DPX, the driver circuit 30 is provided in a layer below the pixel circuit group 55, and the connection distance between them is short. Accordingly, even in the case where the display size is large, display operation with a high-speed frame rate can be achieved.

Table 8 lists the design specifications (Specifications) and data (Result) of the fabricated display apparatus DPX of each item (Item). The OLEDs used as the light-emitting elements 61 of RGB are separately formed by a photolithography method. Since the photolithography method provides higher alignment accuracy than a method using a fine metal mask, a definition higher than 1000 ppi and an aperture ratio of 53.7% were achieved. Furthermore, in the SBS structure, the viewing angle is favorable as compared with a structure in which a white OLED and a color filter are combined, so that the SBS structure can reduce power consumption to approximately one third, free from the luminance decrease due to the color filter. Additionally, patterning can eliminate a current leakage path between adjacent pixels, preventing color mixture due to light emission caused by leakage current.

TABLE 8

| Item | Specifications | | Result | |
|---|---|---|---|---|
| Structure | Si\OS\OEL | | Si\OS\OEL | |
| | (SBS-MML, Single) | | (SBS-MML, Single) | |
| CMOS process | 55 nm HV (1.2 V/6.0 V) | | 55 nm HV (1.2 V/6.0 V) | |
| Driver circuit | Source: integrated in Si, | | Source: integrated in Si, | |
| | Gate: integrated in Si | | Gate: integrated in Si | |
| Coloring method | SBS structure (single) | | SBS structure (single) | |
| (OLED) | | | | |
| Emission type | Top emission | | Top emission | |
| Size | 1.50 | inch | 1.50 | inch |
| (Screen diagonal) | | | | |
| Pixel count | 3840 (H) × 2880 (V) | | 3840 (H) × 2880 (V) | |
| (Resolution) | | | | |
| Pixel density | 3207 | ppi | 3207 | ppi |
| Pixel size | 7.92 μm × 7.92 μm | | 7.92 μm × 7.92 μm | |
| Aperture ratio | >60% | | 53.7% | |
| Luminance | >5000 | cd/m² | Approx. 300 cd/m² | |
| Frame rate | 120 | fps | <60 | fps |

| | | |
|---|---|---|
| Pixel circuit design | 7Tr-3C | 7Tr-3C |
| Pixel layout | RGB S-stripe | RGB S-stripe |
| (arrangement) | | |

Table 9 shows advantages of the display apparatus fabricated with a combination of Si\OS LSI and the SBS structure over a display apparatus fabricated with a combination of Si LSI, white OLED, and color filters.

TABLE 9

| | |
|---|---|
| 1. Aperture ratio | Without reistrictions by fine metal mask, high |
| | aperture ratio can be achieved. |
| 2. Color purity | Mixture of colors is not caused by CF or leakage |
| | current between adjacent pixels. |
| 3. Viewing angle | The viewing angle is wide, without influence by |
| | adjacent CFs. |
| 4. Electric power | Current efficiency of OLED is high, and power |
| | consumption at the same luminance is low. Power |
| | saving using OSLSI/SiLSI is possible. |
| 5. Cost | The chip using OSLSI/SiLSI can be downsized. The |
| | number of chips obtained is increased, leading |
| | to low cost. |

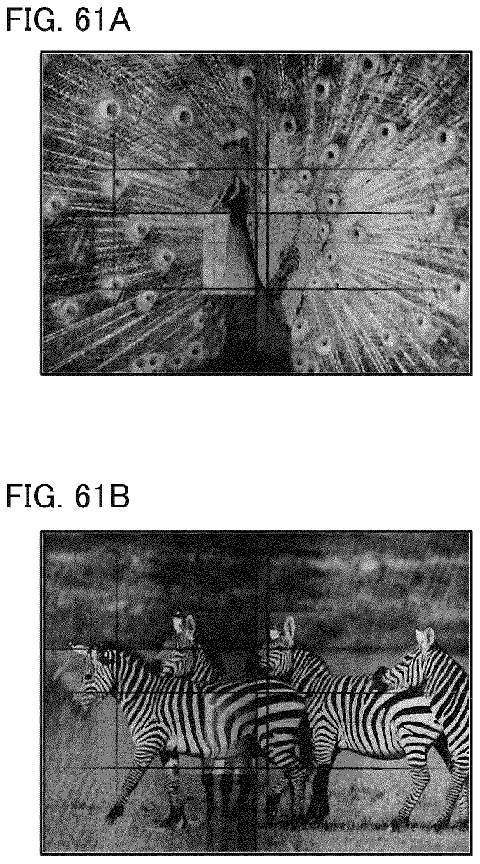

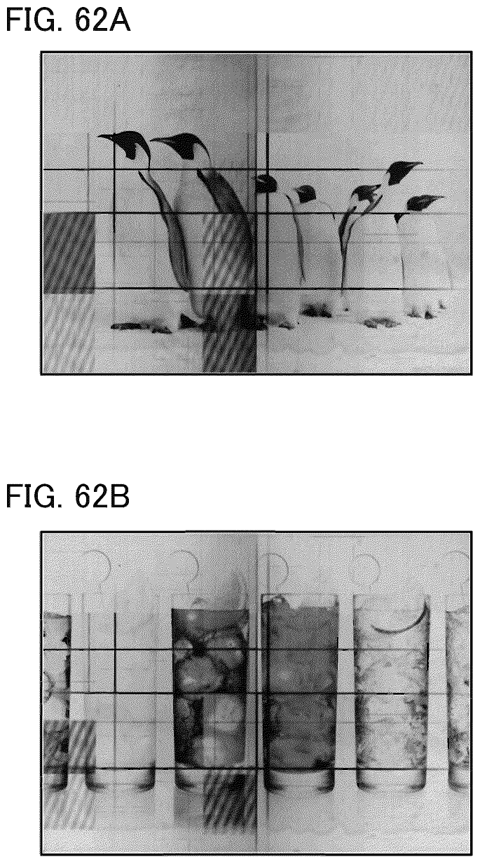

FIG. 61A, FIG. 61B, FIG. 62A, and FIG. 62B illustrate display images of the fabricated display apparatus DPX. As apparent in FIG. 61A, FIG. 61B, FIG. 62A, and FIG. 62B, an image in displayed on the whole display portion 13 with a linear display defect (also referred to as a “line defect”), display unevenness, and the like.

The steady current of the AMPs is dominant in power consumption of the section 39 configured with SiFETs. The power consumption of one driver block including eight sections 39 was 347 mW at a frame rate of 60 Hz. The source driver circuit 31 of the fabricated display apparatus DPX has a standby function of stopping the steady current of the AMPs. The combination of the standby function and IDS driving of each sub-display portion 19 enables power saving operation. Specifically, when the frame rate is low, a period during which image rewriting is not performed is long; thus, power supply to the AMPs is stopped in a period during which image rewriting is not performed.

### <Power Consumption of AMPs>

The fabricated display apparatus DPX was driven in three operation modes and the power consumption of the AMPs in each operation mode was measured. Specifically, power consumption of the AMPs was measured in the following operation modes: Mode A in which the entire display portion 13 is driven at a frame rate of 60 Hz; Mode B in which 12 sub-display portions 19 of the display portion 13 are driven at a frame rate of 60 Hz and the other 20 sub-display portions 19 are driven at a frame rate of 1 Hz; and Mode C in which eight sub-display portions 19 of the display portion 13 are driven at a frame rate of 60 Hz and the other 24 sub-display portions 19 are driven at a frame rate of 1 Hz.

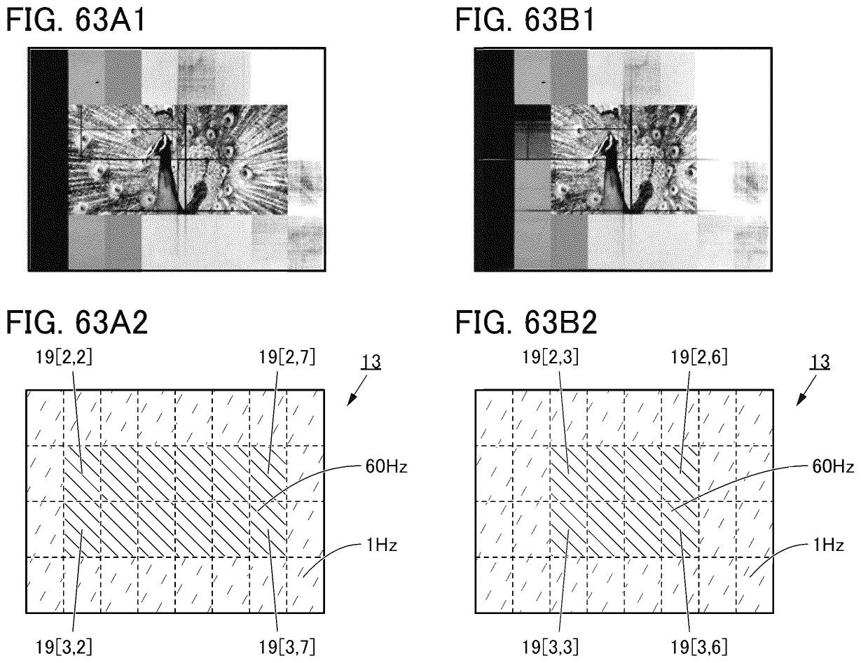

FIG. 63A1 illustrates a display image of the display apparatus DPX when driven in Mode B. FIG. 63A2 is a diagram illustrating the distribution of the set frame rates in FIG. 63A1. As shown in FIG. 63A2, in Mode B, the 12 sub-display portions, the sub-display portion 19[2,2] to the sub-display portion 19[2,7] and the sub-display portion 19[3,2] to the sub-display portions 19[3,7], were driven at a frame rate of 60 Hz, and the other sub-display portions 19 were driven at a frame rate of 1 Hz. In FIG. 63A1, color bars are displayed on the sub display portions 19 driven at a frame rate of 1 Hz.

FIG. 63B1 illustrates a display image of the display apparatus DPX when driven in Mode C. FIG. 63B2 is a diagram illustrating the setting distribution of the frame rate in FIG. 63B1. As shown in FIG. 63B2, in Mode C, the eight sub-display portions 19, the sub-display portion 19[2,3] to the sub-display portion 19[2,6] and the sub-display portion 19[3,3] to the sub-display portion 19[3,6], were driven at a frame rate of 60 Hz, and the other sub-display portions 19 were driven at a frame rate of 1 Hz. In FIG. 63B1, color bars are displayed on the sub display portions 19 driven at a frame rate of 1 Hz.

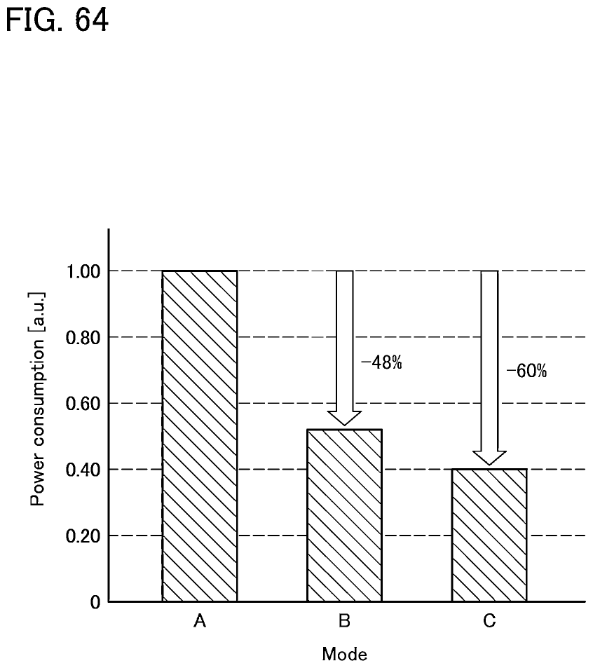

FIG. 64 shows measurement results of the power consumption of the AMPs in each mode. In FIG. 64, the power consumption of the AMPs at the time of driving in Mode A is set to 1 and the power consumption of the AMPs at the time of driving in Mode B and Mode C is shown as the relative value to the value of Mode A.

As shown in FIG. 64, the power consumption of the AMPs at the time of driving in Mode B is 48% lower than that at the time of driving in Mode A. In addition, the power consumption of the AMPs at the time of driving in Mode C is 60% lower than that at the time of driving in Mode A. This indicates that an increased number of sub-display portions 19 driven at the frame rate of 1 Hz reduces the power consumption of the AMPs. In other words, as the number of AMPs stopped by the standby function is increased, power consumption is reduced.

### Example 5

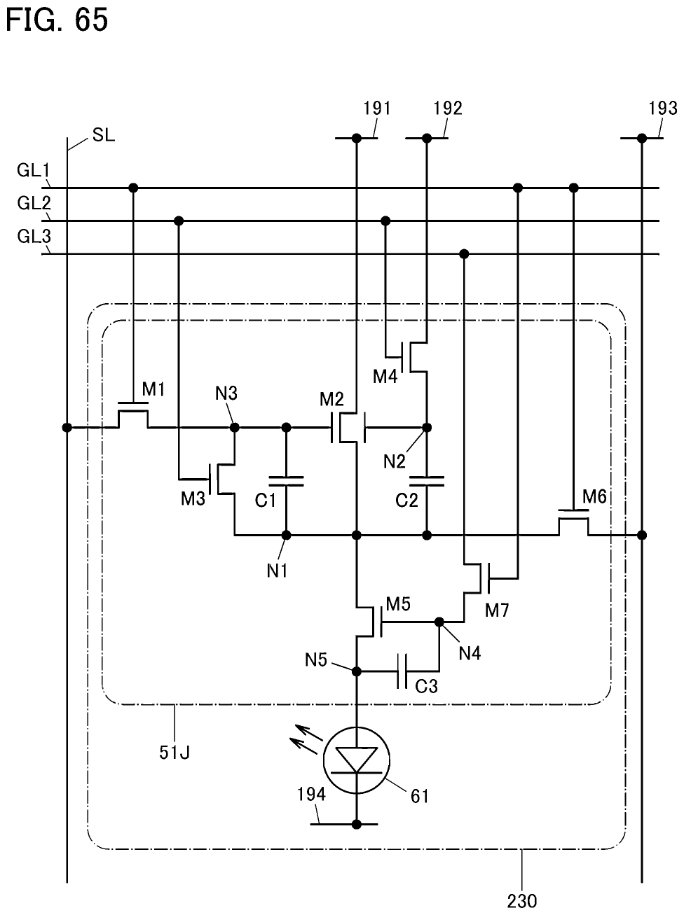

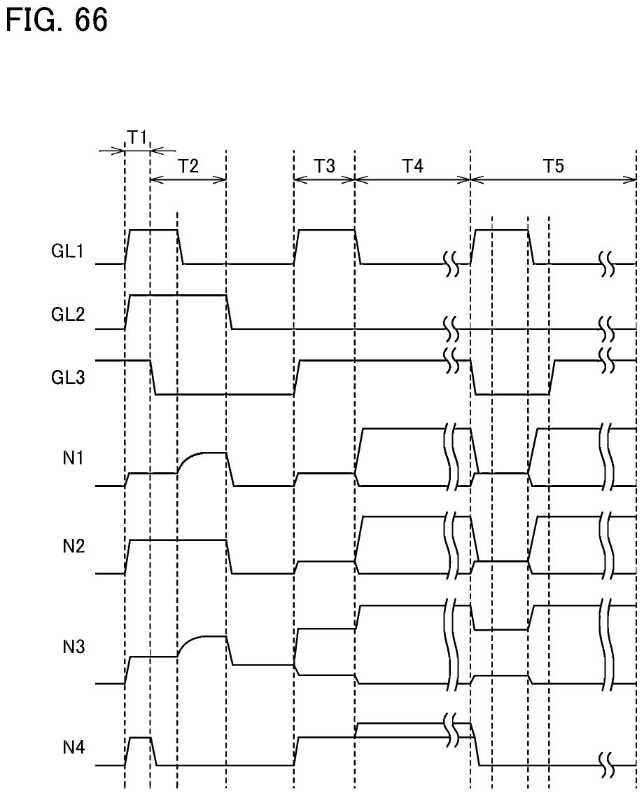

In this example, a circuit configuration and an operation of the pixel 230 are described. FIG. 65 is the same circuit diagram as that of the pixel 230 illustrated in FIG. 56C. Thus, reference numerals are added to components in FIG. 65 for more detailed description.

### <Circuit Configuration>

As described in the above example, the pixel 230 used in the fabricated display apparatus DPX includes the pixel circuit 51J including seven OSFETs (a transistor M1 to a transistor M7) and three capacitors (the capacitor C1 to a capacitor C3). The pixel 230 includes the light-emitting element 61.

The gate of the transistor M1 is electrically connected to the wiring GL1, one of the source and the drain of the transistor M1 is electrically connected to the wiring SL, and the other of the source and the drain of the transistor M1 is electrically connected to the gate of the transistor M2. The transistor M1 has a function of selecting whether to establish electrical continuity between the gate of the transistor M2 and the wiring SL.

The gate of the transistor M2 is electrically connected to one terminal of the capacitor C1, one of the source and the drain of the transistor M2 is electrically connected to the wiring 191, and the other of the source and the drain of the transistor M2 is electrically connected to the other terminal of the capacitor C1. The transistor M2 has a back gate. The back gate of the transistor M2 is electrically connected to one terminal of the capacitor C2. The other terminal of the capacitor C2 is electrically connected to the other of the source and the drain of the transistor M2.

A gate of the transistor M3 is electrically connected to a wiring GL2, one of a source and a drain of the transistor M3 is electrically connected to the one terminal of the capacitor C1, and the other of the source and the drain of the transistor M3 is electrically connected to the other terminal of the capacitor C1. The transistor M3 has a function of selecting whether to establish electrical continuity between the gate and the source of the transistor M2.

A gate of the transistor M4 is electrically connected to the wiring GL2, one of a source and a drain of the transistor M4 is electrically connected to a wiring 192, and the other of the source and the drain of the transistor M4 is electrically connected to the one terminal of the capacitor C2. The transistor M4 has a function of selecting whether to establish electrical continuity between the wiring 192 and the one terminal of the capacitor C2.

A gate of the transistor M5 is electrically connected to one terminal of the capacitor C3, and one of a source and a drain of the transistor M5 is electrically connected to the other of the source and the drain of the transistor M2. The other of the source and the drain of the transistor M5 is electrically connected to the other terminal of the capacitor C3 and one terminal (an anode terminal) of the light-emitting element 61. The other terminal (the cathode terminal) of the light-emitting element 61 is electrically connected to the wiring 194.

A gate of the transistor M6 is electrically connected to the wiring GL1, one of a source and a drain of the transistor M6 is electrically connected to the other of the source and the drain of the transistor M2, and the other of the source and the drain of the transistor M6 is electrically connected to a wiring 193. The transistor M6 has a function of selecting whether to establish electrical continuity between the other of the source and the drain of the transistor M2 and the wiring 193.

A gate of the transistor M7 is electrically connected to the wiring GL1, one of a source and a drain of the transistor M7 is electrically connected to the wiring GL3, and the other of the source and the drain of the transistor M7 is electrically connected to the gate of the transistor M5. The transistor M7 has a function of selecting whether to establish electrical continuity between the gate of the transistor M5 and the wiring GL3.

A region where the other terminals of the capacitor C1 and the capacitor C2, the other of the source and the drain of the transistor M2, the other of the source and the drain of the transistor M3, the one of the source and the drain of the transistor M6, and the one of the source and the drain of the transistor M5 are electrically connected to one another is referred to as a node N1.

A region where the one terminal of the capacitor C2, the back gate of the transistor M2, and the other of the source and the drain of the transistor M4 are electrically connected to one another is referred to as a node N2.

A region where the other of the source and the drain of the transistor M1, the one of the source and the drain of the transistor M3, the one terminal of the capacitor C1, and the gate of the transistor M2 are electrically connected to one another is referred to as a node N3.

A region where the gate of the transistor M5, the one terminal of the capacitor C3, and the other of the source and the drain of the transistor M7 are electrically connected to one another is referred to as a node N4.

A region where the other of the source and the drain of the transistor M5, the other terminal of the capacitor C3, and one terminal of the light-emitting element 61 are electrically connected to one another is also referred to as a node N5.

Note that an anode potential is supplied to the wiring 191, and a cathode potential is supplied to the wiring 194. Image data is supplied to the wiring SL, a potential V1 is supplied to the wiring 192, and a potential V0 is supplied to the wiring 193.

### <Operation>

Next, an operation example of the pixel 230 will be described. FIG. 66 is a timing chart illustrating an operation example of the pixel 230. Note that in this specification and the like, “H potential” is a potential for bringing an n-channel transistor into an on state. Moreover, “L potential” is a potential for bringing an n-channel transistor into an off state.

Period T1 is a reset period. In Period T1, H potential is supplied to the wiring GL1, the wiring GL2, and the wiring GL3. Thus, the transistor M1, the transistor M3, the transistor M4, the transistor M6, and the transistor M7 are brought into on states. Furthermore, the transistor M6 is brought into an on state, so that the potential V0 is supplied to the node N1. The potential V0 is a potential at which the light-emitting element 61 does not emit light when supplied to the node N5. The potential V0 may be a cathode potential, for example.

Furthermore, the transistor M3 is brought into an on state, so that the potential V0 is supplied to the node N3. Furthermore, the transistor M4 is brought into an on state, so that the potential V1 is supplied to the node N2. The potential V1 may be a potential at which the potential difference between the potential V0 and the potential V1 is higher than or equal to the threshold voltage of the transistor M2. Thus, when the potential V1 is supplied to the node N2, the transistor M2 is brought into an on state.

Period T2 is a correction period. In Period T2, L potential is supplied to the wiring GL3. Then, L potential is supplied to the node N4, so that the transistor M5 is brought into an off state. Next, L potential is supplied to the wiring GL1. Thus, the transistor M1, the transistor M6, and the transistor M7 are brought into off states.

When the transistor M6 is brought into an off state, the supply of the potential V0 to the node N1 is stopped. Meanwhile, since the potential V1 is supplied to the node N2, the transistor M2 is in an on state and the potential of the node N1 increases. The potential of the node N1 increases until the potential difference between the node N2 and the node N1 becomes equal to the threshold voltage of the transistor M2.

After that, the L potential is supplied to the wiring GL2 to bring the transistor M3 and the transistor M4 into off states. Since the OSFET included in the pixel circuit 51J has an extremely low off-state current, a potential difference between the node N1 and the node N2 is retained in the capacitor C2 for a long time. In this manner, the threshold voltage of the transistor M2 can be obtained and retained.

As described above, even if the threshold voltage of the transistor M2 differs between pixels, the threshold voltage of the transistor M2 can be obtained for each pixel by the operation of Period T1 and Period T2. In other words, a variation in the threshold voltage of the transistor M2 can be corrected. Note that a pixel circuit having a function of correcting the threshold voltage, like the pixel circuit 51J included in the pixel 230, is also referred to as an “internal correction circuit”.

Period T3 is a period during which image data is written. In Period T3, H potential is supplied to the wiring GL1 and the wiring GL3, and L potential is supplied to the wiring GL2. When the H potential is supplied to the wiring GL1, the transistor M1, the transistor M6, and the transistor M7 are brought into on states.

When the transistor M1 is brought into an on state, image data is written into the node N3. When the transistor M6 is brought into an on state, the potential V0 is written to the node N1. When the transistor M7 is brought into an on state, the potential of the wiring GL3 is supplied to the gate of the transistor M5. Thus, the transistor M5 is also brought into an on state.

Period T4 is a light-emitting period. In Period T4, L potential is supplied to the wiring GL1 and the wiring GL2, and H potential is supplied to the wiring GL3. When L potential is supplied to the wiring GL1, the transistor M6 and the transistor M7 are brought into off states. A current flows through the light-emitting element 61, whereby the light-emitting element 61 emits light. The emission luminance of the light-emitting element 61 and the potential of the node N5 change in accordance with the value of current flowing through the light-emitting element 61. When the potential of the node N5 increases, the potential of the node N4 also increases. Thus, the capacitor C3 serves as a bootstrap capacitor.

Note that the changes of the potentials of the node N1 to the node N4 in the case where the emission luminance of the light-emitting element 61 is maximum and in the case where the emission luminance of the light-emitting element 61 is minimum are shown to be superimposed in FIG. 66.

Period T5 is a non-light-emitting period. In Period T5, first, H potential is supplied to the wiring GL1, and L potential is supplied to the wiring GL2 and the wiring GL3. When the H potential is supplied to the wiring GL1, the transistor M7 is brought into an on state. Next, the potential (L potential) of the wiring GL3 is supplied to the node N4, so that the transistor M5 is brought into an off state. Then, current supply to the light-emitting element 61 is stopped, whereby light emission is stopped.

In general, in the internal correction circuit, the operation of correcting the threshold voltage is performed for each frame; thus, it is not easy to increase the driving frequency. Furthermore, the number of wirings connected to the pixel circuit is increased, and the power consumption is likely to increase accordingly. Meanwhile, since the pixel circuit described in this example and the like is configured with OSFETs, leakage current of each element can be reduced and the power consumption can be reduced. Furthermore, correction data obtained by threshold correction can be retained for a long time; thus, the correction operation of the threshold voltage is not necessarily performed for each frame and the driving frequency can be increased.

After Period T2 (the correction period), the wiring GL2 preferably keeps the L potential. Thus, the operation of the driver circuit connected to the wiring GL2 can be stopped after Period T2. The operation of at least part of the driver circuit is stopped, whereby power consumption can be reduced. Furthermore, in the case where a still image is displayed, IDS driving can be achieved and power consumption can be further reduced.

### Example 6

In this example, a normally-off processor using OS transistors will be described. In recent years, power saving techniques have attracted attention, such as a clock gating technique (also referred to as “CG”) for reduction of power consumption by stopping supply of a synchronization signal (a clock signal) to a circuit that does not need to operate and a power gating technique (also referred to as “PG”) for reduction of power consumption by stopping power supply to a circuit that does not need to operate. For example, by stopping power supply to a circuit in standby among the circuits included in the functional circuit 40 described above, further reduction of power consumption of the display apparatus 10 is possible.

As an application example of CG and PG, normally-off computing has attracted attention, in which power supply is stopped in a standby period between processing steps by a processor. In particular, a processor using PG is referred to as “normal-off processor” or “Noff processor” in some cases. In the normally-off processor, a backup operation of storing data necessary for restoration in a memory before power supply is stopped, and a restoration operation of reading the stored data after the power supply restarts are performed.

Examples of the memory used for the normally-off processor include nonvolatile memories such as a magnetoresistive memory (MRAM) including an MTJ element, a resistive random access memory (ReRAM), and a phase change memory (PCM), and volatile memories such as an SRAM.

Note that as a nonvolatile memory, a flash memory, a ferroelectric memory (FeRAM), and the like are known; however, such a memory has low access speed and a limited number of writing and is unlikely to be used as a nonvolatile memory in a normally-off processor.

An OS memory is suitably used as a nonvolatile memory used for the normally-off processor. An OS memory is a memory element using an OS transistor. As the OS memory, DOSRAM (registered trademark) and NOSRAM (registered trademark) are known.

An OS memory can retain written data for a period of one year or longer, or ten years or longer even after power supply is stopped. In an OS memory, written charge amount is less likely to change over a long period of time; hence, the OS memory can hold multilevel (multibit) data or analog value data as well as binary (1-bit) data.

In the OS memory, charge is written to a node through the OS transistor; hence, a high voltage in data writing operation is unnecessary and high-speed writing operation is possible. Thus, electric power to be consumed in the saving operation and the restoration operation (overhead power) is low and delay time is short. Differently from an MRAM, a ReRAM, or the like, the OS memory does not need electric charge injection and electric charge extraction into/from a charge trap layer, which are performed in a flash memory, and is not accompanied with a structure change at the atomic level. Thus, the OS memory enables substantially unlimited number of times of data writing and reading, and deteriorates less than the above memories, offering high reliability.

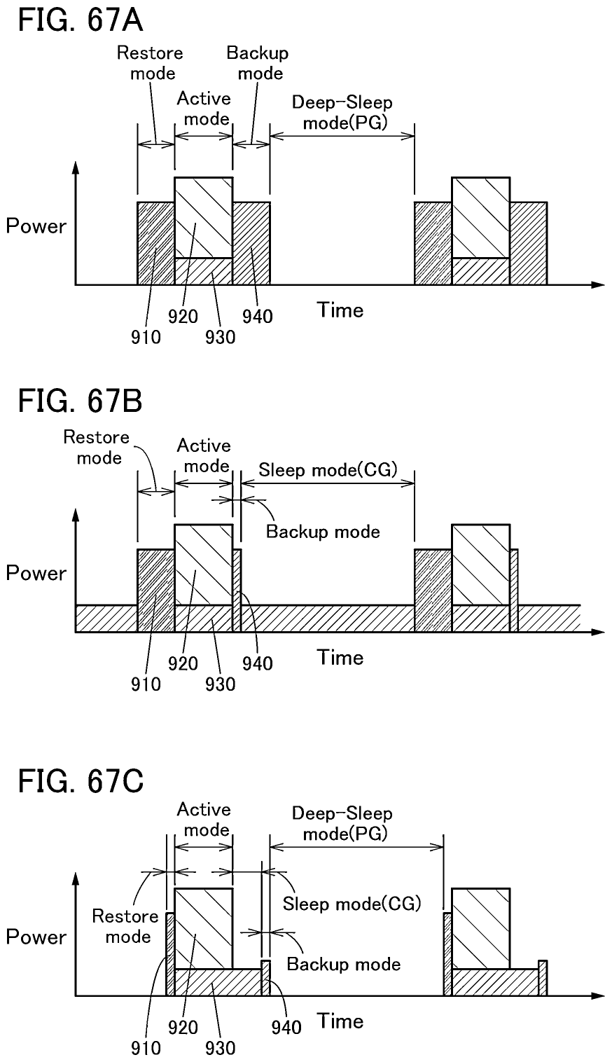

FIG. 67A to FIG. 67C are conceptual diagrams showing changes in power consumption of normally-off processors. In FIG. 67A to FIG. 67C, the horizontal axis represents time (Time) and the vertical axis represents power consumption (Power). FIG. 67A shows changes in power consumption in the case where an MRAM, a ReRAM, a PCM, or the like is used as a nonvolatile memory, FIG. 67B shows changes in power consumption in the case where an SRAM or the like, which is a volatile memory, is used instead of the nonvolatile memory, and FIG. 67C shows changes in power consumption in the case where an OS memory is used as a nonvolatile memory.

In FIG. 67A to FIG. 67C, a period during which a processor or the like performs normal operation (a normal operation period) is Active mode, a period during which data needed for restoration before a standby period is stored (a backup period) is Backup mode, and a period during which the stored data is read after restarting power supply (a restoration period) is shown as Restore mode.

In FIG. 67A and FIG. 67C, a standby period in which power supply is stopped using PG is shown as a Deep-Sleep mode. Note that in the case where a volatile memory is used as a data storing destination, power supply to the volatile memory cannot be stopped while the operation of a processor or the like can be stopped. Thus, in FIG. 67B, a period during which operation of a processor or the like is stopped using CG is shown as Sleep mode.

In FIG. 67A to FIG. 67C, electric power consumed in the restoration period is shown as restoration power 910; electric power consumed in the normal operation period by circuits such as a core (Core), a peripheral circuit (Peripheral), a power management circuit (PMU), and a memory (Memory) excluding the power supply circuits (PUs) is shown as active power 920; electric power consumed by the PUs is shown as PU power 930; and electric power consumed in the backup period is shown as backup power 940. In the normal operation period, the active power 920 and the PU power 930 are consumed.

Data necessary for the restoration is stored in the nonvolatile memory to stop power supply to the processor or the like, whereby Deep-Sleep mode can be achieved (see FIG. 67A). Meanwhile, when a volatile memory is used as a storing destination of data necessary for the restoration, power supply to the volatile memory cannot be stopped; thus, the active power 920 can be reduced but the PU power 930 cannot be reduced (see FIG. 67B).

In addition, a normally-off processor using an MRAM, an SRAM, or the like cannot retain multi-level data or analog data, and thus has a restoration period longer than that of a normally-off processor using the OS memory that enables retention of multi-level data or analog data, needing more restoration power 910. When an OS memory is used as a nonvolatile memory for data storing, the area occupied by the nonvolatile memory can be reduced.

In the normally-off processor using an OS memory, data can be restored in a short time as compared with the normally-off processor using an MRAM, an SRAM, or the like (see FIG. 67C). Furthermore, in Deep-Sleep mode using PG, both of the active power 920 and the PU power 930 can be reduced and a high voltage is not required for data reading and writing. With the use of an OS memory, a normally-off processor with lower power consumption can be achieved.

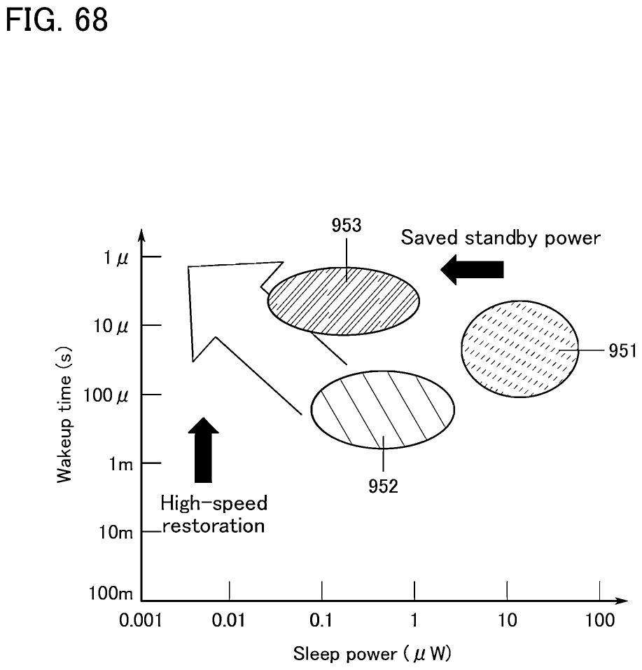

In the normally-off processor, not only lowering power consumption in a standby period (saved standby power) but also shortening a restoration period (high-speed restoration) is required. FIG. 68 is a graph showing an example of the relation of the normally-off processor between power consumption (standby power) of the standby period and time required for restoration. In FIG. 68, the horizontal axis logarithmically represents standby power (Sleep power) and the vertical axis logarithmically represents time (Wakeup time) needed for restoration. The graph in FIG. 68 indicates that the left side of the horizontal axis represents lower power consumption, and the upper side of the vertical axis represents shorter restoration time. Accordingly, the relation of the normally-off processor between power consumption (standby power) of the standby period and the restoration time is preferably positioned on the upper left side of the graph in FIG. 68.

In FIG. 68, a normally-off processor using a volatile memory including SiFETs, such as an SRAM, is roughly included in a first distribution 951. Furthermore, the normally-off processor using a volatile memory such as an MRAM is roughly included in a second distribution 952. Furthermore, the normally-off processor using an OS memory is roughly included in a third distribution 953.

The normally-off processor using a volatile memory such as an SRAM has higher standby power because power is supplied in a standby period but has a restoration period shorter than that of a normally-off processor using a nonvolatile memory such as an MRAM. Furthermore, the normally-off processor using a nonvolatile memory such as an MRAM has low standby power and tends to have a restoration time longer than that of the normally-off processor using a volatile memory such as an SRAM. As just described, the standby power and the high-speed restoration have a trade-off relationship.

Meanwhile, in the normally-off processor using an OS memory, standby power is reduced and the restoration time is short. The normally-off processor using an OS memory can achieve both saved standby power and high-speed restoration.

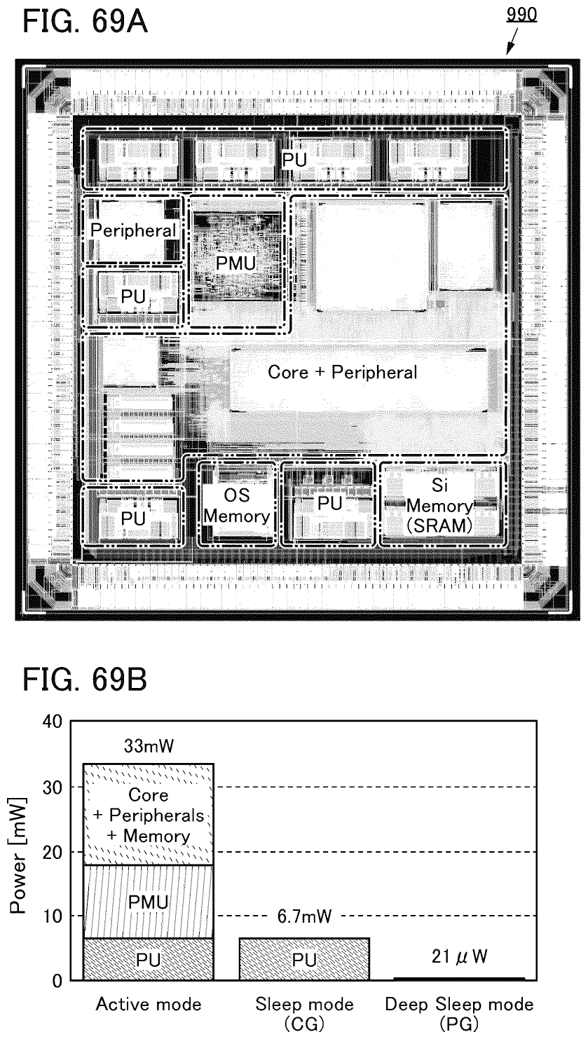

The normally-off processor 990 using an OS memory was assumed, and the power consumption of each of Active mode, Sleep mode, and Deep Sleep mode was estimated. FIG. 69A is a planar layout diagram of the assumed normally-off processor.

The assumed normally-off processor 990 includes a core and its peripheral circuit (Core+Peripheral), a power management circuit (PMU) and its peripheral circuit (Peripheral), a plurality of power supply circuits (PU), an OS memory (OS Memory), and a Si memory (Si Memory). Note that an SRAM was assumed as the Si memory.

FIG. 69B is a graph showing estimation results of power consumption in the case where the normally-off processor 990 operates in Active mode, power consumption in the case where the normally-off processor 990 operates in Sleep mode (CG), and power consumption in the case where the normally-off processor 990 operates in Deep Sleep mode (PG). Note that the vertical axis of the graph illustrated in FIG. 69B shows power consumption (Power) of the operation modes.

In Active mode, all the circuits included in the normally-off processor 990 operate. The power consumption in Active mode is estimated to be 33 mW. In Sleep mode in which the supply of the clock signal is stopped by CG, the power consumption of the circuits other than the PU is the lowest, but the power consumption of the PU is unchanged. The power consumption in Sleep mode is estimated to be 6.7 mW. In Deep sleep mode in which power supply is stopped by PG, electric power of circuits other than the PMU is not consumed. On the other hand, the PMU continues to operate with minimum power consumption for the restoration operation. The power consumption in Deep Sleep mode is estimated to be 21 μW.

As shown in FIG. 69B, the power consumption in Sleep mode is approximately one fifth of the power consumption in Active mode. It is also shown that the power consumption of Deep Sleep mode can be reduced to approximately 1/300 of that of Sleep mode.

### REFERENCE NUMERALS

10_L: display apparatus 10_R: display apparatus, 30: driver circuit, 40: functional circuit, 51: pixel circuit, 61: light-emitting element, 100: electronic device 101: motion detection portion 102: gaze detection portion 103: arithmetic portion 104: communication portion 105: housing

1.-28. (canceled)

29. An electronic device comprising:
a display apparatus comprising:
a functional circuit; and
a display portion comprising a plurality of sub-display portions;
a gaze detection portion configured to detect a gaze of a user; and
an arithmetic portion configured to distribute each of the plurality of sub-display portions into a first section or a second section on the basis of a detection result by the gaze detection portion,
wherein the first section has a first driving frequency,
wherein the second section has a second driving frequency, and
wherein the functional circuit is configured to set the second driving frequency to be lower than the first driving frequency.

30. The electronic device according to claim 29,
wherein the first section has a first resolution,
wherein the second section has a second resolution, and
wherein the functional circuit is configured to set the second resolution to be lower than the first resolution.

31. The electronic device according to claim 29,
wherein the first section has a first luminance,
wherein the second section has a second luminance, and
wherein the functional circuit is configured to set the second luminance to be lower than the first luminance.

32. The electronic device according to claim 29, wherein the first section comprises a region overlapping with a gaze point of the user.

33. The electronic device according to claim 29, wherein the second driving frequency is lower than or equal to a half of the first driving frequency.

34. The electronic device according to claim 29, wherein each of the plurality of sub-display portions comprises a plurality of pixel circuits and a plurality of light-emitting elements.

35. The electronic device according to claim 29,
wherein the display apparatus comprises a plurality of gate driver circuits and a plurality of source driver circuits, and
wherein one of the plurality of gate driver circuits and one of the plurality of source driver circuits are electrically connected to one of the plurality of sub-display portions.

36. The electronic device according to claim 29, further comprising a first layer, a second layer over the first layer, and a third layer over the second layer,
wherein the first layer comprises the plurality of gate driver circuits and the plurality of source driver circuits,
wherein the second layer comprises the plurality of pixel circuits, and
wherein the third layer comprises the plurality of light-emitting elements.

37. The electronic device according to claim 29,
wherein the functional circuit comprises a transistor including a first semiconductor,
wherein each of the plurality of sub-display portions comprises a plurality of pixel circuits and a plurality of light-emitting elements,
wherein the plurality of pixel circuits comprise a transistor including a second semiconductor, and
wherein the first semiconductor and the second semiconductor are different from each other.

38. The electronic device according to claim 37, wherein the first semiconductor comprises silicon.

39. The electronic device according to claim 37, wherein the second semiconductor comprises an oxide semiconductor.

40. The electronic device according to claim 29, further comprising a memory device configured to store image data of each of the plurality of sub-display portions.

41. An electronic device comprising:
a display apparatus comprising:
a functional circuit; and
a display portion comprising a plurality of sub-display portions;
a gaze detection portion configured to detect a gaze of a user;
a distance detection portion; and
an arithmetic portion configured to distribute each of the plurality of sub-display portions into a first section or a second section on the basis of a detection result by the gaze detection portion and a detection result by the distance detection portion,
wherein the first section has a first driving frequency,
wherein the second section has a second driving frequency, and
wherein the functional circuit is configured to set the second driving frequency to be lower than the first driving frequency.

42. The electronic device according to claim 41,
wherein the first section has a first resolution,
wherein the second section has a second resolution, and
wherein the functional circuit is configured to set the second resolution to be lower than the first resolution.

43. The electronic device according to claim 41,
wherein the first section has a first luminance,
wherein the second section has a second luminance, and
wherein the functional circuit is configured to set the second luminance to be lower than the first luminance.

44. The electronic device according to claim 41, wherein the first section comprises a region overlapping with a gaze point of the user.

45. The electronic device according to claim 41, wherein the second driving frequency is lower than or equal to a half of the first driving frequency.

46. The electronic device according to claim 41, wherein each of the plurality of sub-display portions comprises a plurality of pixel circuits and a plurality of light-emitting elements.

47. The electronic device according to claim 41,
wherein the display apparatus comprises a plurality of gate driver circuits and a plurality of source driver circuits, and
wherein one of the plurality of gate driver circuits and one of the plurality of source driver circuits are electrically connected to one of the plurality of sub-display portions.

48. The electronic device according to claim 41, further comprising a first layer, a second layer over the first layer, and a third layer over the second layer,
wherein the first layer comprises the plurality of gate driver circuits and the plurality of source driver circuits,
wherein the second layer comprises the plurality of pixel circuits, and
wherein the third layer comprises the plurality of light-emitting elements.

49. The electronic device according to claim 41,
wherein the functional circuit comprises a transistor including a first semiconductor,
wherein each of the plurality of sub-display portions comprises a plurality of pixel circuits and a plurality of light-emitting elements,
wherein the plurality of pixel circuits comprise a transistor including a second semiconductor, and
wherein the first semiconductor and the second semiconductor are different from each other.

50. The electronic device according to claim 49, wherein the first semiconductor comprises silicon.

51. The electronic device according to claim 49, wherein the second semiconductor comprises an oxide semiconductor.

52. The electronic device according to claim 41, further comprising a memory device configured to store image data of each of the plurality of sub-display portions.

53. An electronic device comprising:
a display apparatus comprising:
a functional circuit;
a display portion comprising a plurality of sub-display portions;
a plurality of gate driver circuits each electrically connected to any one of the plurality of sub-display portions independently; and
a plurality of source driver circuits each electrically connected to any one of the plurality of sub-display portions independently;
a gaze detection portion configured to detect a gaze of a user; and
an arithmetic portion configured to distribute each of the plurality of sub-display portions into a first section or a second section on the basis of a detection result by the gaze detection portion,
wherein the first section has a first driving frequency,
wherein the second section has a second driving frequency,
wherein the functional circuit is configured to set the second driving frequency to be lower than the first driving frequency,
wherein each of the plurality of gate driver circuits and the plurality of source driver circuits comprises a transistor including a first semiconductor,
wherein each of the plurality of sub-display portions comprises a plurality of pixel circuits and a plurality of light-emitting elements,
wherein each of the plurality of pixel circuits comprises a transistor including a second semiconductor, and
wherein the first semiconductor and the second semiconductor are different from each other.

54. The electronic device according to claim 53,
wherein the first section has a first resolution,
wherein the second section has a second resolution, and
wherein the functional circuit is configured to set the second resolution to be lower than the first resolution.

55. The electronic device according to claim 53,
wherein the first section has a first luminance,
wherein the second section has a second luminance, and
wherein the functional circuit is configured to set the second luminance to be lower than the first luminance.

56. The electronic device according to claim 53, wherein the first section comprises a region overlapping with a gaze point of the user.

57. The electronic device according to claim 53, wherein the second driving frequency is lower than or equal to a half of the first driving frequency.

58. The electronic device according to claim 53, further comprising a first layer, a second layer over the first layer, and a third layer over the second layer,
wherein the first layer comprises the plurality of gate driver circuits and the plurality of source driver circuits,
wherein the second layer comprises the plurality of pixel circuits, and
wherein the third layer comprises the plurality of light-emitting elements.

59. The electronic device according to claim 53, wherein the first semiconductor comprises silicon.

60. The electronic device according to claim 53, wherein the second semiconductor comprises an oxide semiconductor.

61. The electronic device according to claim 53, further comprising a memory device configured to store image data of each of the plurality of sub-display portions.

62. An electronic device comprising:
a display apparatus comprising:
a functional circuit; and
a display portion comprising a plurality of sub-display portions;
a touch sensor configured to detect a selected position on the display portion; and
an arithmetic portion,
wherein the arithmetic portion is configured to distribute each of the plurality of sub-display portions into a first section or a second section on the basis of a detection result by the touch sensor,
wherein the first section has a first driving frequency,
wherein the second section has a second driving frequency, and
wherein the functional circuit is configured to set the second driving frequency to be lower than the first driving frequency.

63. The electronic device according to claim 62,
wherein the first section has a first resolution,
wherein the second section has a second resolution, and
wherein the functional circuit is configured to set the second resolution to be lower than the first resolution.

64. The electronic device according to claim 62,
wherein the first section has a first luminance,
wherein the second section has a second luminance, and
wherein the functional circuit is configured to set the second luminance to be lower than the first luminance.

65. The electronic device according to claim 62, wherein the first section comprises a region overlapping with the selected position.
